(19) United States
(12) Patent Application Publication
(10) Pub. No.: US 2026/0211319 A1
(43) Pub. Date: Jul. 23, 2026

(54) RESIST COMPOSITION, LAMINATE AND PATTERNING PROCESS

(71) Applicant: SHIN-ETSU CHEMICAL CO., LTD., Tokyo (JP)

(72) Inventors: Satoshi KUSAMA, Joetsu-shi (JP); Kousuke OHYAMA, Joetsu-shi (JP); Shun KIKUCHI, Joetsu-shi (JP); Ryo NISHIKAWA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/447,530

(22) Filed: Jan. 13, 2026

(30) Foreign Application Priority Data
Jan. 20, 2025 (JP) 2025-008091

(51) Int. Cl. G03F 7/004; G03F 7/00; G03F 7/038; G03F 7/039; G03F 7/20

(52) U.S. Cl. CPC G03F 7/0045; G03F 7/0388; G03F 7/039; G03F 7/2004; G03F 7/70033

(57) ABSTRACT

The present invention provides a resist composition which can achieve high sensitivity and high resolvability in a patterning process. A resist composition containing a hypervalent iodine compound represented by the following formula (1), a carboxy group-containing compound, and a solvent.

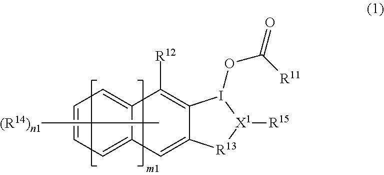

R¹¹ is a halogen atom, or a hydrocarbyl group having 1 to 10 carbon atoms and optionally containing a heteroatom. R¹² is a halogen atom, or a hydrocarbyl group having 1 to 40 carbon atoms and optionally containing a heteroatom. R¹⁴ is a halogen atom, or a hydrocarbyl group having 1 to 40 carbon atoms and optionally containing a heteroatom. R¹³ is a carbonyl group, or a hydrocarbylene group having 1 to 10 carbon atoms and optionally containing a heteroatom. X¹ is an oxygen atom, a nitrogen atom, or a sulfur atom, and when X¹ is a nitrogen atom, R¹⁵ is present.

### TECHNICAL FIELD

The present invention relates to a resist composition, a laminate and a patterning process.

### BACKGROUND ART

Along with the expansion of the IoT market, LSIs are further required to have higher degree of integration, higher speed and lower power consumption, and the miniaturization of pattern rules is in rapid progress. In particular, logic devices lead the miniaturization. State-of-the-art miniaturization techniques carried out include volume manufacturing of 10-nm node devices by double patterning, triple patterning and quadruple patterning with ArF immersion lithography, and furthermore there are advanced studies about 7-nm node devices with next-generation extreme-ultraviolet (EUV) lithography at a wavelength of 13.5 nm.

With the progression of miniaturization, image blurs due to acid diffusion are problematic (Non Patent Document 1). In order to ensure the resolvability in fine patterns with a processing dimension of 45 nm or less, there is proposed the importance of not only an enhancement in dissolution contrast, which has been conventionally proposed, but also control of acid diffusion (Non Patent Document 2). However, chemically-amplified resist compositions are increased in sensitivity and contrast by acid diffusion, and therefore, if acid diffusion is tried to be suppressed as much as possible by a reduction in post-exposure bake (PEB) temperature or a decrease in PEB time, such sensitivity and contrast remarkably deteriorate.

It is effective to suppress acid diffusion by addition of acid generators that generate bulky acids. There is then proposed copolymerization of acid generators which are onium salts having polymerizable olefins, with polymers. However, patterning on resist films with a processing dimension of 16 nm or less is considered not to be able to be achieved with chemically-amplified resist compositions from the viewpoint of acid diffusion, and non-chemically-amplified resist compositions are demanded to be developed.

Examples of materials for non-chemically-amplified resist compositions include polymethyl methacrylate (PMMA). PMMA is a positive-type resist material that is enhanced in solubility in a developer which is an organic solvent by virtue of cleavage of a mainchain by EUV irradiation and thus a reduction in molecular weight.

Hydrogen silsesquioxane (HSQ) is a negative-type resist material that is made insoluble in an alkali developer by virtue of crosslinking by a condensation reaction of silanol generated by EUV irradiation. Chlorine-substituted calixarene also serves as a negative-type resist material. These negative type resist materials are small in molecular size before crosslinking and do not cause any blurs due to acid diffusion, therefore are small in edge roughness and very high in resolvability, and therefore are used as pattern transfer materials for exhibiting the resolving limit of an exposure apparatus. However, these materials are insufficient in sensitivity and are required to be further improved.

Examples of factors making material development for EUV lithography difficult include a small number of photons in EUV exposure. The energy of EUV is much higher than that of ArF excimer laser light, and the number of photons in EUV exposure is one-fourteenth that of ArF exposure. Furthermore, the dimension of patterns formed in EUV exposure is less than half that in ArF exposure. Therefore, EUV exposure is easily affected by the variation in number of photons. The variation in number of photons in the region of radiation light at extremely short wavelengths is shot noise as a physical phenomenon, and the influence of this shot noise cannot be eliminated. Therefore, so-called probability theory (Stochastics) attracts attention. Although the influence of shot noise cannot be eliminated, how to reduce this influence is discussed. There is observed a phenomenon in which the influence of shot noise leads to not only increases in critical dimension uniformity (CDU) and line width roughness (LWR), but also blocking of holes at a probability of one several millionth. Such blocking of holes causes electric conduction failure not to allow for transistor operations, and therefore adversely affects the performance of the entire device. In a case where practical sensitivity is considered, resist compositions mainly containing PMMA or HSQ are largely affected by Stochastics, and cannot achieve the desired resolving performance.

With respect to methods for reducing the influence of shot noise by resists, introduction of elements with large absorption of EUV light attracts attention. Patent Document 1 proposes a chemically-amplified resist composition containing an iodine atom with large absorption of EUV light. However, as described above, chemically-amplified resist compositions cannot realize excellent resolving performance in EUV lithography in which processing dimensions will be hereafter increasingly miniaturized.

Patent Document 2 proposes a negative-type resist composition in which a tin compound is used. This composition mainly contains a tin element with large absorption of EUV light, and therefore Stochastics can be improved and high sensitivity/high resolvability can be realized. However, so-called such metal resists have many problems such as insufficient solubility in solvents for resists, storage stability, and defects due to residues after etching.

On the contrary, Patent Document 3 proposes a positive-type resist composition in which a hypervalent iodine compound is used. This composition contains an iodine element with large absorption of EUV light, and therefore Stochastics can be improved and high sensitivity/high resolvability can be realized as in metal resists. Furthermore, this composition is constituted from only organic molecules, and therefore the problems of metal resists, such as solubility in developer and defects due to residues, can be improved. However, performance in the case of use as a resist material is still not satisfactory, and there is a demand for development of a resist material useful for further fine patterning.

### CITATION LIST

### Patent Literature

Patent Document 1: JP 2018-5224 A
Patent Document 2: JP 2021-503482 A
Patent Document 3: JP 2023-167368 A

### Non Patent Literature

Non Patent Document 1: SPIE Vol. 5039 p 1 (2003)
Non Patent Document 2: SPIE Vol. 6520 p 65203L-1 (2007)

### SUMMARY OF INVENTION

### Technical Problem

The present invention has been made in view of the above circumstances, and an object thereof is to provide a resist composition which can achieve high sensitivity and high resolvability in a patterning process, a laminate including a resist film obtained from the resist composition, and a patterning process in which the resist composition is used.

### Solution to Problem

In order to solve the above problems, the present invention provides a resist composition comprising a hypervalent iodine compound represented by the following formula (1);
a carboxy group-containing compound; and
a solvent:

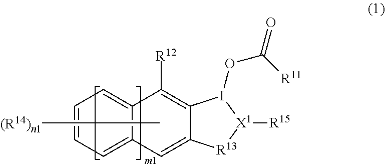

wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom; and
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.

Such a resist composition of the present invention has an iodine atom having high ability to absorb EUV light. Furthermore, the hypervalent iodine compound represented by the formula (1) has a substituent R¹² introduced to the ortho-position relative to such an iodine atom and thus is enhanced in photodegradability by strain energy due to steric hindrance. As a result, the resist composition of the present invention can exhibit higher sensitivity as compared with the case of use of only other hypervalent iodine compound. In other words, the resist composition of the present invention can achieve high sensitivity, high resolvability and low LWR in a patterning process, by virtue of these characteristics.

The carboxy group-containing compound is preferably a polymer containing a repeating unit represented by the following formula (2) or a compound represented by the following formula (3):

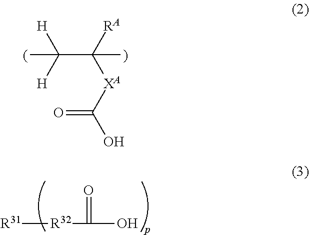

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a mainchain;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³1 is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted with a group containing a heteroatom, and some of —CH₂— in the p-valent hydrocarbon group are each optionally substituted with a group containing a heteroatom; and
R³² is a single bond or a hydrocarbylene group having 1 to 10 carbon atoms, some or all of hydrogen atoms in the hydrocarbylene group are each optionally substituted with a group containing a heteroatom, and some of —CH₂— in the hydrocarbylene group are each optionally substituted with a group containing a heteroatom; and when “p” is 2, 3 or 4, R³²s are the same as or different from each other.

Such a resist composition comprising a carboxy group-containing compound can more certainly achieve high sensitivity, high resolvability and low LWR in a patterning process.

The resist composition preferably further comprises at least one hypervalent iodine compound represented by the following formula (4) or (5):

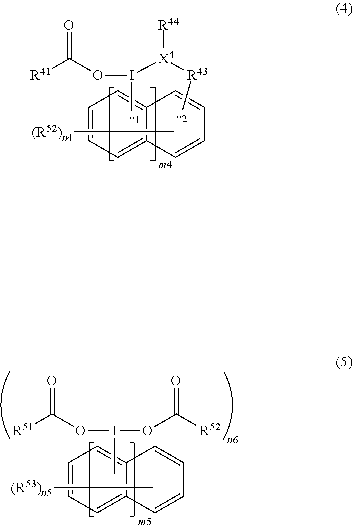

wherein m4 and m5 are each an integer of 0 to 2;
n4 is an integer of 0 to 3 when m4 is 0, or is an integer of 0 to 5 when m4 is 1, or is an integer of 0 to 7 when m4 is 2;
when m5 is 0, n6 is an integer of 1 to 3, n5 is an integer of 0 to 5, and 1≤(n5+n6)≤6 is satisfied;
when m5 is 1, n6 is an integer of 1 to 3, n5 is an integer of 0 to 7, and 1≤(n5+n6)≤8 is satisfied;
when m5 is 2, n6 is an integer of 1 to 3, n5 is an integer of 0 to 9, and 1≤(n5+n6)≤10 is satisfied;
*1 and *2 each represent a point of attachment to a carbon atom in an aromatic ring in the formula, provided that *1 and *2 have to be bound to adjacent carbon atoms in an aromatic ring;
R⁴¹ is a halogen atom, or a hydrocarbyl group having 1 to 10 carbon atoms and optionally containing a heteroatom;
R⁴² is a halogen atom, or a hydrocarbyl group having 1 to 40 carbon atoms and optionally containing a heteroatom; and when n4 is 2 to 7, R⁴²s are the same as or different from each other, and plural R⁴²s are optionally bound to each other to form a ring together with carbon atoms in an aromatic ring to which these are bound, provided that R⁴² is not bound to any carbon atom in an aromatic ring adjacent to *1;
R⁴³ is a carbonyl group, or a hydrocarbylene group having 1 to 10 carbon atoms and optionally containing a heteroatom;
X⁴ is an oxygen atom, a nitrogen atom, or a sulfur atom, and when X⁴ is a nitrogen atom, R⁴⁴ is present; and R⁴⁴ is a hydrogen atom, a carbonyl group, a halogen atom, or a hydrocarbyl group or ester having 1 to 20 carbon atoms and optionally containing a heteroatom;
R⁵¹ and R⁵² are each independently a halogen atom, or a hydrocarbyl group having 1 to 10 carbon atoms and optionally containing a heteroatom; and when n6 is 2 to 3, R⁵¹s and R⁵²s are the same as or different from each other; and
R⁵³ is a halogen atom, or a hydrocarbyl group having 1 to 40 carbon atoms and optionally containing a heteroatom; and when n5 is 2 to 9, R⁵³s are the same as or different from each other, and plural R⁵³s are optionally bound to each other to form a ring together with carbon atoms in an aromatic ring to which these are bound.

By further containing the hypervalent iodine compound represented by the formula (4) or formula (5), reactivity against light can be controlled and thus sensitivity can be adjusted.

The present invention also provides a laminate comprising:
a substrate; and
a resist film on the substrate, the resist film being obtained from the resist composition of the present invention.

In the laminate of the present invention, comprising a resist film obtained from the resist composition of the present invention, the resist film not only has high sensitivity and furthermore exhibits excellent limit resolvability and is effective for precise fine-processing, but also can be applied to both of positive-type patterning and negative-type patterning. Therefore, the laminate of the present invention can be widely used in a variety of applications and is highly useful for resist process techniques.

In this case, a resist underlayer film is optionally further provided between the substrate and the resist film.

When a resist underlayer film is necessary for patterning, such a resist underlayer film can also be appropriately disposed between the substrate and the resist film.

The resist film can contain a product of a ligand exchange reaction between the hypervalent iodine compound and the carboxy group-containing compound.

The resist film optionally contains, for example, a product of a ligand exchange reaction between the hypervalent iodine compound and the carboxy group-containing compound, but not limited thereto.

The present invention also provides a patterning process comprising the steps of:
forming a resist film on a substrate or on a resist underlayer film on a substrate on which the resist underlayer film is laminated, with the resist composition of the present invention;
exposing the resist film to a high energy ray; and
developing the resist film having been exposed with a developer.

Such a patterning process of the present invention, in which the resist composition of the present invention is used, thus can achieve high sensitivity, high resolvability and low LWR to be achieved.

For example, an i-ray, a KrF excimer laser, an ArF excimer laser, an electron beam or an extreme-ultraviolet ray can be used as the high energy ray.

Any of various high energy rays described above can be used as the high energy ray.

For example, a developer that dissolves an exposed area and that does not dissolve an unexposed area can be used as the developer.

Alternatively, a developer that dissolves an unexposed area and that does not dissolve an exposed area can also be used as the developer.

Thus, the patterning process of the present invention can also be applied to both of positive-type patterning and negative-type patterning.

### Advantageous Effects of Invention

As described above, the resist composition of the present invention can achieve both high sensitivity and high resolution in a patterning process, for example, photolithography with a high energy ray, in particular, electron beam (EB) lithography and EUV lithography. Therefore, the resist composition of the present invention is extremely effective for formation of a fine pattern.

The laminate of the present invention can also be applied to both of positive-type patterning and negative-type patterning and therefore can be widely used in a variety of applications and is highly useful for resist process techniques.

The patterning process of the present invention can achieve both high sensitivity and high resolvability.

### BRIEF DESCRIPTION OF DRAWING

FIG. 1 is a schematic cross-sectional view showing one example of the laminate of the present invention.

### DESCRIPTION OF EMBODIMENTS

As described above, the development of a resist composition which can achieve both high sensitivity and high resolvability in the patterning process has been required.

The present inventors have made intensive studies about the above problems, and as a result, have found that a resist composition mainly containing predetermined hypervalent iodine compound and carboxy group-containing polymer provides a resist film having extremely high sensitivity and also exhibiting excellent resolving power, and is extremely effective for precise fine-processing, and thus the present invention has been completed based on this finding.

That is, the present invention relates to a resist composition containing:
a hypervalent iodine compound represented by the following formula (1);
a carboxy group-containing compound; and
a solvent:

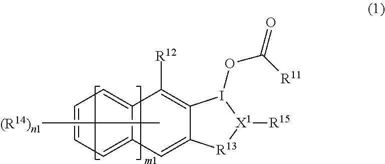

wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom; and
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.

Hereinafter, the present invention is described in detail, but the present invention is not limited thereto.

### [Resist Composition]

The resist composition of the present invention contains, as main components, a hypervalent iodine compound represented by the following formula (1), a carboxy group-containing compound, and a solvent:

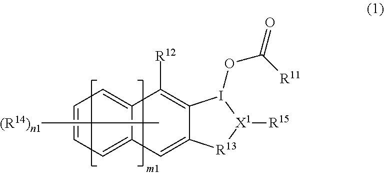

wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom; and
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.

The resist composition of the present invention contains the hypervalent iodine compound represented by the formula (1) and the carboxy group-containing compound as main components as described above. Meanwhile, the resist composition of the present invention does not have to contain any acid-labile group-containing base polymer and photo-acid generator which are contained in a conventional chemically-amplified resist composition. However, the resist composition of the present invention can form a positive-type or negative-type pattern by virtue of the difference in solubility generated between an exposed section and an unexposed section particularly by EB or EUV exposure. Without wishing to be bound by any theory, the mechanism, although not completely clear and not intended to be bound to any theory, is presumed as follows, for example.

The hypervalent iodine compound represented by the formula (1) is a compound having a three-coordinate hypervalent iodine atom having a carboxylate ligand. It is considered that such a three-coordinate iodine compound is mixed with a carboxylic acid compound to result in exchange of the carboxylate ligand in an equilibrium reaction. If the original carboxylate ligand can be here removed by any process, a hypervalent iodine compound having a new ligand is generated. For example, relatively easily available 3-methyl-1-acetoxy-1,2-benziodoxol-3-(1H)-one as the hypervalent iodine compound and a large-molecular weight carboxylic acid compound are mixed to generate acetic acid having a low boiling point generated, and then the acetic acid is removed, resulting in the complete of ligand exchange. Here, a polymer is provided in which the carboxy group-containing compound is crosslinked by the hypervalent iodine compound.

The polymer crosslinked with the hypervalent iodine compound is generated during film formation. The reason is that such a crosslinked polymer, even if synthesized in advance, is not dissolved in many organic solvents and therefore a solution cannot be prepared. It is presumed that this is caused, because the hypervalent iodine compound which is naturally highly-polarized and therefore is low in solvent solubility much further deteriorates in solubility due to use of the carboxy group-containing compound as a ligand. It is here desirable to provide a step of removing the original low-molecular-weight carboxylic acid component in film formation and in a subsequent baking step, thereby not only completing a ligand exchange reaction, but also forming a resist film.

The resist film in the present invention thus formed on the substrate is changed in polarity due to decomposition of the hypervalent iodine compound as a main component by light, and a pattern is formed in a development step. Herein, any of a positive type or negative type pattern can be formed by appropriately selecting the developer.

The resist composition of the present invention can be a positive type or a negative type by selection of the components. In the case of a positive type, a polymer to which the hypervalent iodine compound is bound during film formation is contained. This compound is decomposed by light and formed into a monovalent iodine compound, and at the same time the binding between the carboxy group-containing compound and the hypervalent iodine compound is released and the molecular weight is also decreased. It is presumed that, as a result, a positive-type pattern in which an exposed area is to be removed by an organic solvent is formed.

On the other hand, in the case of a negative type, a polymer crosslinked by the hypervalent iodine compound, the crosslinked polymer generated during film formation, is contained. The polymer is decomposed by light, resulting in the occurrence of replacing of crosslinking or binding, and the occurrence of an increase in molecular weight and polarity conversion. It is presumed that, as a result, a negative-type pattern in which an unexposed area is to be removed by an aqueous alkali solution is formed.

It can be said from the above presumptions that the resist composition of the present invention is a non-chemically-amplified resist composition. Unlike a conventional chemically-amplified resist composition, the resist composition of the present invention does not require any acid-labile group-containing base polymer and photo-acid generator, and therefore an adverse effect due to acid diffusion (for example, image blurs) is not caused, and a fine pattern can be resolved.

The resist composition of the present invention is extremely effective particularly for EUV lithography. The reason for this is that the resist composition of the present invention is characterized in that the resist composition has an iodine atom having high ability to absorb EUV light and furthermore the hypervalent iodine compound represented by the formula (1) has a substituent R¹² introduced to the ortho-position relative to such an iodine atom and thus is enhanced in photodegradability by strain energy due to steric hindrance, to enable higher sensitivity to be achieved as compared with the case of use of only other hypervalent iodine compound. In other words, the resist composition of the present invention can achieve high sensitivity, high resolvability and low LWR in a patterning process, by virtue of these characteristics.

As a resist composition for EUV lithography, capable of forming a fine pattern, a metal resist is proposed, which contains as a main component, a compound of tin as a metal having high ability to absorb EUV light as in an iodine atom (for example, Patent Document 2). However, as described above, such a metal resist has many problems, for example, insufficient solubility in a solvent, storage stability, and defects by the residue after etching due to inclusion of a metal element. In this regard, the resist composition of the present invention, in which no metal element is used, thus is more advantageous than a metal resist in terms of defects, and does not have the problem about solubility in a solvent. Furthermore, the resist composition of the present invention can be applied to any case of a positive type and a negative type, and therefore can be widely used in a variety of applications. For example, a metal resist adopted in negative-type development in a contact hole forming step requires a reverse process step after pillar patterning, but such a reverse process step is not necessary about a positive type. Accordingly, it can be said that the resist composition of the present invention is more useful than a metal resist also from the viewpoint of process simplicity.

JP 2015-180928 A and JP 2018-95853 A describe a resist composition containing a hypervalent iodine compound as an additive, and a resist composition in which a hypervalent iodine compound is incorporated into a polymer skeleton of a base polymer. However, these Patent Documents merely describe the resist composition characterized by being able to be improved in line edge roughness, and mention neither the ability of such a hypervalent iodine compound to be photolytically degraded, nor the ability of such a hypervalent iodine compound to function as a material of a non-chemically-amplified resist composition, at all. Furthermore, according to the description and specific examples of the blending amount thereof, such a hypervalent iodine compound does not serve as a main component. In addition, Patent Document 3 proposes a positive type resist composition in which a hypervalent iodine compound is used, but does not describe the hypervalent iodine compound represented by the formula (1) in the present invention, and does not mention that by virtue of strain energy due to steric hindrance by introduction of a substituent to the ortho-position relative to an iodine atom, photodegradability is improve, and then sensitivity is further improved. Accordingly, it is considered that the non-chemically-amplified resist composition according to the present invention, having extremely high sensitivity, also exhibiting excellent resolving power, and being extremely effective for precise fine-processing, is not conceived from these Patent Documents. That is, the present invention can be said to provide resist composition and patterning process which are clearly novel.

Hereinafter, each component in the resist composition of the present invention is described.

### [Hypervalent Iodine Compound]

The hypervalent iodine compound is a three-coordinate hypervalent iodine compound represented by the following formula (1):

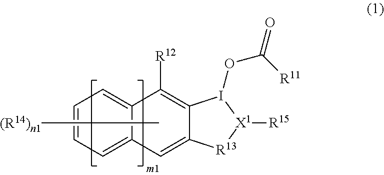

wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom; and
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.

In the formula (1), m1 is an integer of 0 to 2, n1 is an integer of 0 to 3 when m1 is 0, or is an integer of 0 to 5 when m1 is 1, or is an integer of 0 to 7 when ml is 2. n1 is preferably 0 to 7, more preferably 0 to 5, further preferably 0 to 3, still further preferably 0 to 1, most preferably 0.

In the formula (1), R¹¹ is a halogen atom, or a hydrocarbyl group having 1 to 10 carbon atoms and optionally containing a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be any of linear, branched or cyclic. Specific examples thereof include alkyl groups each having 1 to 10 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group and an adamantyl group; alkenyl groups each having 2 to 10 carbon atoms, such as a vinyl group and an allyl group; aryl groups each having 6 to 10 carbon atoms, such as a phenyl group and a naphthyl group; and any group obtained by combination thereof. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R¹¹ is preferably a hydrocarbyl group having 1 to 4 carbon atoms or a fluorinated hydrocarbyl group having 1 to 4 carbon atoms, more preferably a hydrocarbyl group having 1 to 4 carbon atoms.

In the formula (1), R¹² is a halogen atom, or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be any of linear, branched or cyclic. Specific examples thereof include alkyl groups each having 1 to 40 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R¹² is particularly preferably a hydrocarbyl group having 1 to 40 carbon atoms and optionally containing a heteroatom.

In the formula (1), R¹⁴ is a halogen atom, or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be any of linear, branched or cyclic. Specific examples thereof include alkyl groups each having 1 to 40 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. When n1 is 2 or more, R¹⁴s are the same as or different from each other. In addition, plural R¹⁴s are optionally bound to each other to form a ring together with carbon atoms in an aromatic ring to which these are bound.

In the formula (1), R¹³ is a carbonyl group or a hydrocarbylene group having 1 to 10 carbon atoms and optionally containing a heteroatom. The hydrocarbylene group having 1 to 10 carbon atoms may be saturated or unsaturated, and may be any of linear, branched or cyclic. Specific examples thereof include alkylene groups each having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group and a decane-1,10-diyl group; cyclic saturated hydrocarbylene groups each having 3 to 10 carbon atoms, such as a cyclopentanediyl group, a cyclohexanediyl group, a norbornanediyl group, an adamantanediyl group and a tricyclo[5.2.1.0^{2,6}]decanediyl group; alkenylene groups each having 2 to 10 carbon atoms, such as a vinylene group and a propynylene group; arylene groups each having 6 to 10 carbon atoms, such as a phenylene group, a methyl phenylene group, an ethyl phenylene group, a n-propyl phenylene group, an isopropyl phenylene group, a n-butyl phenylene group and a naphthylene group; and any group obtained by combination thereof. In addition, some or all of hydrogen atoms in the hydrocarbylene group are each optionally substituted with a group containing a heteroatom such as an oxygen atom, a sulfur atom, a nitrogen atom, or a halogen atom, some of —CH₂— in the hydrocarbylene group are each optionally substituted with a group containing a heteroatom such as an oxygen atom, a sulfur atom, or a nitrogen atom, and as a result, a hydroxy group, a cyano group, an alkyl halide group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R¹³ is preferably a carbonyl group, a hydrocarbylene group having 1 to 4 carbon atoms or a fluorinated hydrocarbylene group having 1 to 4 carbon atoms.

In the formula (1), X¹ is an oxygen atom, a nitrogen atom, or a sulfur atom, and when X¹ is a nitrogen atom, R¹⁵ is present. In other words, when X¹ is a nitrogen atom, the formula (1) contains an NR¹⁵ group. In this regard, when X¹ is an oxygen atom or a sulfur atom, the formula (1) contains no R¹⁵ group.

In the formula (1), R¹⁵ is a hydrogen atom, a carbonyl group, a halogen atom, or a hydrocarbyl group or ester having 1 to 20 carbon atoms and optionally containing a heteroatom. Specific examples of the halogen atom include a fluorine atom, a chlorine atom, a bromine atom, and an iodine atom. The hydrocarbyl group having 1 to 20 carbon atoms may be saturated or unsaturated, and may be any of linear, branched or cyclic. Specific examples thereof include alkyl groups each having 1 to 20 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 20 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 20 carbon atoms, such as a phenyl group, a naphthyl group and an anthracenyl group. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained.

Specific examples of the hypervalent iodine compound represented by the formula (1) include the following hypervalent iodine compounds, but not limited thereto. It should be noted that, in the following formulae, Me is a methyl group and Ph is a phenyl group.

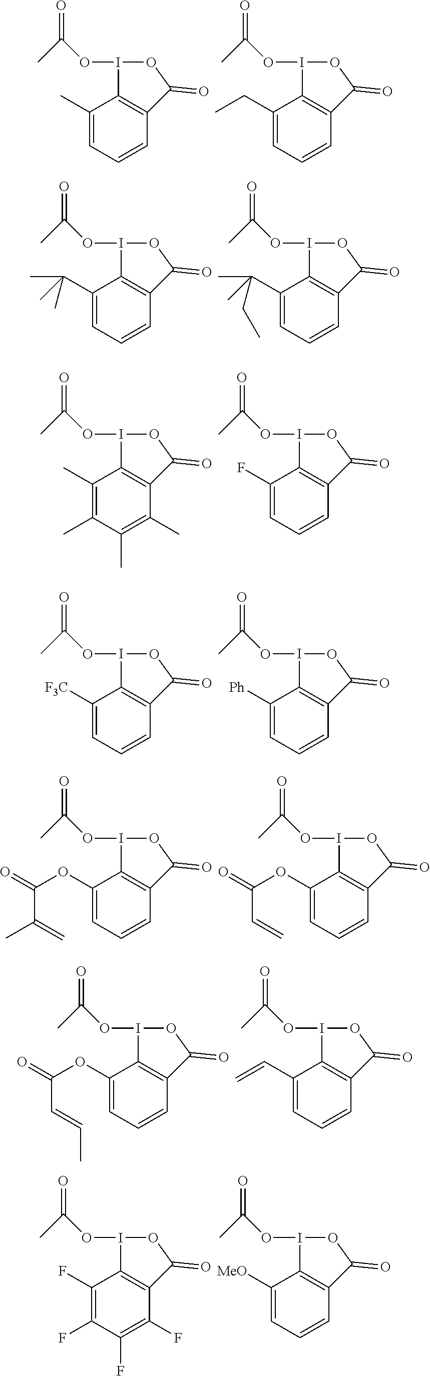

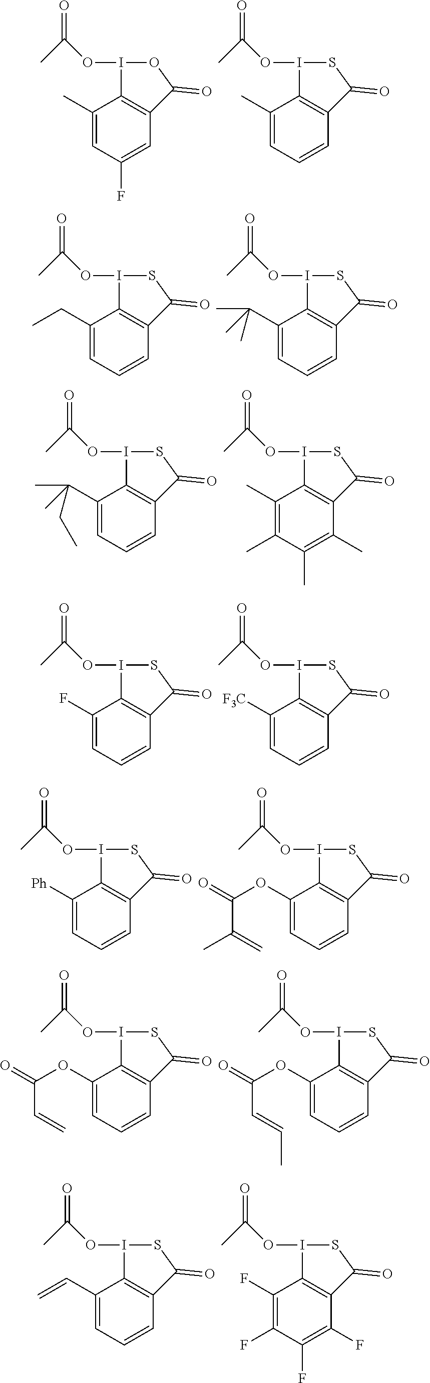

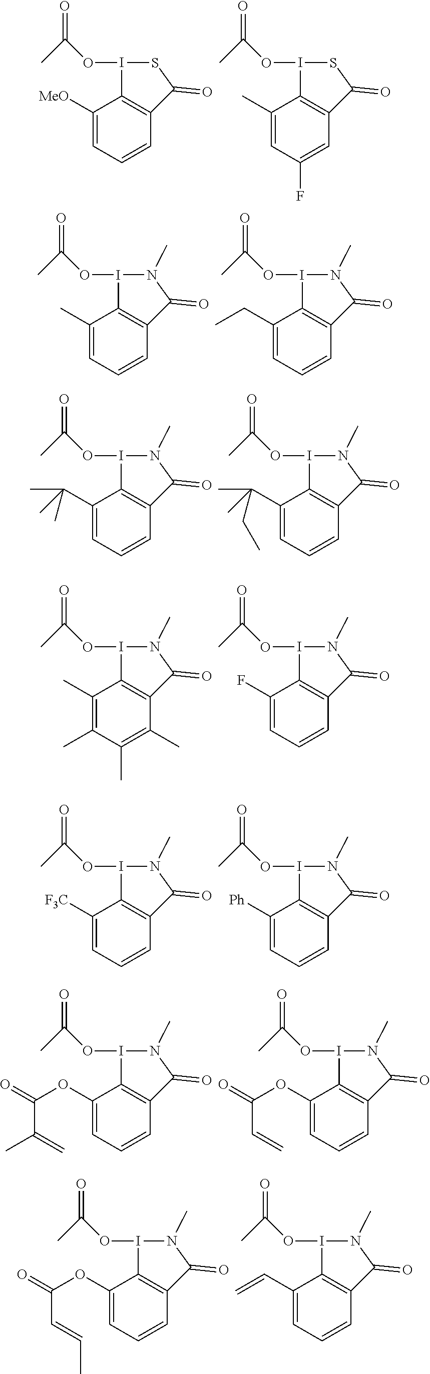

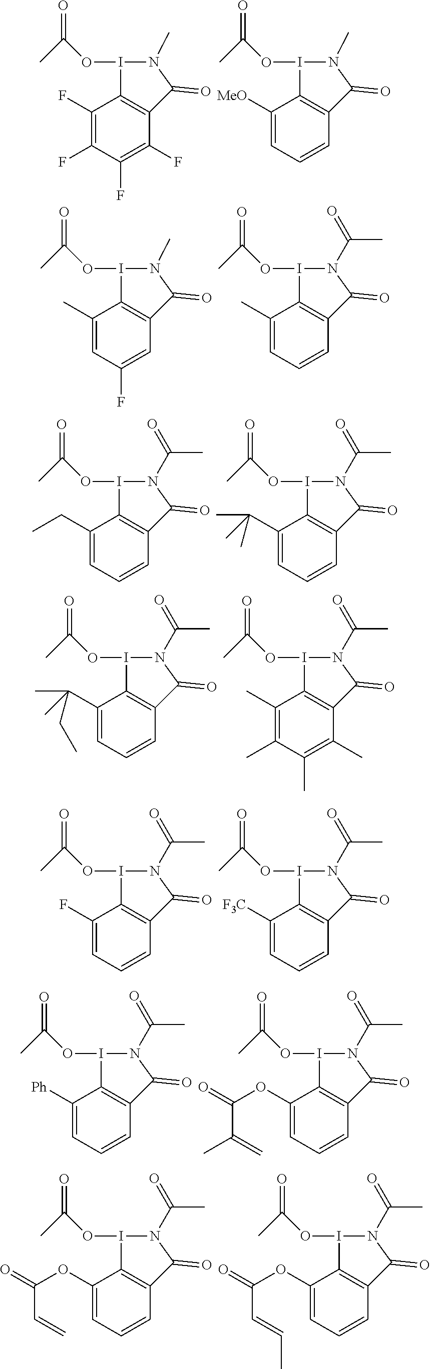

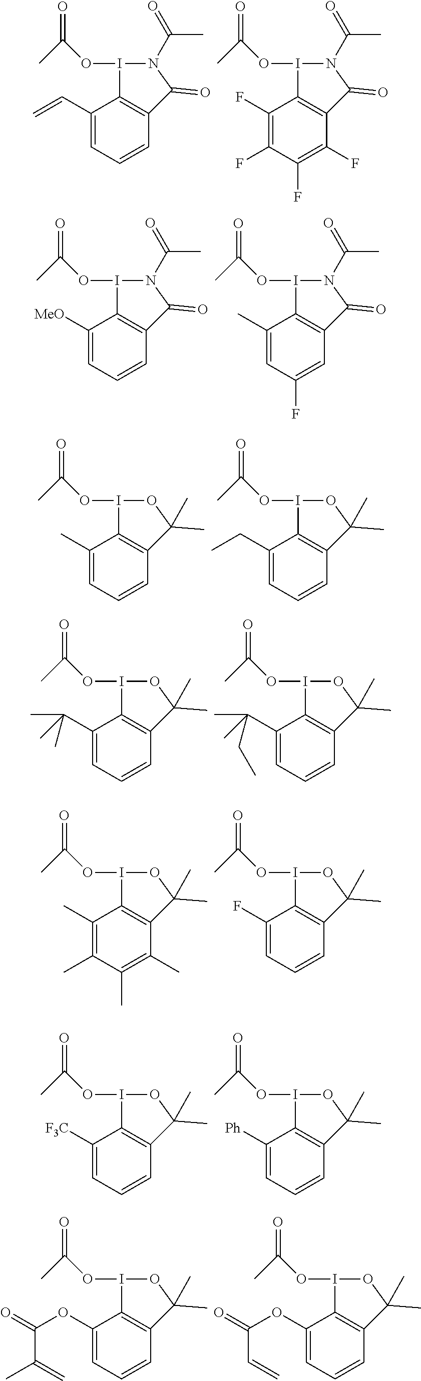

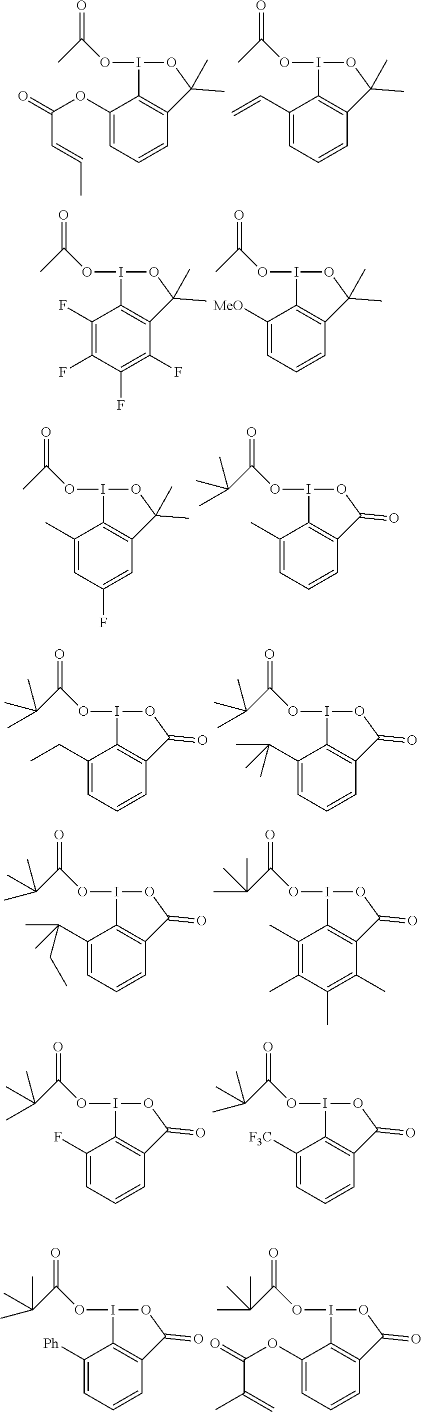

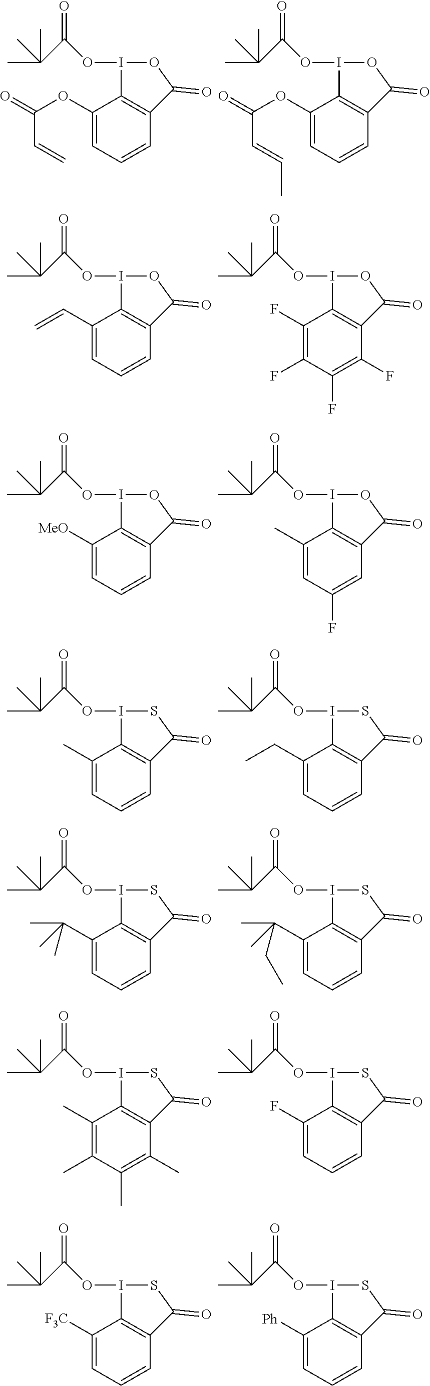

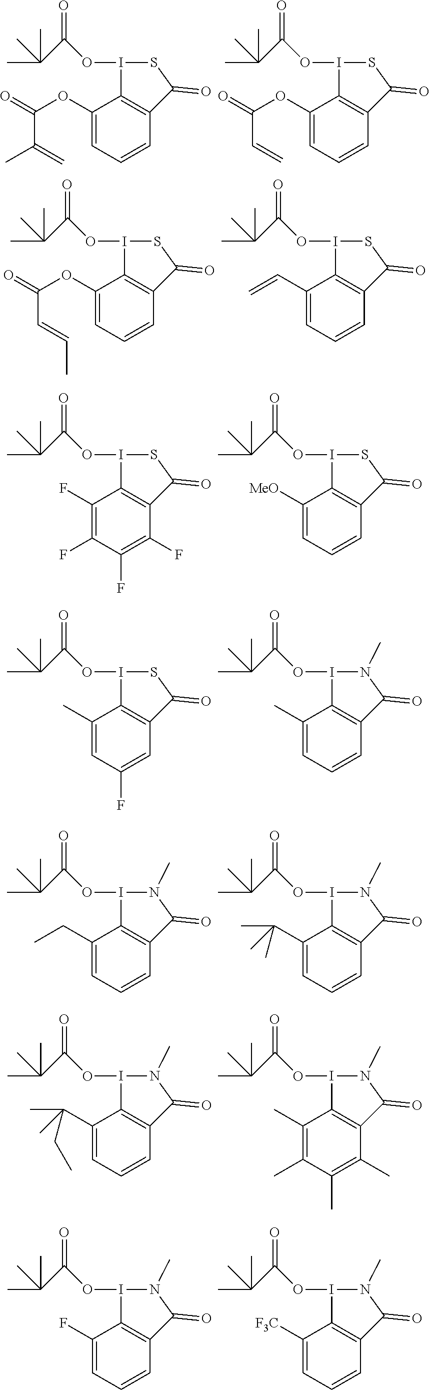

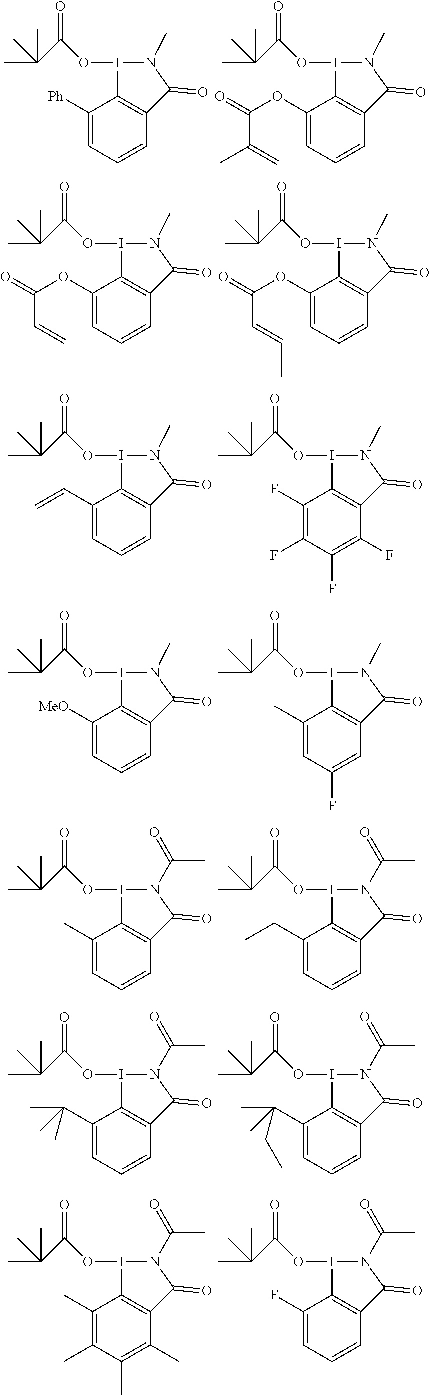

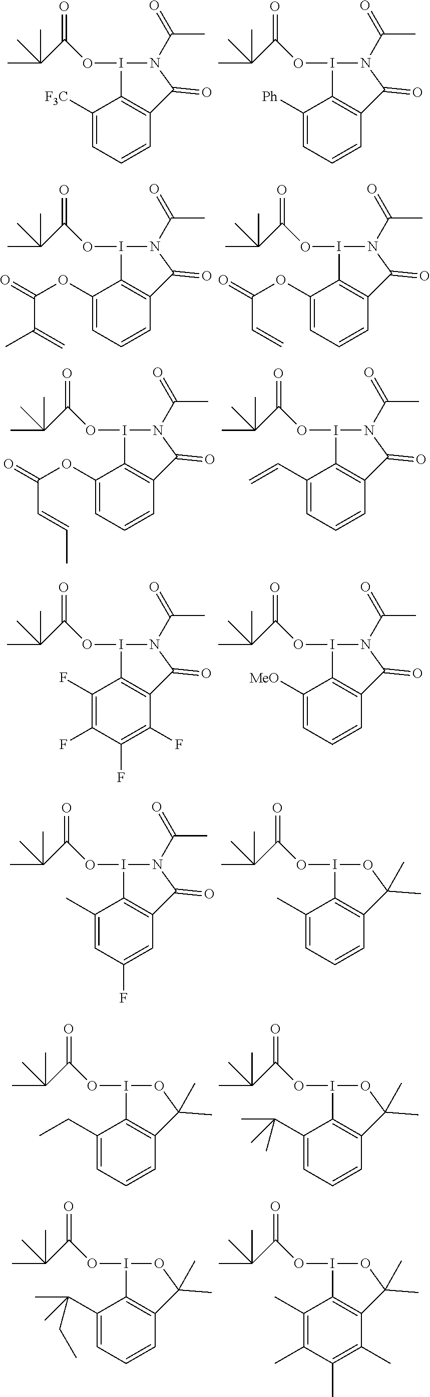

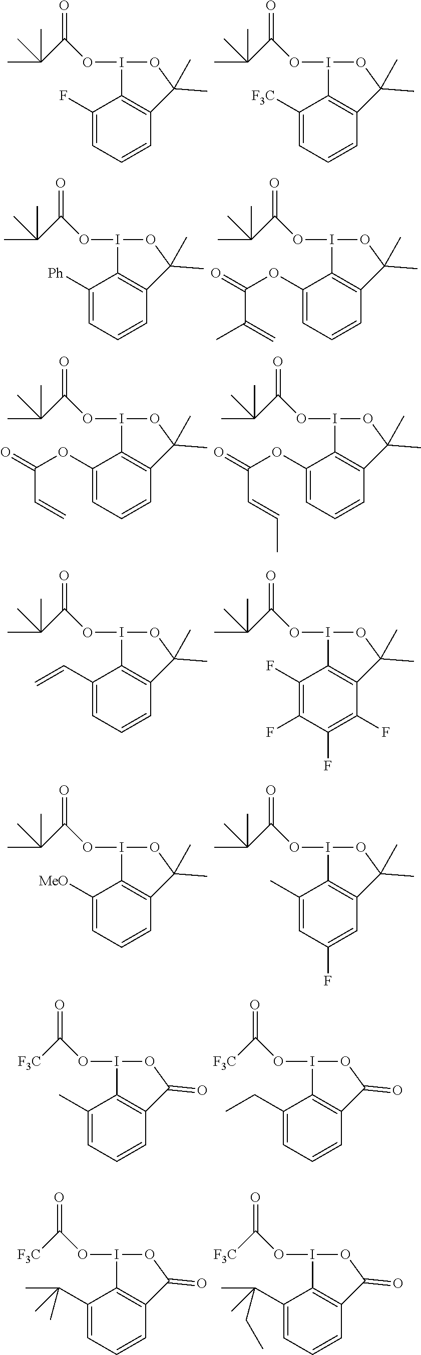

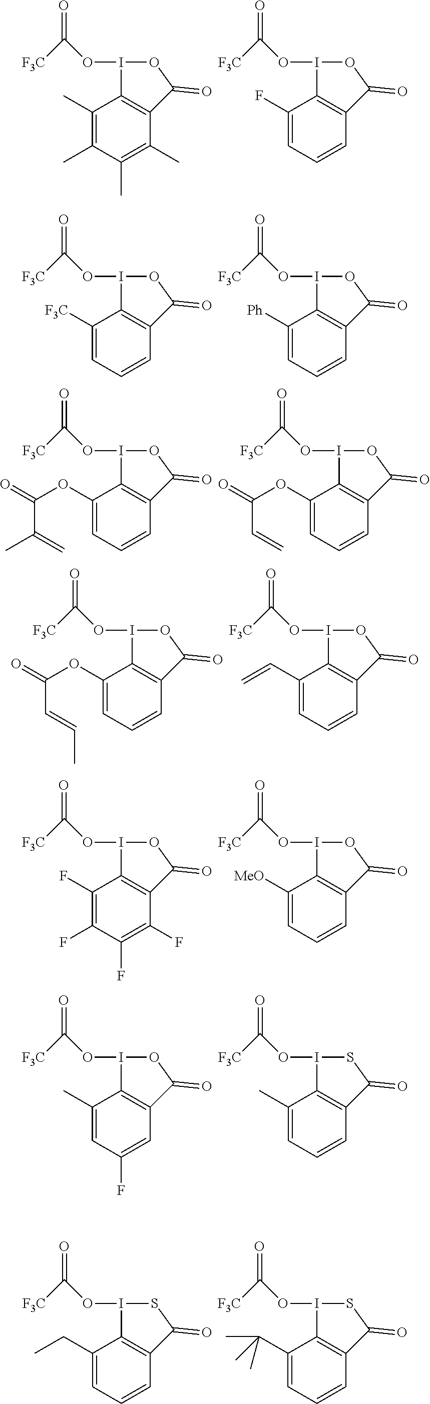

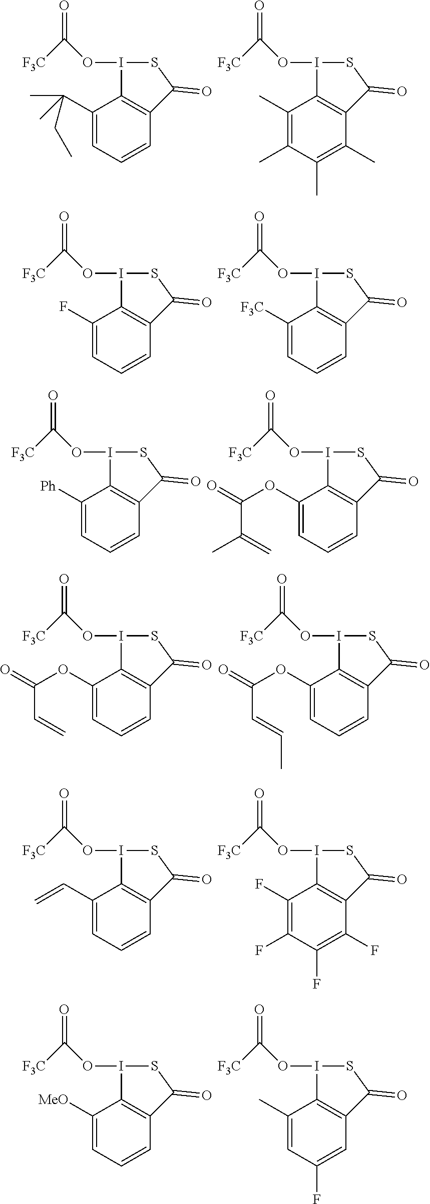

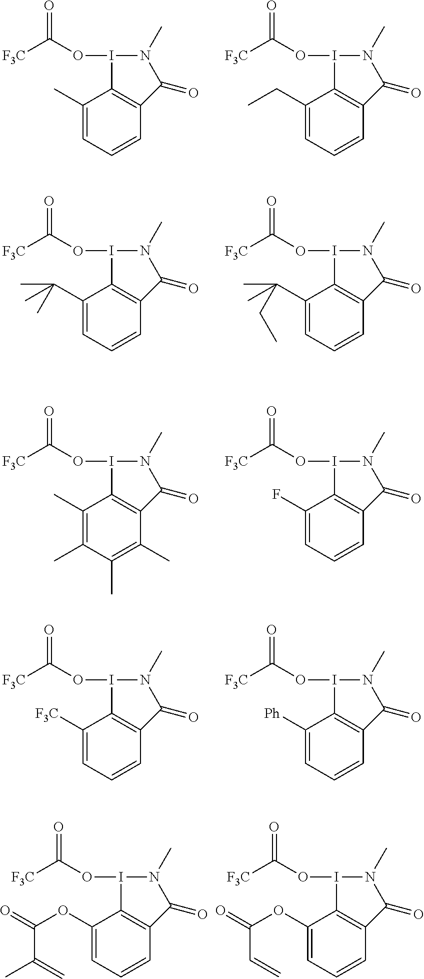

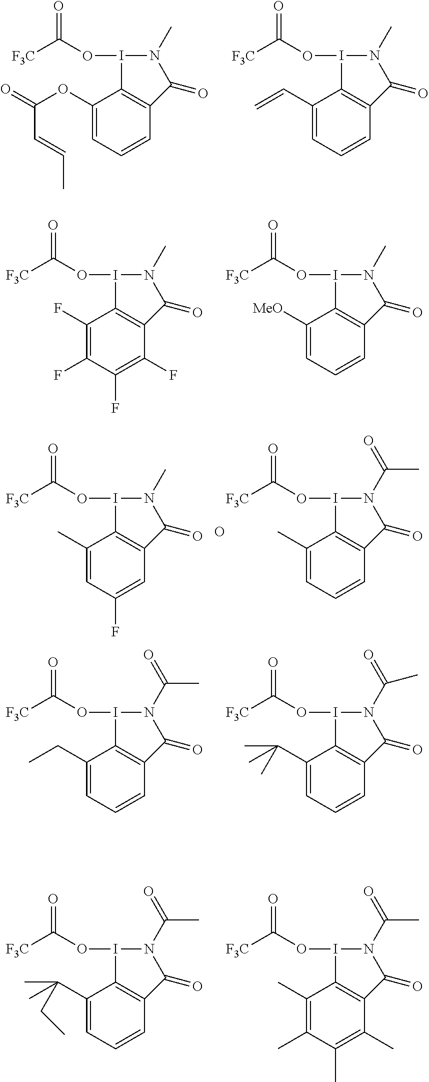

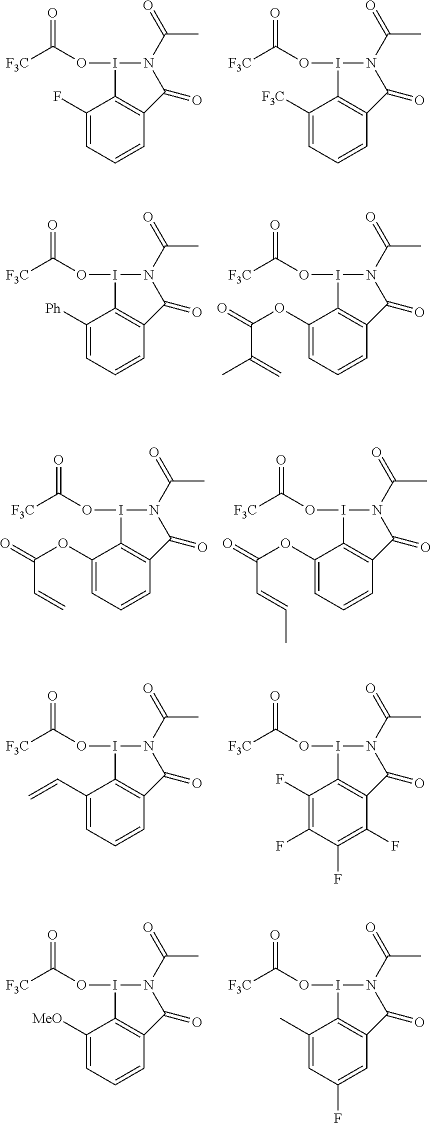

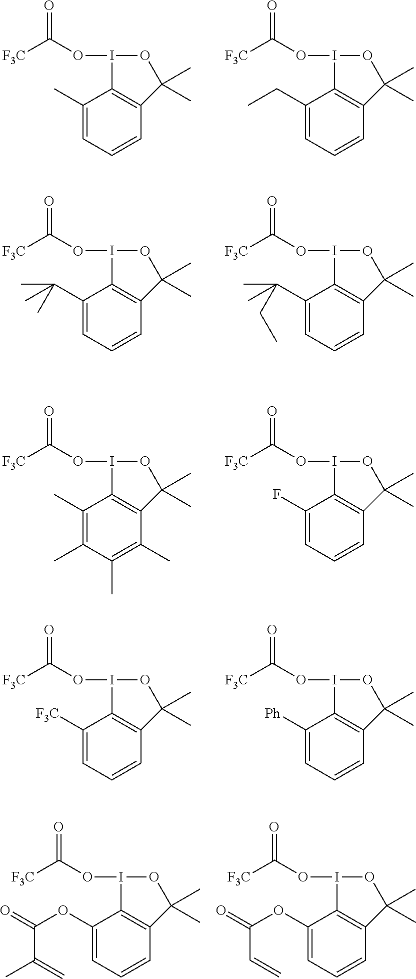

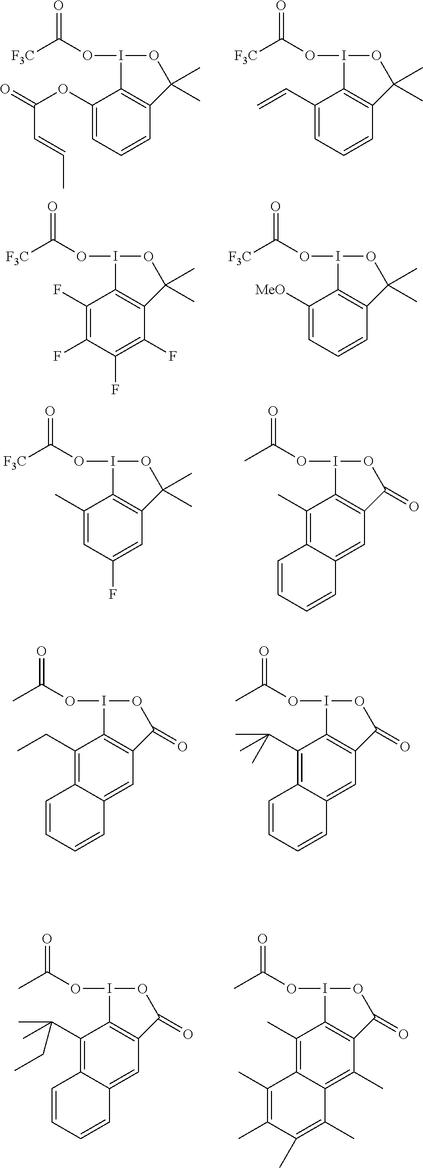

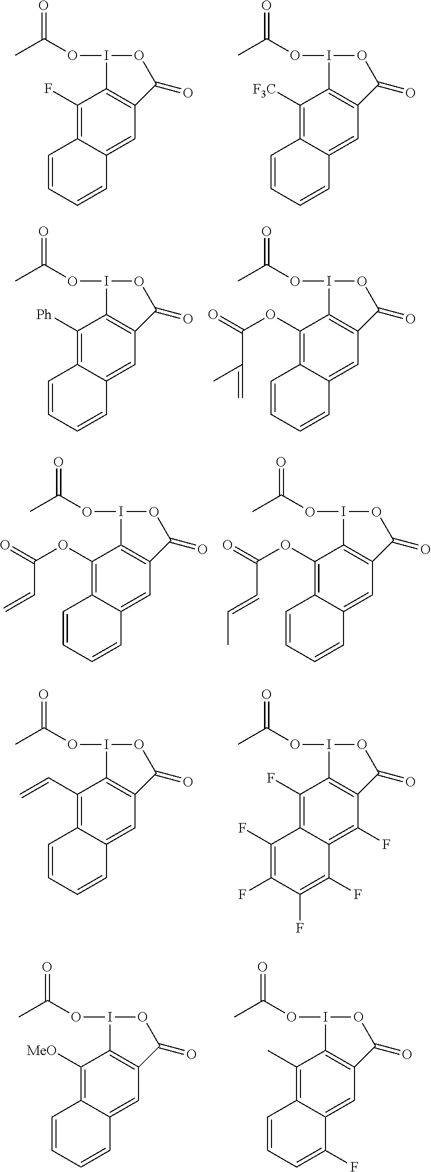

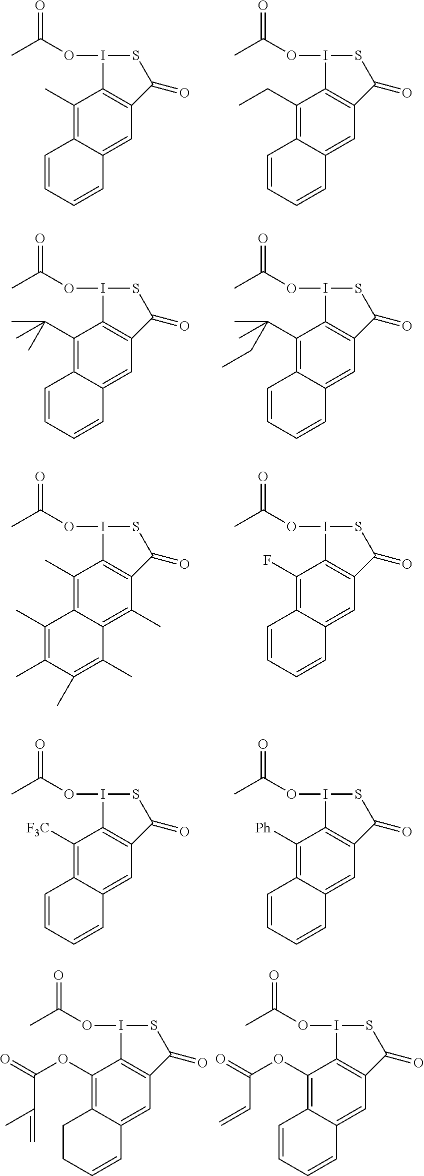

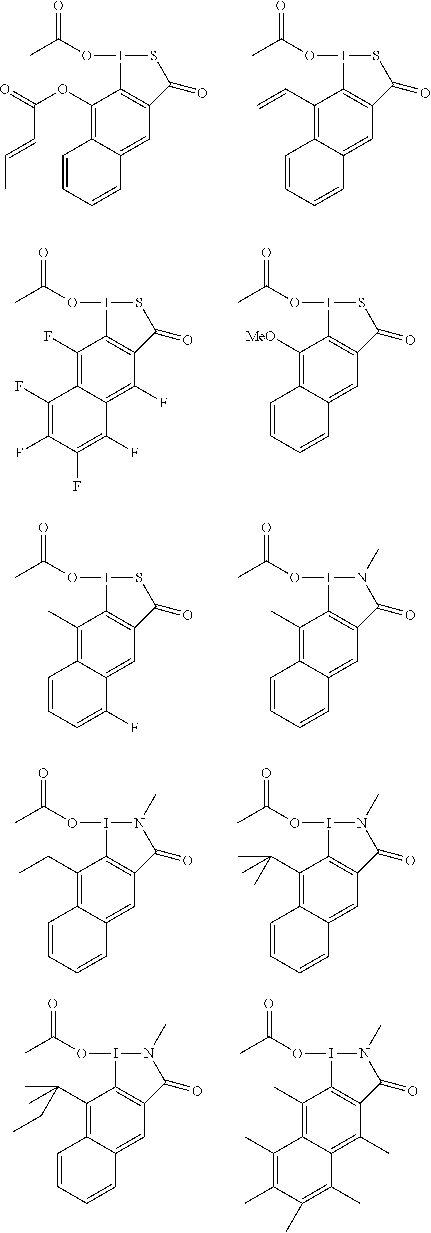

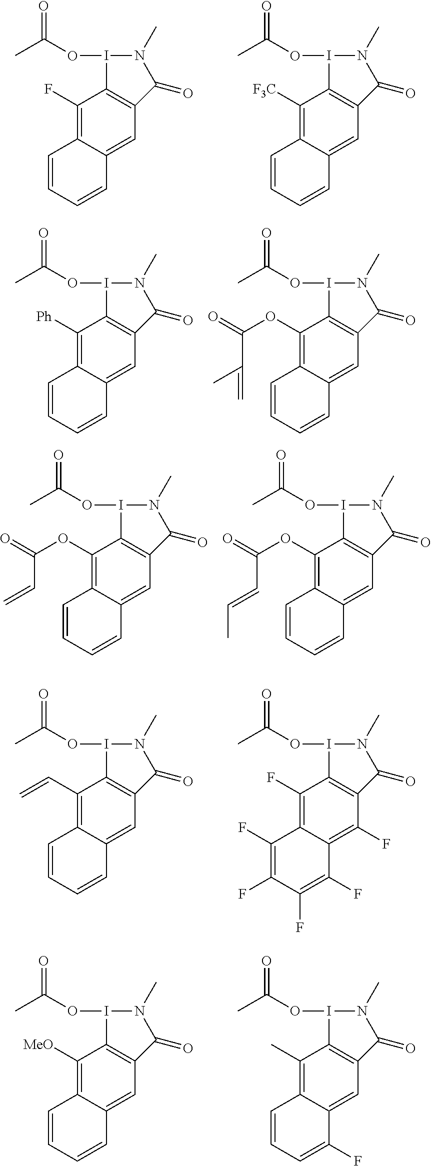

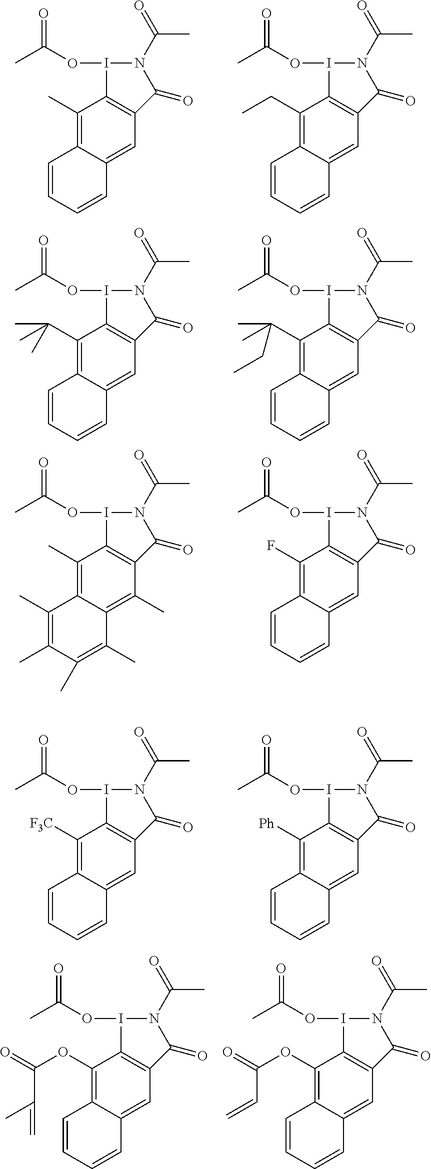

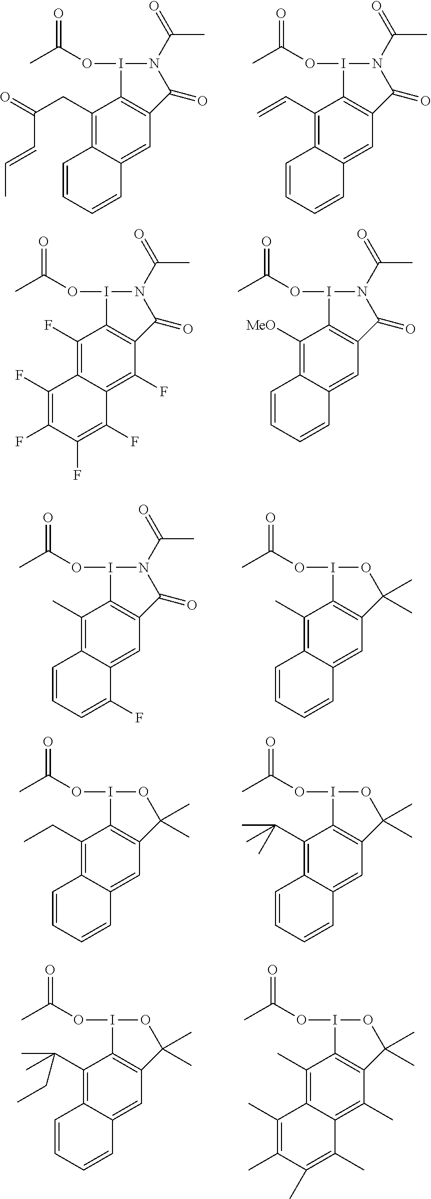

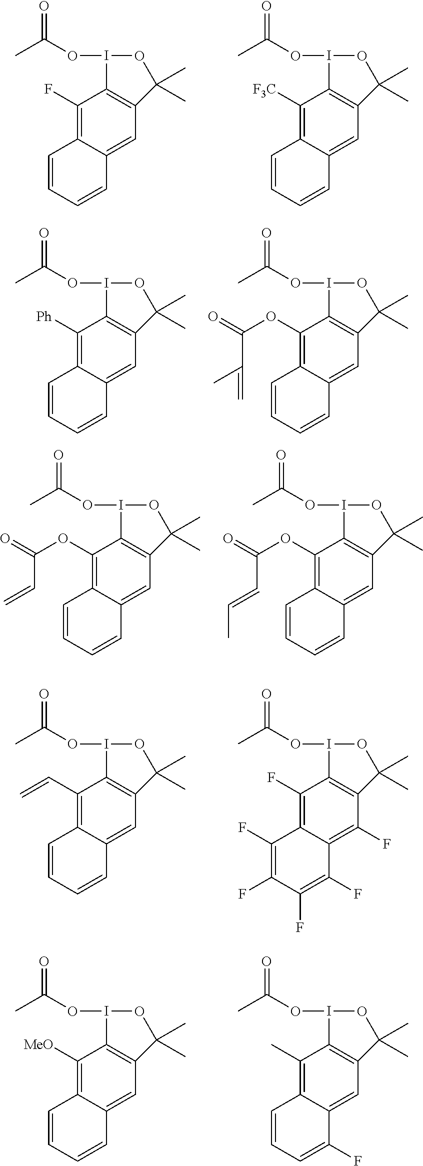

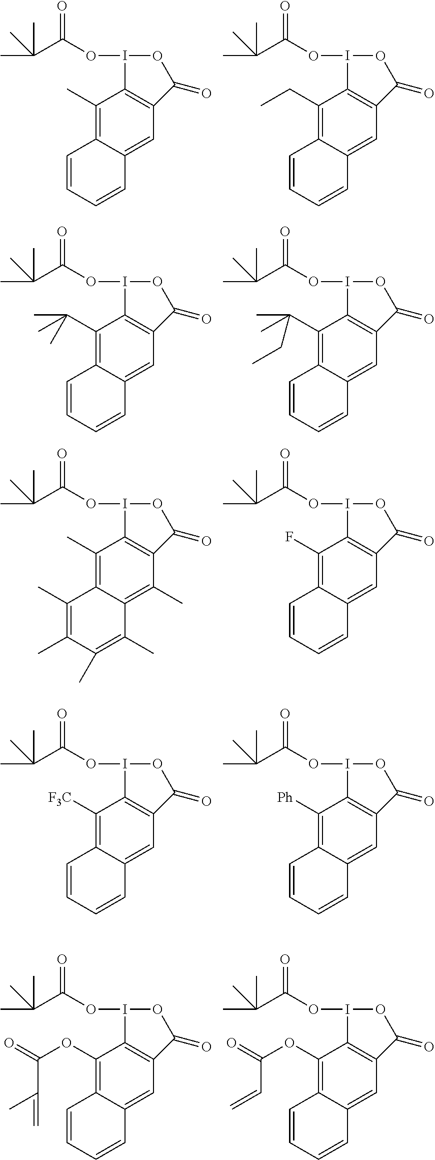

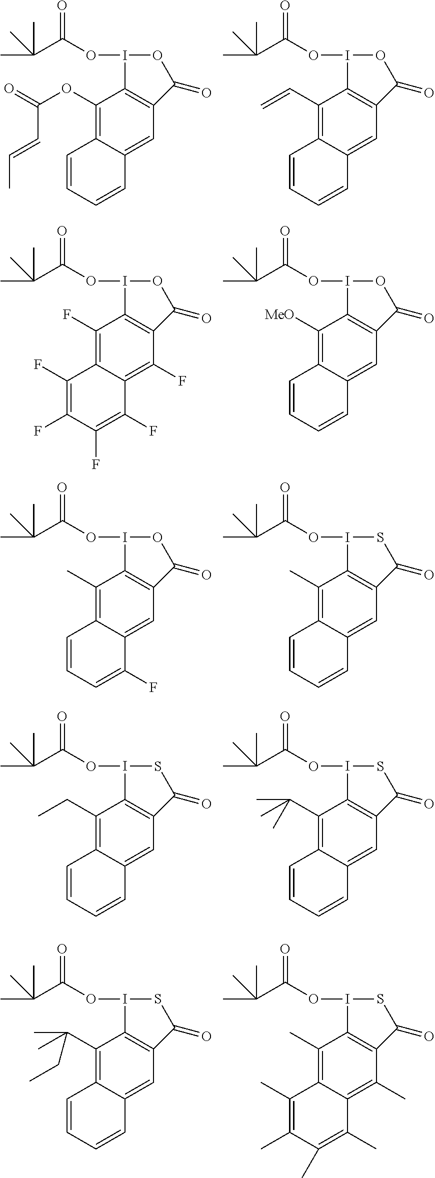

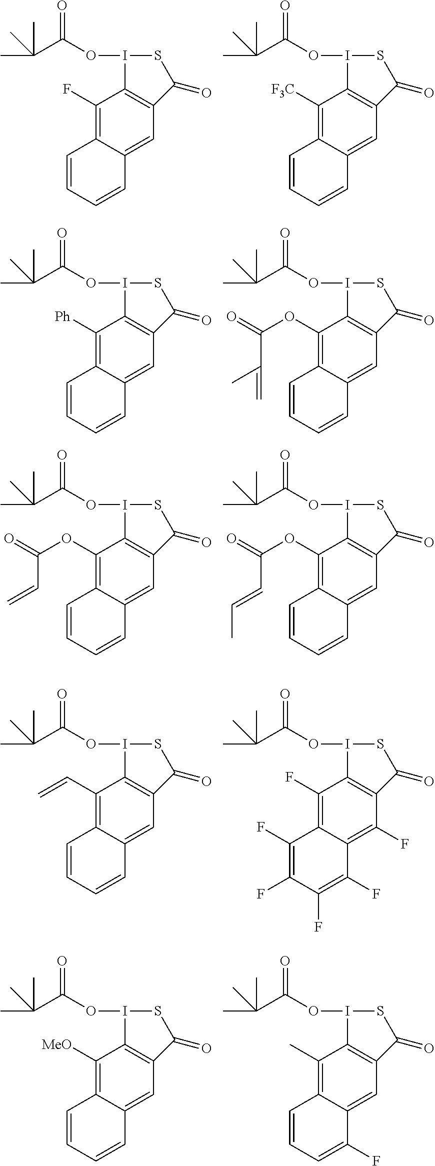

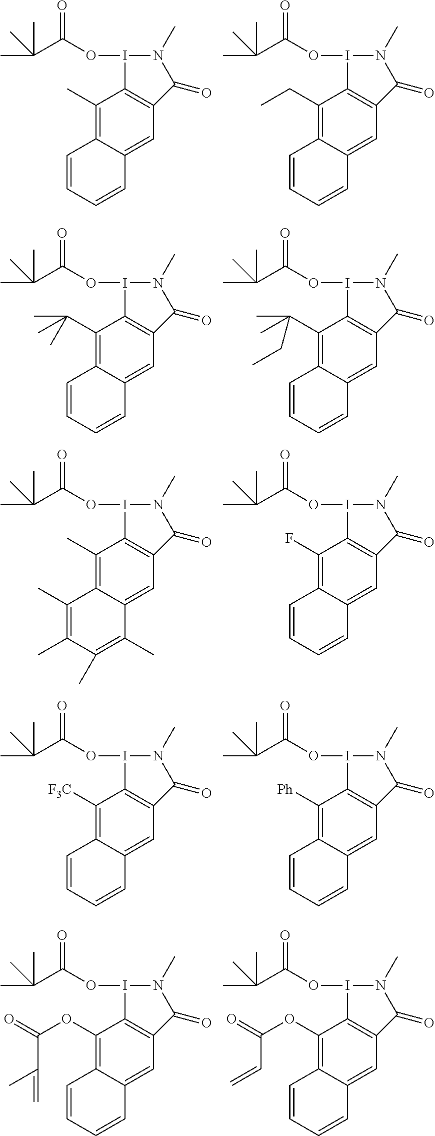

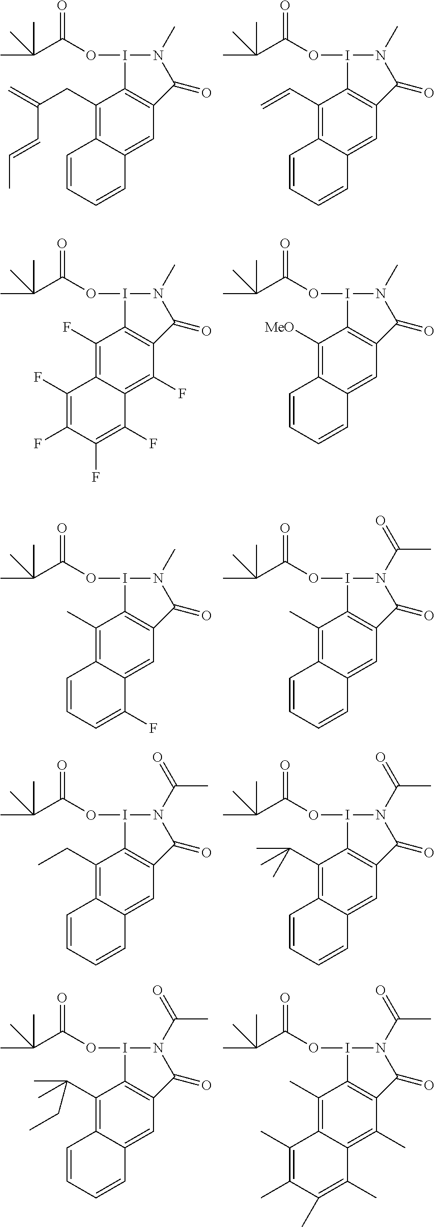

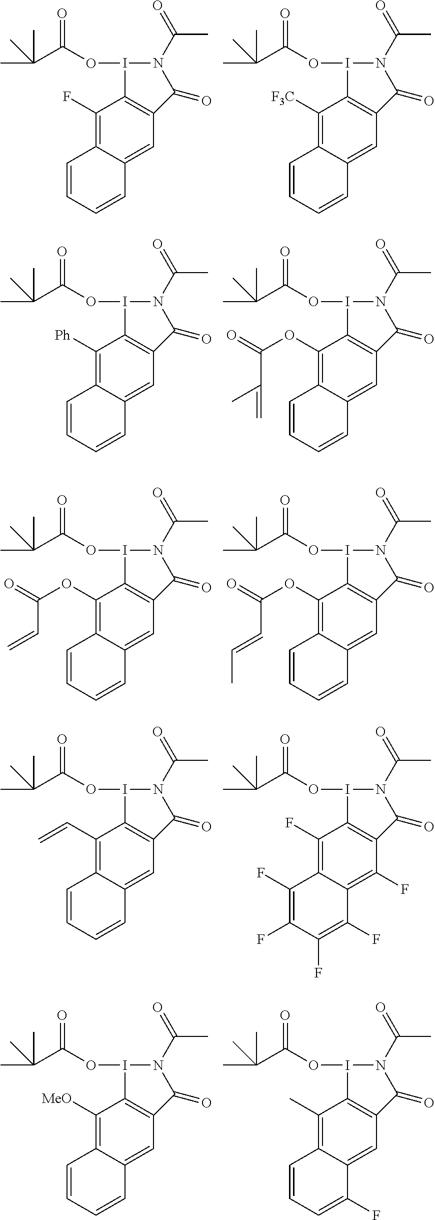

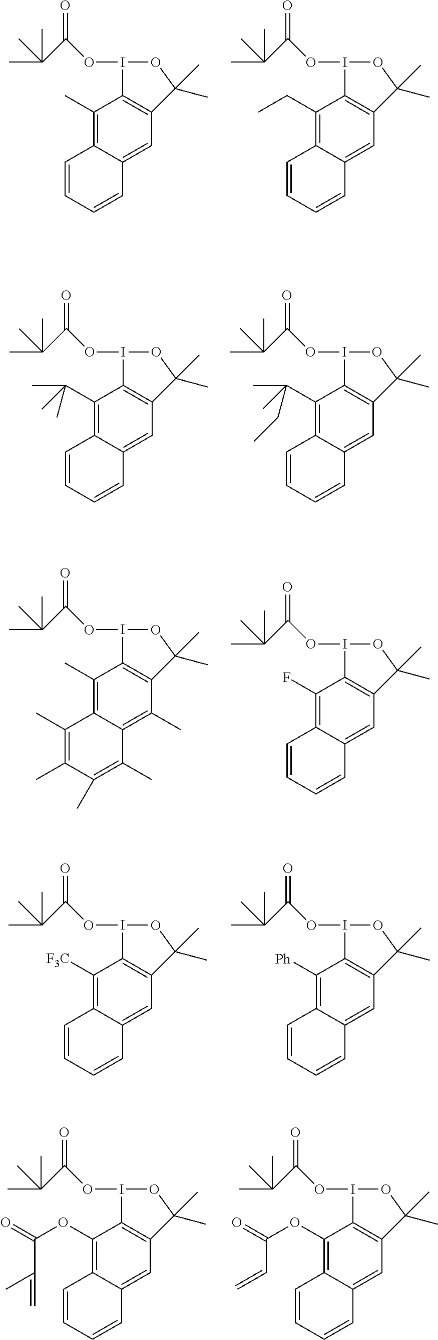

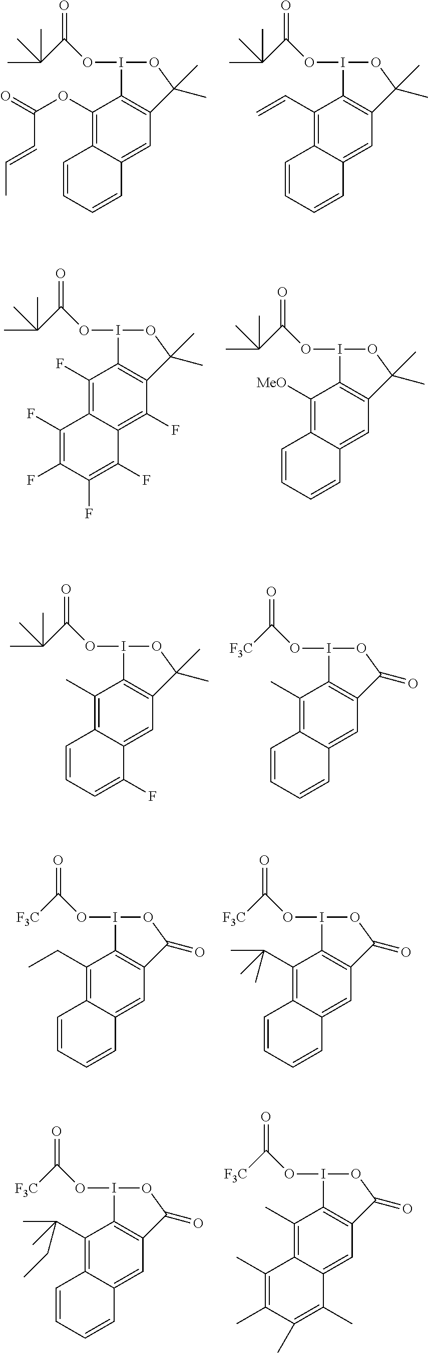

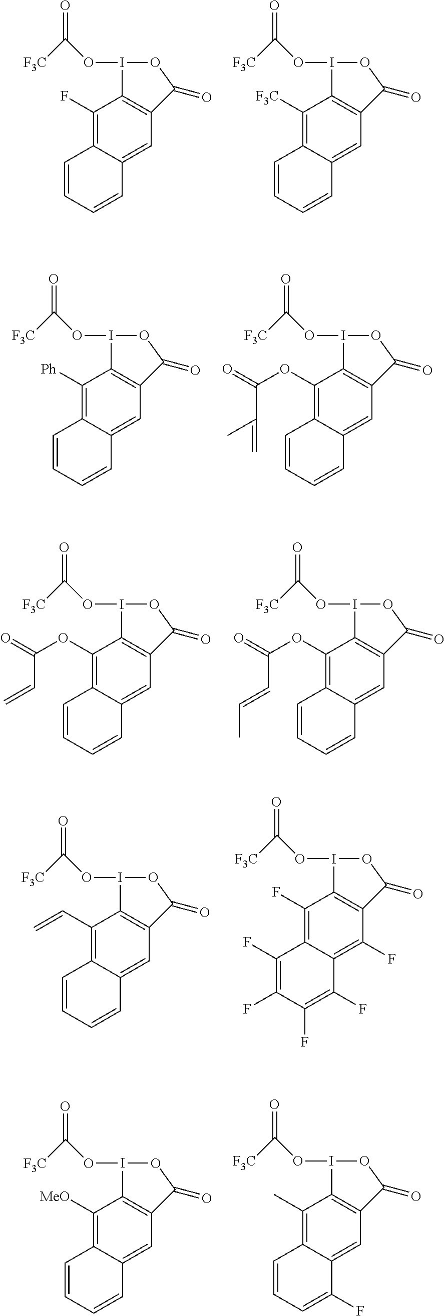

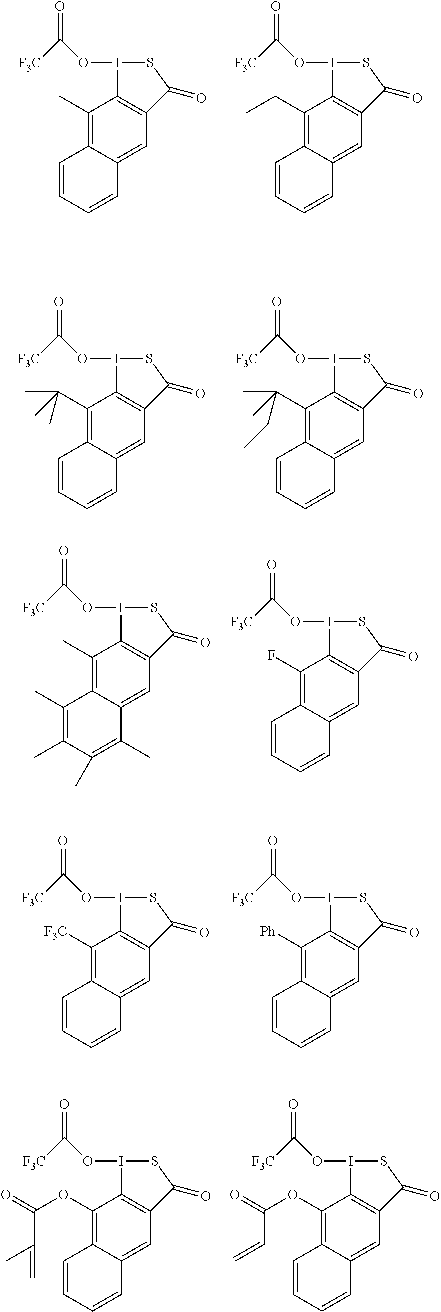

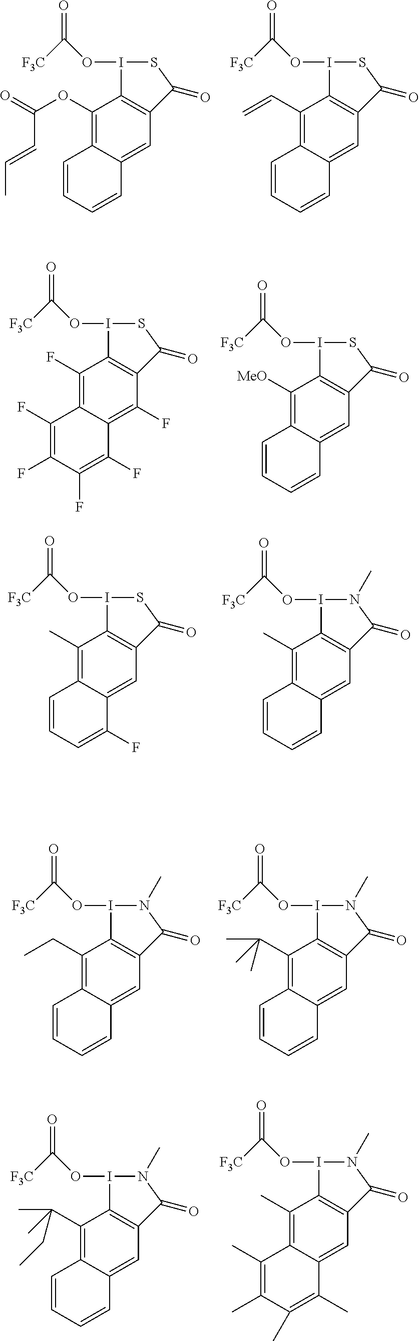

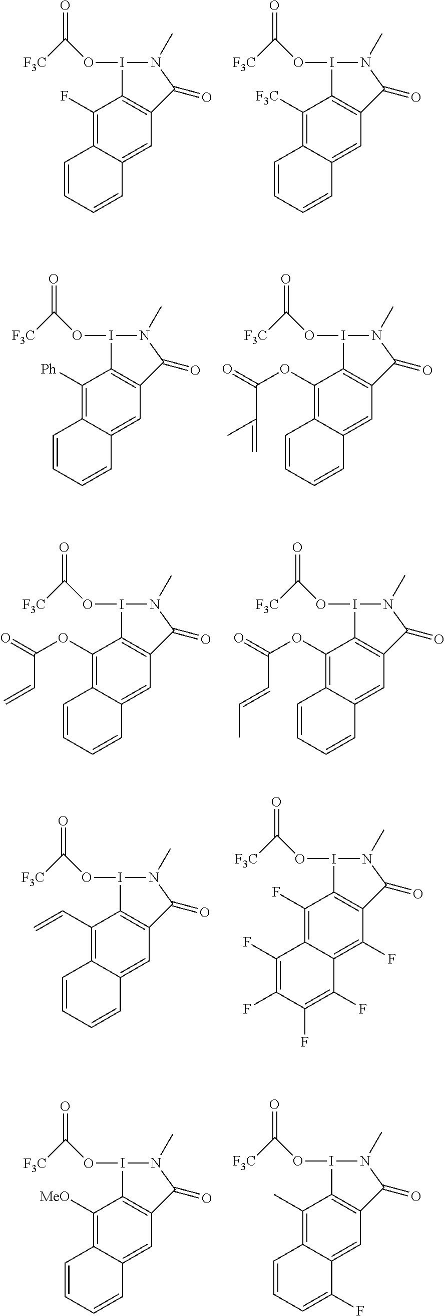

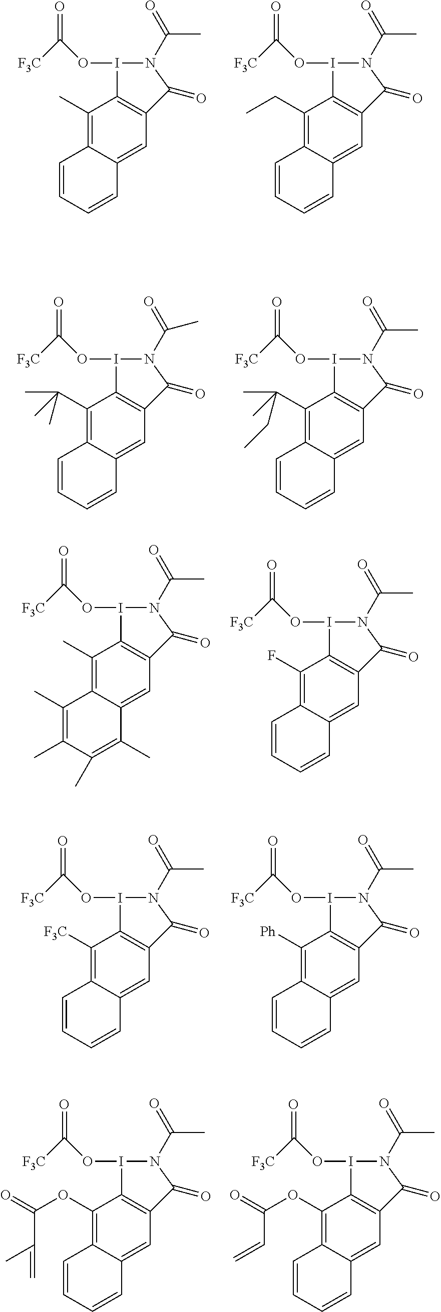

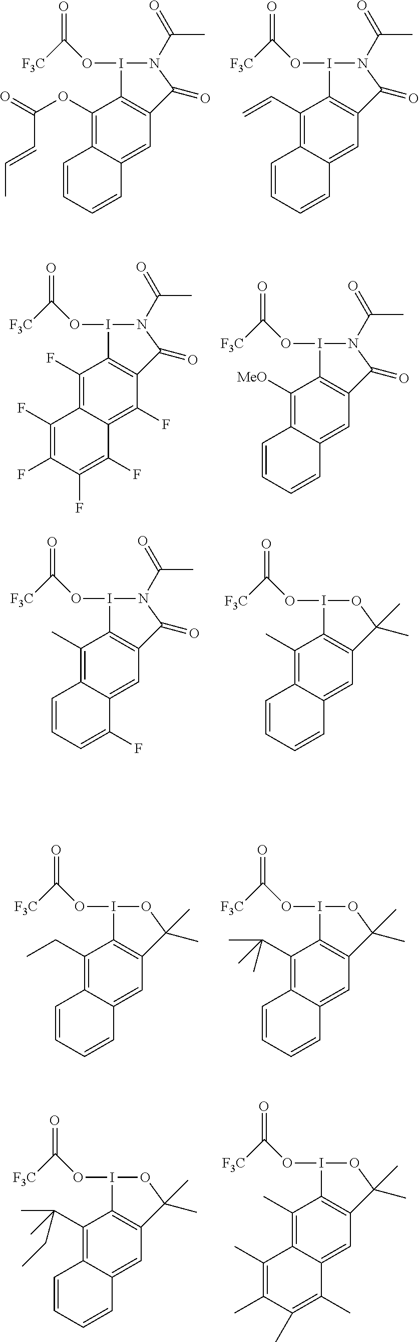

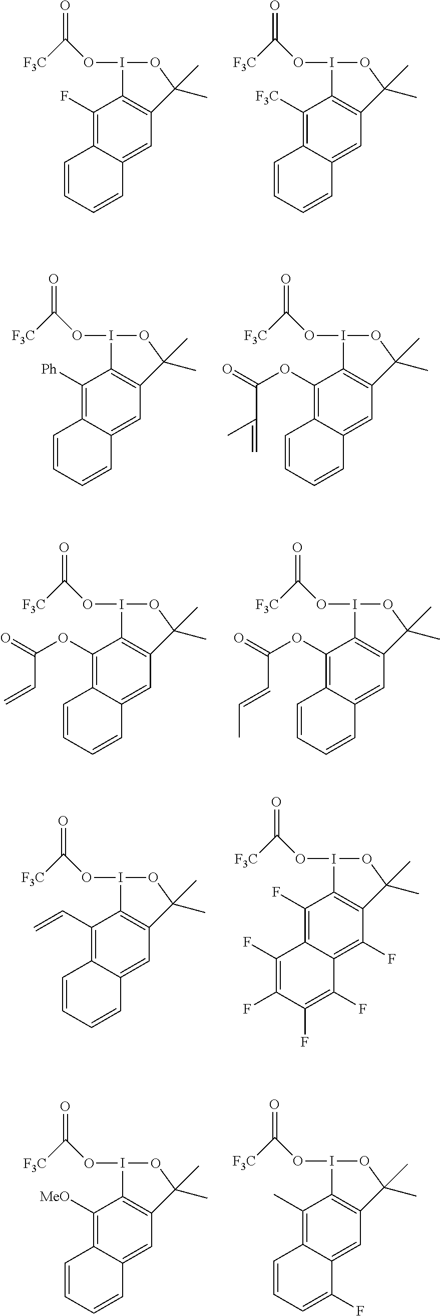

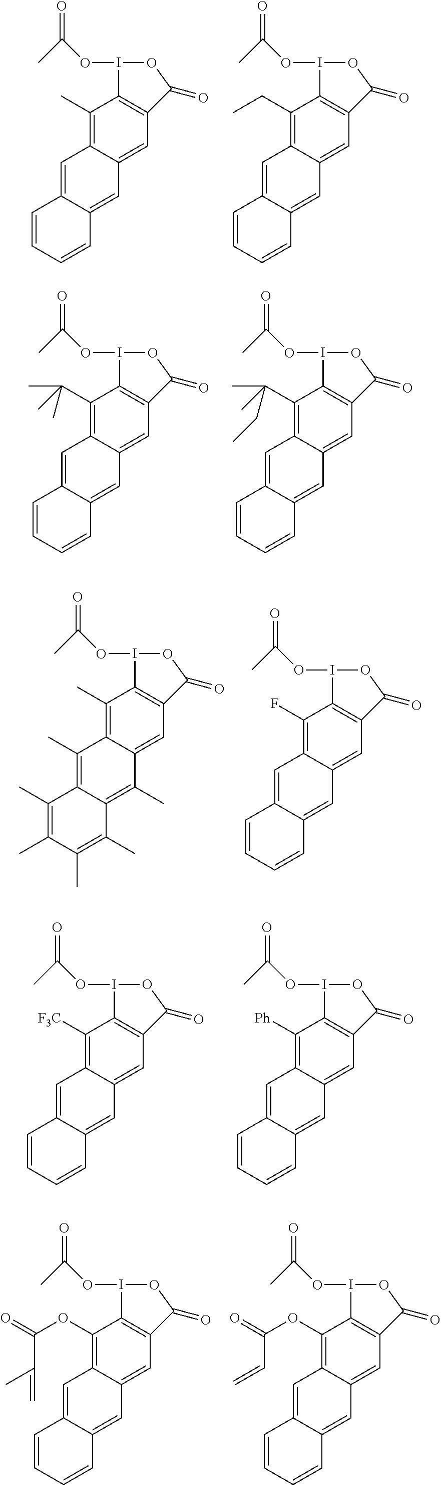

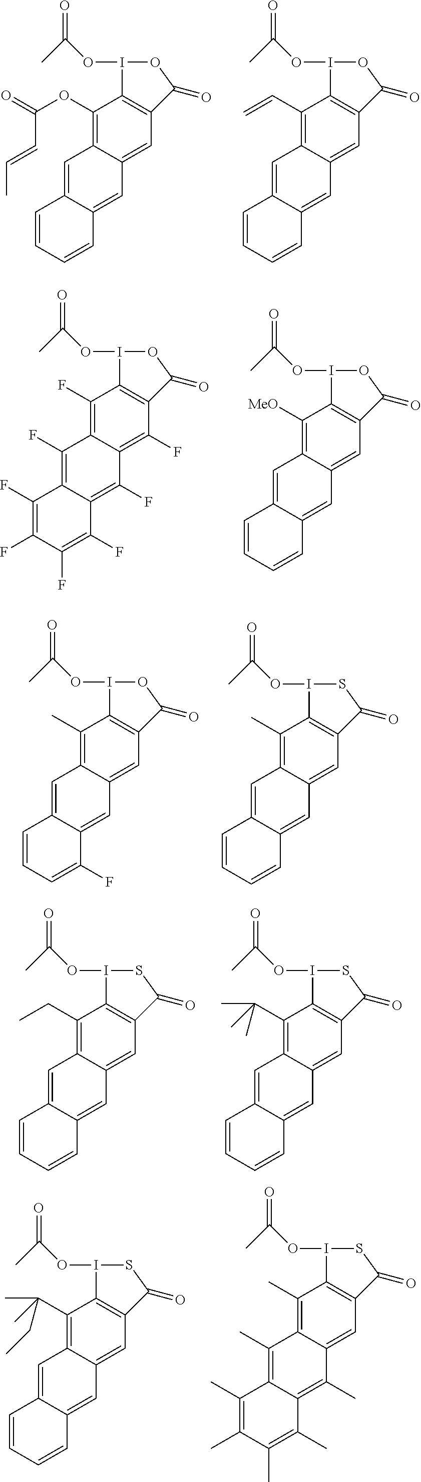

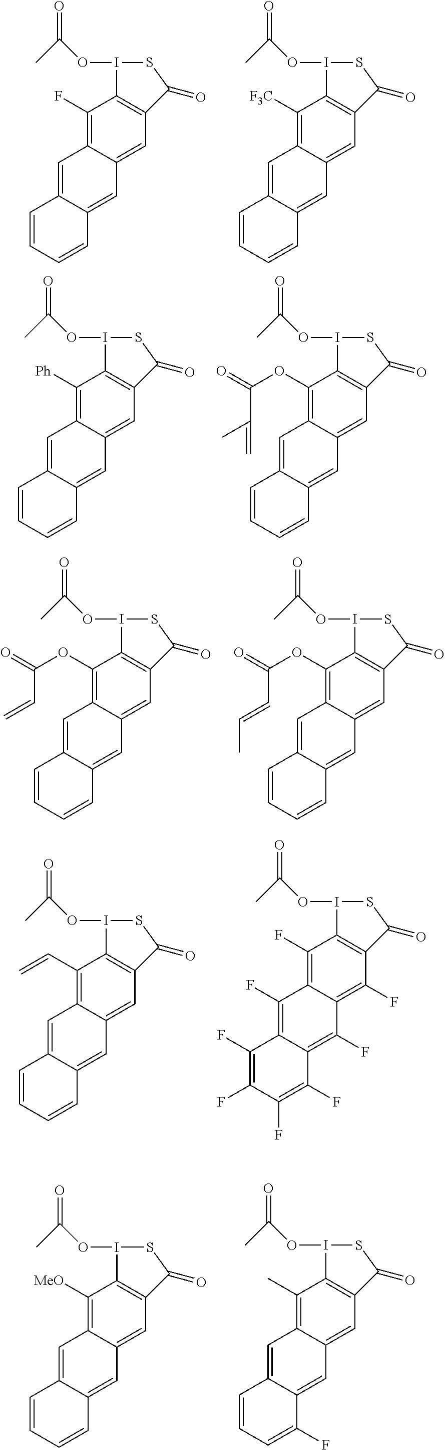

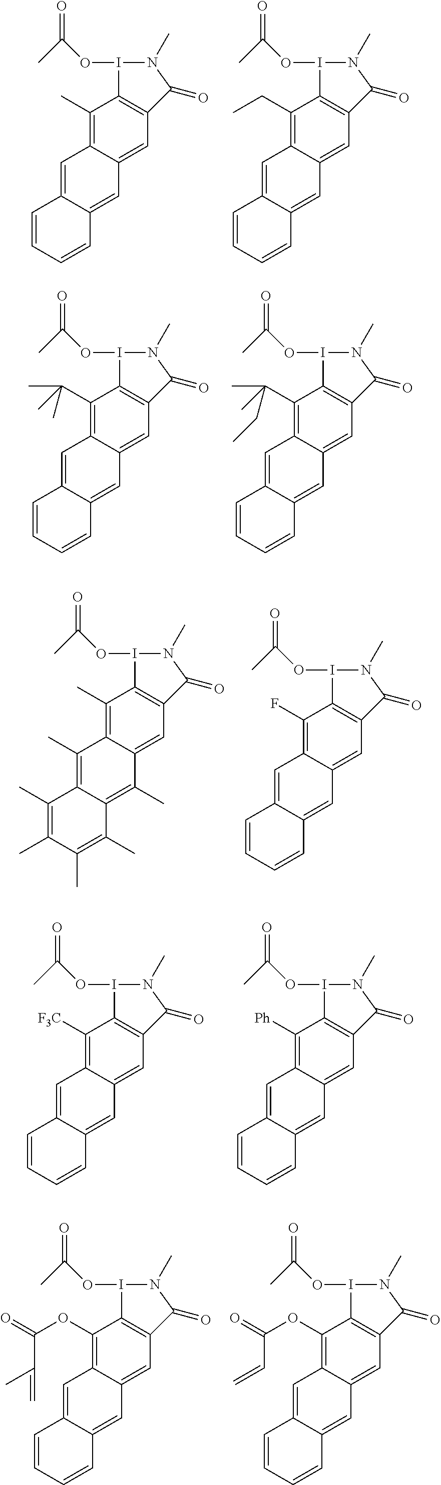

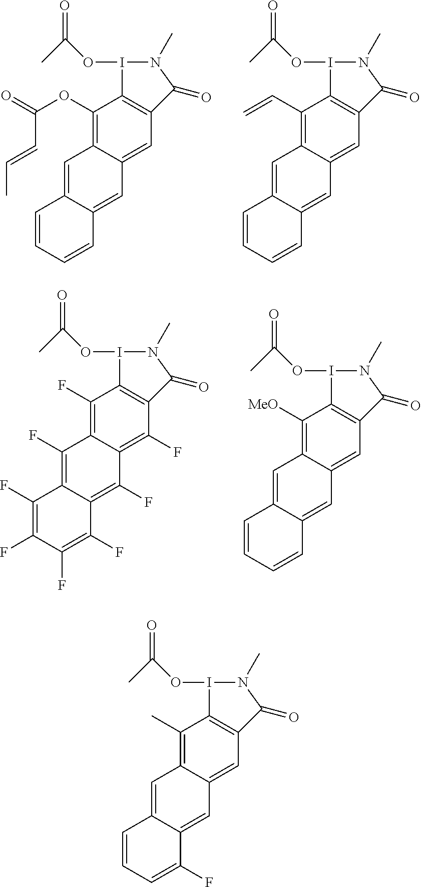

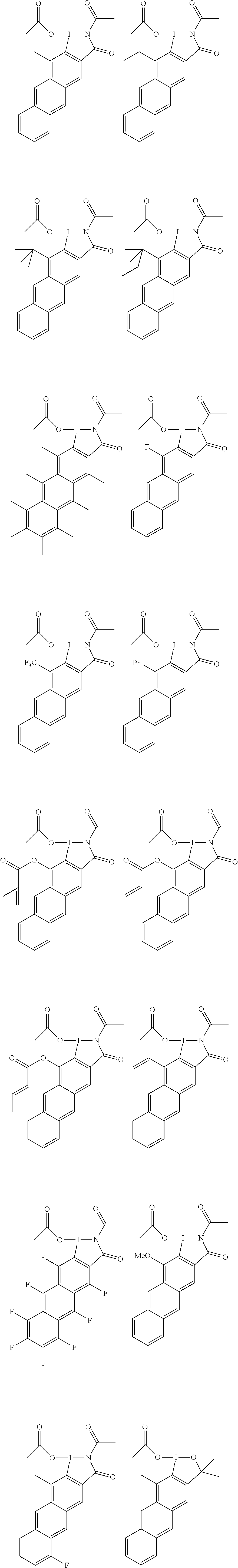

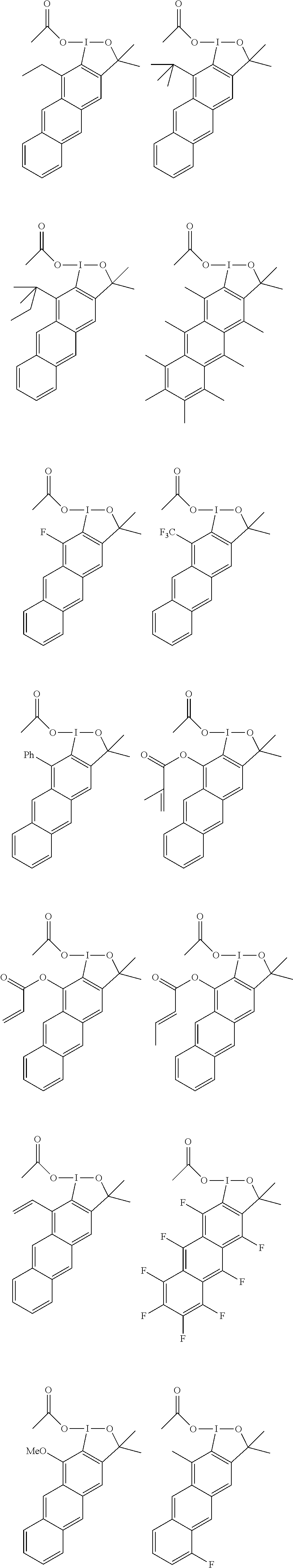

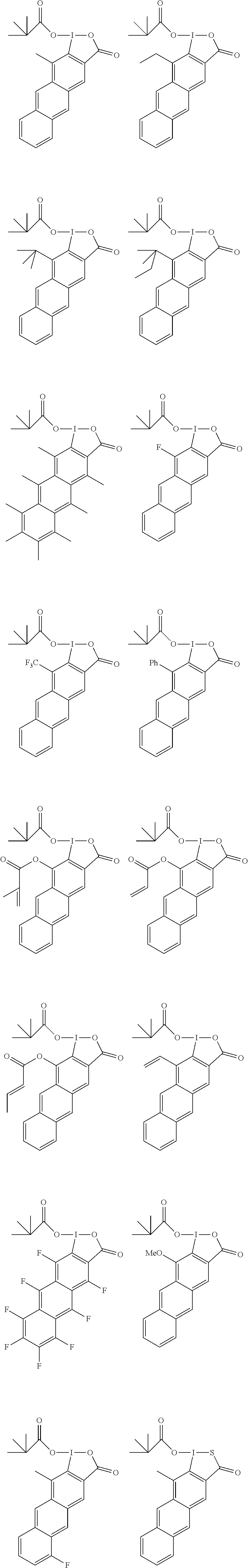

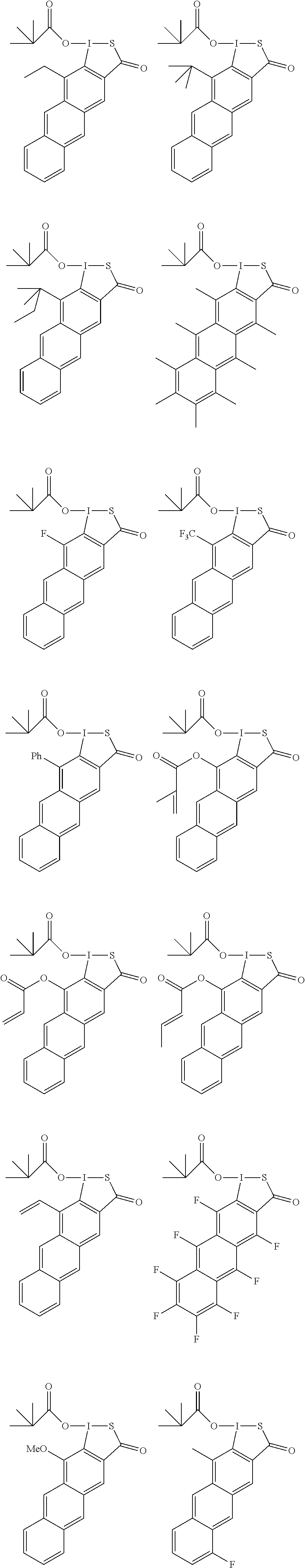

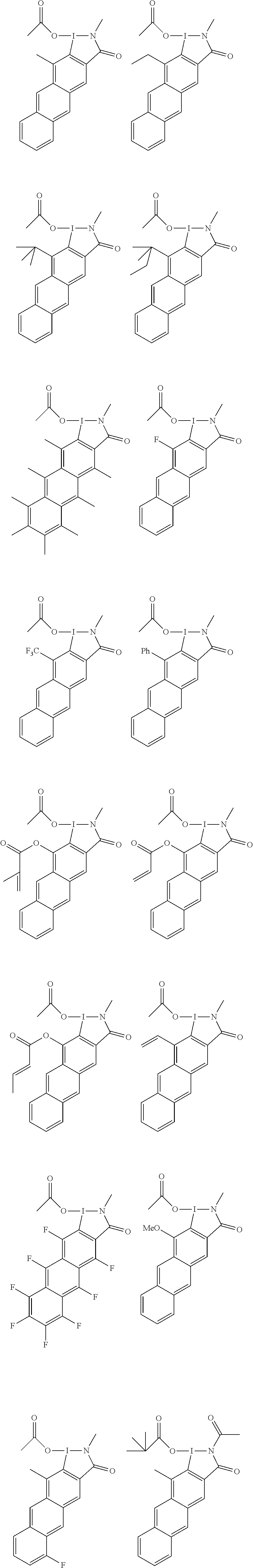

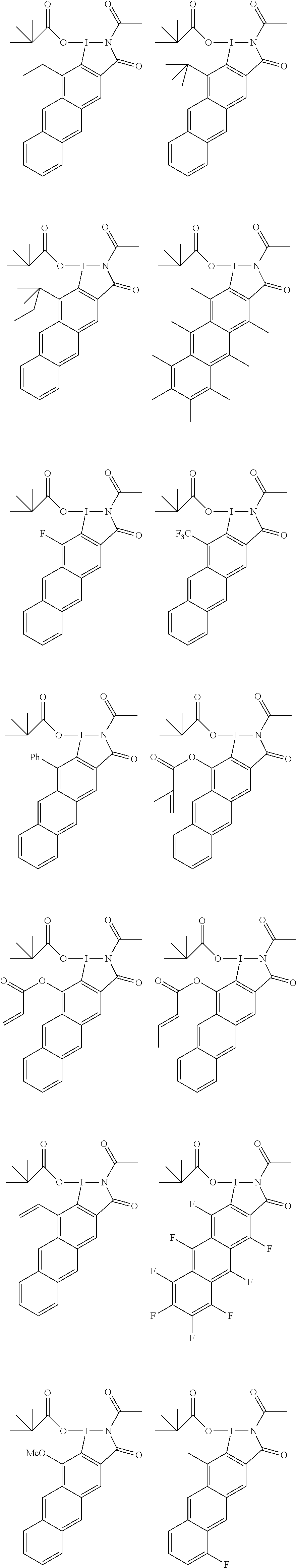

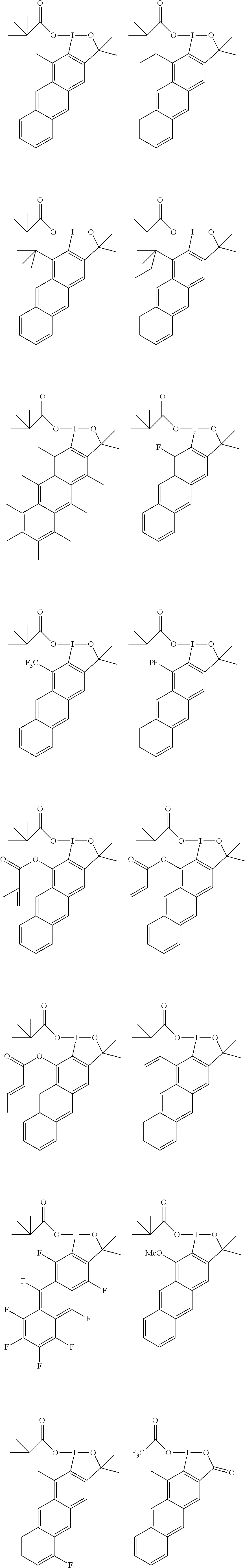

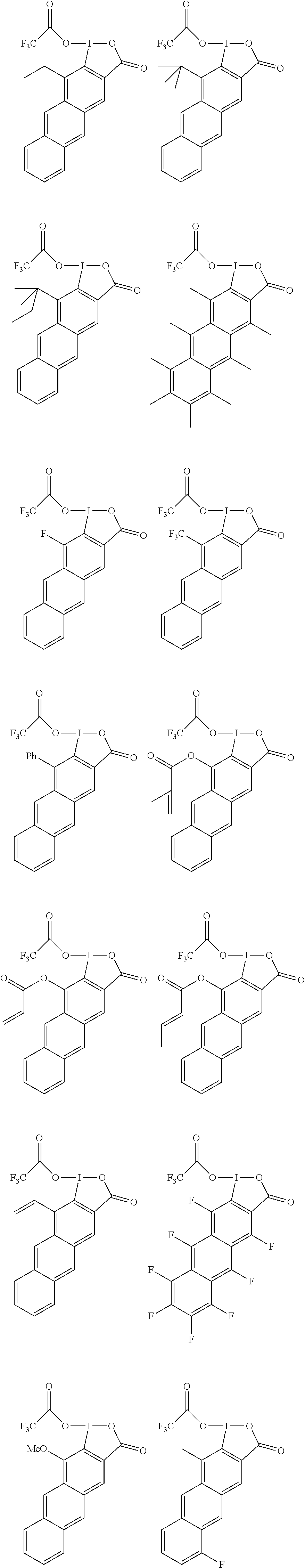

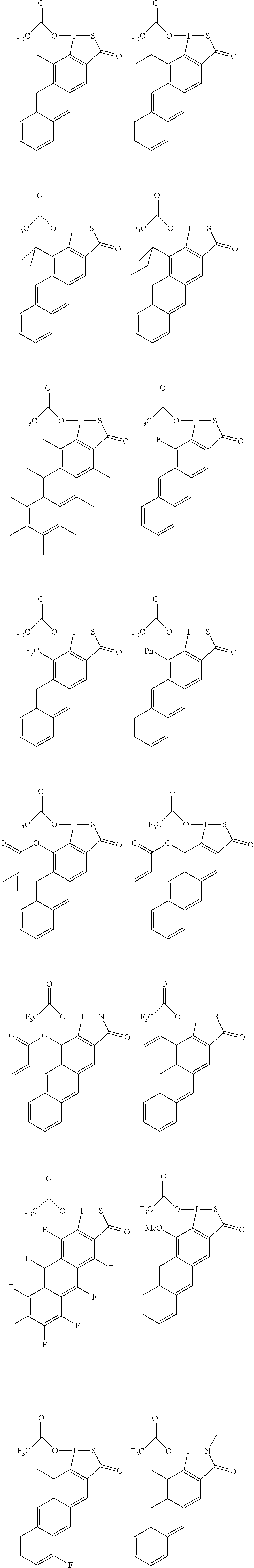

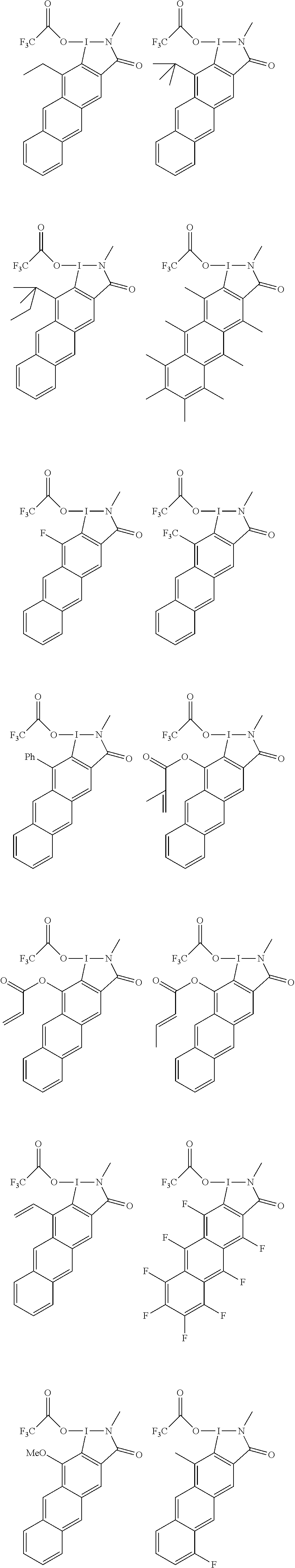

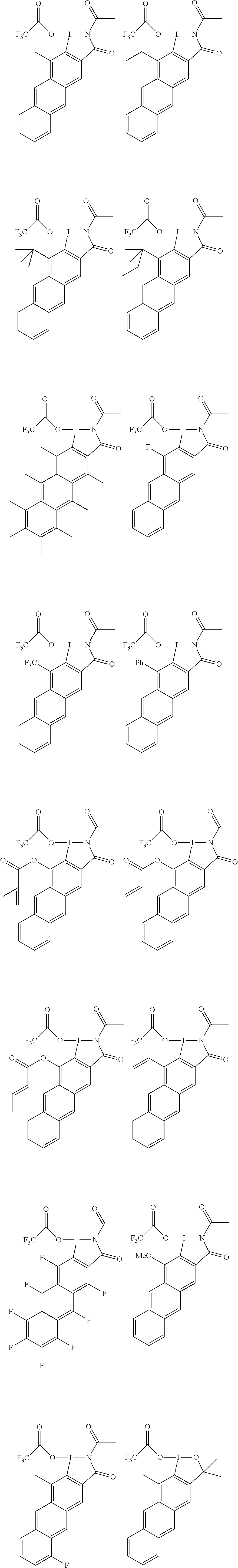

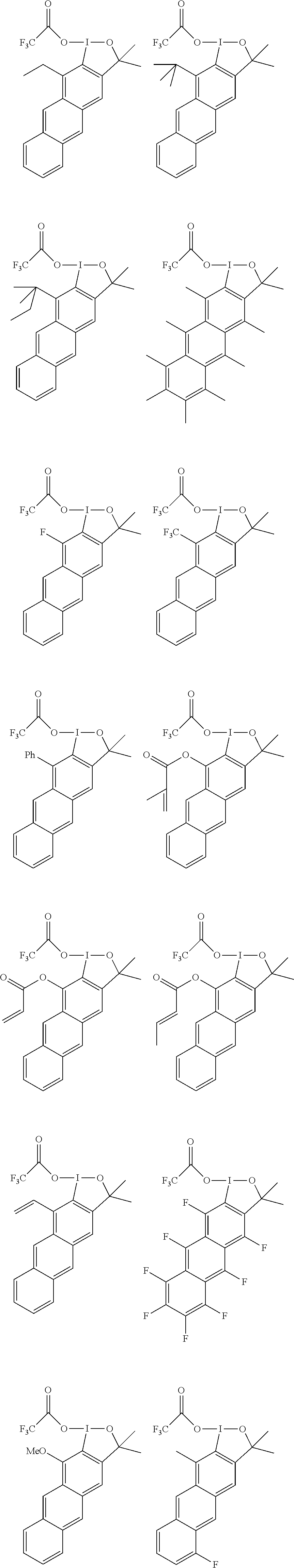

[Method for producing Hypervalent Iodine Compound]

The hypervalent iodine compound used in the present invention can be obtained by a known method. For example, when an objective hypervalent iodine compound is a 5-membered heterocycle containing iodine (III) and nitrogen, the compound can be obtained by oxidatively ring-closing 2-iodobenzamide derivative with an oxidant such as peracetic acid and then acetylating an OH group or an NH group with acetic anhydride or the like. A compound being a 5-membered heterocyclic compound containing oxygen and sulfur instead of nitrogen can also be obtained in the same manner with a 2-iodobenzoic acid derivative or a 2-iodothiobenzoic acid derivative as a raw material. In the formula (1), when X¹ is a nitrogen atom and R¹⁵ is one other than a hydrogen atom, 2-iodobenzamide having a substituent of R¹⁵ may be used as a raw material or R¹⁵ may be introduced by an appropriate substitution reaction after formation of a 5-membered heterocycle. The synthetic method can be seen in, for example, J. Am. Chem. Soc., 1997, vol. 119, No. 31, p. 7408-7409, or JP 2015-186792 A.

### [Carboxy Group-Containing Compound]

The carboxy group-containing compound is preferably a polymer containing a repeating unit represented by the following formula (2) or a compound represented by the following formula (3):

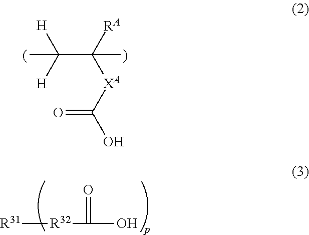

wherein R^{A} is a hydrogen atom, a halogen atom, a methyl group or a trifluoromethyl group; X^{A} is a single bond, a phenylene group, a naphthylene group, or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; * represents a point of attachment to a carbon atom in a mainchain; “p” is 1, 2, 3 or 4; R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; some or all of hydrogen atoms in the p-valent hydrocarbon group or the p-valent heterocyclic group are each optionally substituted with a group containing a heteroatom, and some of —CH₂— in the p-valent hydrocarbon group are each optionally substituted with a group containing a heteroatom; R³² is a single bond or a hydrocarbylene group having 1 to 10 carbon atoms, some or all of hydrogen atoms in the hydrocarbylene group are each optionally substituted with a group containing a heteroatom, and some of —CH₂— in the hydrocarbylene group are each optionally substituted with a group containing a heteroatom; and when “p” is 2, 3 or 4, R³²s are the same as or different from each other.

In the formula (2), R^{A} is a hydrogen atom, a halogen atom, a methyl group or a trifluoromethyl group; X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a mainchain.

In the formula (3), “p” is 1, 2, 3 or 4.

In the formula (3), R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; some or all of hydrogen atoms in the p-valent hydrocarbon group or the p-valent heterocyclic group are each optionally substituted with a group containing a heteroatom, and some of —CH₂— in the p-valent hydrocarbon group are each optionally substituted with a group containing a heteroatom.

In the formula (3), R³² is a single bond or a hydrocarbylene group having 1 to 10 carbon atoms, some or all of hydrogen atoms in the hydrocarbylene group are each optionally substituted with a group containing a heteroatom, and some of —CH₂— in the hydrocarbylene group are each optionally substituted with a group containing a heteroatom; and when “p” is 2, 3 or 4, R³²s are the same as or different from each other.

The p-valent hydrocarbon group represented by R³¹ may be saturated or unsaturated, and may be any of linear, branched or cyclic. The p-valent hydrocarbon group is a group obtained by detaching “p” hydrogen atoms from hydrocarbon. Examples of the hydrocarbon include, for example, alkane having 1 to 40 carbon atoms, alkene having 2 to 40 carbon atoms, alkyne having 2 to 40 carbon atoms, cyclic saturated hydrocarbon having 3 to 40 carbon atoms, cyclic unsaturated hydrocarbon having 3 to 40 carbon atoms, and aromatic hydrocarbon having 6 to 40 carbon atoms.

Examples of the alkane having 1 to 40 carbon atoms include, for example, methane, ethane, propane, butane, pentane, hexane, heptane, octane, nonane, decane, and any structural isomer thereof.

Examples of the alkene having 2 to 40 carbon atoms include, for example, ethylene, propylene, butene, pentene, hexene, heptene, octene, nonene, decene, and any structural isomer thereof.

Examples of the alkyne having 2 to 40 carbon atoms include, for example, acetylene, propyne, butyne, pentyne, hexyne, heptyne, octyne, nonyne, decyne, and any structural isomer thereof.

Examples of the cyclic saturated hydrocarbon having 3 to 40 carbon atoms include, for example, cyclopropane, cyclobutane, cyclohexane, cycloheptane, cyclooctane, adamantane, and norbornane.

Examples of the cyclic unsaturated hydrocarbon having 3 to 40 carbon atoms include, for example, cyclopropene, cyclobutene, cyclopentene, cyclohexene, cycloheptene, cyclooctene, and norbornene.

Examples of the aromatic hydrocarbon having 6 to 40 carbon atoms include, for example, benzene, naphthalene, and biphenyl.

The p-valent heterocyclic group represented by R³¹ is a group obtained by detaching “p” hydrogen atoms from a heterocyclic compound. Examples of the heterocyclic compound include, for example, furan, pyridine, pyrazole, and thiazolidine.

Some or all of hydrogen atoms in the p-valent hydrocarbon group or p-valent heterocyclic group are each optionally substituted with a group containing a heteroatom such as an oxygen atom, a sulfur atom, a nitrogen atom, or a halogen atom, and as a result, a hydroxy group, a cyano group, a fluorine atom, a chlorine atom, a bromine atom, an iodine atom, or the like is optionally contained. Some of —CH₂— constituting the p-valent hydrocarbon group are each optionally substituted with a group containing a heteroatom such as an oxygen atom, a sulfur atom, or a nitrogen atom, and as a result, a carbonyl group, an ether bond, a thioether bond, an ester bond, a sulfonic acid ester bond, a carbonate bond, a carbamate bond, a lactone ring, a sultone ring, a carboxylic anhydride(—C(═O)—O—C(═O)—), or the like is optionally contained.

The hydrocarbylene group represented by R³² may be saturated or unsaturated, and may be any of linear, branched or cyclic. Specific examples thereof include alkanediyl groups each having 1 to 20 carbon atoms, such as a methanediyl group, an ethane-1,1-diyl group, an ethane-1,2-diyl group, a propane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group and a dodecane-1,12-diyl group; cyclic saturated hydrocarbylene groups each having 3 to 20 carbon atoms, such as a cyclopentanediyl group, a cyclohexanediyl group, a norbornanediyl group and an adamantanediyl group; unsaturated aliphatic hydrocarbylene groups each having 2 to 20 carbon atoms, such as a vinylene group and a propene-1,3-diyl group; arylene groups each having 6 to 20 carbon atoms, such as a phenylene group and a naphthylene group; and any group obtained by combination thereof. Some or all of hydrogen atoms in the hydrocarbylene group are each optionally substituted with a group containing a heteroatom such as an oxygen atom, a sulfur atom, a nitrogen atom, or a halogen atom, some of —CH₂— in the hydrocarbylene group are each optionally substituted with a group containing a heteroatom such as an oxygen atom, a sulfur atom, or a nitrogen atom, and as a result, a hydroxy group, a cyano group, a fluorine atom, a chlorine atom, a bromine atom, an iodine atom, a carbonyl group, an ether bond, a thioether bond, an ester bond, a sulfonic acid ester bond, a carbonate bond, a carbamate bond, a lactone ring, a sultone ring, a carboxylic anhydride, or the like is optionally contained.

The carboxylic acid compound represented by the formula (3) is preferably such a compound in which “p” is 2, 3 or 4. Such a carboxylic acid compound is preferred from the viewpoints of etching resistance and developer resistance because a stiff resist film in which the molecular weight is high is easily formed during mixing with the hypervalent iodine compound.

Specific examples of the carboxy group-containing repeating unit represented by the formula (2) include those represented below, but are not limited thereto. In the following formulae, R^{A} is the same as described above.

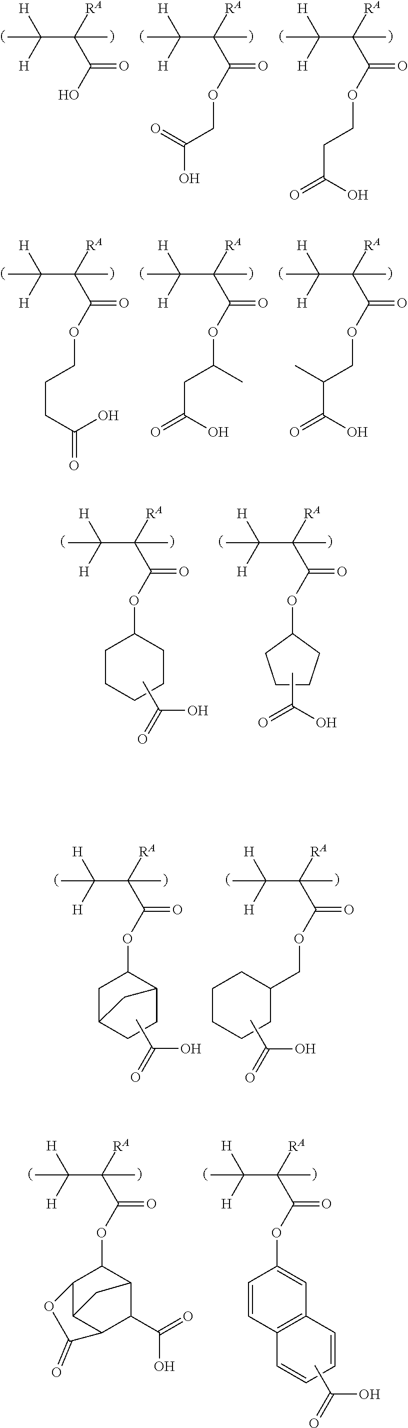

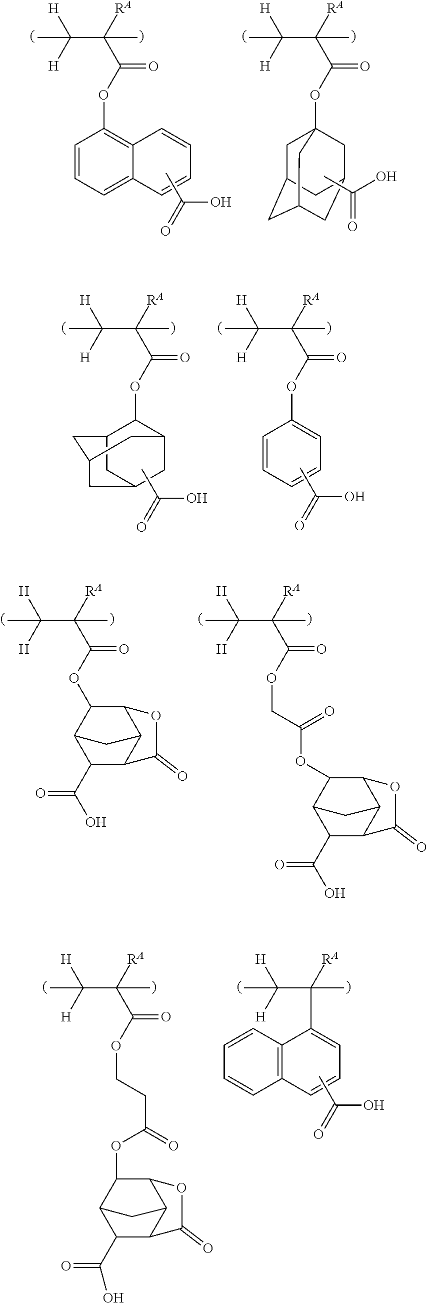

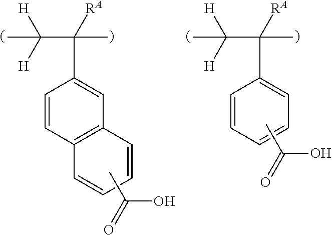

Examples of the carboxylic acid compound represented by the formula (3) include, for example, those represented below, but are not limited thereto.

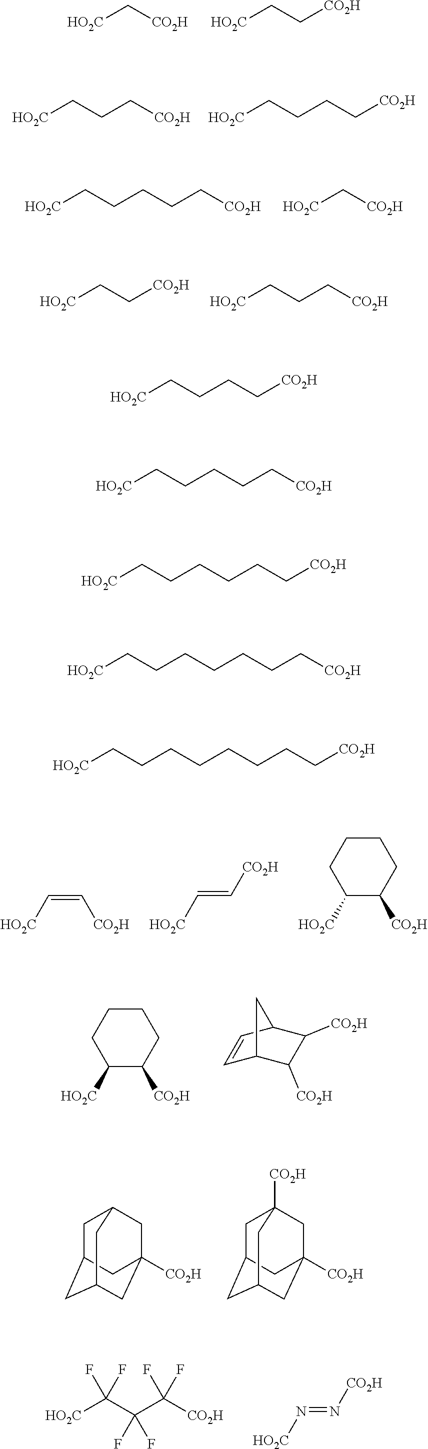

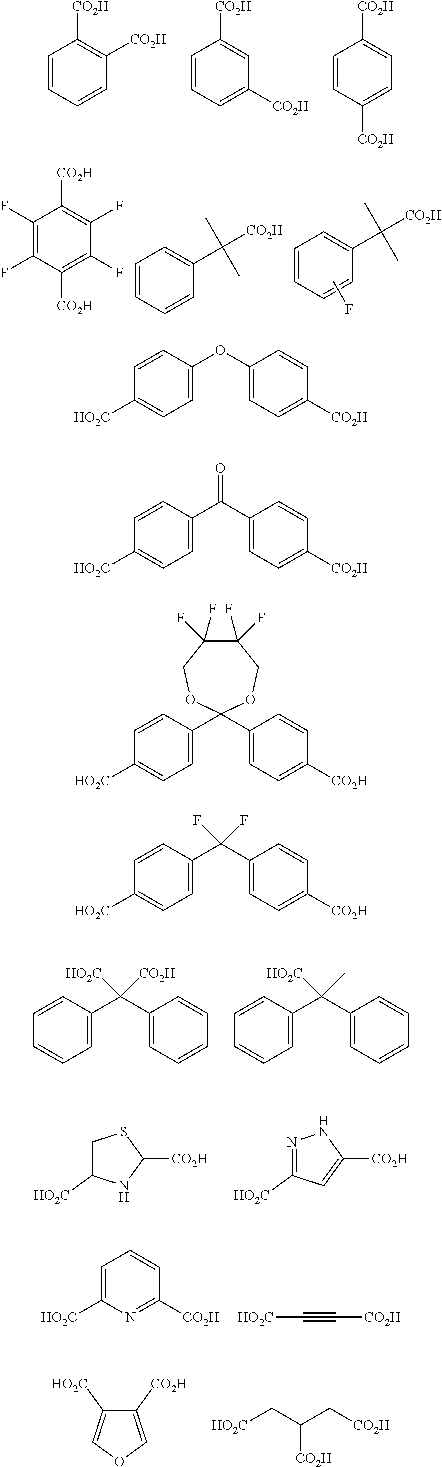

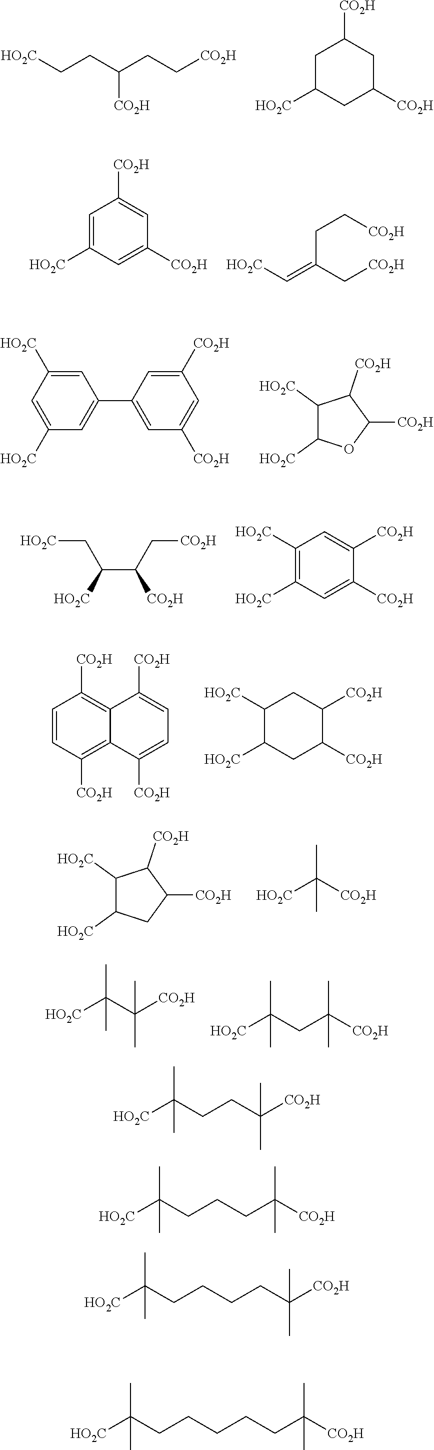

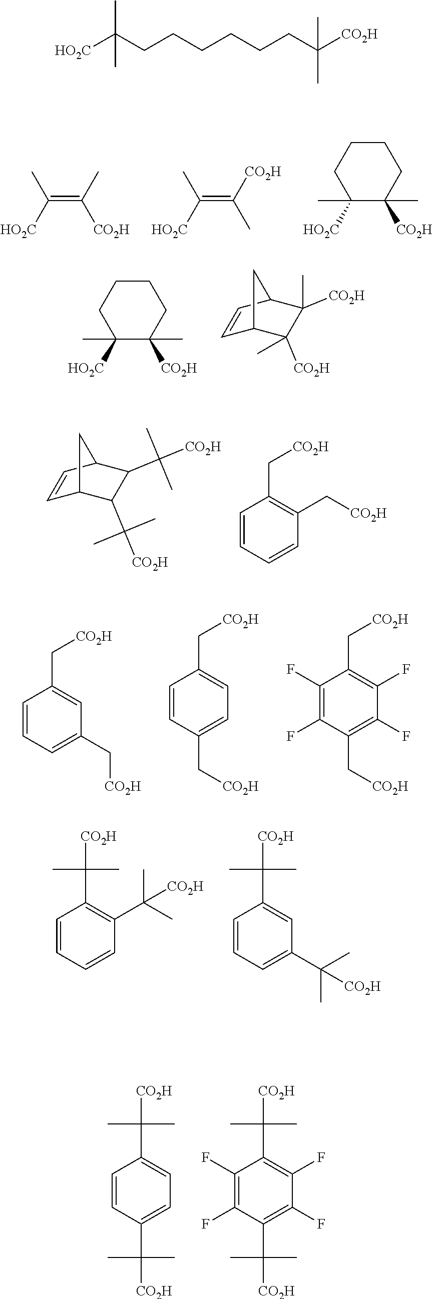

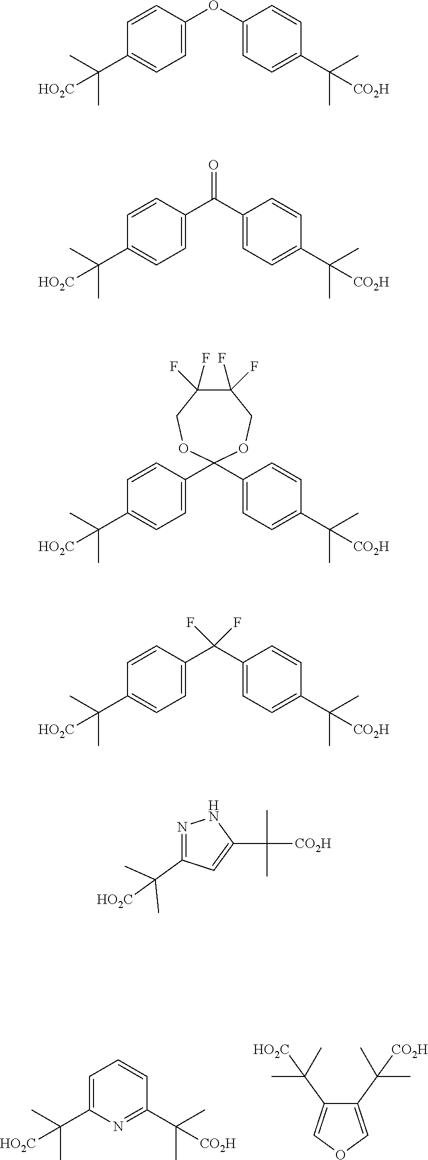

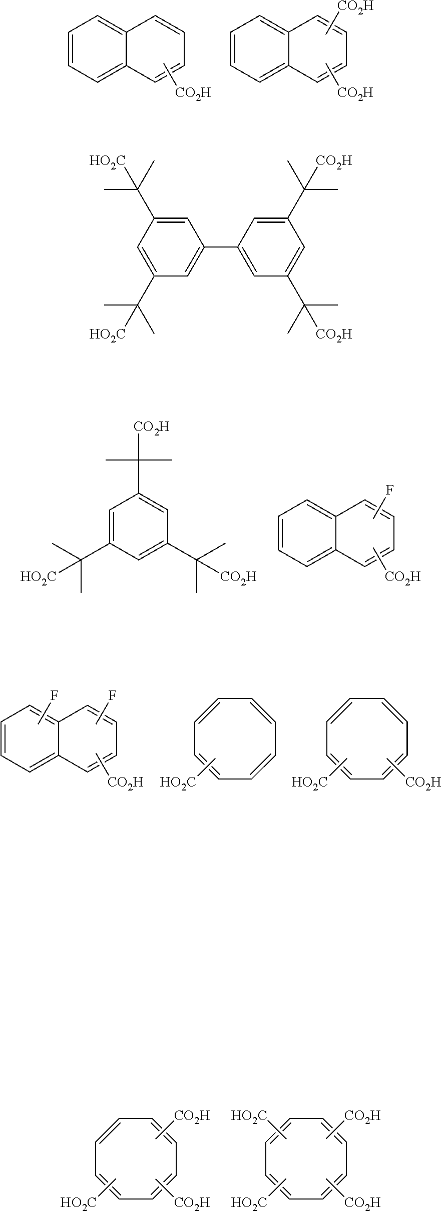

The carboxy group-containing polymer containing the repeating unit represented by the formula (2) may further contains any repeating unit (hereinafter, also referred to as other repeating unit) other than the repeating unit represented by the formula (2). Such other repeating unit is not particularly limited, and is preferably a unit capable of enhancing the solubility of a polymer which is difficult to dissolve only by a repeating unit having a carboxy group, in a solvent. Such other repeating unit is preferably a repeating unit having a rigid skeleton and having a cyclic structure expected to impart high etching resistance, or a repeating unit having a styrene skeleton.

Specific examples of such other repeating unit described above include those represented below, but are not limited thereto. In the following formulae, R^{A} is the same as described above, and each X^{B} is independently —CH₂— or —O—.

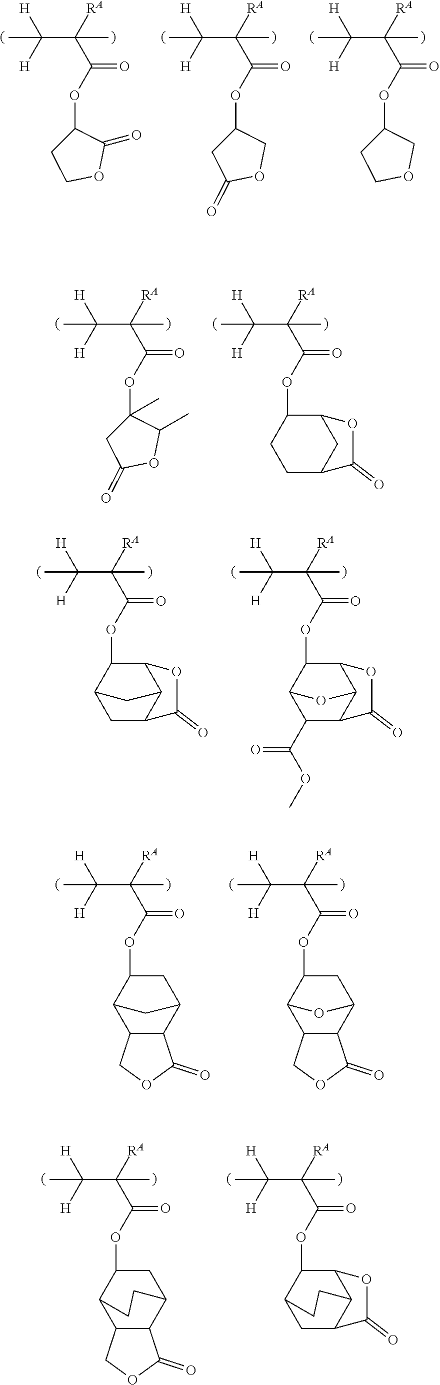

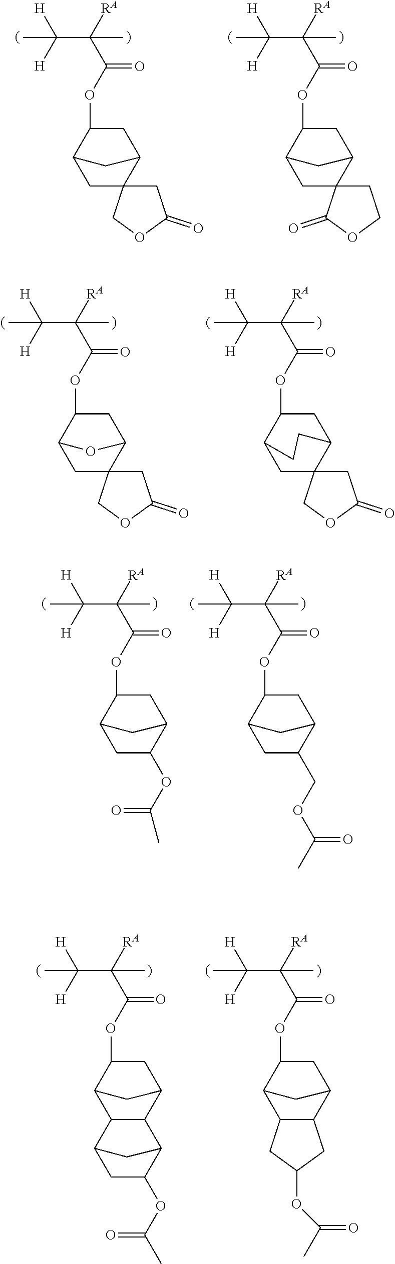

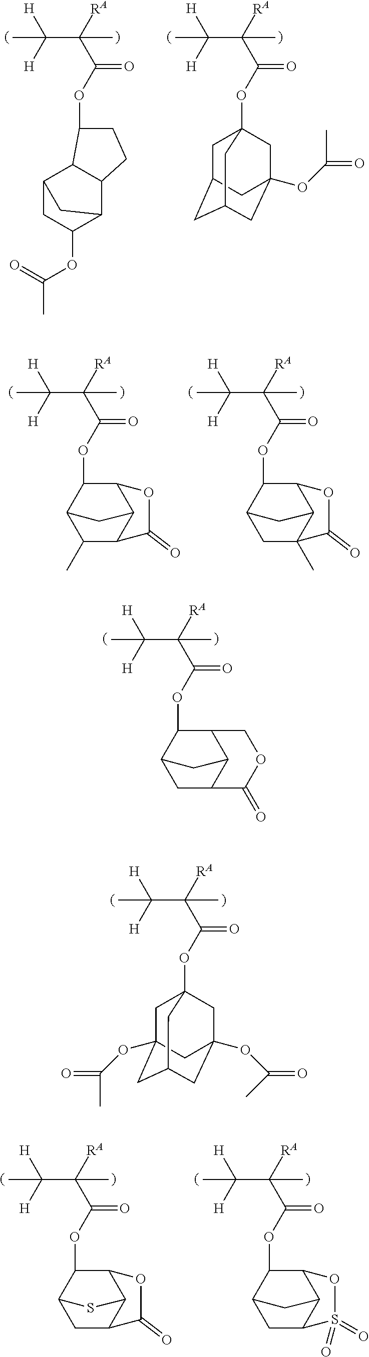

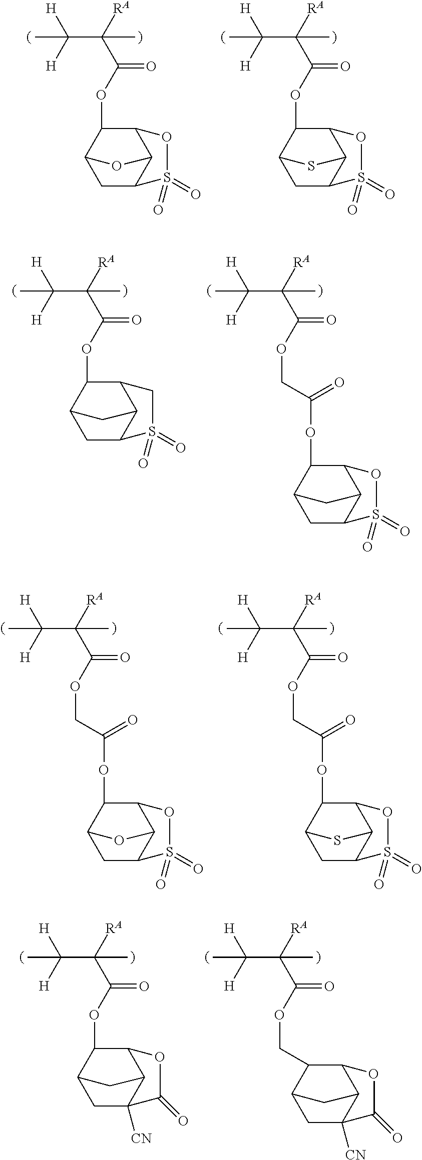

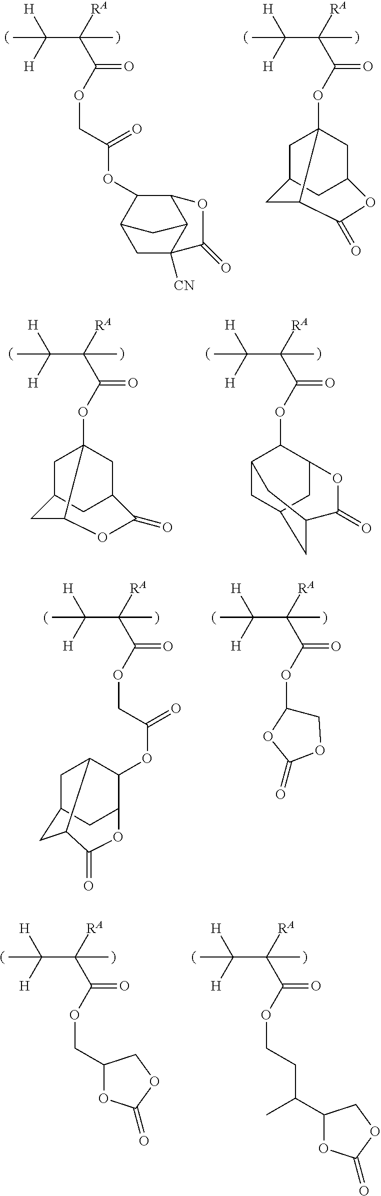

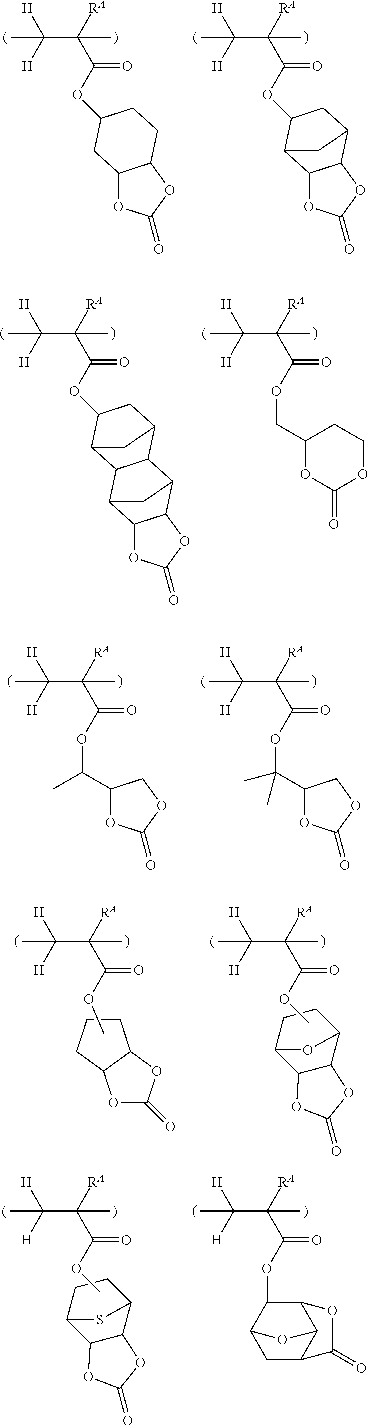

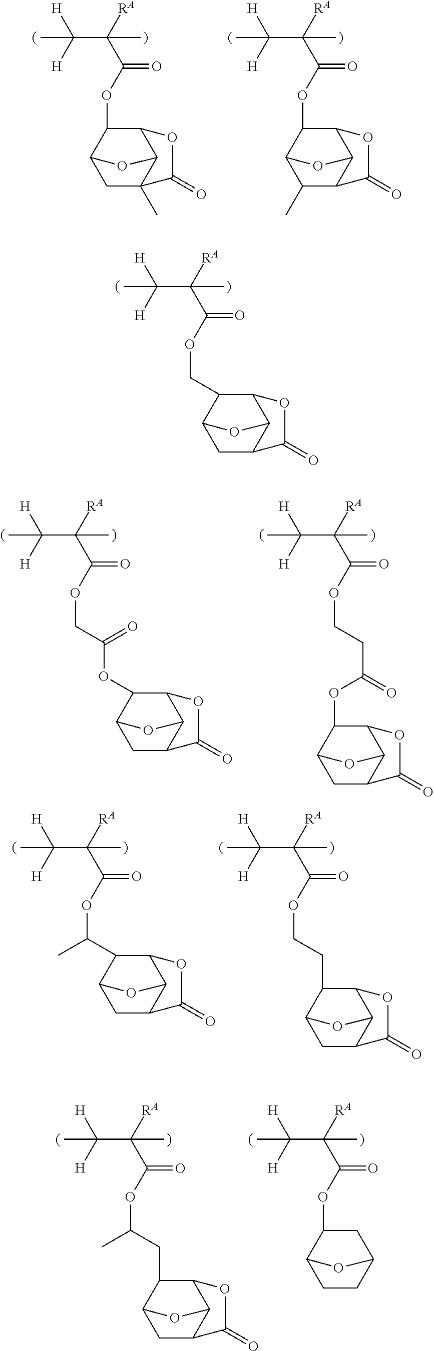

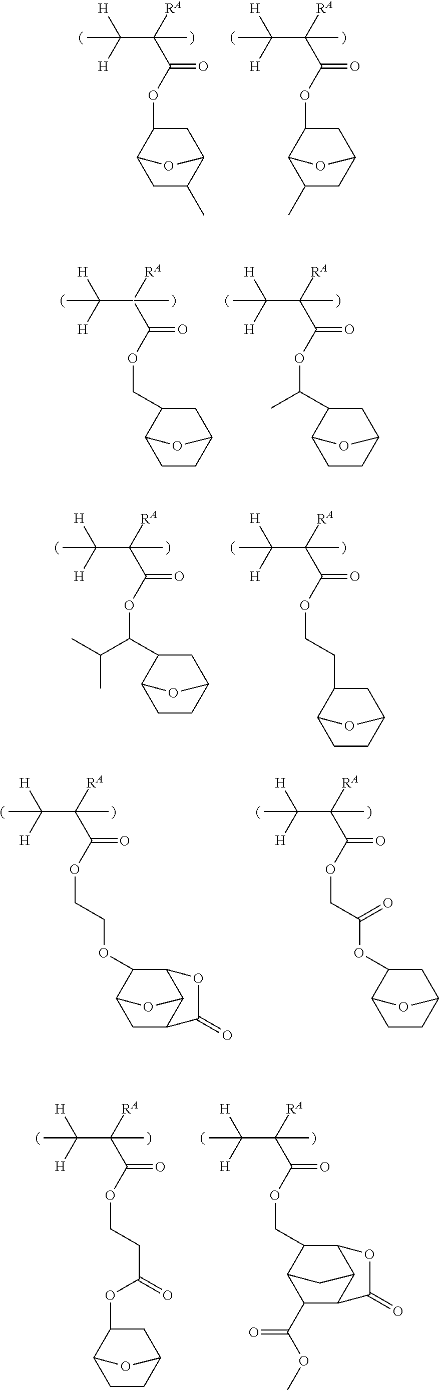

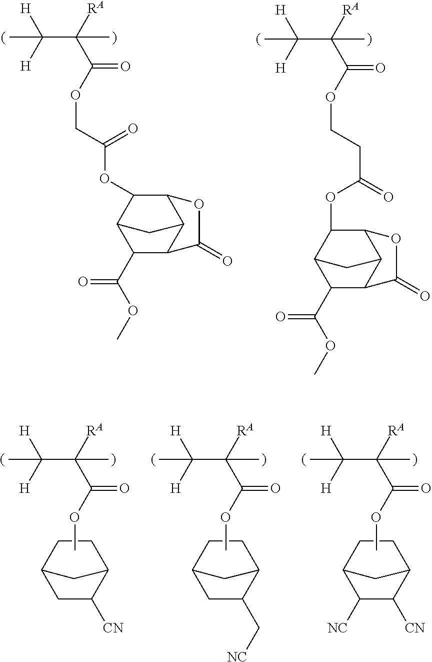

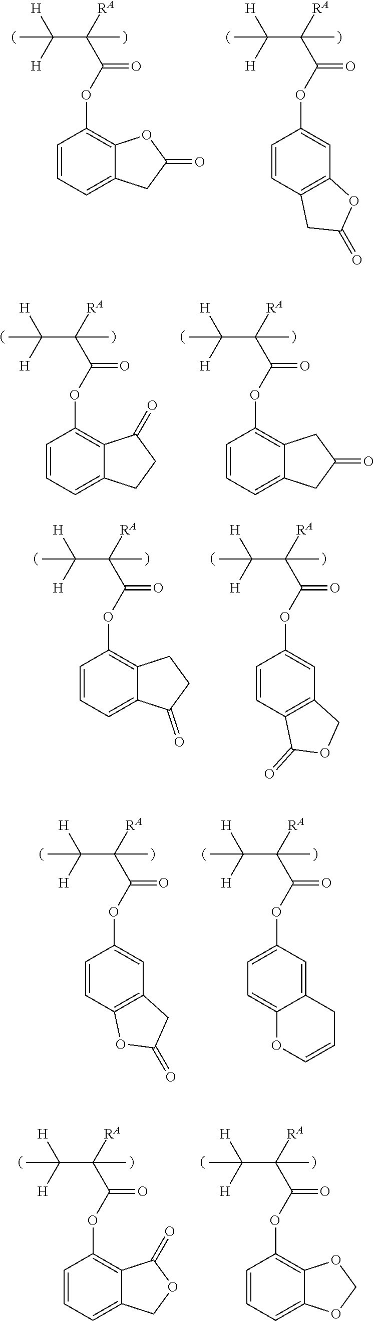

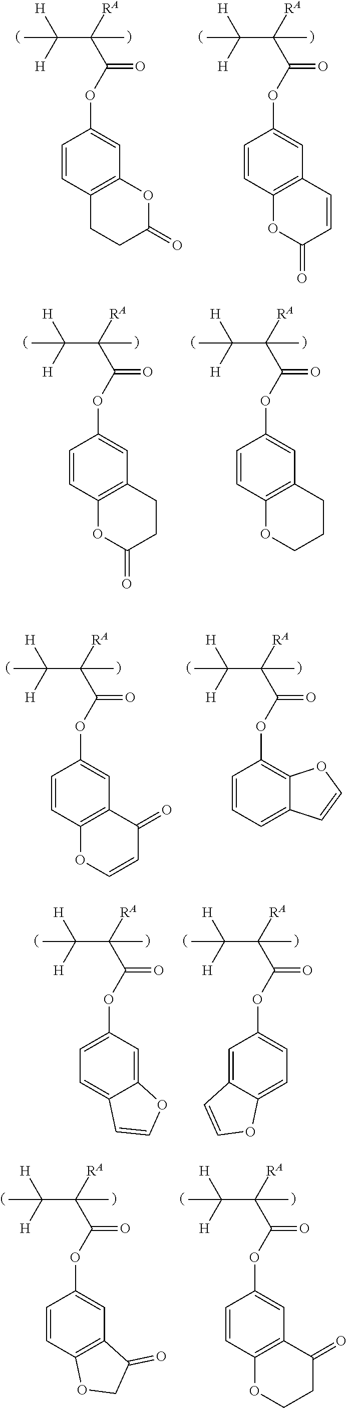

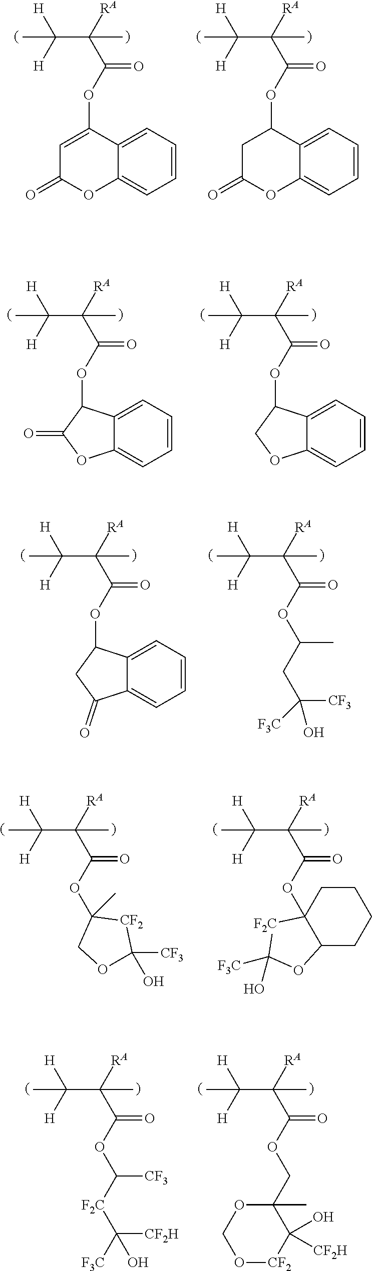

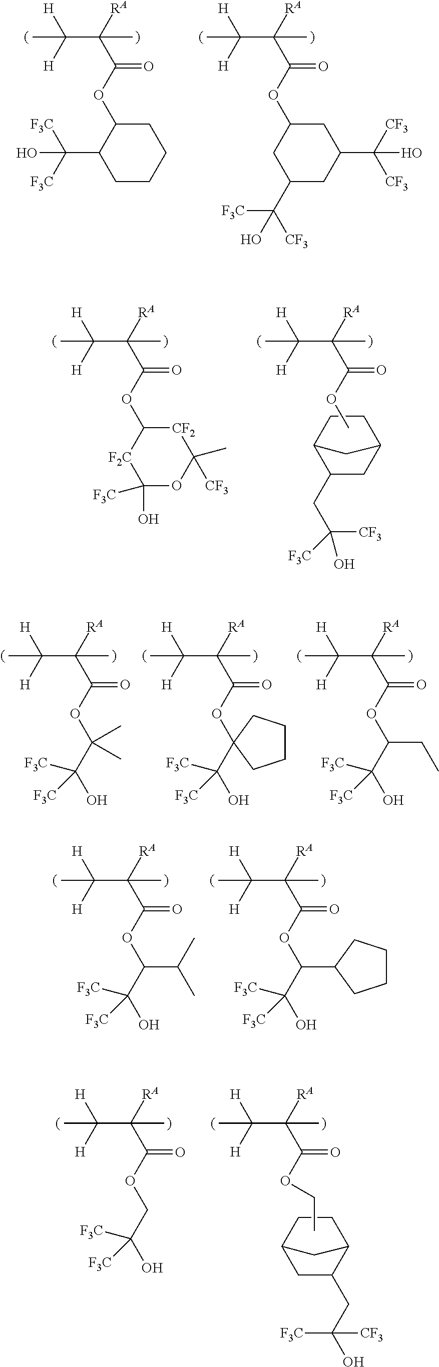

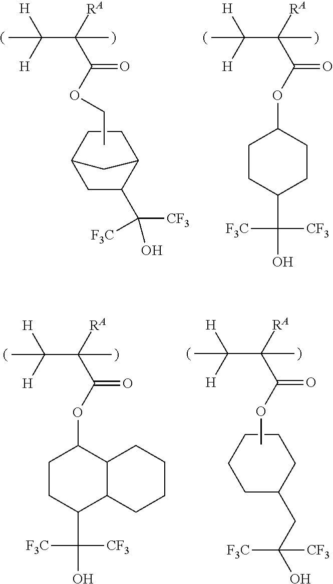

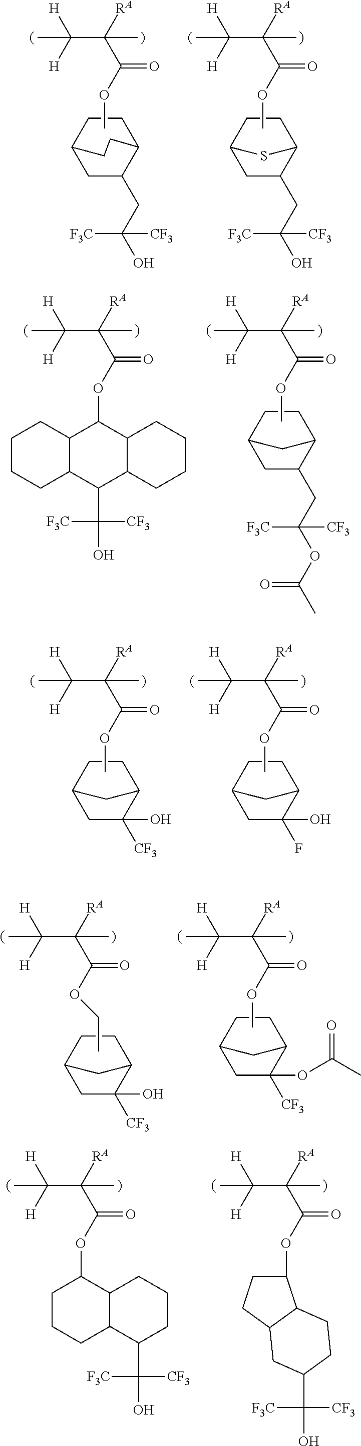

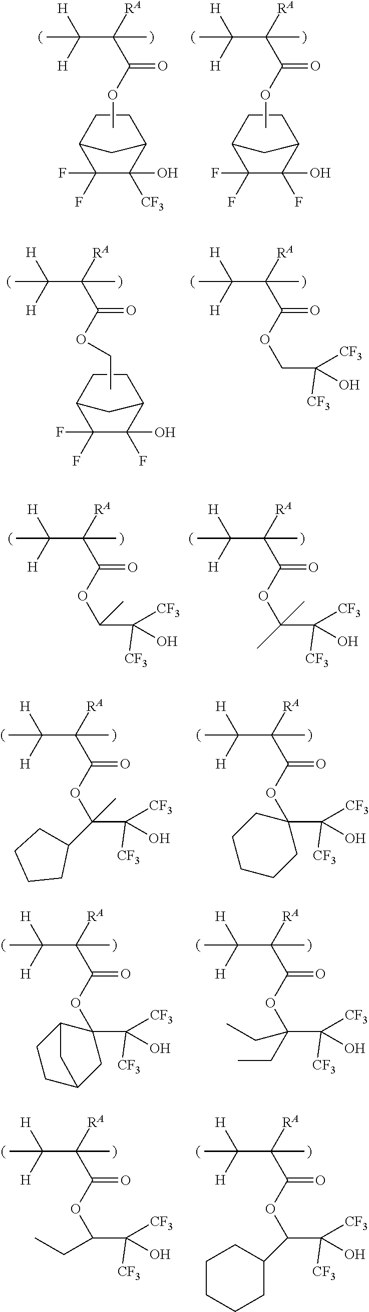

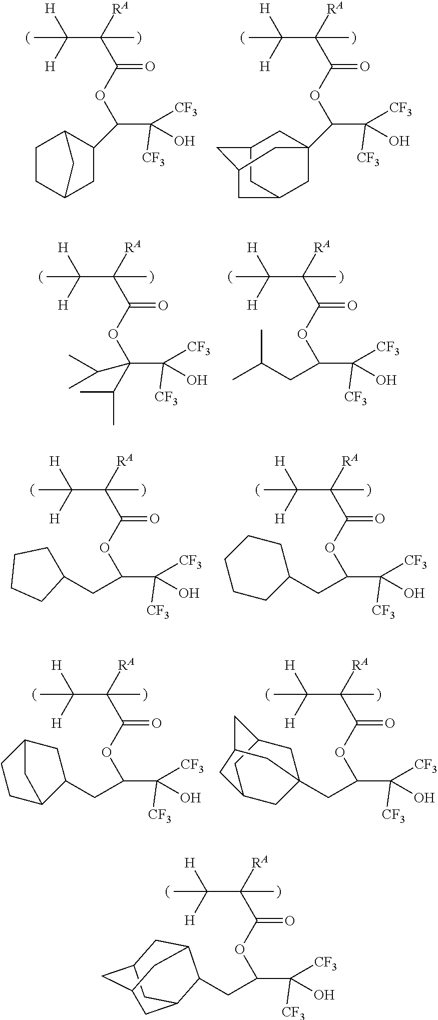

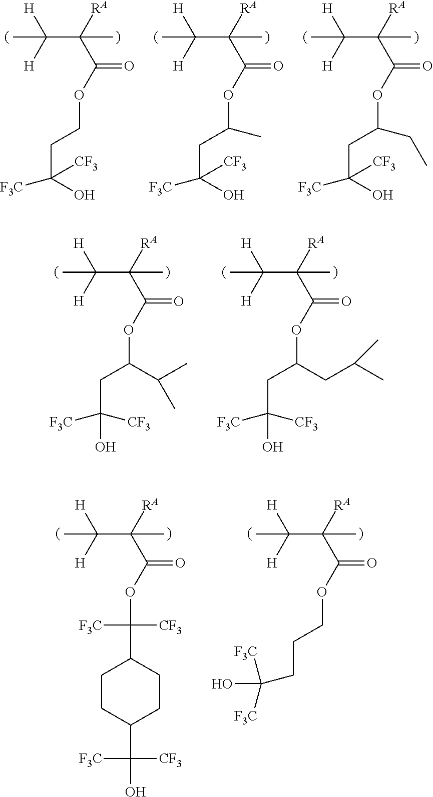

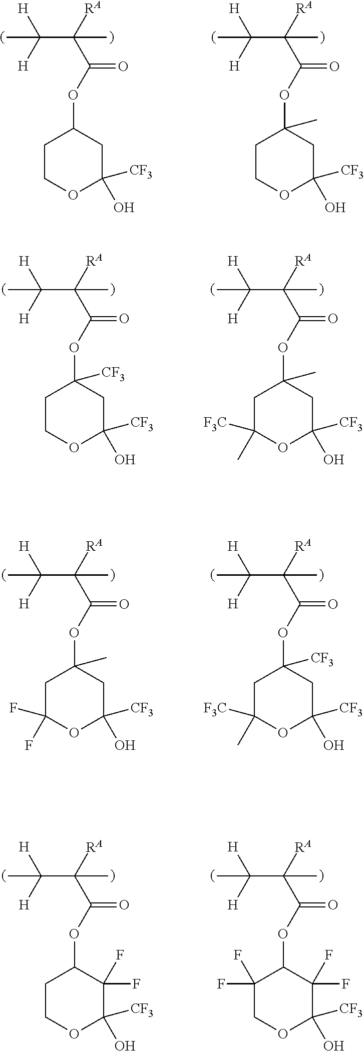

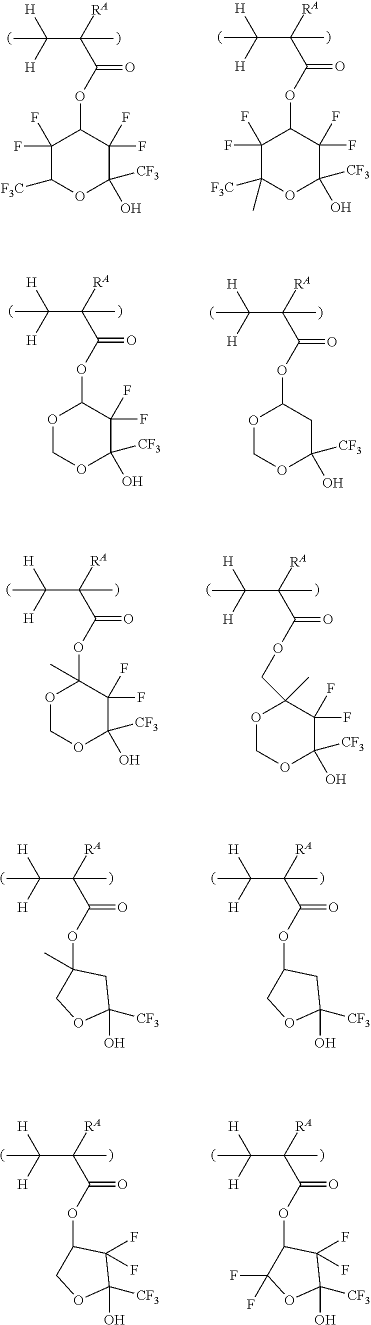

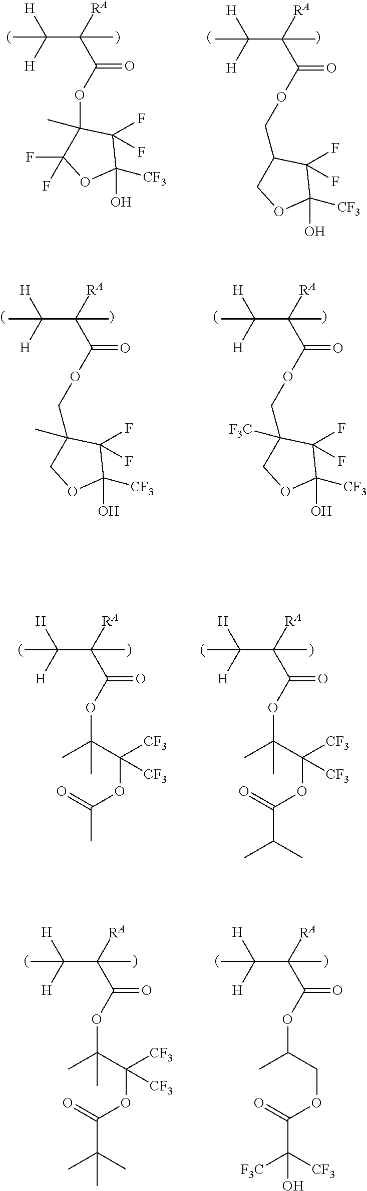

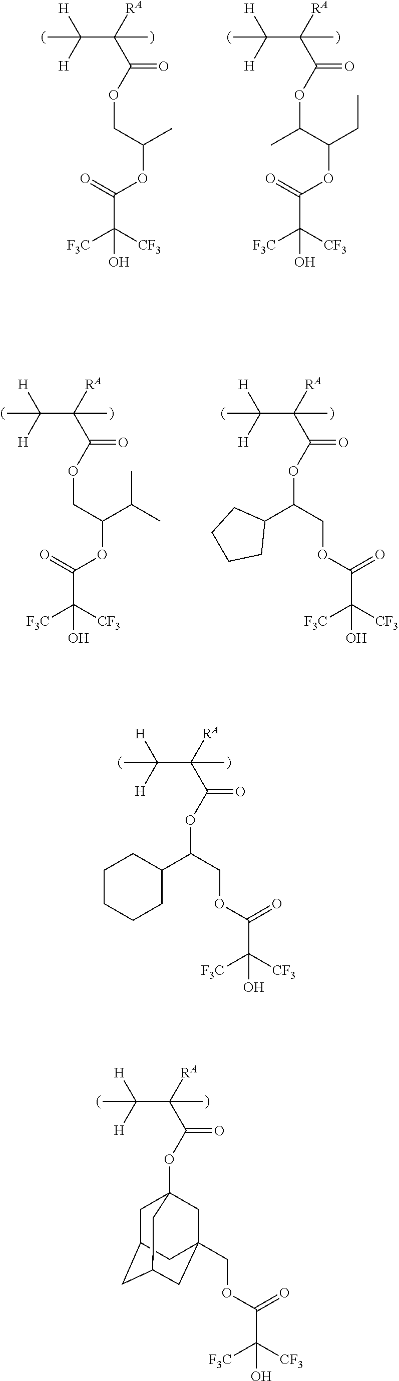

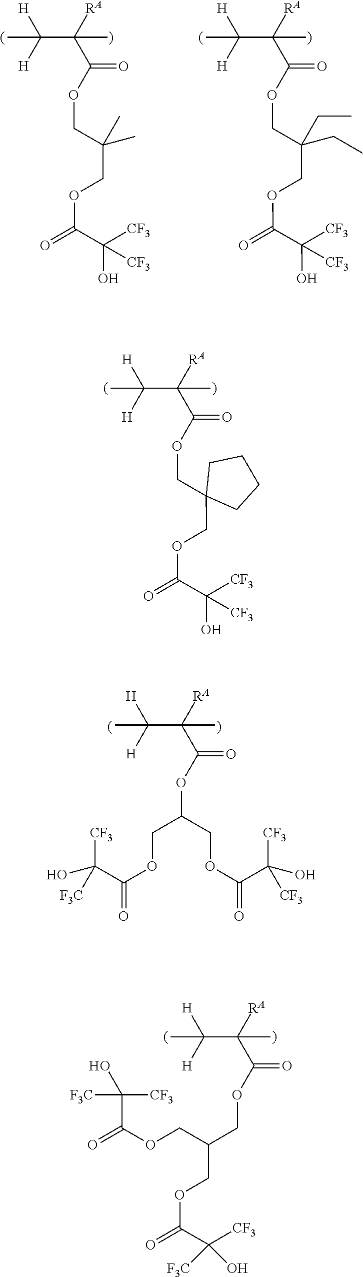

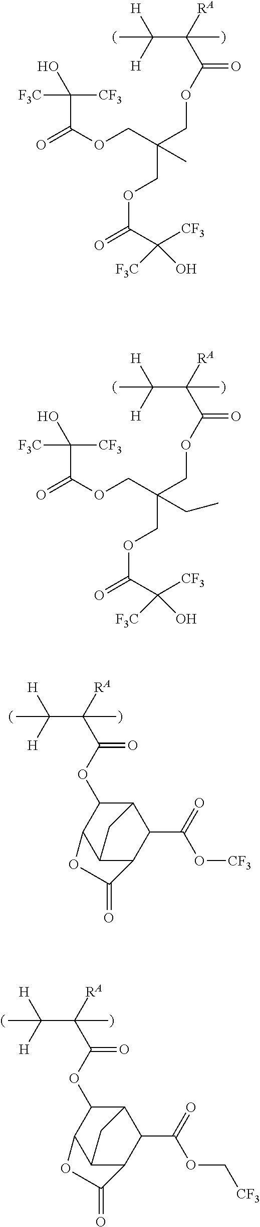

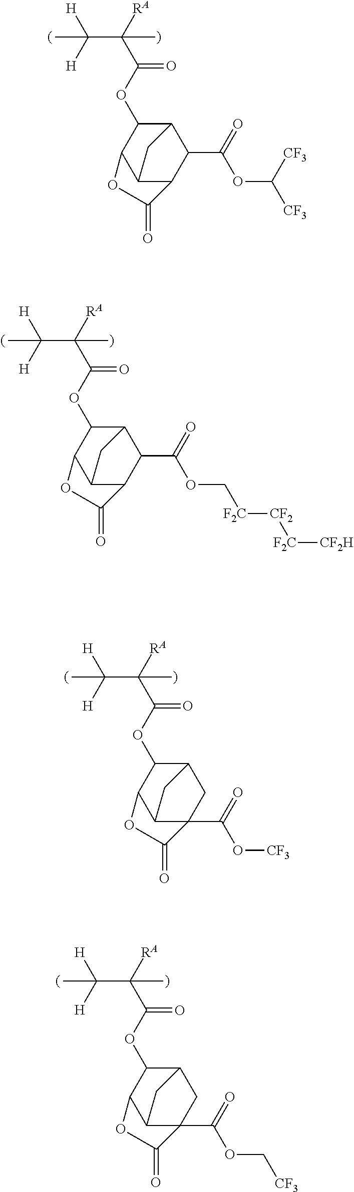

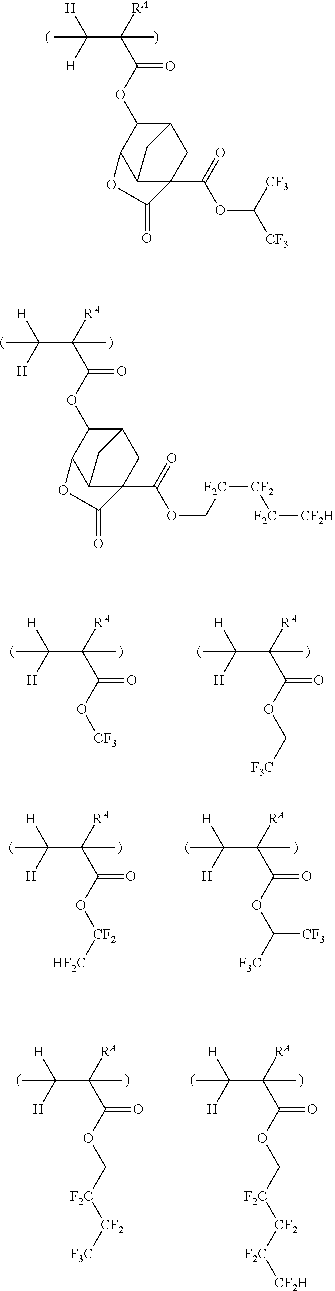

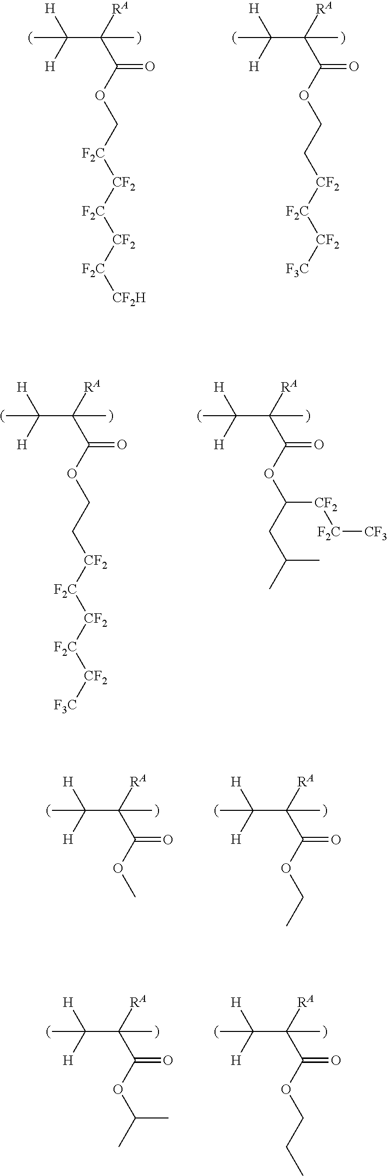

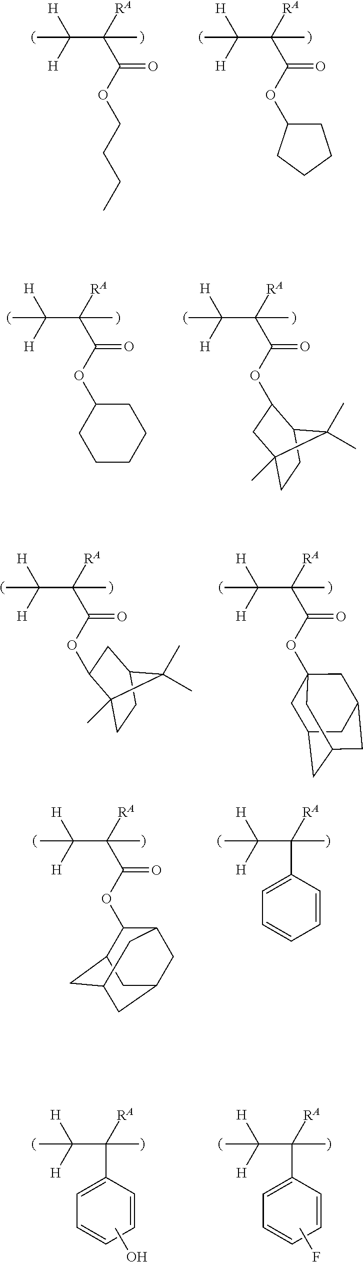

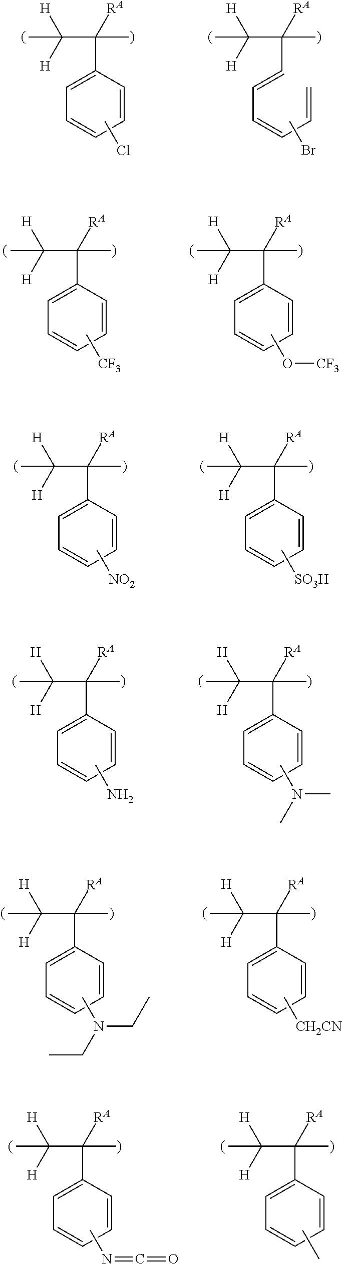

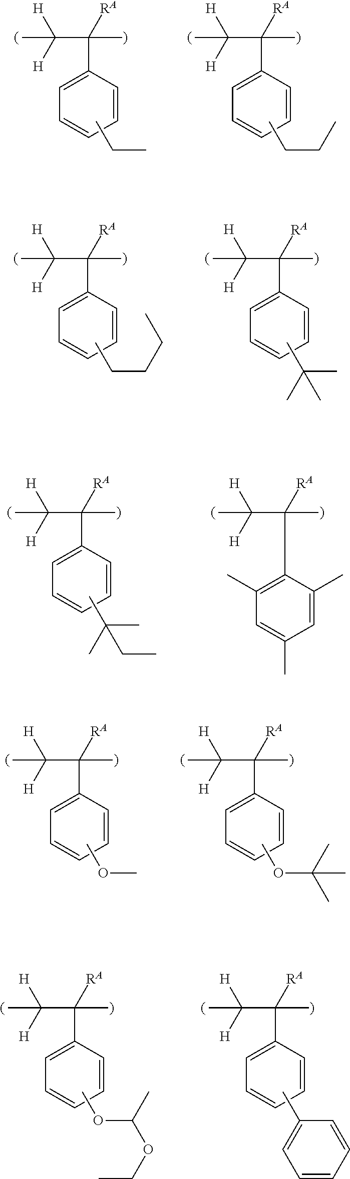

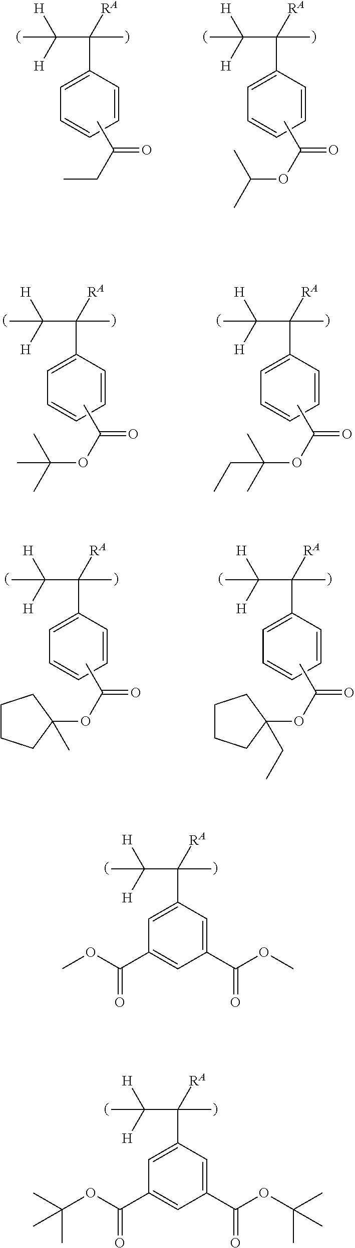

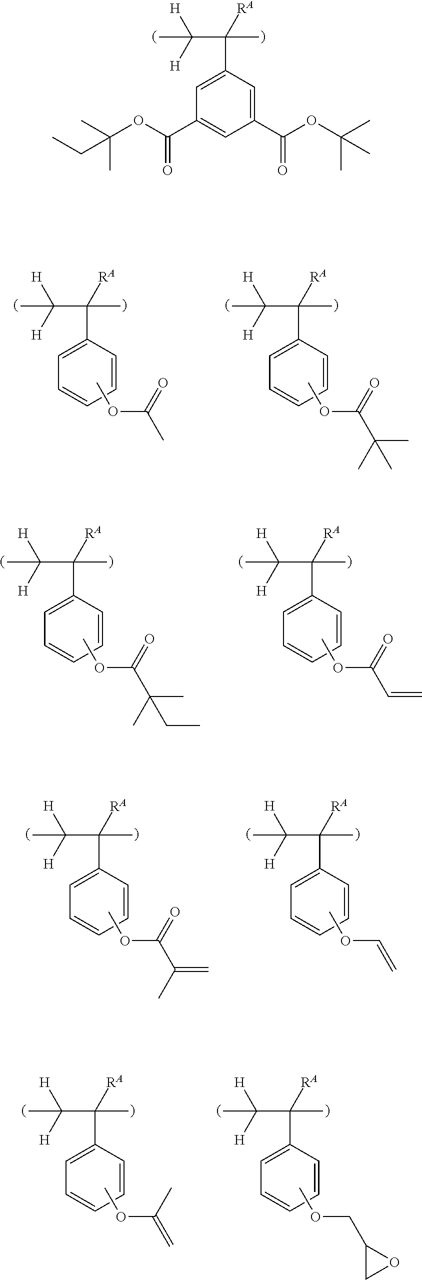

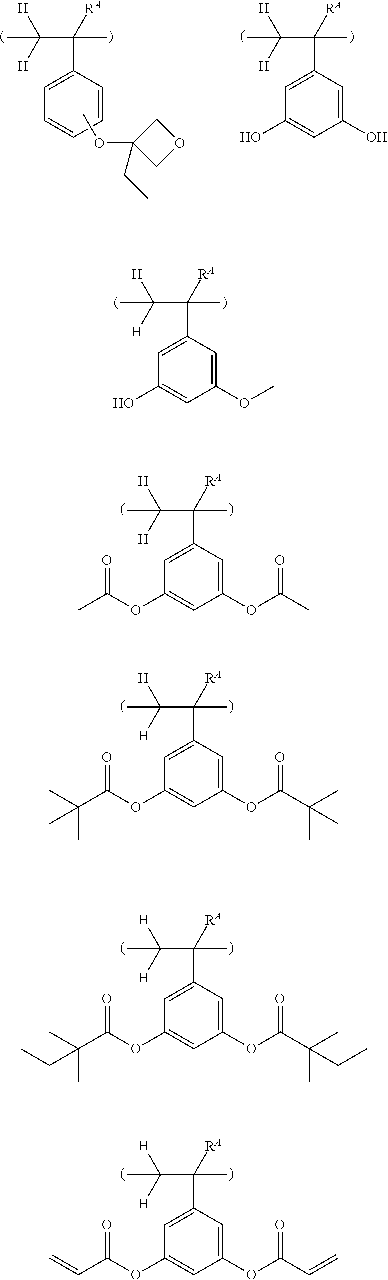

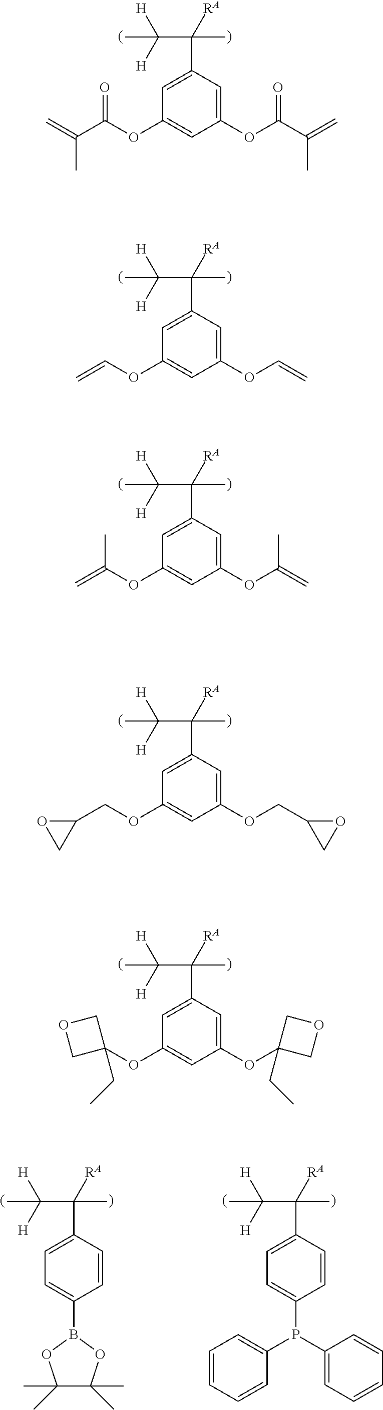

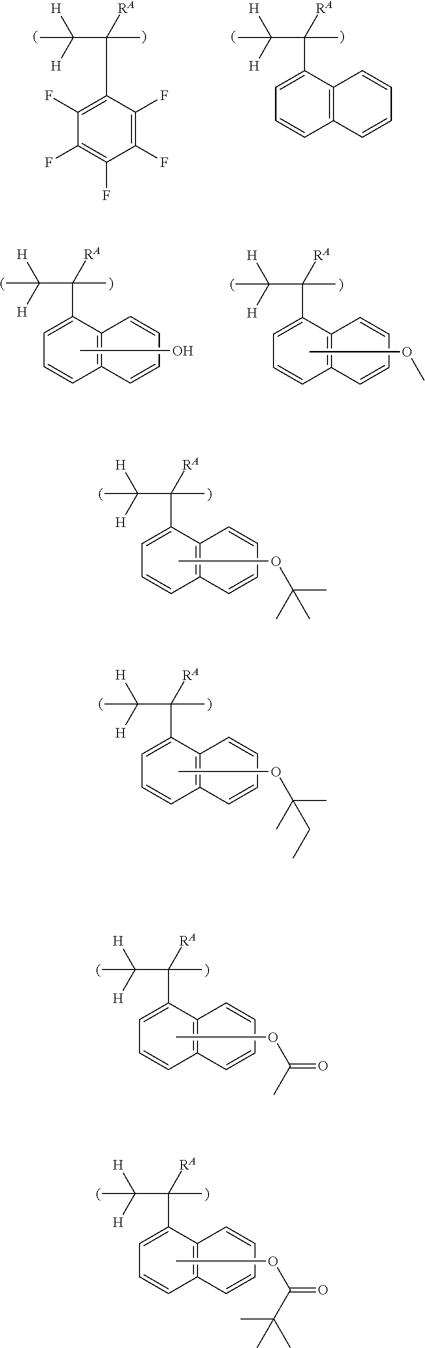

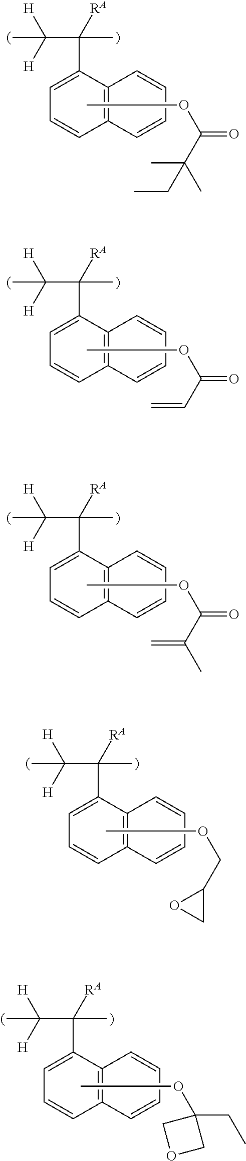

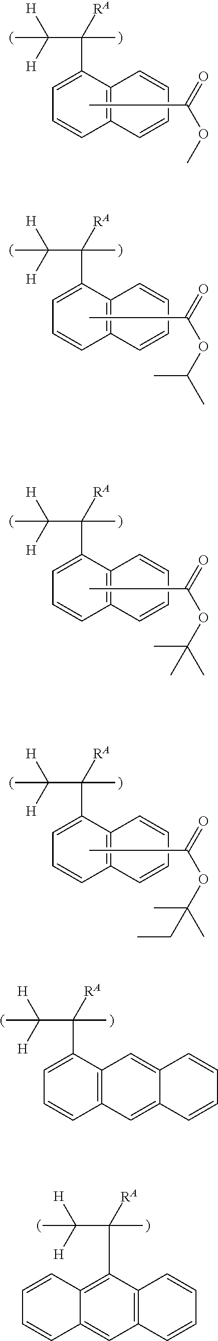

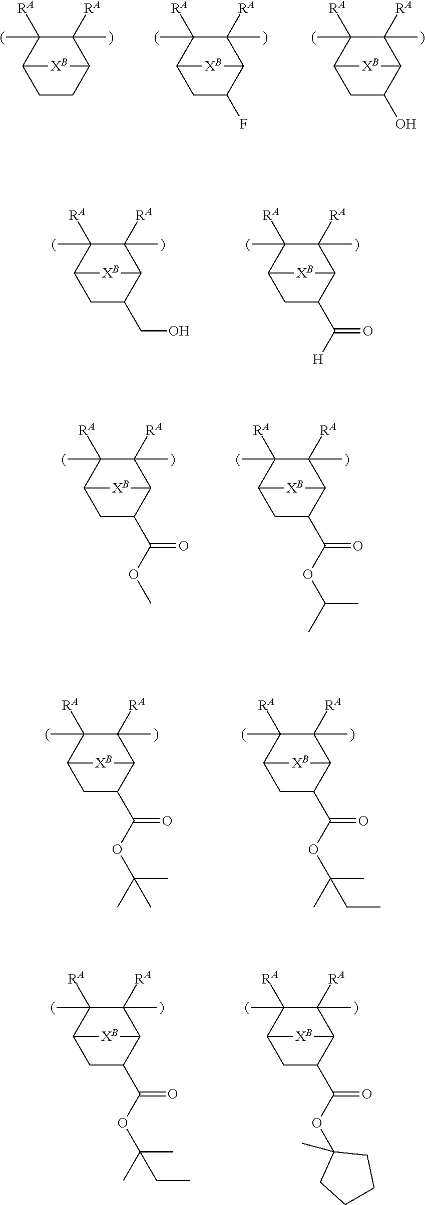

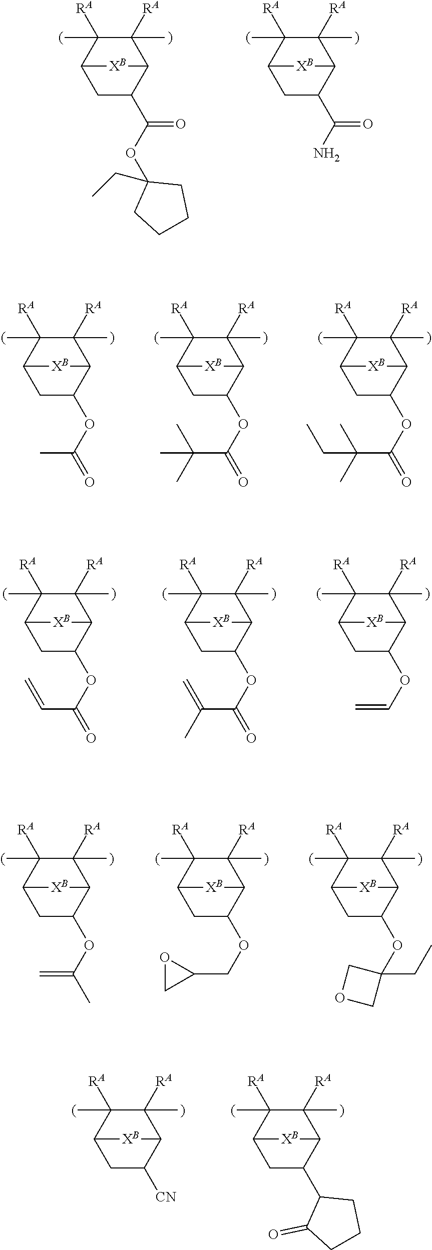

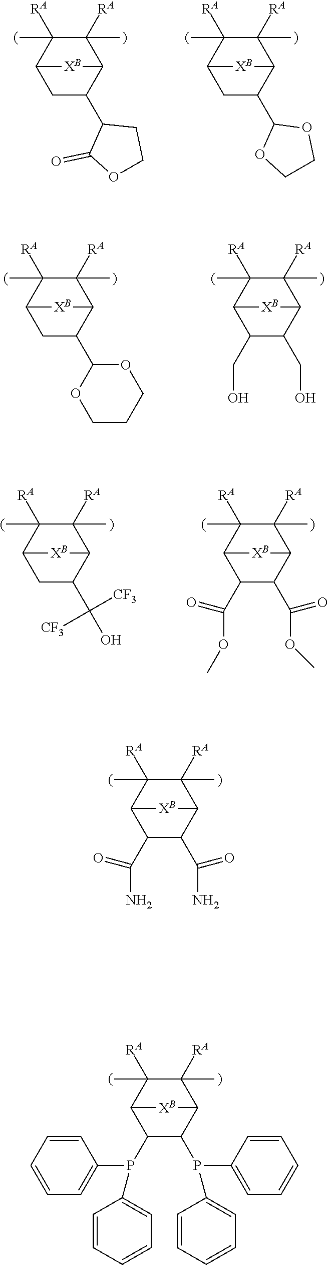

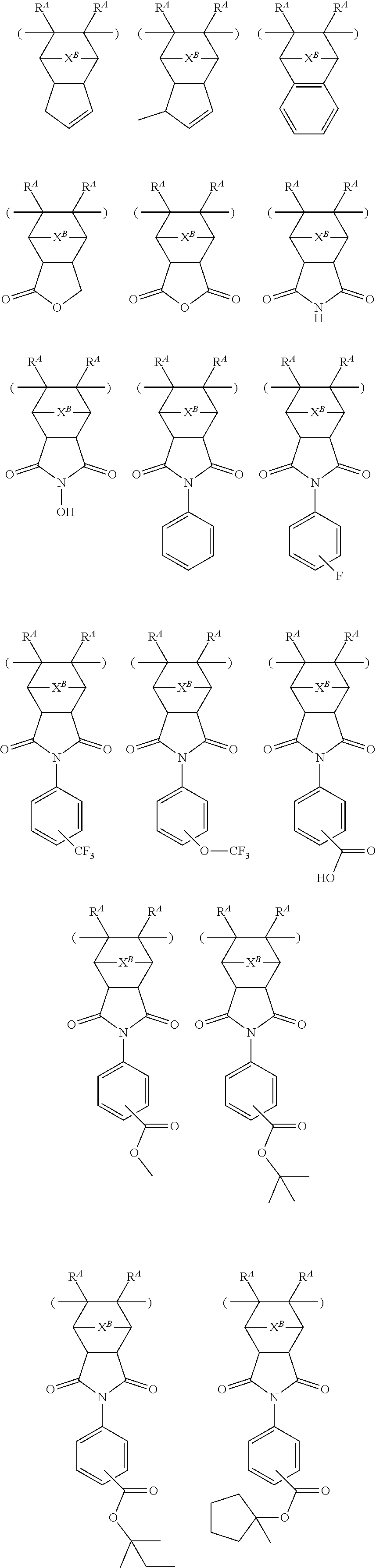

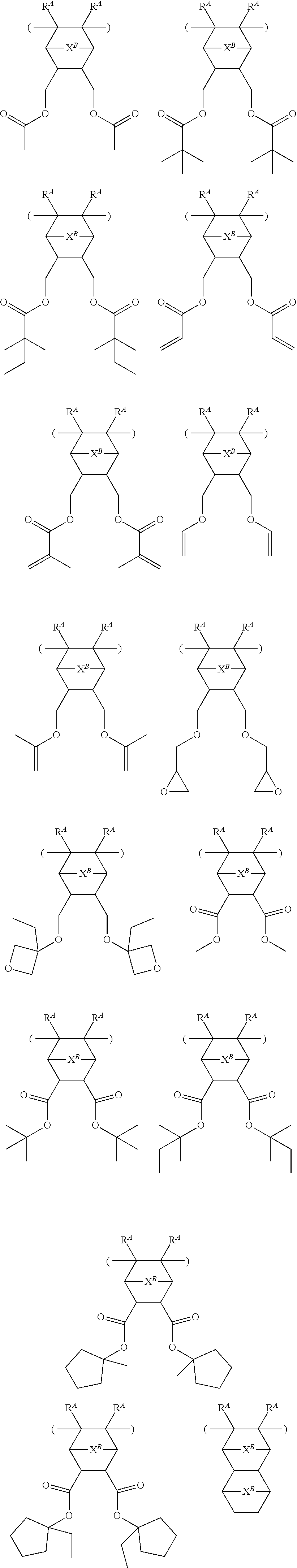

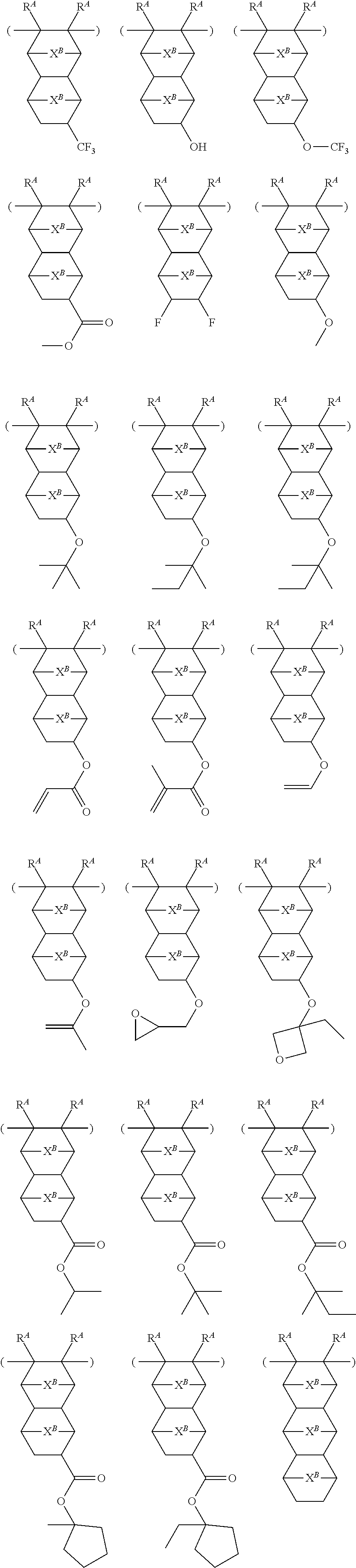

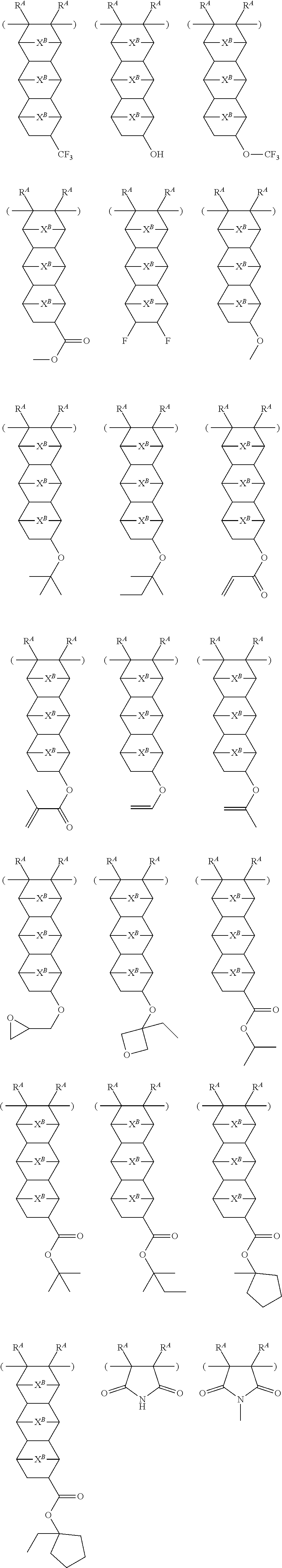

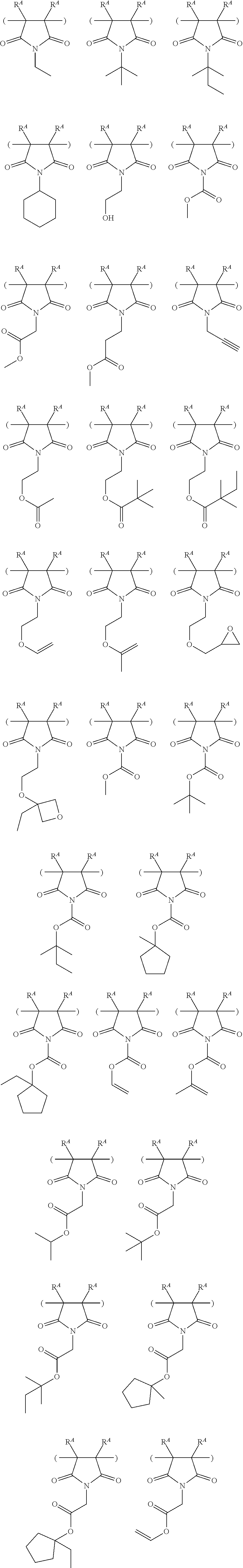

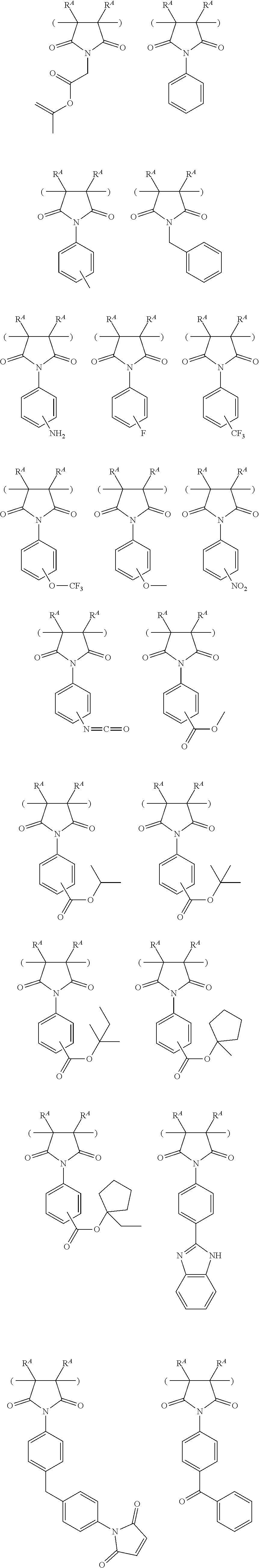

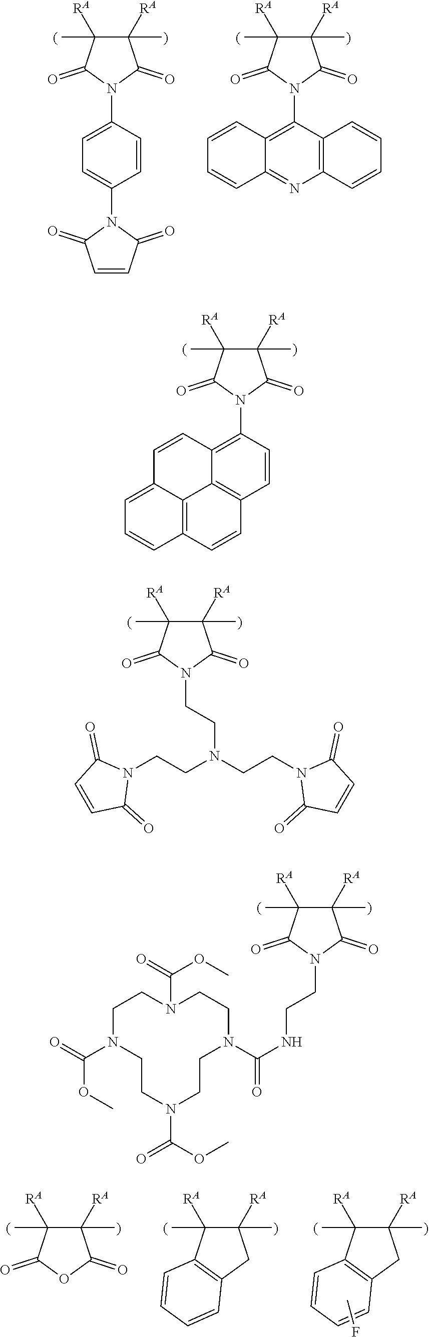

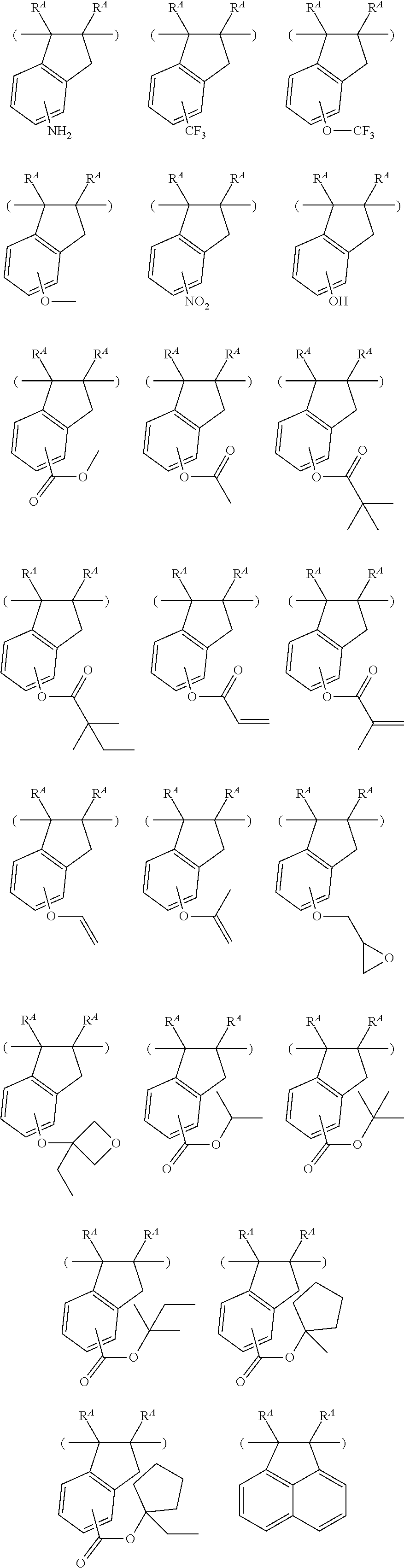

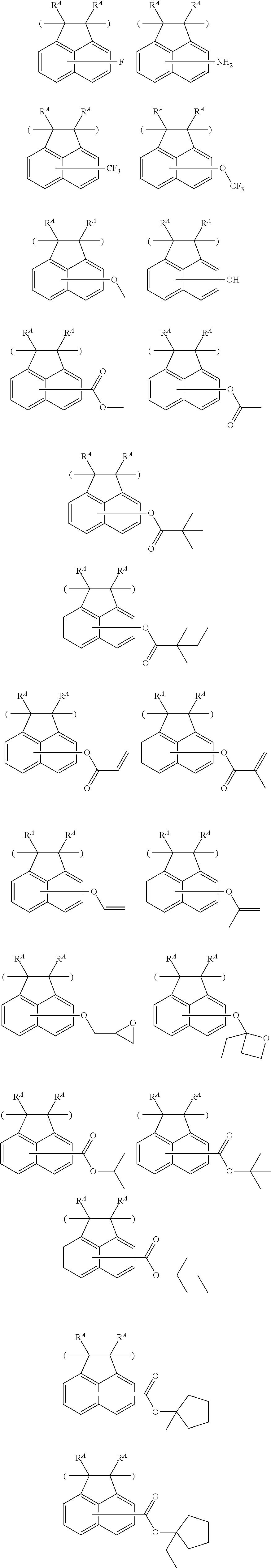

The content ratio of the hypervalent iodine compound represented by the formula (1) to the carboxy group-containing compound in the resist composition of the present invention (when the carboxy group-containing compound is a carboxy group-containing polymer, the content ratio of the hypervalent iodine compound represented by the formula (1) to a carboxylic acid-containing repeating unit in the polymer) is preferably 1:99 to 99:1, more preferably 10:90 to 90:10, further preferably 20:80 to 80:20 in terms of the molar ratio of hypervalent iodine compound represented by formula (1) carboxy group-containing compound. As the hypervalent iodine compound represented by the formula (1), one kind thereof may be used singly or combination of two or more kinds thereof may be used. Similarly, regarding the carboxy group-containing compound, one kind thereof may be used singly or combination of two or more kinds thereof may be used. When the carboxy group-containing compound is the polymer, one kind of the polymer may be used singly or combination of two or more kinds of the polymers different in compositional ratio, Mw and/or Mw/Mn may be used.

The content ratio (molar ratio) of the carboxy group-containing repeating unit and other repeating unit in the carboxy group-containing polymer is preferably 10:90 to 90:10, more preferably 15:85 to 85:15, further preferably 20:80 to 80:20 in terms of carboxy group-containing repeating unit:other repeating unit.

The weight average molecular weight (Mw) of the carboxy group-containing polymer is preferably 1000 to 500000, more preferably 3000 to 100000. Herein, the weight average molecular weight Mw and the number average molecular weight Mn in the present invention are each a value measured in terms of polystyrene by gel permeation chromatography (GPC) with tetrahydrofuran (THF) as a solvent.

The molecular weight distribution Mw/Mn can be determined from Mw and Mn thus obtained. When the molecular weight distribution (Mw/Mn) of the carboxy group-containing polymer is broad, a low-molecular-weight polymer and/or a high-molecular-weight polymer are present and therefore foreign substances may be found on a pattern after exposure and/or the shape of the pattern may deteriorate. Therefore, the influences by Mw and Mw/Mn are easily increased according to miniaturization of a pattern rule, and thus the Mw/Mn of the carboxy group-containing polymer is preferably 1.00 to 2.00 which corresponds to a narrow distribution, in order to obtain a resist composition suitably used for a fine pattern dimension. Mw/Mn is preferably more than 1.30, and the lower limit thereof may be 1.40, 1.50 or 1.60 and the upper limit thereof may be 1.70, 1.80 or 1.90.

Examples of the process for synthesizing the carboxy group-containing polymer include a process consisting steps of adding a radical polymerization initiator to a monomer imparting the above-described repeating unit in an organic solvent and heating for polymerizing.

Specific examples of the organic solvent used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and y-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the polymerization initiator added is preferably 0.01 to 25% by mol relative to the total monomer to be polymerized. The reaction temperature is preferably 50 to 150° C., more preferably 60 to 100° C. The reaction time is preferably 2 to 24 hours, and is more preferably 2 to 12 hours from the viewpoint of production efficiency.

The polymerization initiator may be added to the monomer solution and these may be supplied to a reaction oven, or an initiator solution may be prepared separately from the monomer solution and these may be each independently supplied to a reaction oven. Since the polymerization reaction can progress due to radical generated from the initiator during a waiting time to generate an ultra-high molecular weight polymer, the monomer solution and the initiator solution are preferably each independently prepared and dropped from the viewpoint of quality control. A known chain transfer agent such as dodecylmercaptan or 2-mercaptoethanol may be used in combination for adjustment of the molecular weight. In this case, the amount of the chain transfer agent added is preferably 0.01 to 20% by mol based on the total monomer to be polymerized.

The amount of each monomer in the monomer solution may be appropriately set, for example, so that a preferred proportion of the repeating unit contained is achieved.

### [Other Hypervalent Iodine Compounds]

The resist composition of the present invention may further contain, as an optional component, other hypervalent iodine compound other than the hypervalent iodine compound represented by the formula (1). By adding such other hypervalent iodine compound, reactivity against light can be controlled, and thus, sensitivity is adjusted. Such other hypervalent iodine compound is preferably a hypervalent iodine compound represented by the following formula (4) or (5) (hereinafter, also referred to as other hypervalent iodine compound).

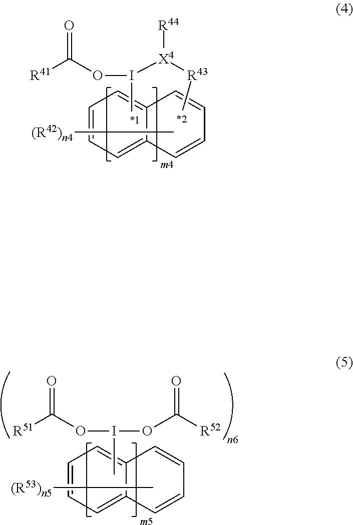

In the formulae, m4 and m5 are each an integer of 0 to 2. n4 is an integer of 0 to 3 when m4 is 0, or is an integer of 0 to 5 when m4 is 1, or is an integer of 0 to 7 when m4 is 2. When m5 is 0, n6 is an integer of 1 to 3, n5 is an integer of 0 to 5, and 1≤(n5+n6)≤6 is satisfied.

When m5 is 1, n6 is an integer of 1 to 3, n5 is an integer of 0 to 7, and 1≤(n5+n6)≤8 is satisfied.

When m5 is 2, n6 is an integer of 1 to 3, n5 is an integer of 0 to 9, and 1≤(n5+n6)≤10 is satisfied.

*1 and *2 each represent a point of attachment to a carbon atom in an aromatic ring in the formula, provided that *1 and *2 have to be bound to adjacent carbon atoms in an aromatic ring.

R⁴¹ is a halogen atom, or a hydrocarbyl group having 1 to 10 carbon atoms and optionally containing a heteroatom.

R⁴² is a halogen atom, or a hydrocarbyl group having 1 to 40 carbon atoms and optionally containing a heteroatom. When n4 is 2 to 7, R⁴²s are the same as or different from each other. In addition, plural R⁴²s are optionally bound to each other to form a ring together with carbon atoms in an aromatic ring to which these are bound, provided that R⁴² is not bound to any carbon atom in an aromatic ring adjacent to *1.

R⁴³ is a carbonyl group, or a hydrocarbylene group having 1 to 10 carbon atoms and optionally containing a heteroatom.

X⁴ is an oxygen atom, a nitrogen atom, or a sulfur atom, and when X⁴ is a nitrogen atom, R⁴⁴ is present; and
R⁴⁴ is a hydrogen atom, a carbonyl group, a halogen atom, or a hydrocarbyl group or ester having 1 to 20 carbon atoms and optionally containing a heteroatom.

R⁵¹ and R⁵² are each independently a halogen atom, or a hydrocarbyl group having 1 to 10 carbon atoms and optionally containing a heteroatom. When n6 is 2 to 3, R⁵¹s and R⁵²s are the same as or different from each other.

R⁵³ is a halogen atom, or a hydrocarbyl group having 1 to 40 carbon atoms and optionally containing a heteroatom. When n5 is 2 to 9, R⁵³s are the same as or different from each other. In addition, plural R⁵³s are optionally bound to each other to form a ring together with carbon atoms in an aromatic ring to which these are bound.

In the general formula (4), m4 is an integer of 0 to 2. n4 is an integer of 0 to 3 when m4 is 0, or is an integer of 0 to 5 when m4 is 1, or is an integer of 0 to 7 when m4 is 2. n4 is preferably 0, 1, 2, 3 or 4, more preferably 0, 1, 2 or 3, further preferably 0, 1 or 2, most preferably 0 or 1.

In the general formula (4), R⁴¹ is a halogen atom, or a hydrocarbyl group having 1 to 10 carbon atoms and optionally containing a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be any of linear, branched or cyclic. Specific examples thereof include alkyl groups each having 1 to 10 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group and an adamantyl group; alkenyl groups each having 2 to 10 carbon atoms, such as a vinyl group and an allyl group; aryl groups each having 6 to 10 carbon atoms, such as a phenyl group and a naphthyl group; and any group obtained by combination thereof. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R⁴¹ is preferably a hydrocarbyl group having 1 to 4 carbon atoms or a fluorinated hydrocarbyl group having 1 to 4 carbon atoms, more preferably a hydrocarbyl group having 1 to 4 carbon atoms.

In the general formula (4), R⁴² is a halogen atom, or a hydrocarbyl group having 1 to 40 carbon atoms and optionally containing a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be any of linear, branched or cyclic. Specific examples thereof include alkyl groups each having 1 to 40 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. When n4 is 2 to 7, R²s are the same as or different from each other. In addition, plural R⁴²s are optionally bound to each other to form a ring together with carbon atoms in an aromatic ring to which these are bound, provided that R⁴² is not bound to any carbon atom in an aromatic ring adjacent to *1.

In the general formula (4), R⁴³ is a carbonyl group, or a hydrocarbylene group having 1 to 10 carbon atoms and optionally containing a heteroatom. The hydrocarbylene group having 1 to 10 carbon atoms may be saturated or unsaturated, and may be any of linear, branched or cyclic. Specific examples thereof include alkylene groups each having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group and a decane-1,10-diyl group; cyclic saturated hydrocarbylene groups each having 3 to 10 carbon atoms, such as a cyclopentanediyl group, a cyclohexanediyl group, a norbornanediyl group, an adamantanediyl group and a tricyclo[5.2.1.0^{2,6}]decanediyl group; alkenylene groups each having 2 to 10 carbon atoms, such as a vinylene group and a propynylene group; arylene groups each having 6 to 10 carbon atoms, such as a phenylene group, a methyl phenylene group, an ethyl phenylene group, a n-propyl phenylene group, an isopropyl phenylene group, a n-butyl phenylene group and a naphthylene group; and any group obtained by combination thereof. In addition, some or all of hydrogen atoms in the hydrocarbylene group are each optionally substituted with a group containing a heteroatom such as an oxygen atom, a sulfur atom, a nitrogen atom, or a halogen atom, some of —CH₂— in the hydrocarbylene group are each optionally substituted with a group containing a heteroatom such as an oxygen atom, a sulfur atom, or a nitrogen atom, and as a result, a hydroxy group, a cyano group, an alkyl halide group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained. R⁴³ is preferably a carbonyl group, a hydrocarbylene group having 1 to 4 carbon atoms or a fluorinated hydrocarbylene group having 1 to 4 carbon atoms.

In the general formula (4), X⁴ is an oxygen atom, a nitrogen atom, or a sulfur atom, and when X⁴ is a nitrogen atom, R⁴⁴ is contained. In other words, when X⁴ is a nitrogen atom, the formula (4) contains an NR⁴⁴ group. In this regard, when X⁴ is an oxygen atom or a sulfur atom, the formula (4) contains no R⁴⁴ group.

In the general formula (4), R⁴⁴ is a hydrogen atom, a carbonyl group, a halogen atom, or a hydrocarbyl group or ester having 1 to 20 carbon atoms and optionally containing a heteroatom. Specific examples of the halogen atom include a fluorine atom, a chlorine atom, a bromine atom, and an iodine atom. The hydrocarbyl group having 1 to 20 carbon atoms may be saturated or unsaturated, and may be any of linear, branched or cyclic. Specific examples thereof include alkyl groups each having 1 to 20 carbon atoms, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 20 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 20 carbon atoms, such as a phenyl group, a naphthyl group and an anthracenyl group. In addition, some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, carboxylic anhydride (—C(═O)—O—C(═O)—), or the like is optionally contained.

In the general formula (4), *1 and *2 each represent a point of attachment to a carbon atom in an aromatic ring in the formula, provided that *1 and *2 are bound to adjacent carbon atoms in an aromatic ring. Such a combination of *1, *2 and m4 is considered to have seven patterns shown below:

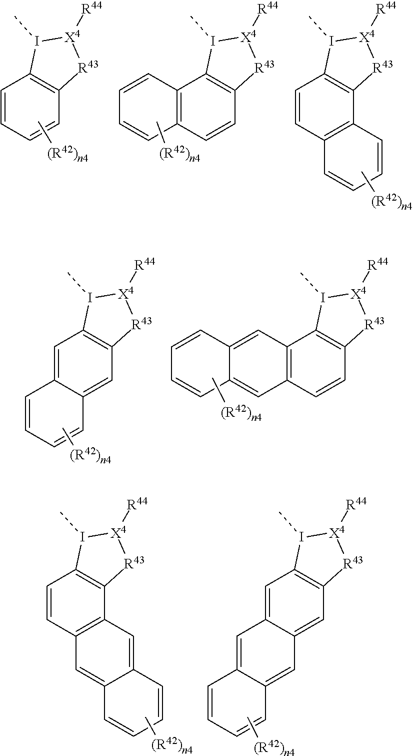

wherein n4, R⁴², R⁴³, X⁴ and R⁴⁴ are each the same as described above; and a broken line represents a point of attachment to R⁴¹—C(═O)—O—.

Specific examples of the hypervalent iodine compound represented by the general formula (4) include the following, but not limited thereto. Herein, in the following formulae, Me is a methyl group.

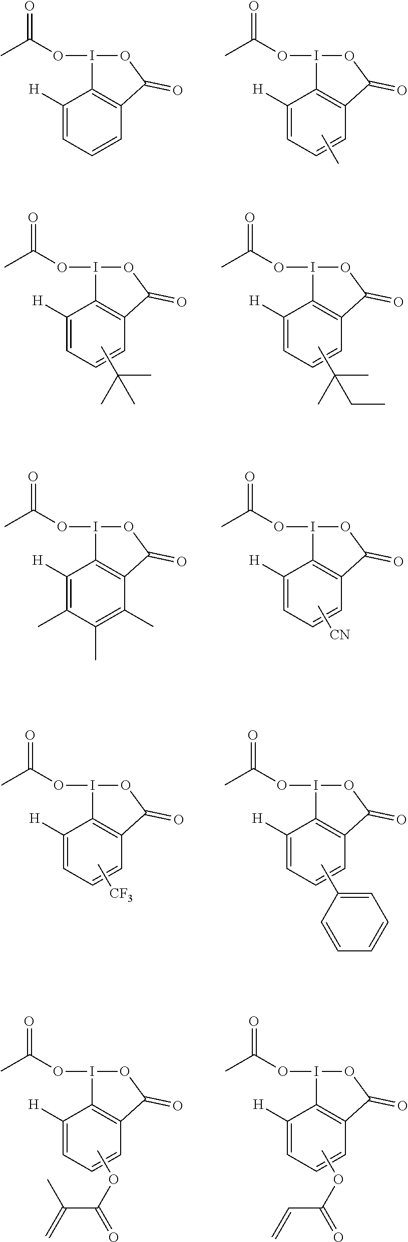

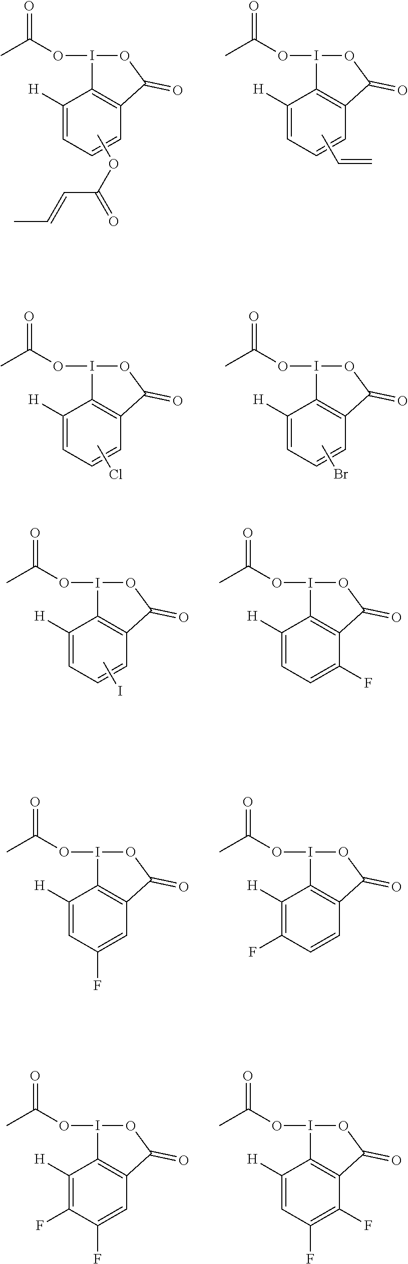

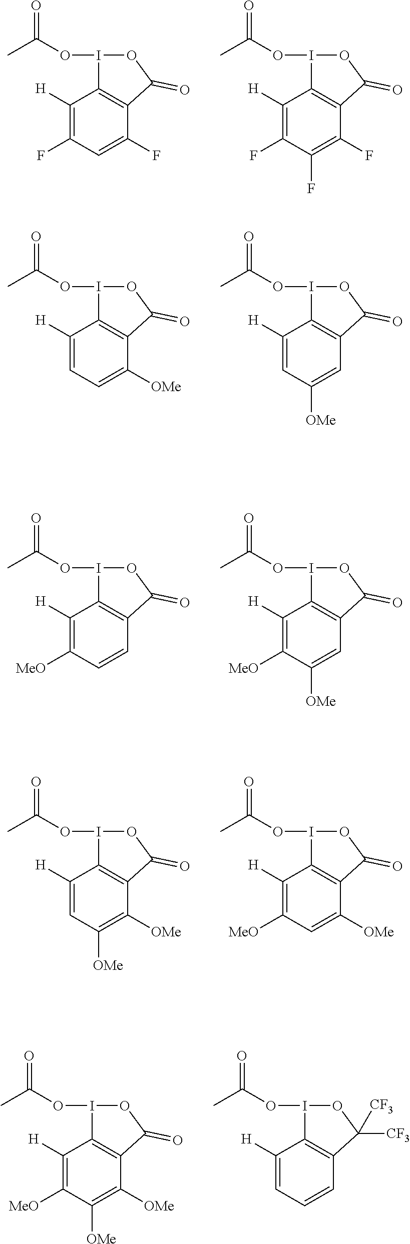

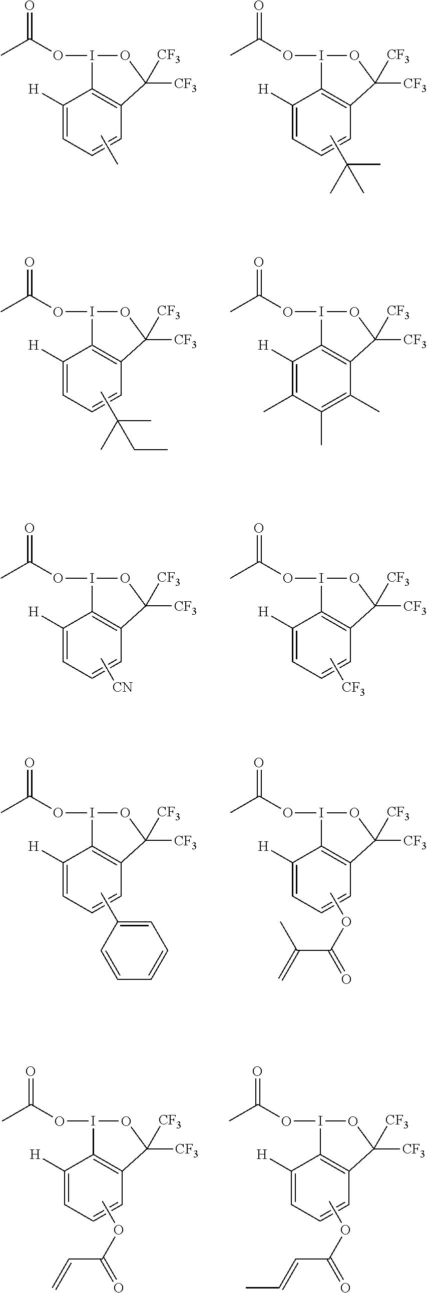

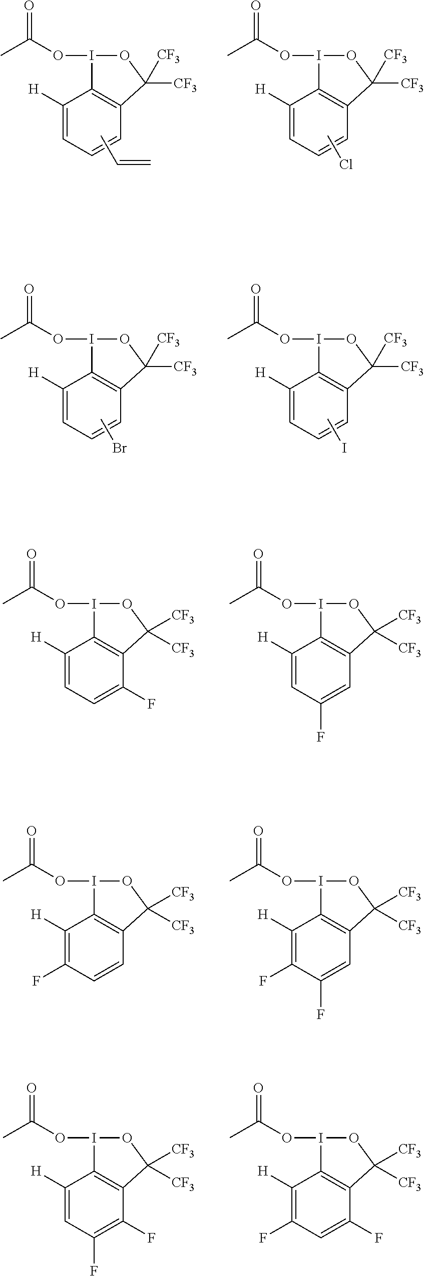

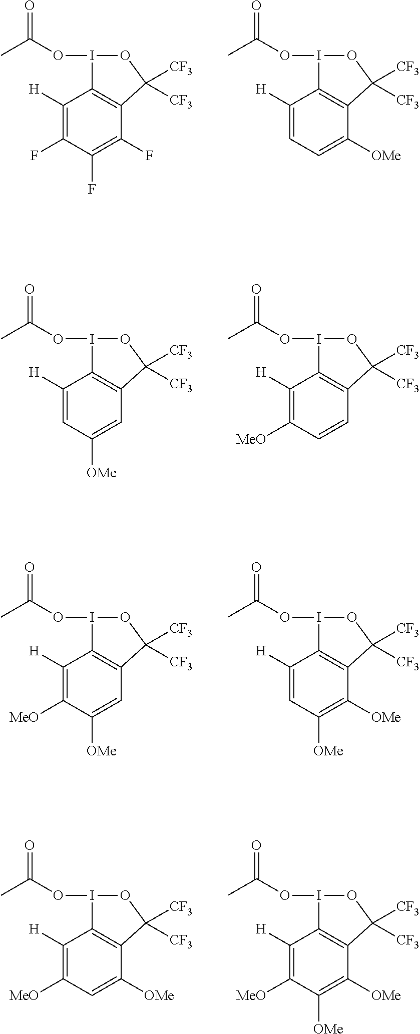

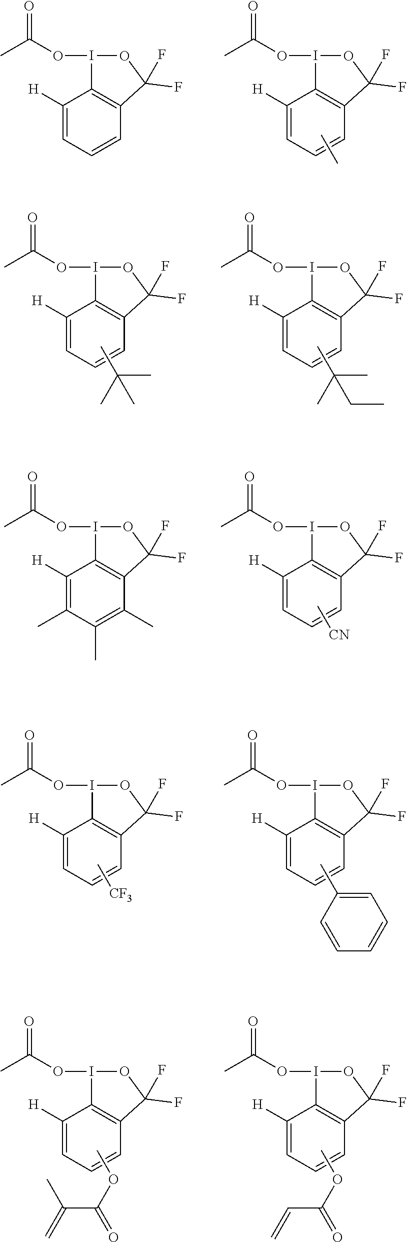

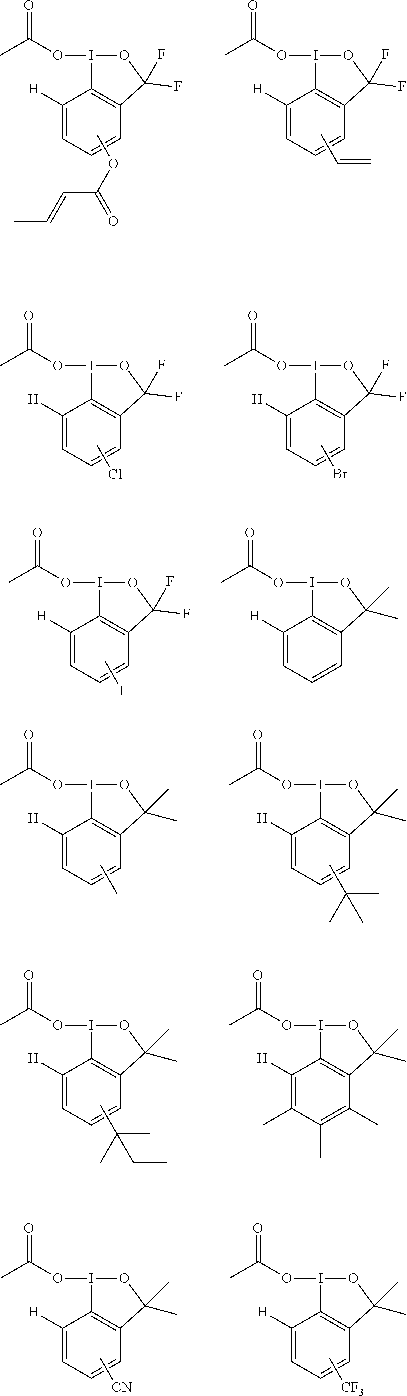

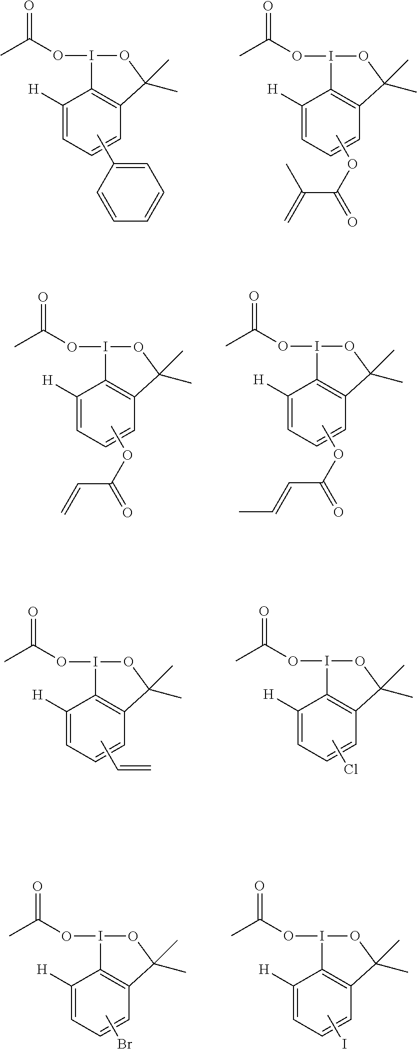

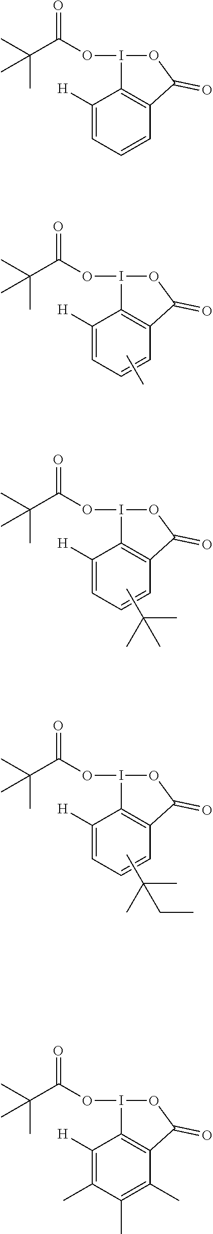

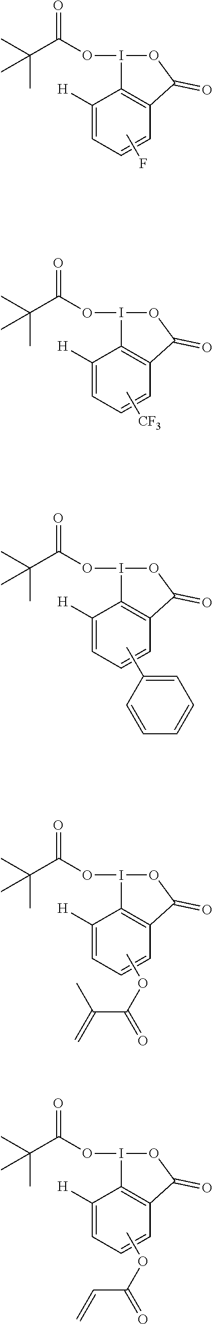

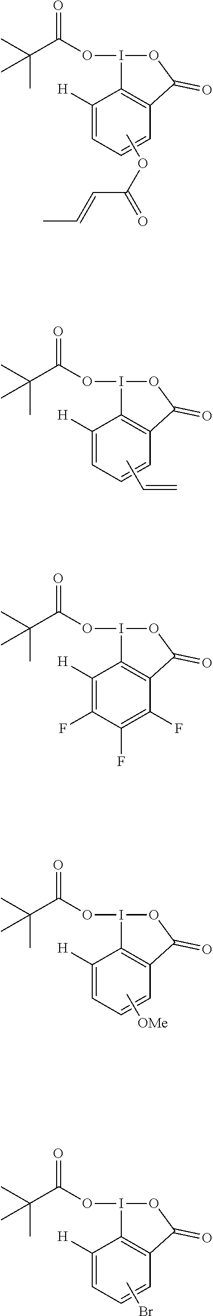

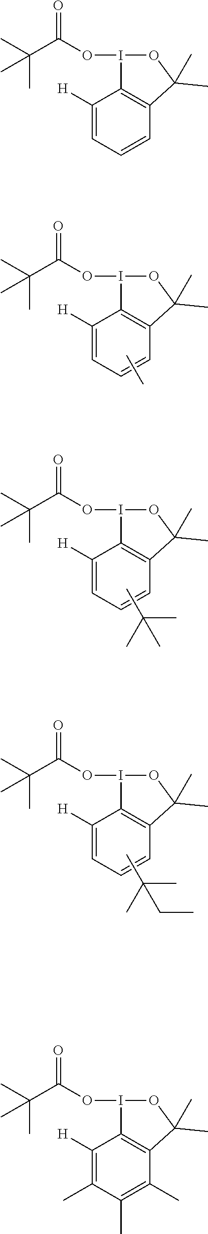

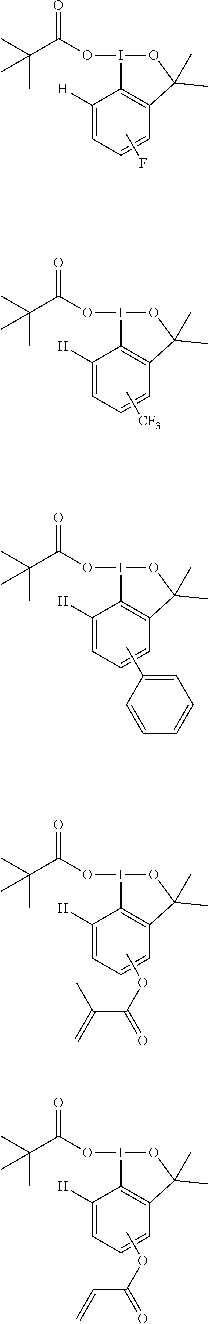

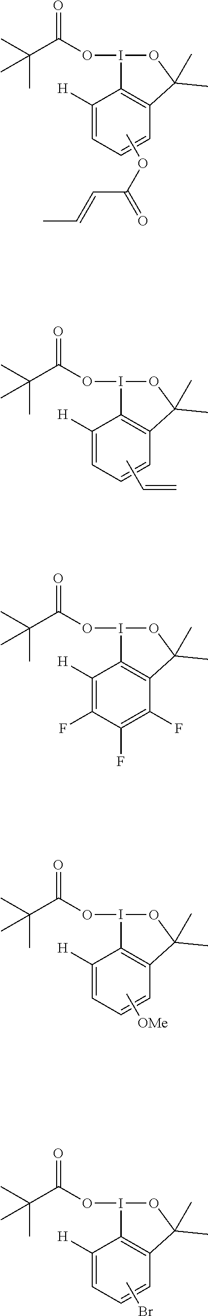

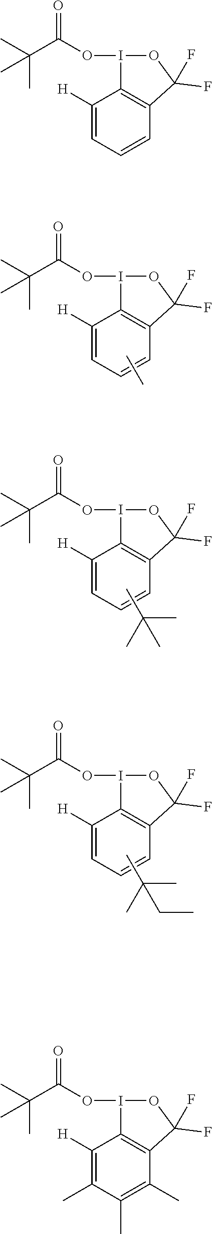

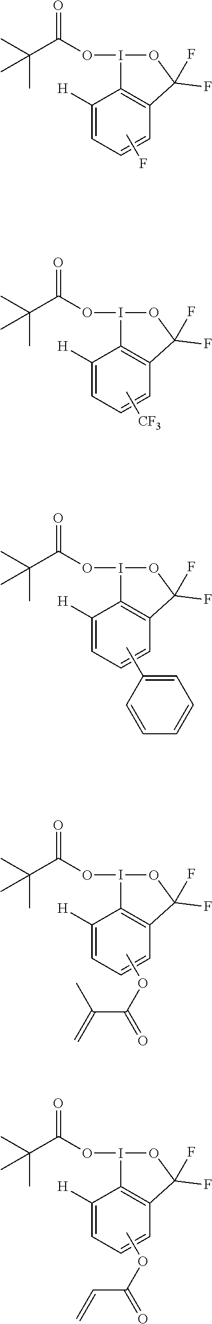

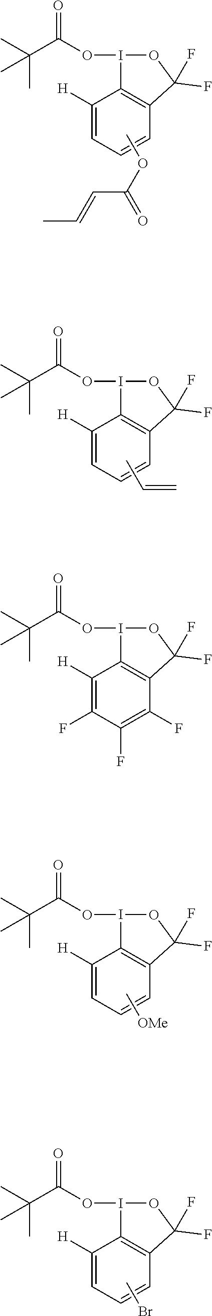

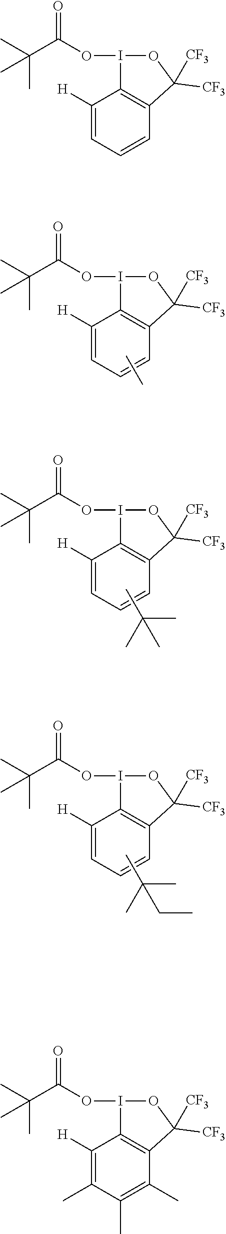

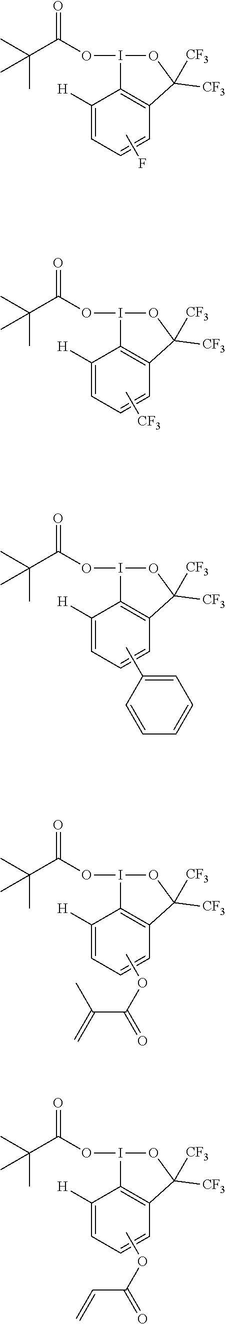

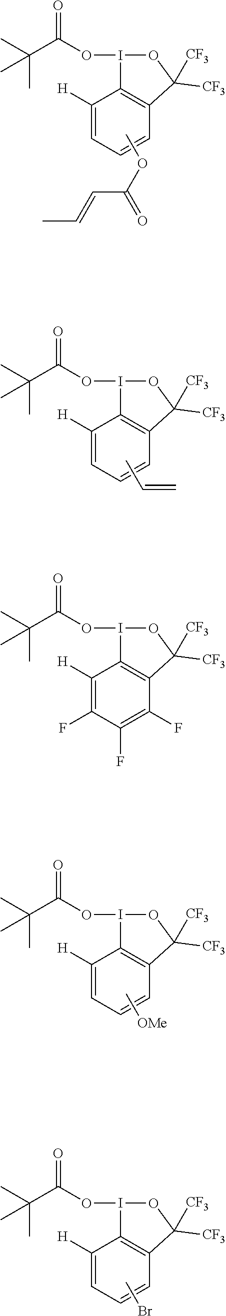

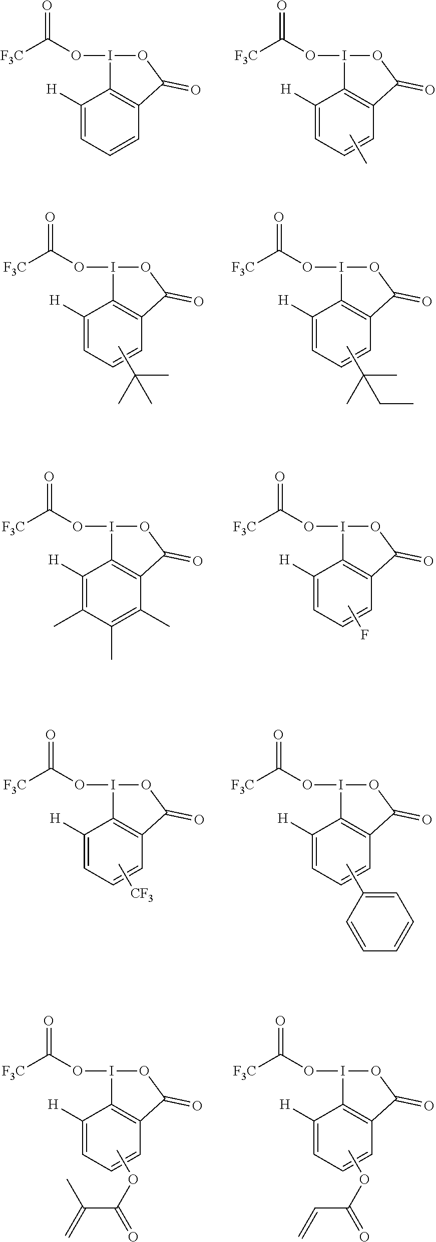

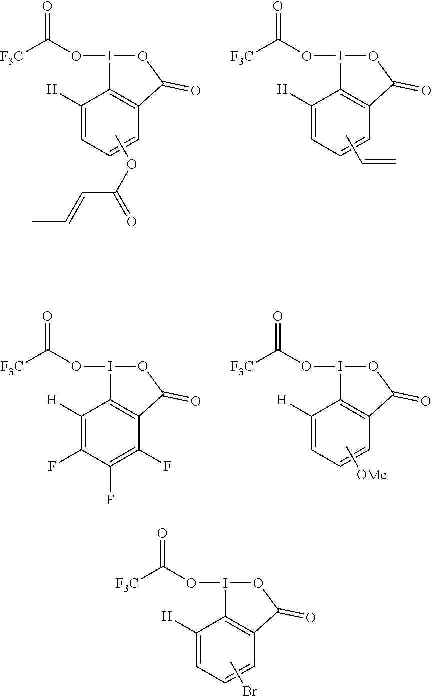

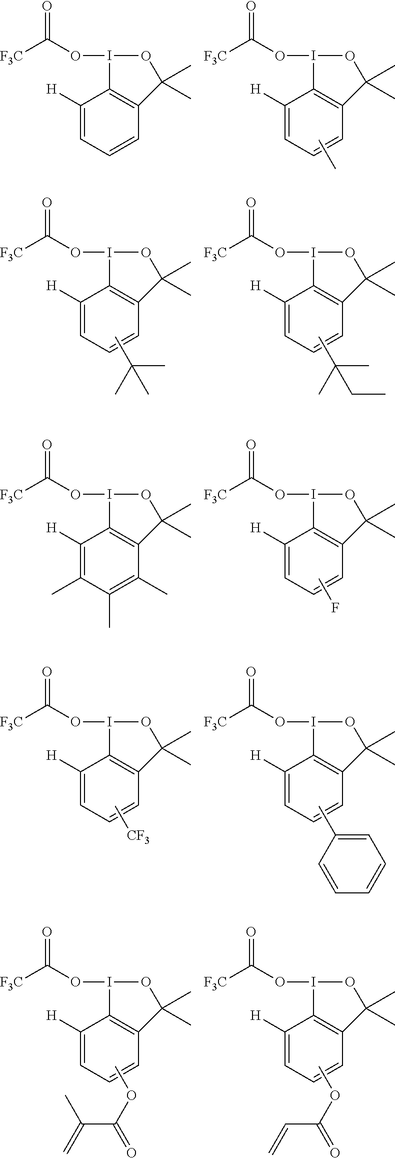

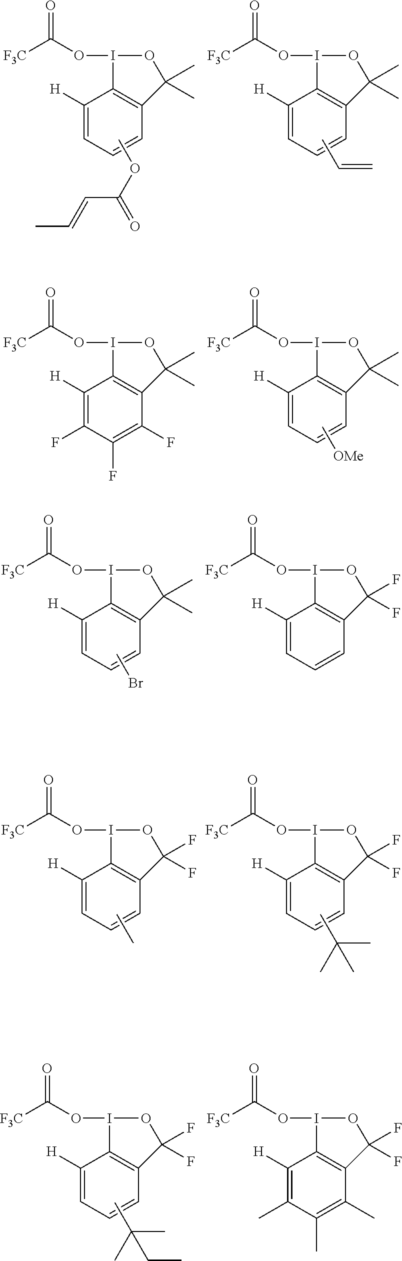

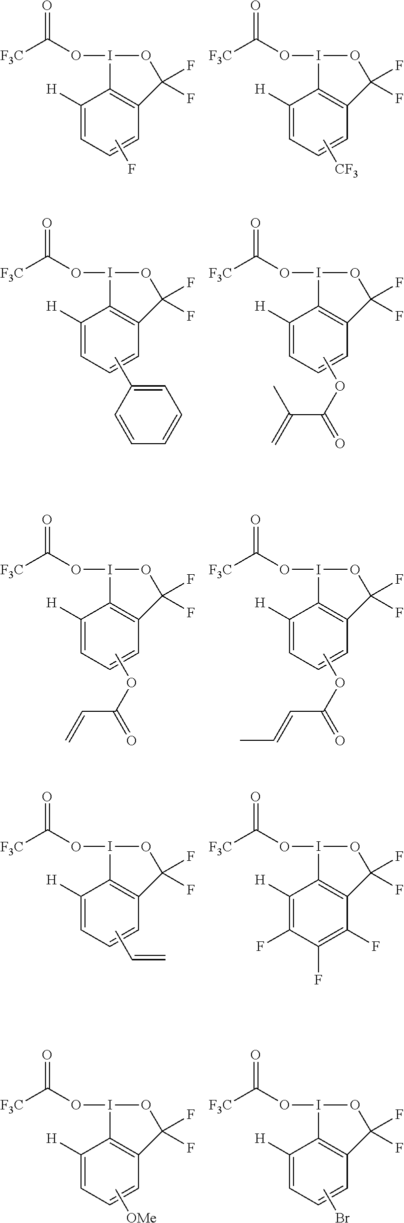

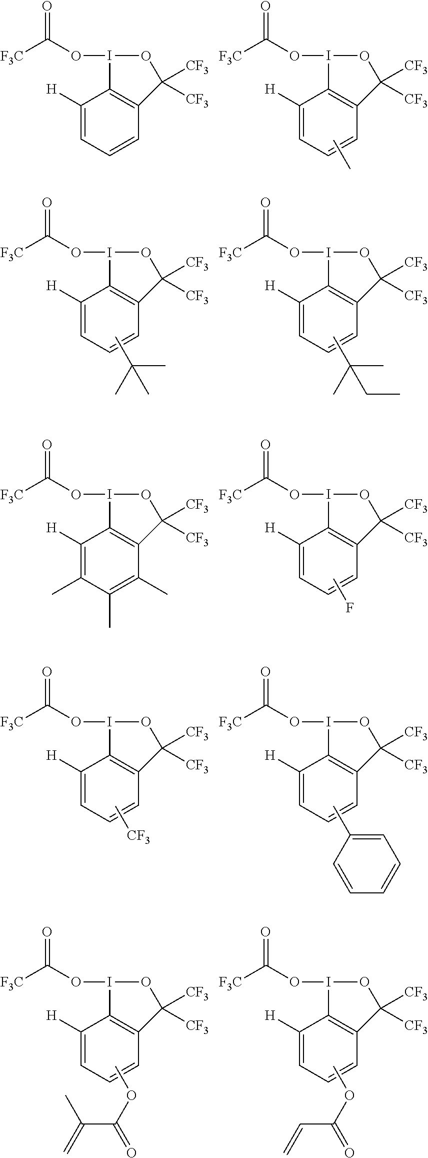

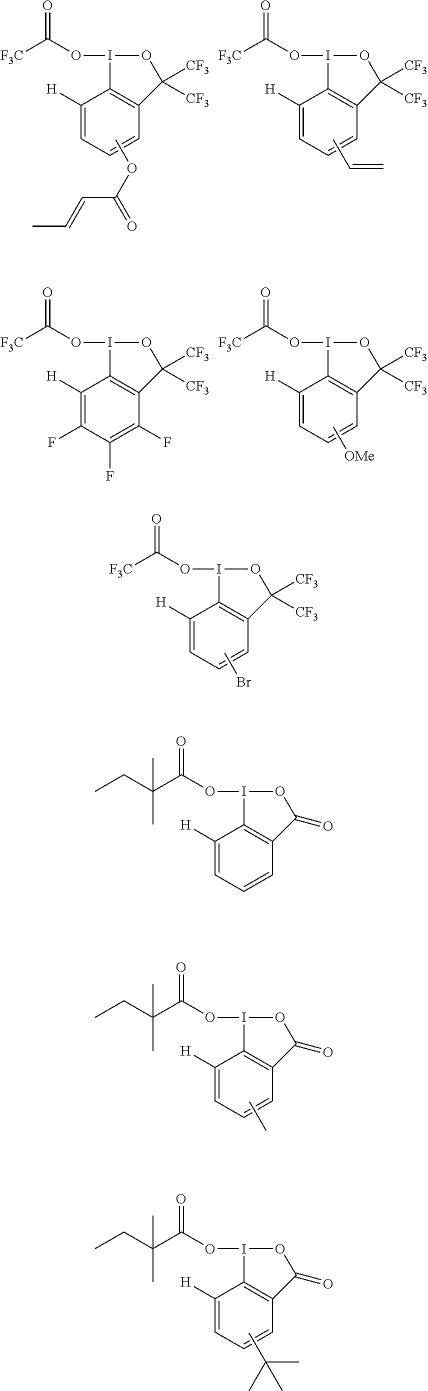

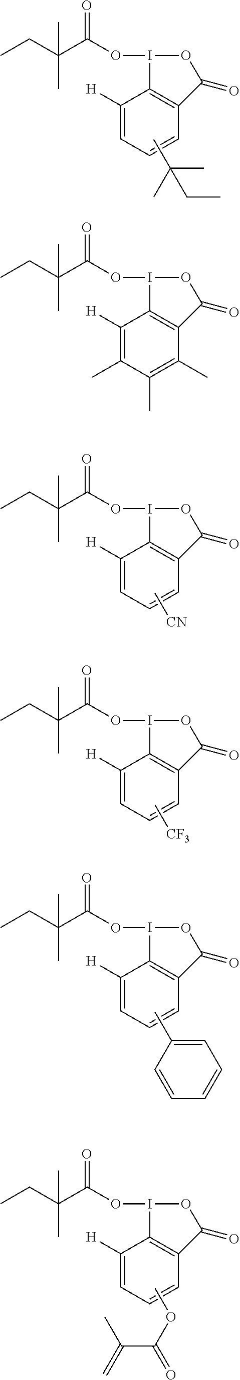

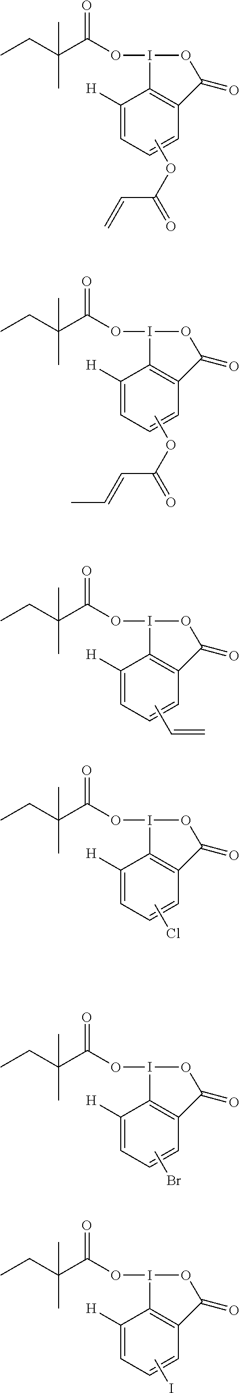

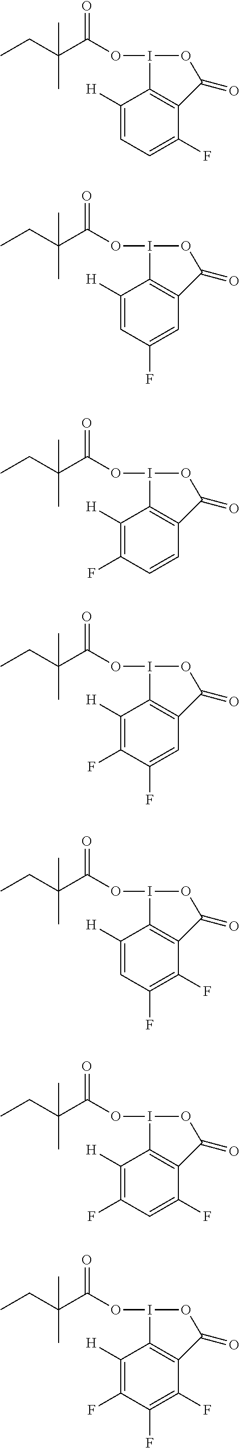

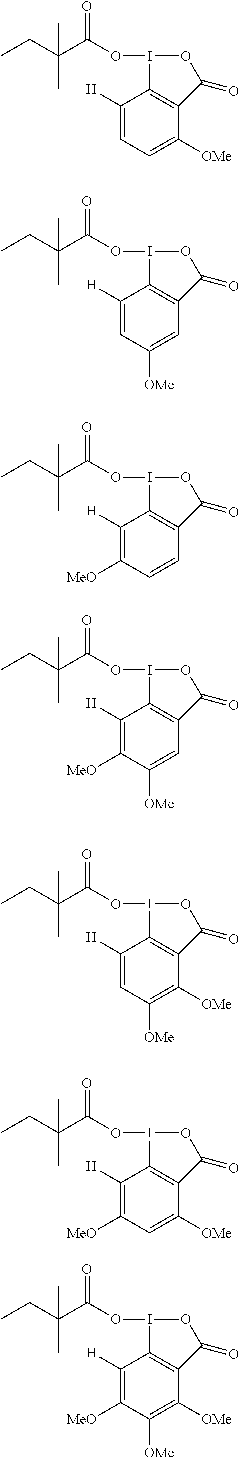

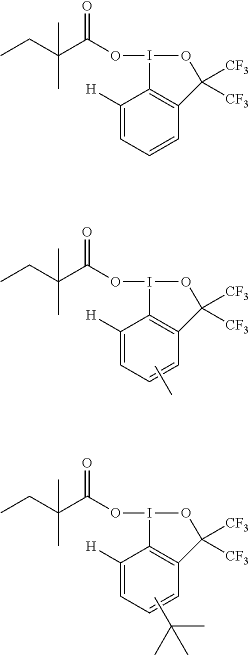

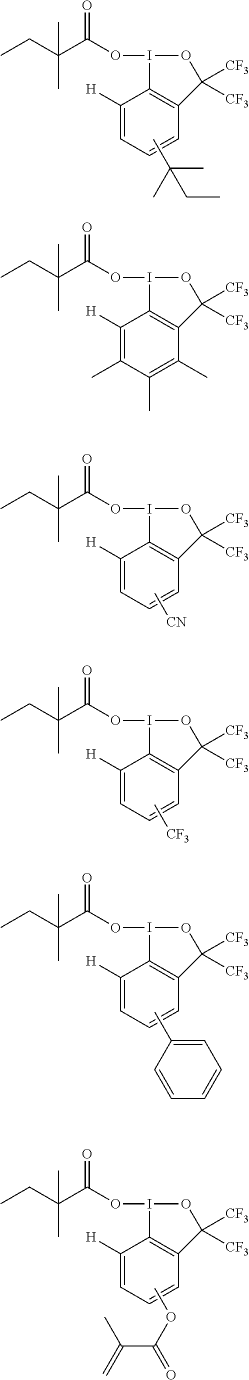

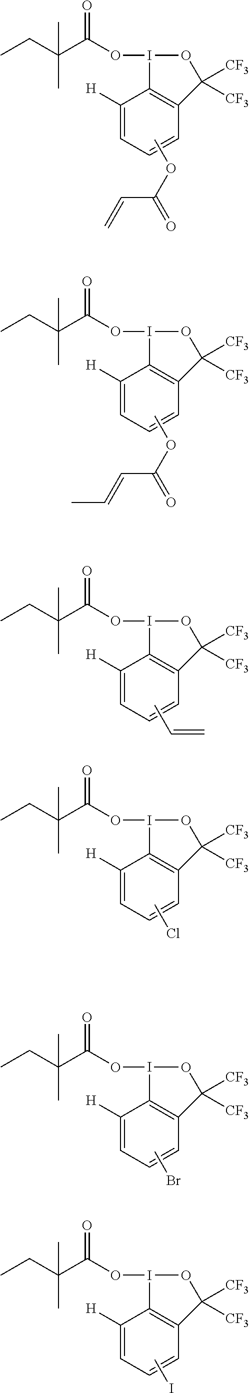

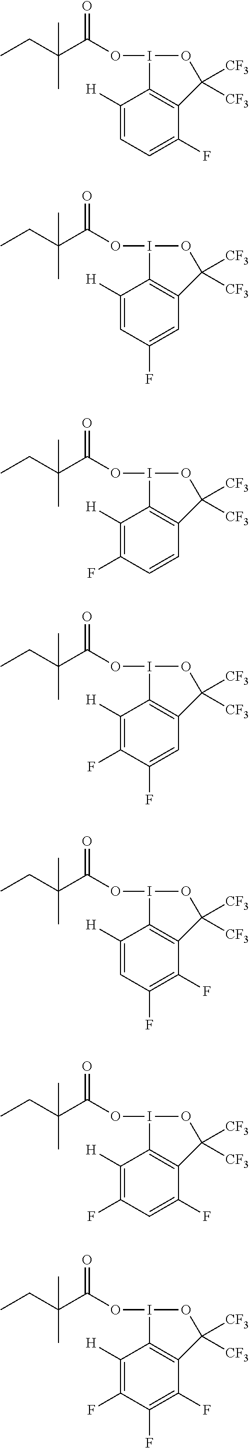

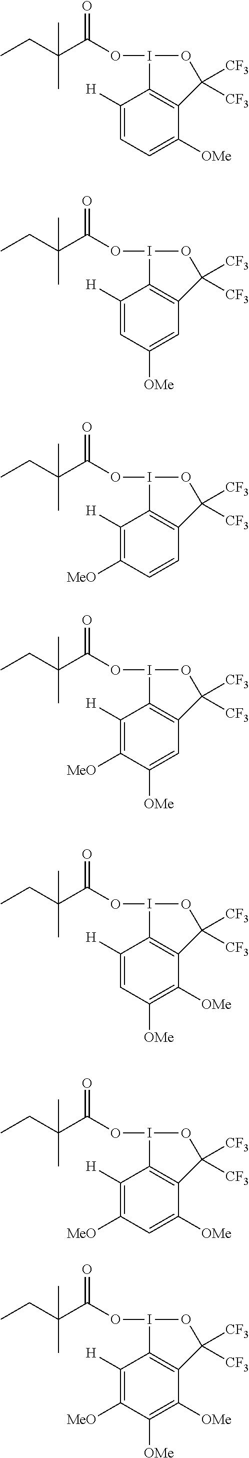

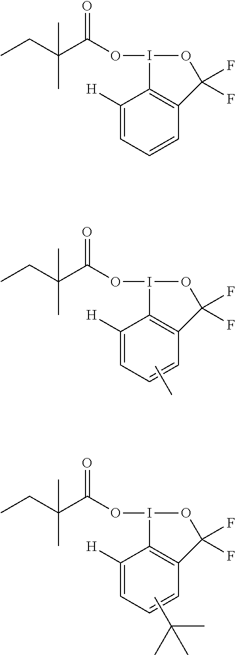

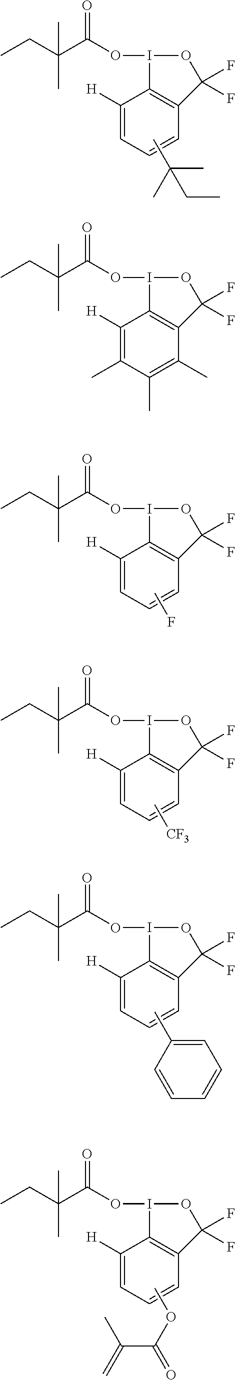

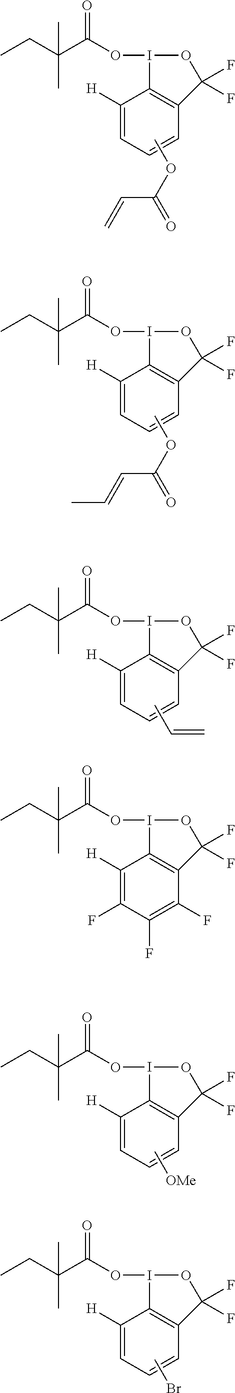

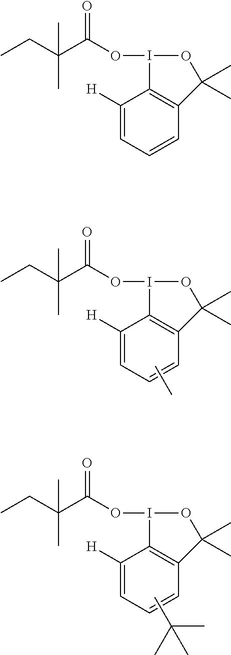

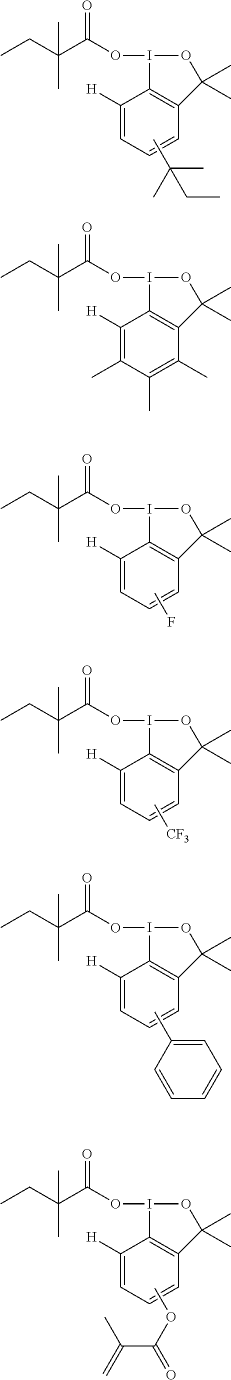

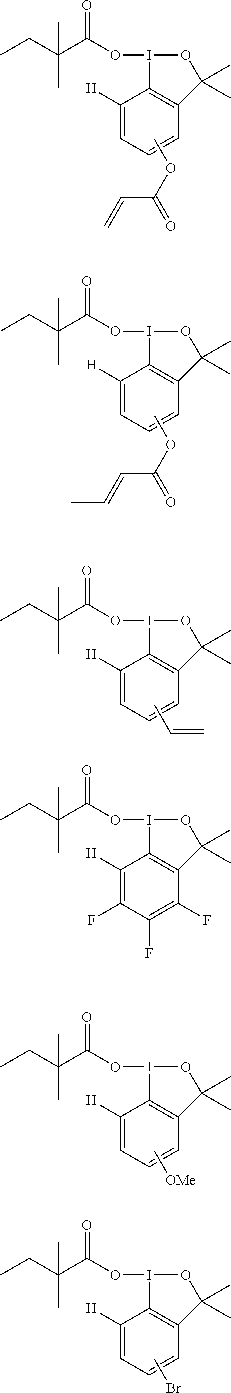

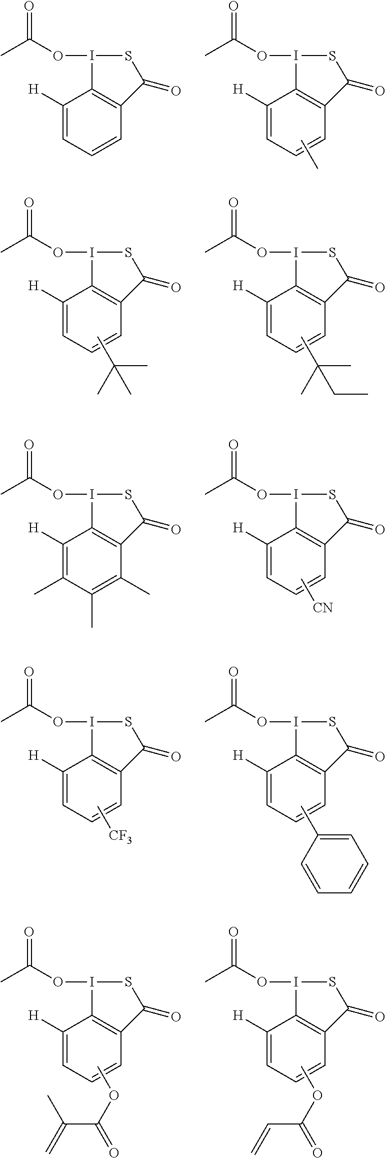

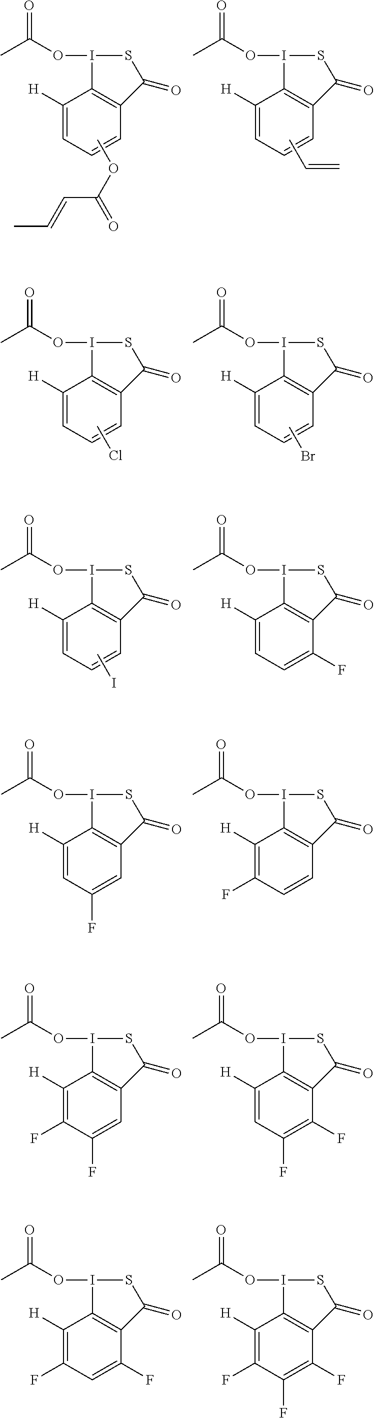

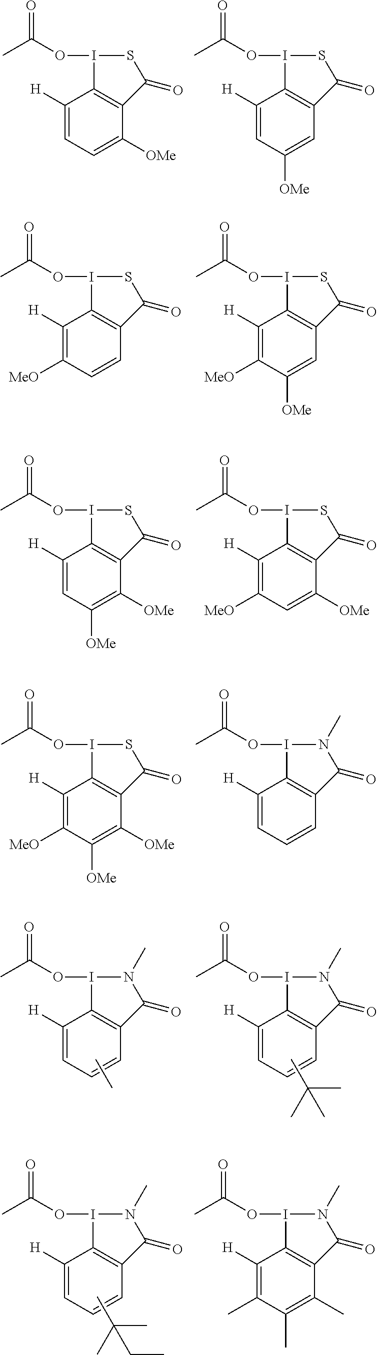

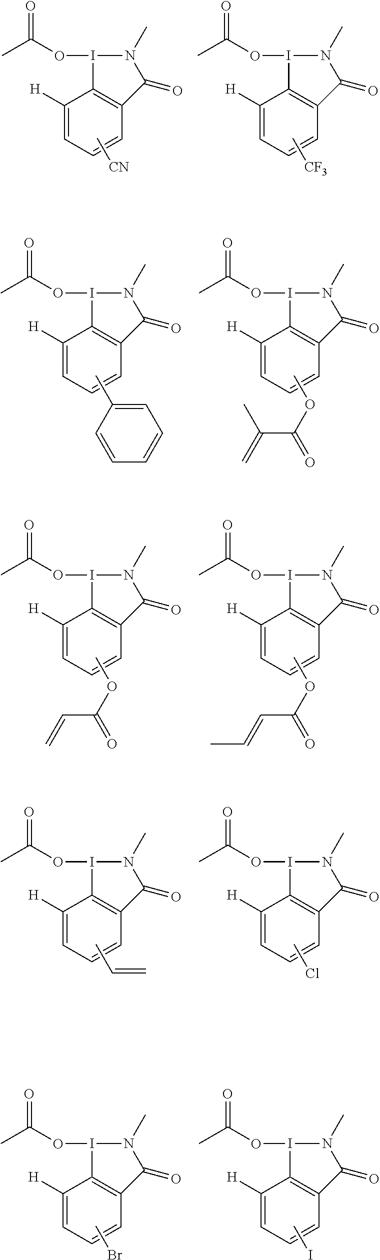

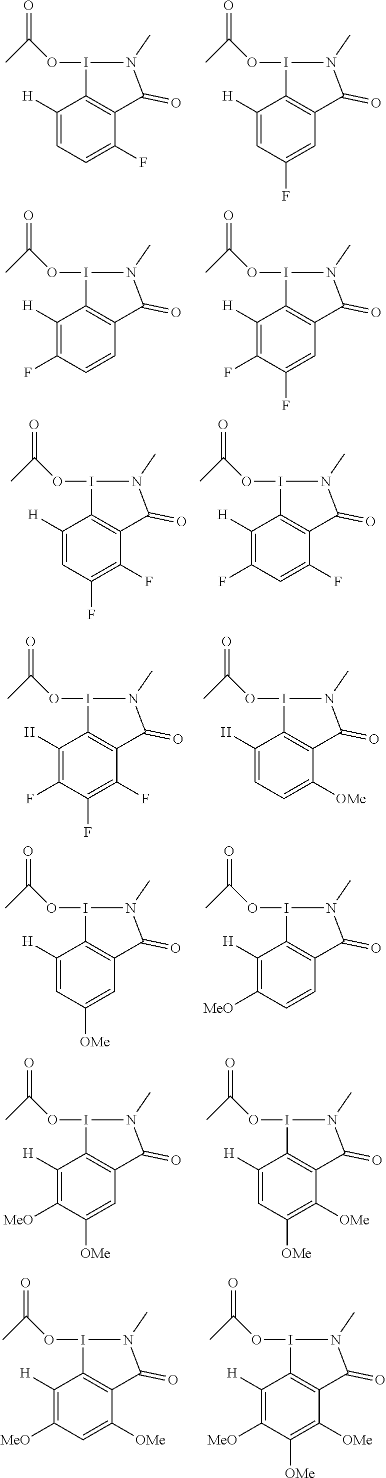

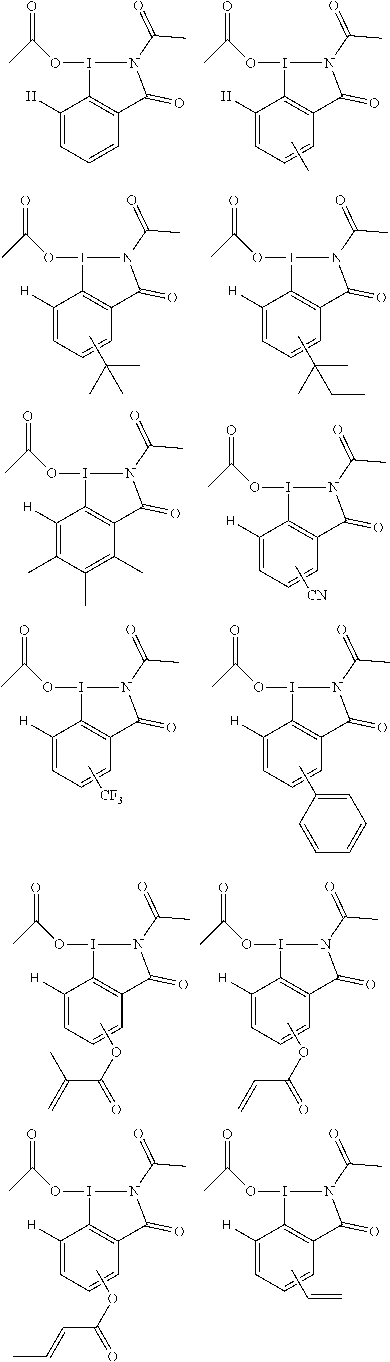

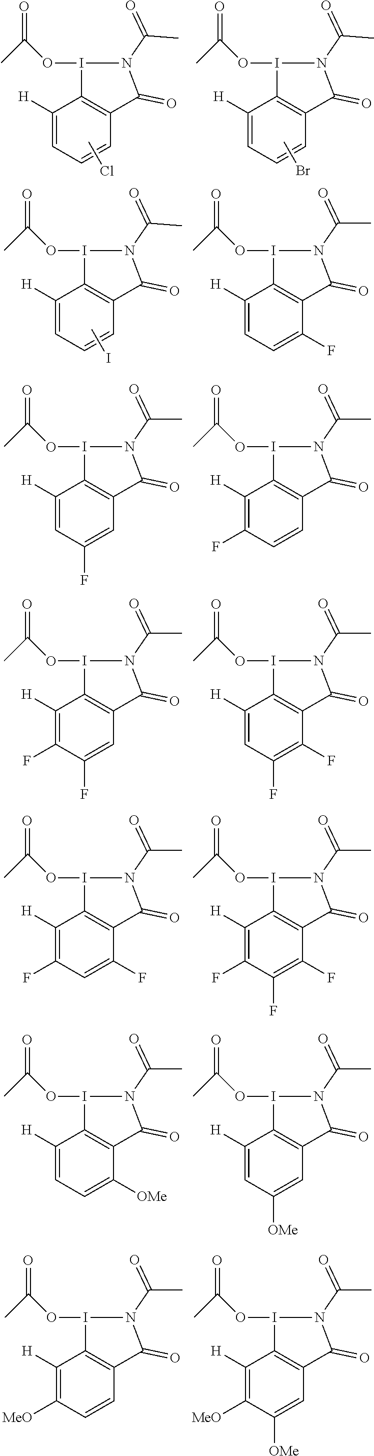

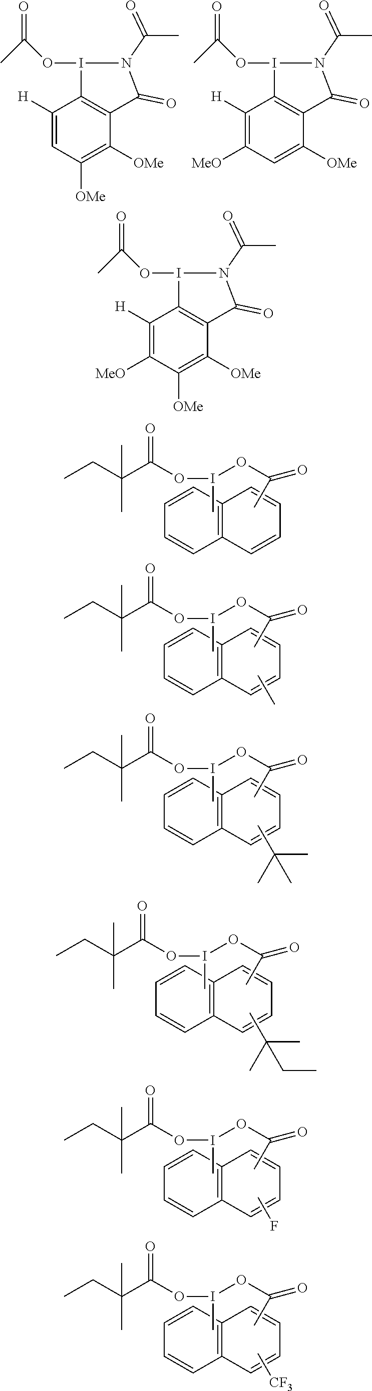

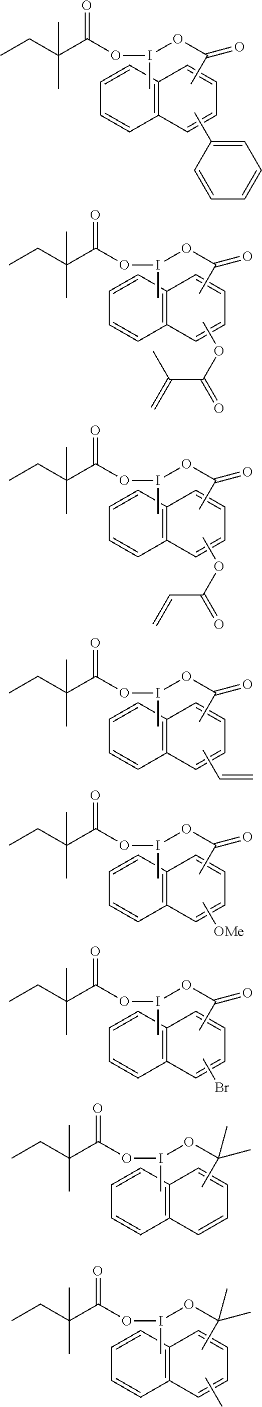

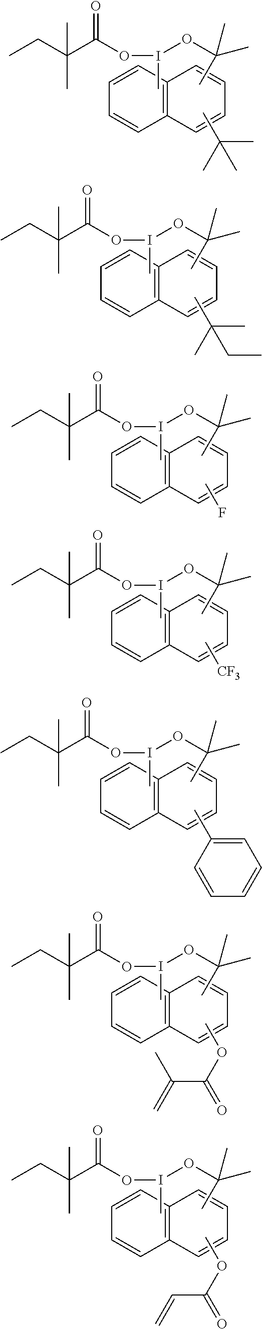

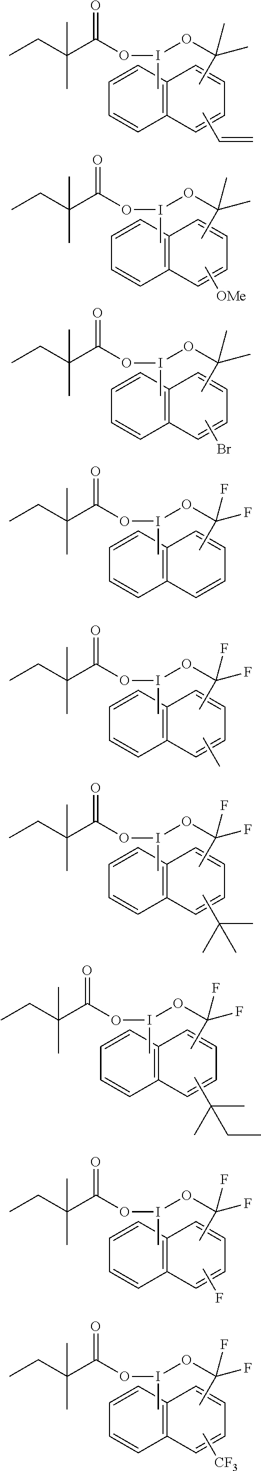

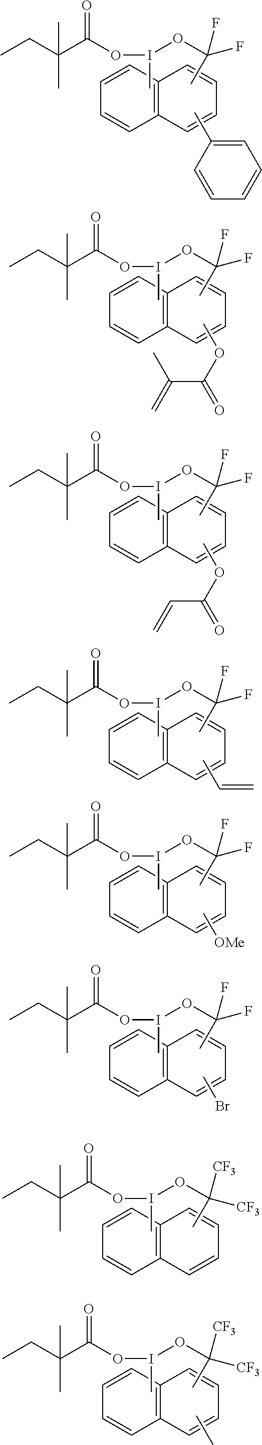

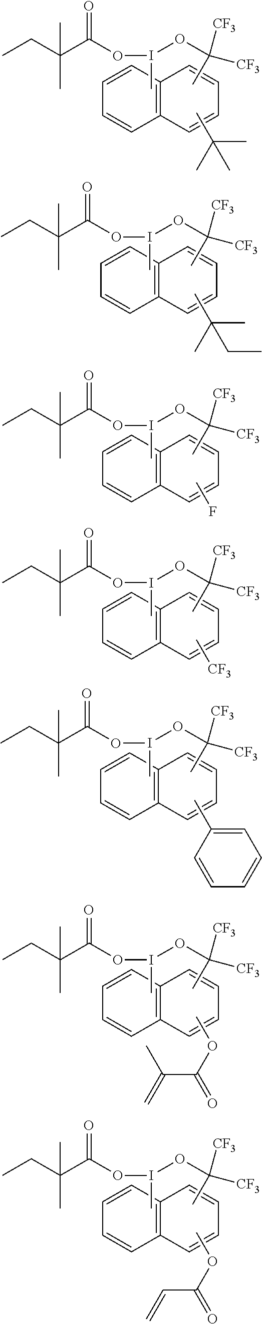

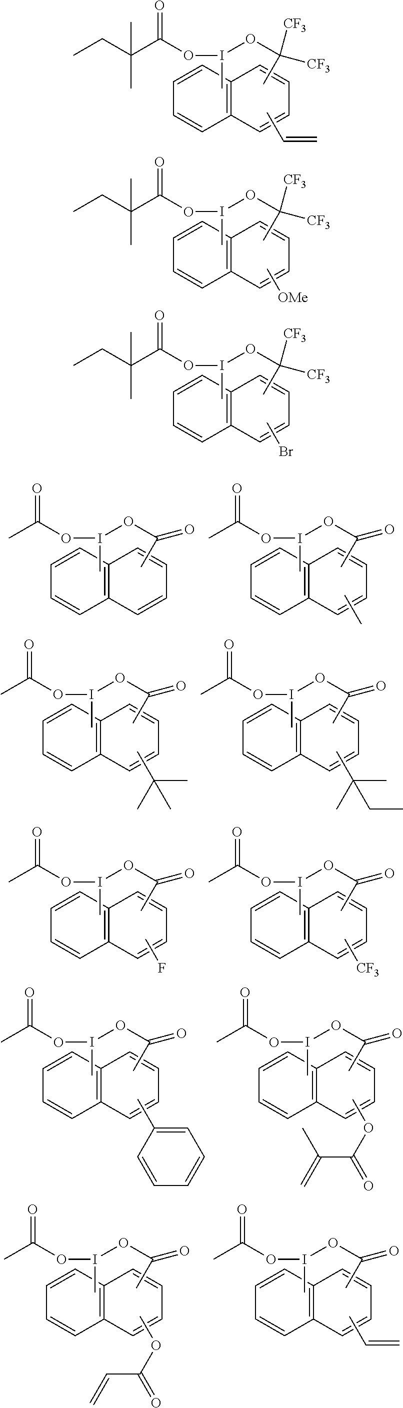

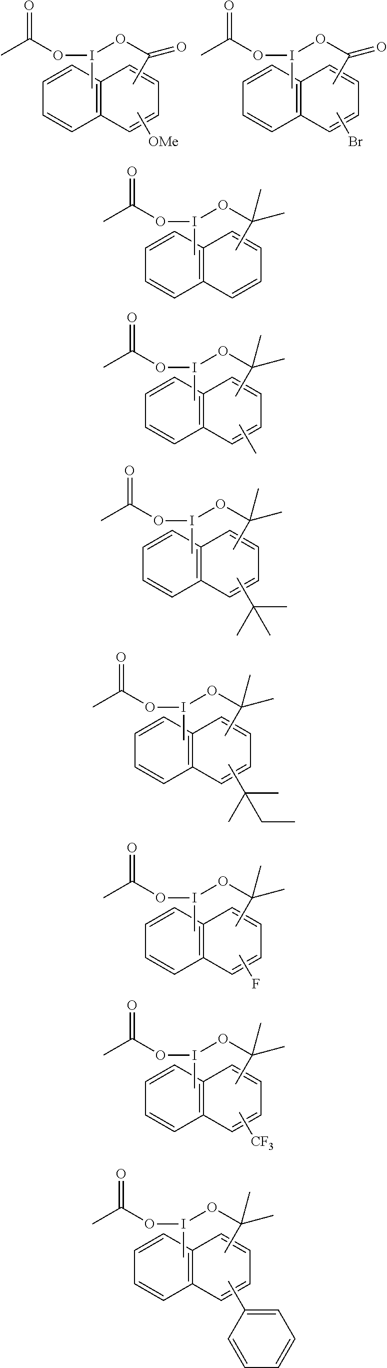

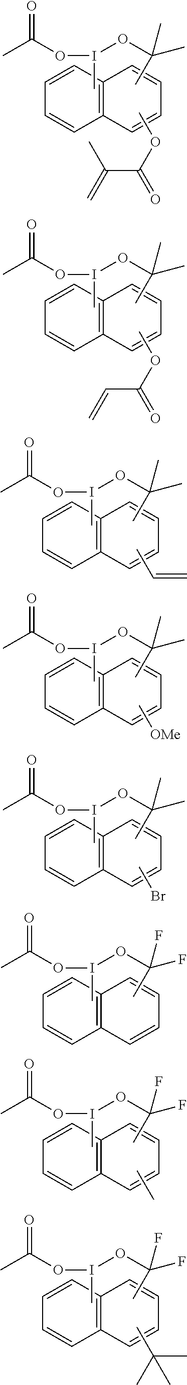

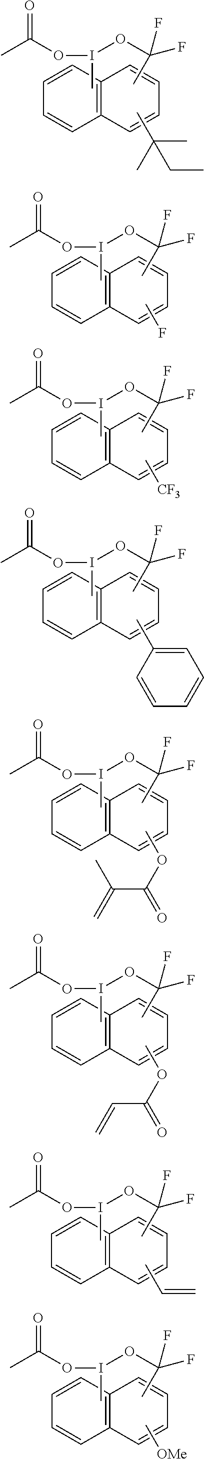

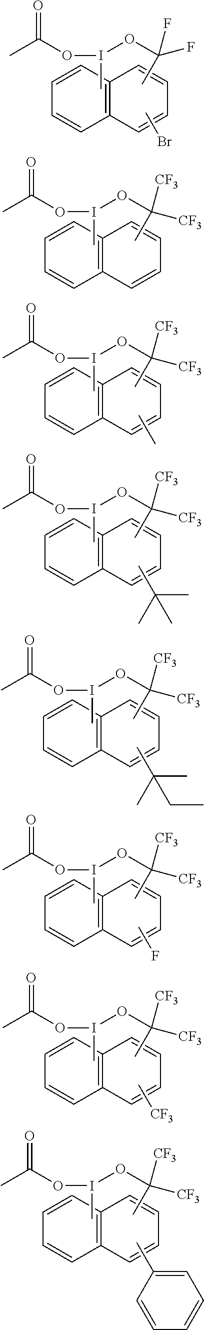

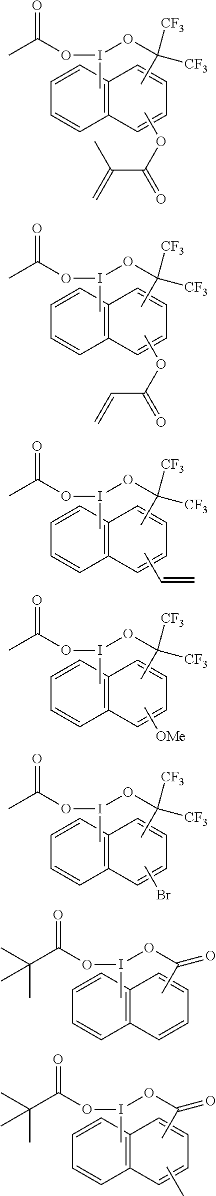

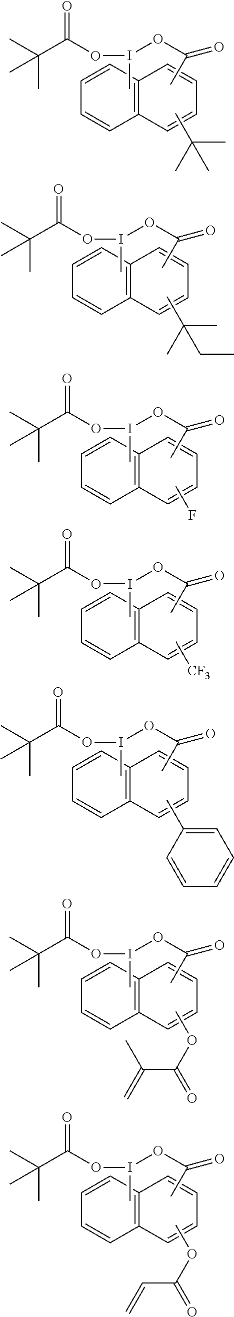

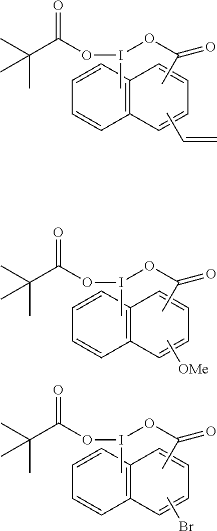

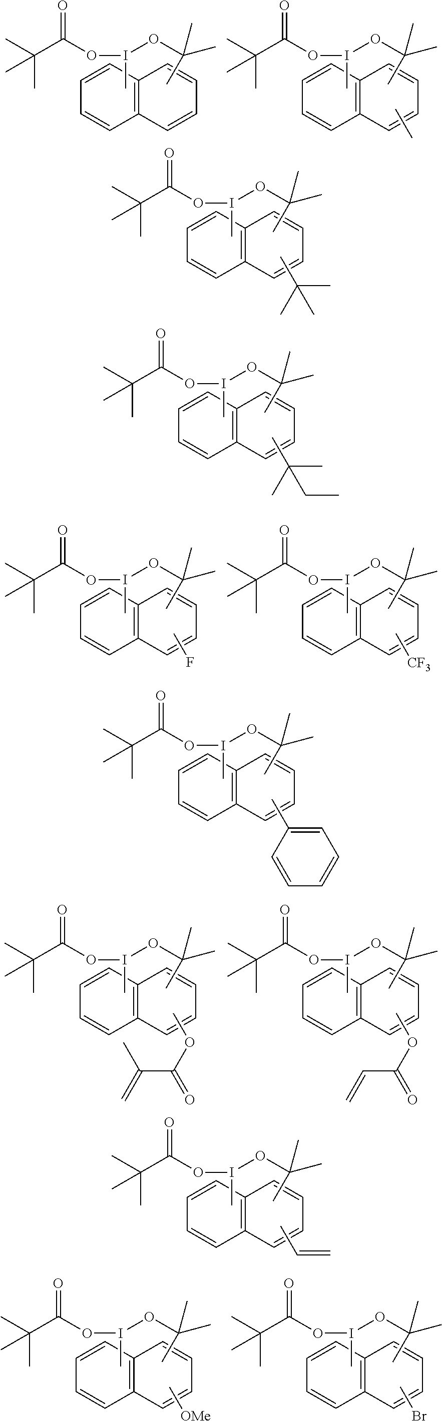

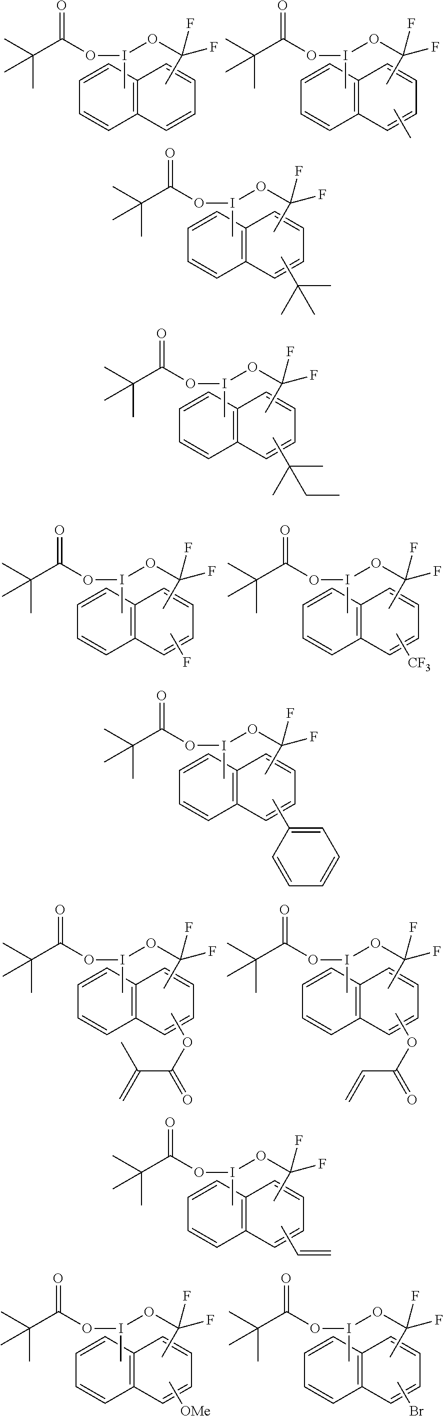

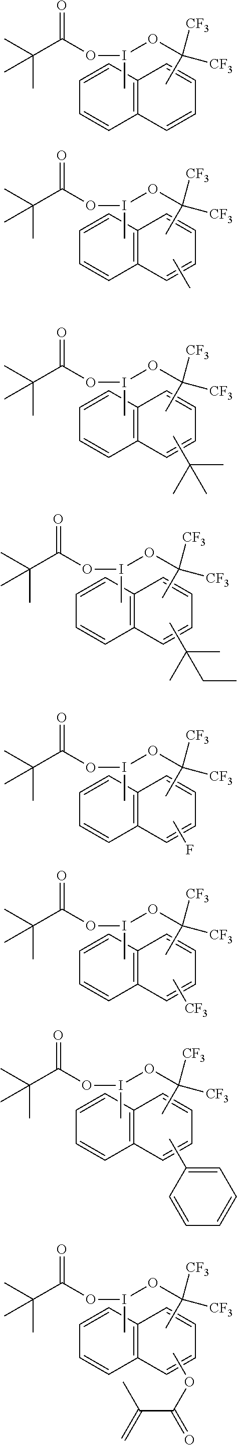

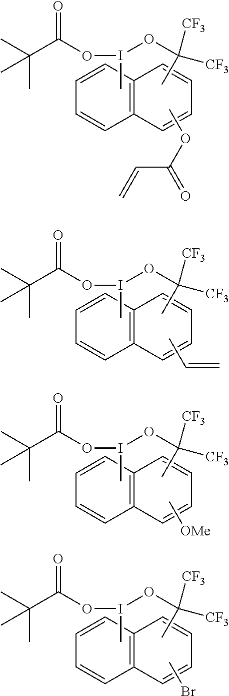

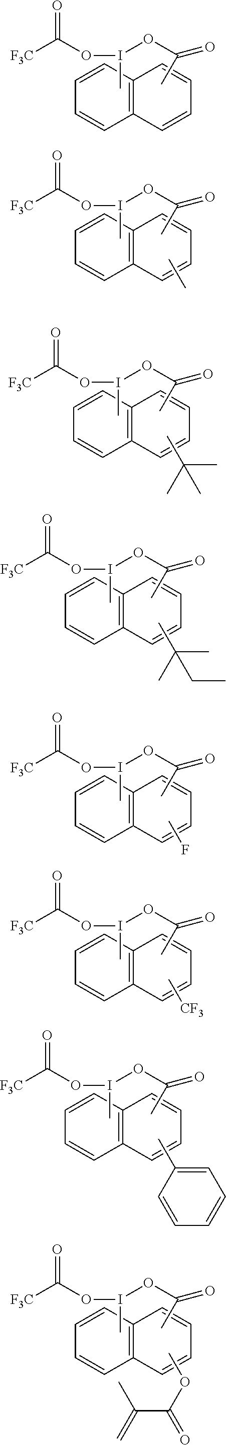

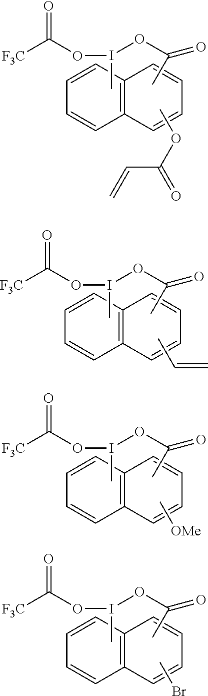

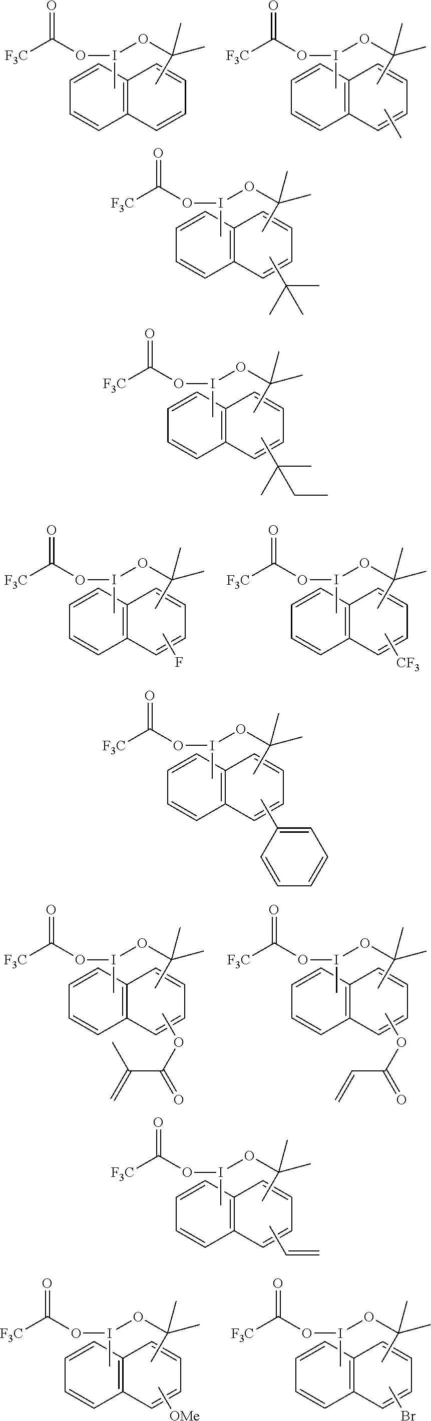

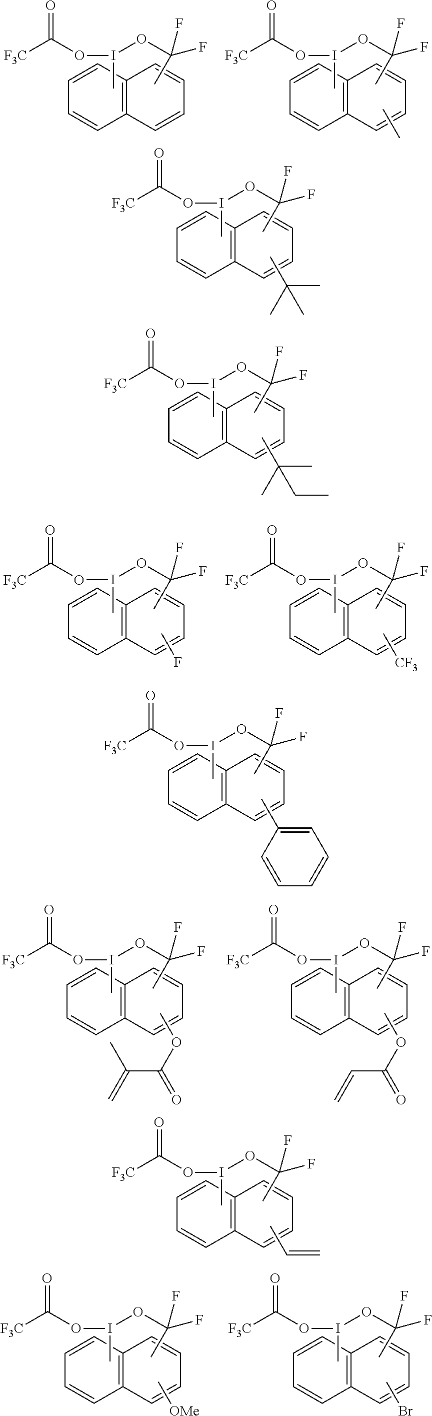

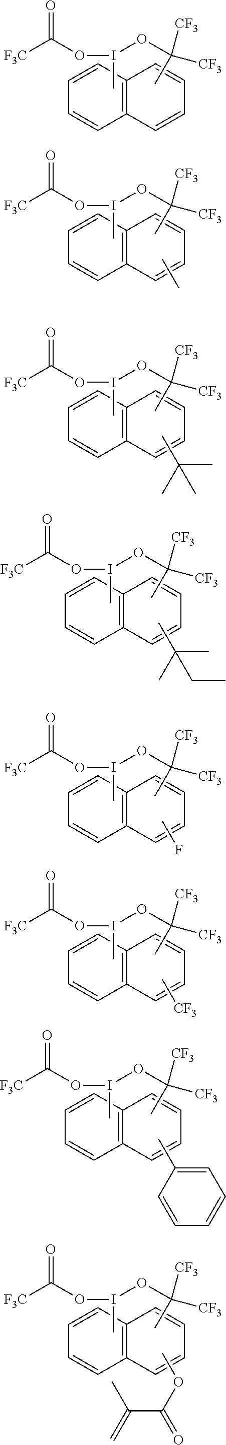

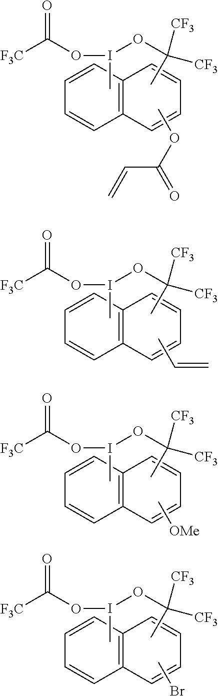

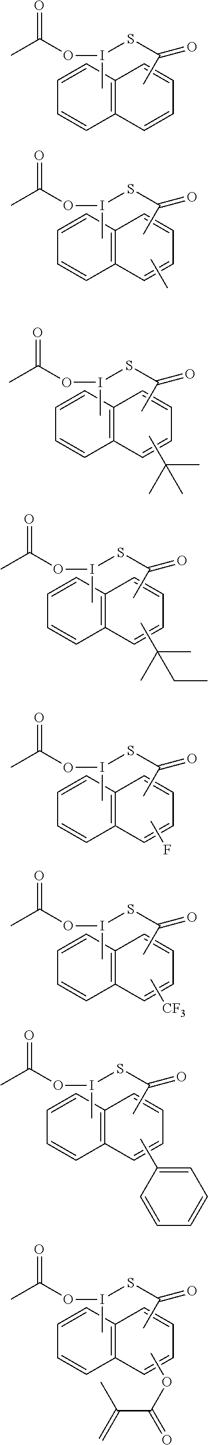

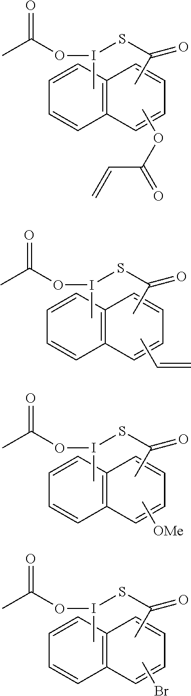

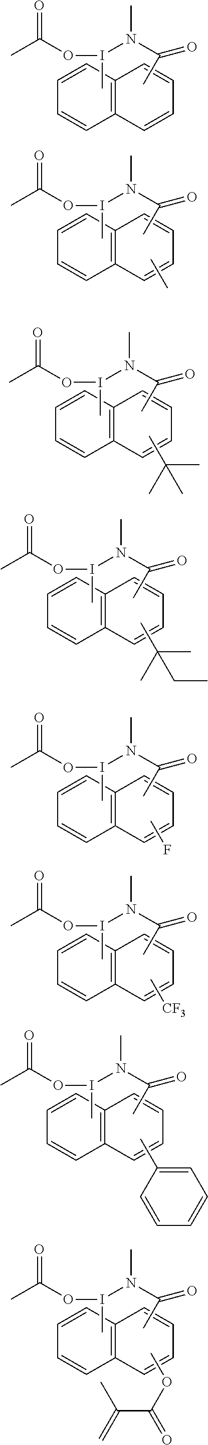

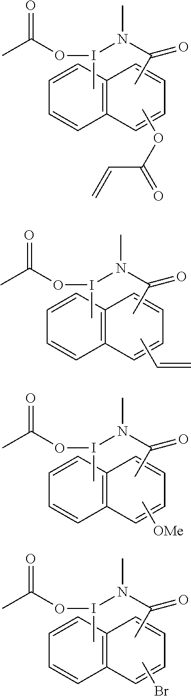

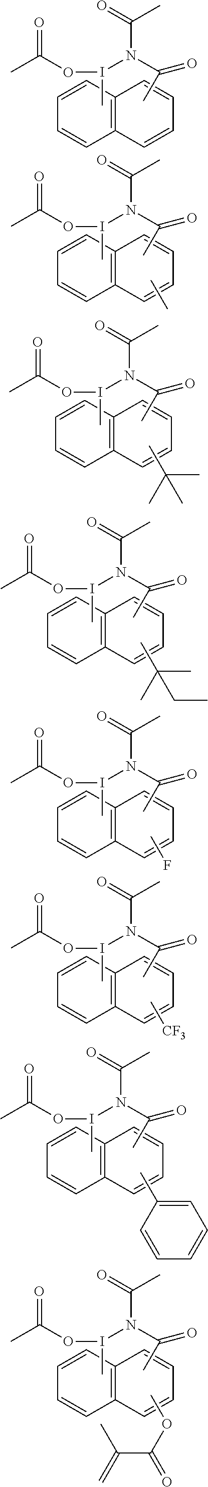

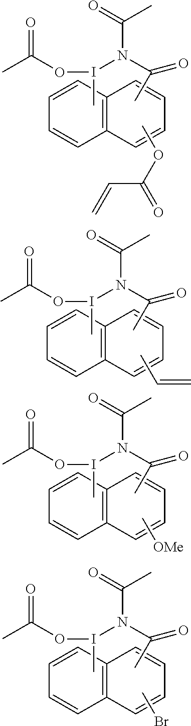

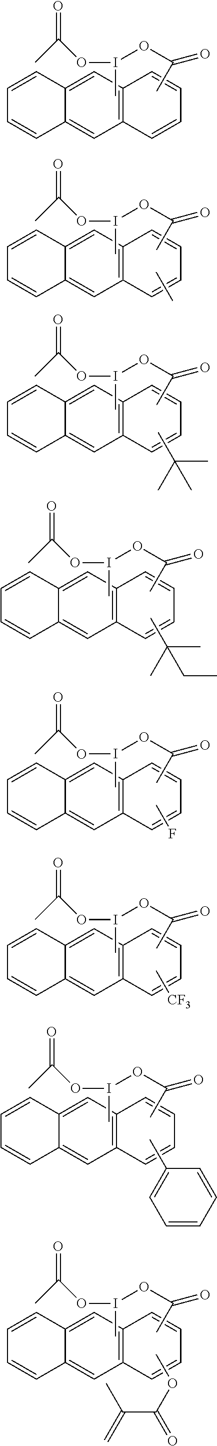

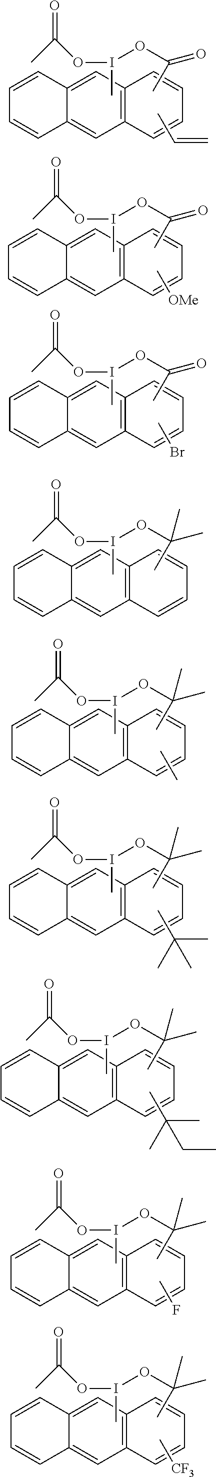

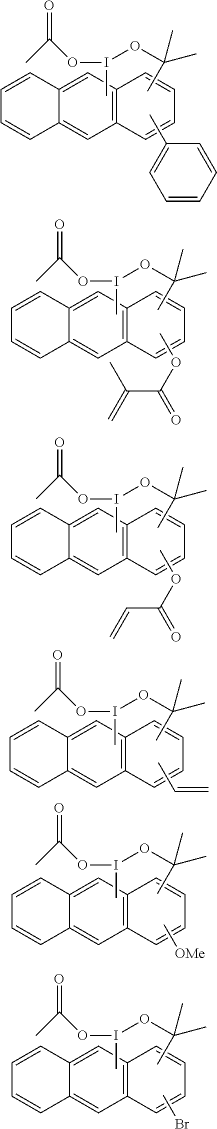

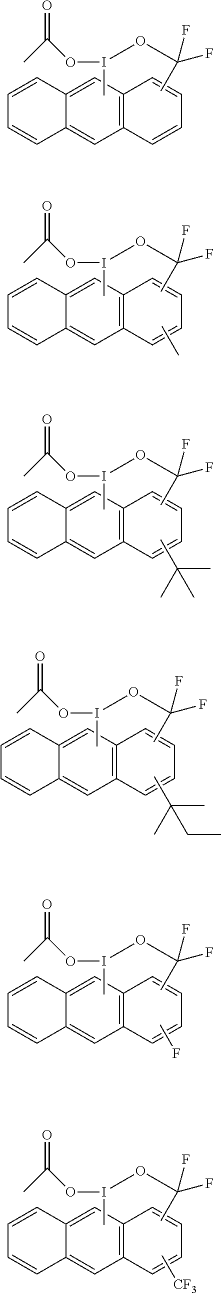

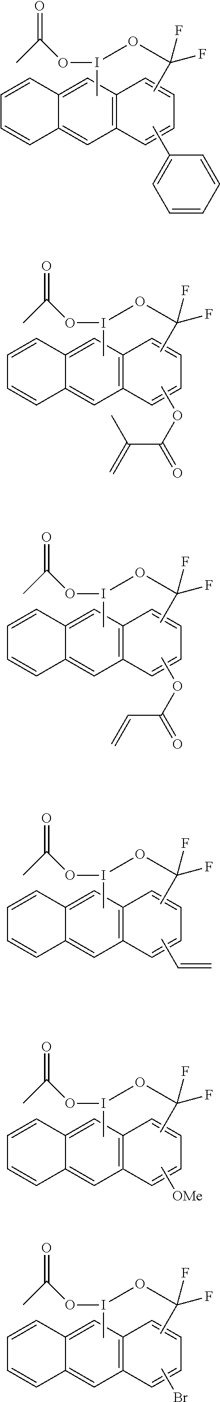

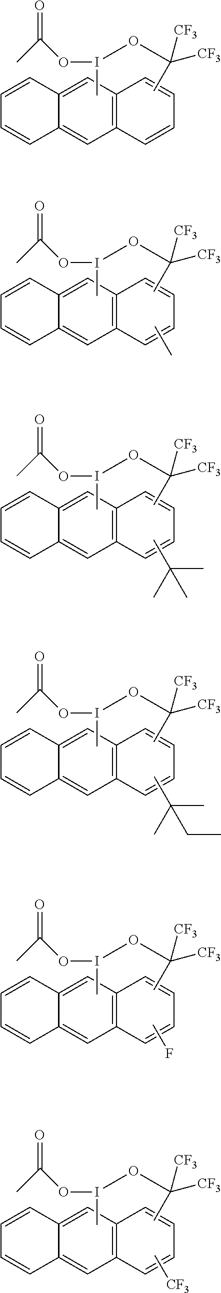

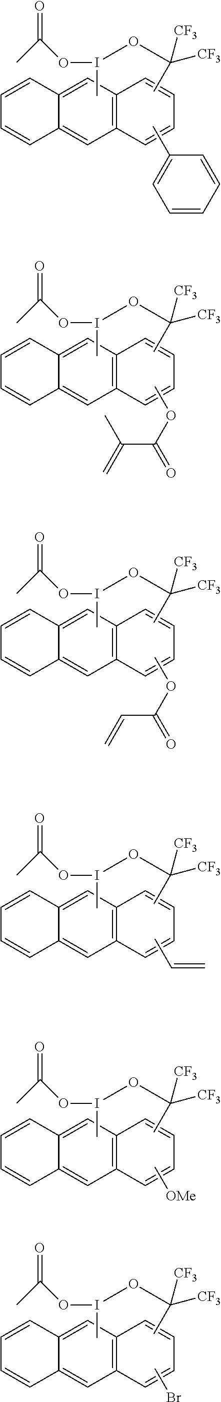

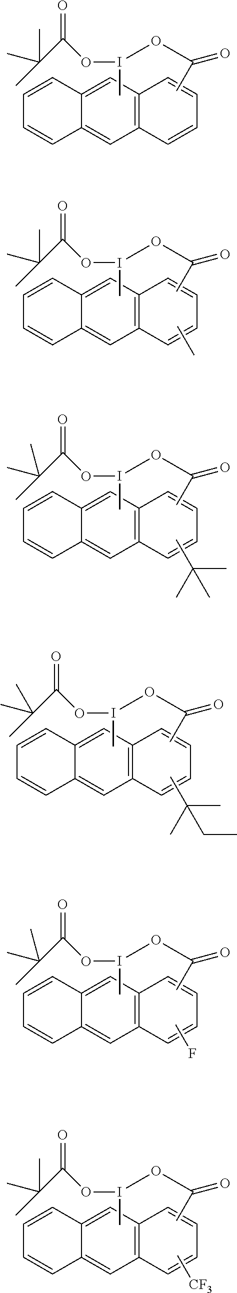

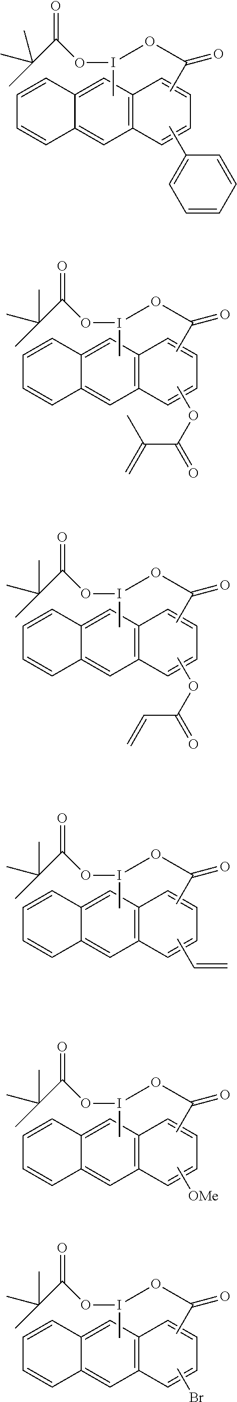

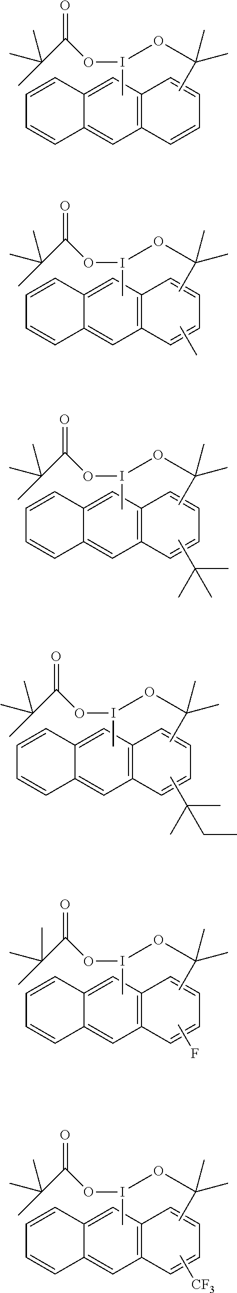

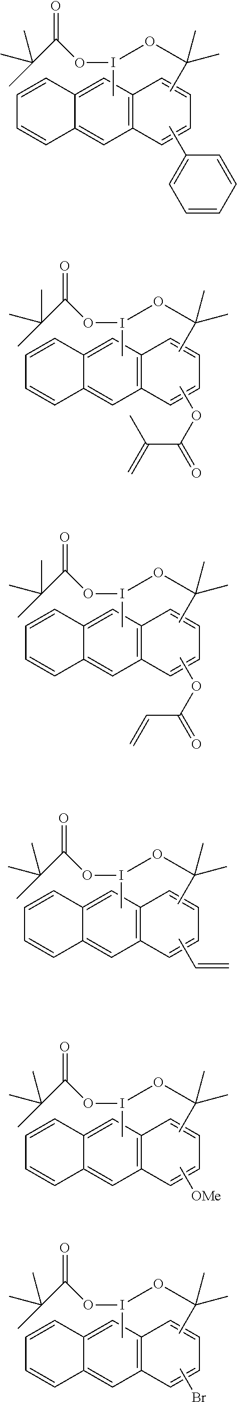

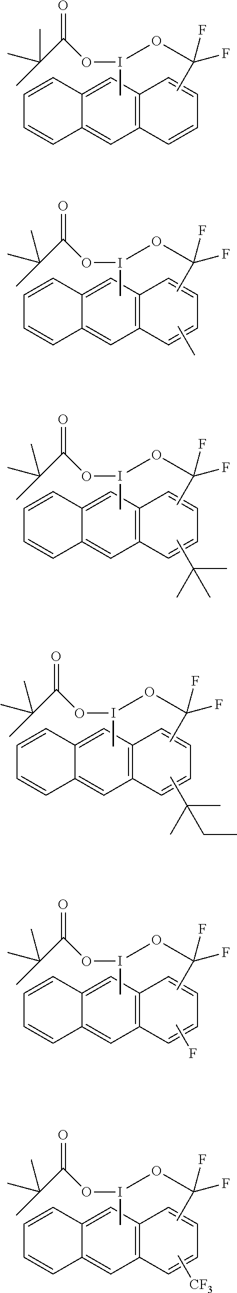

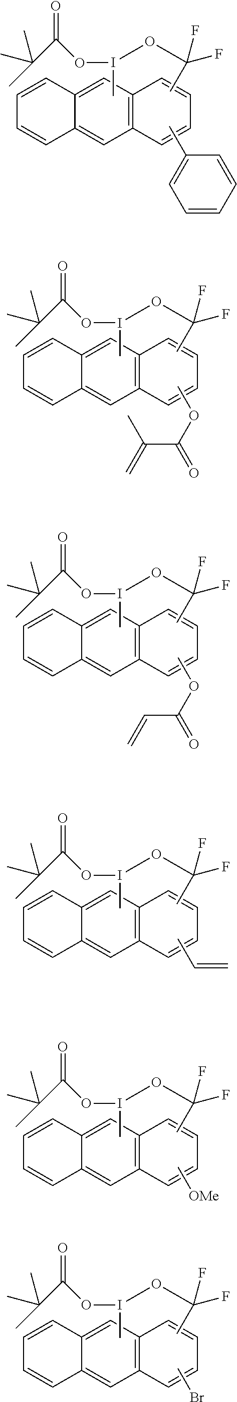

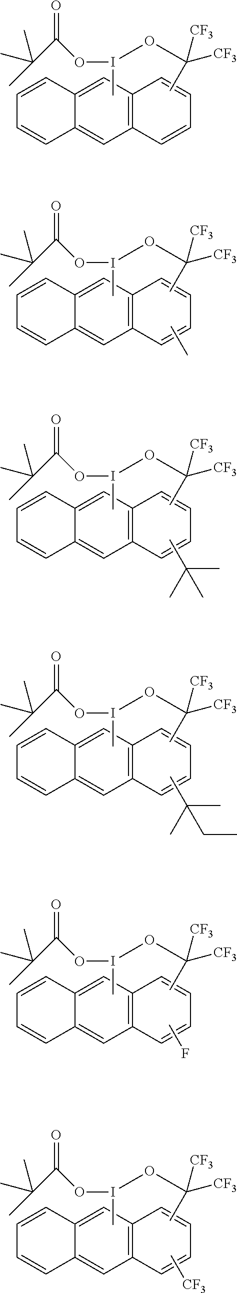

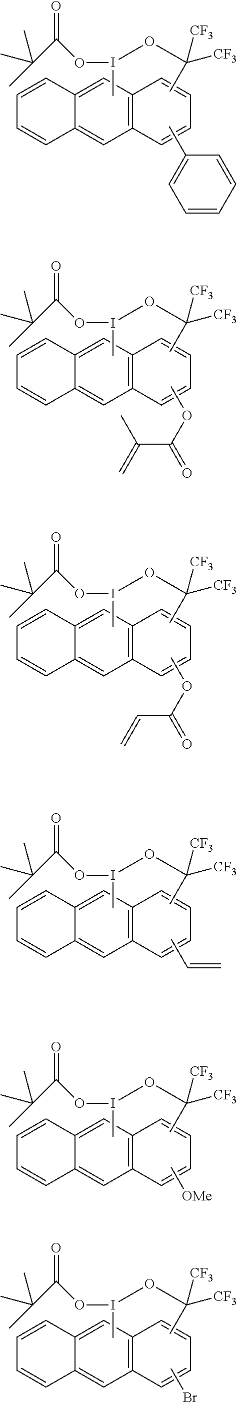

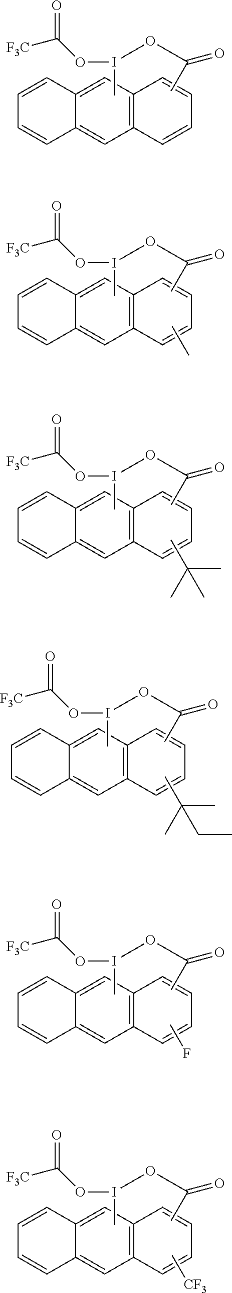

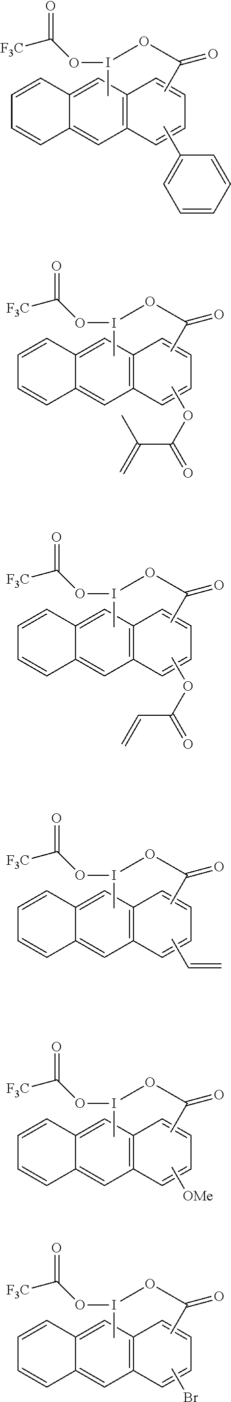

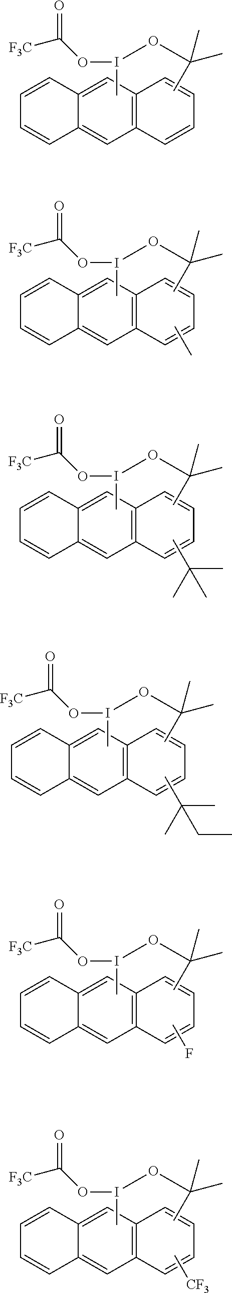

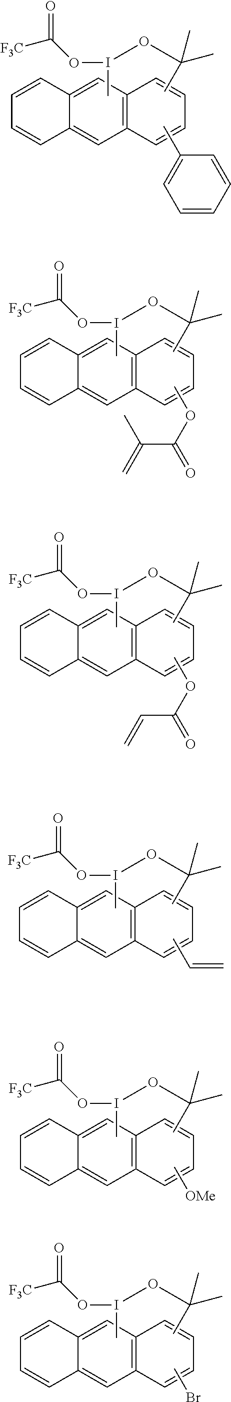

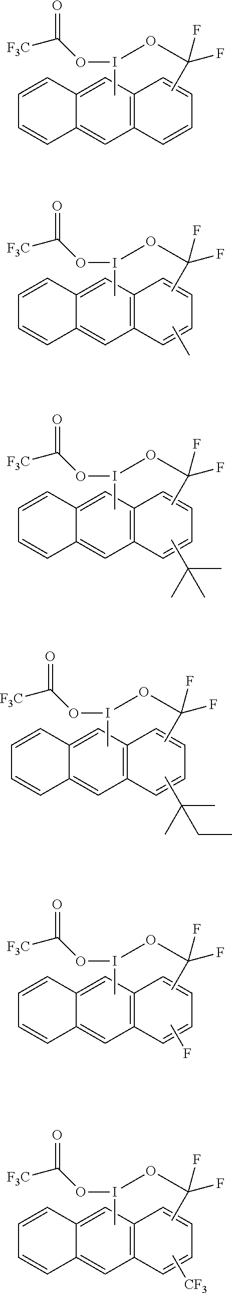

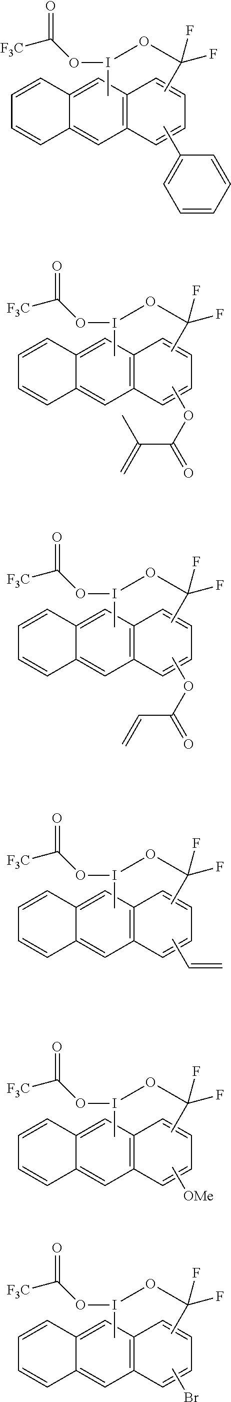

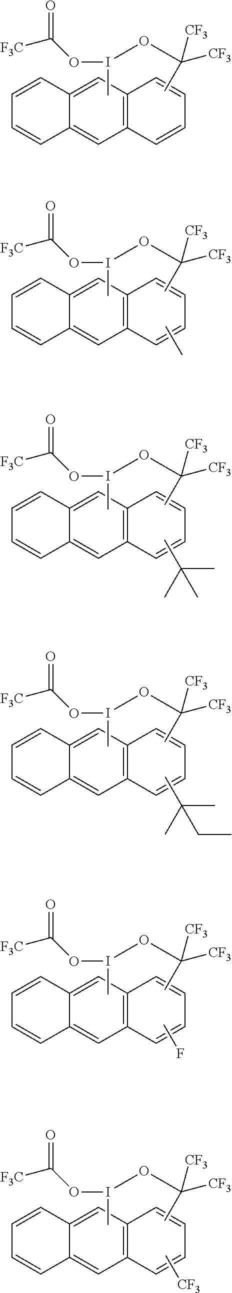

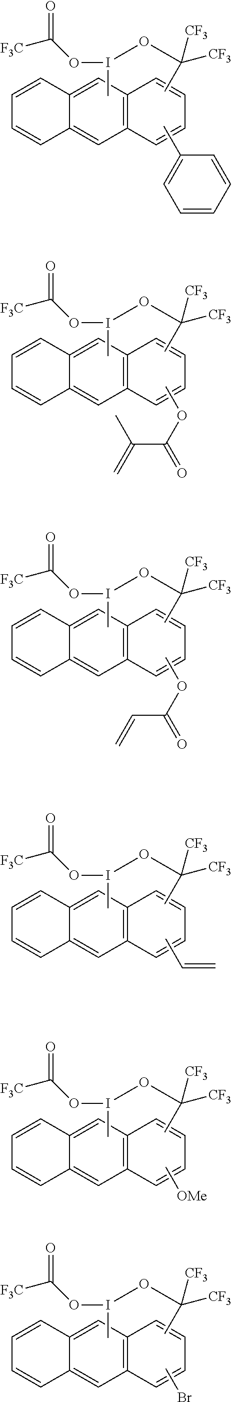

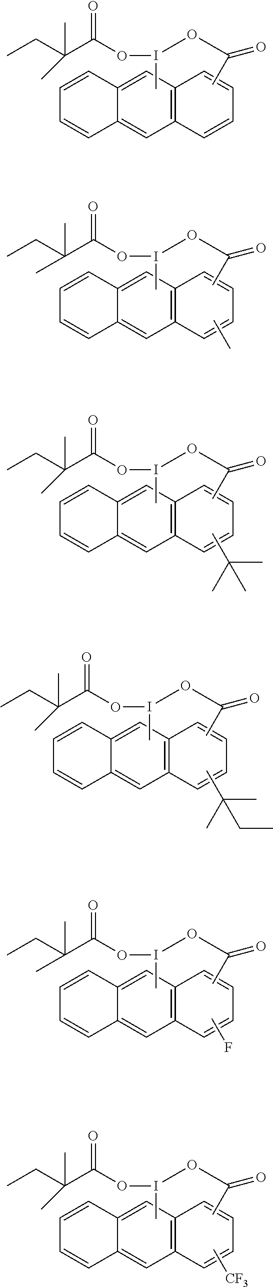

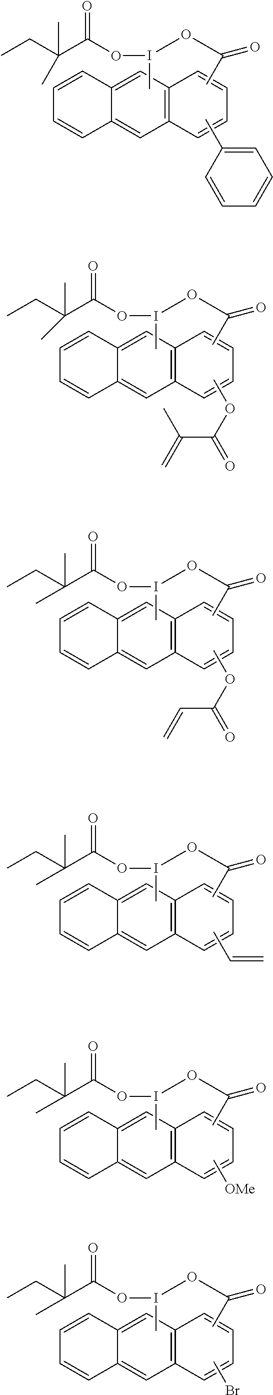

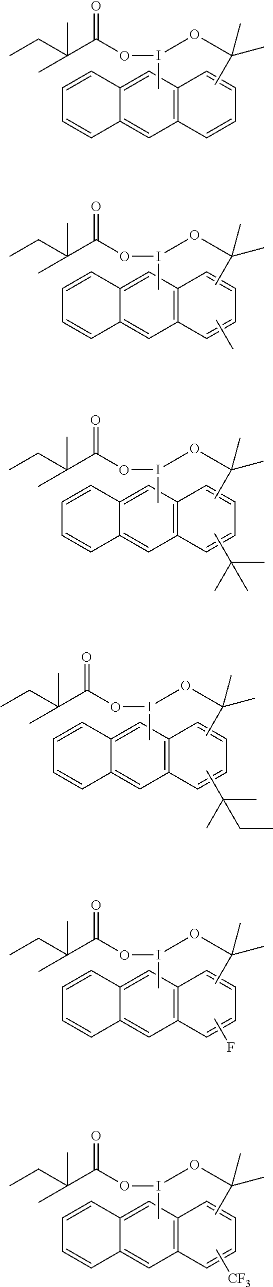

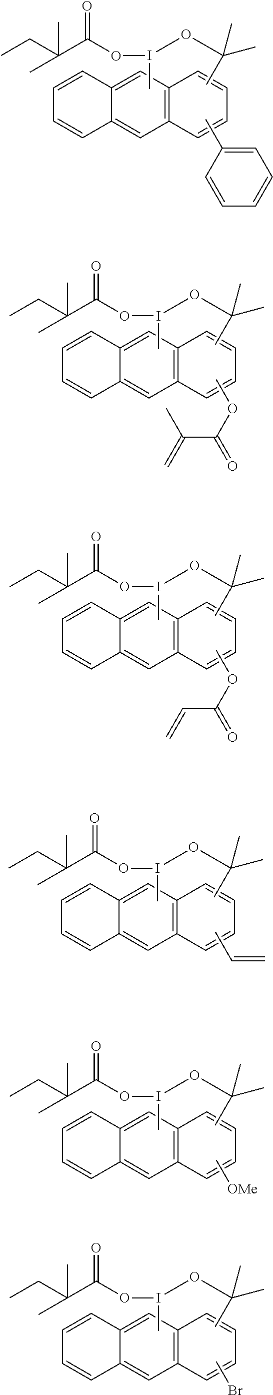

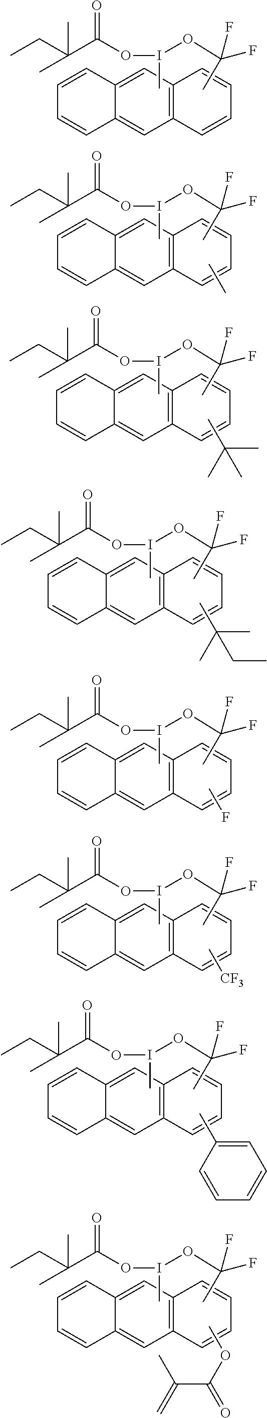

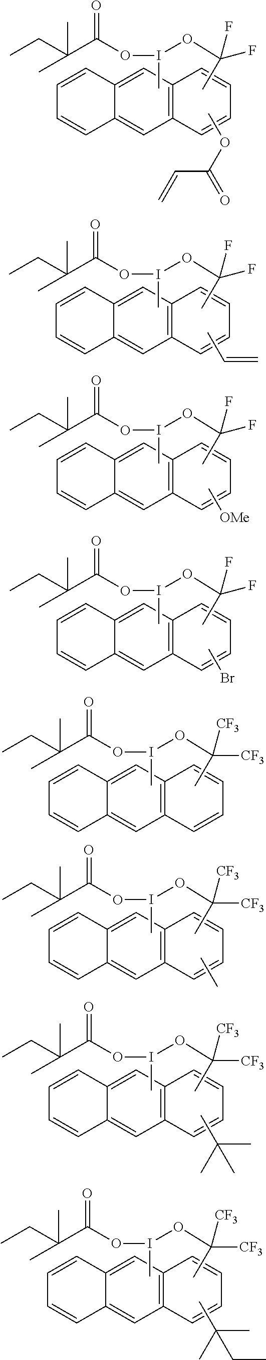

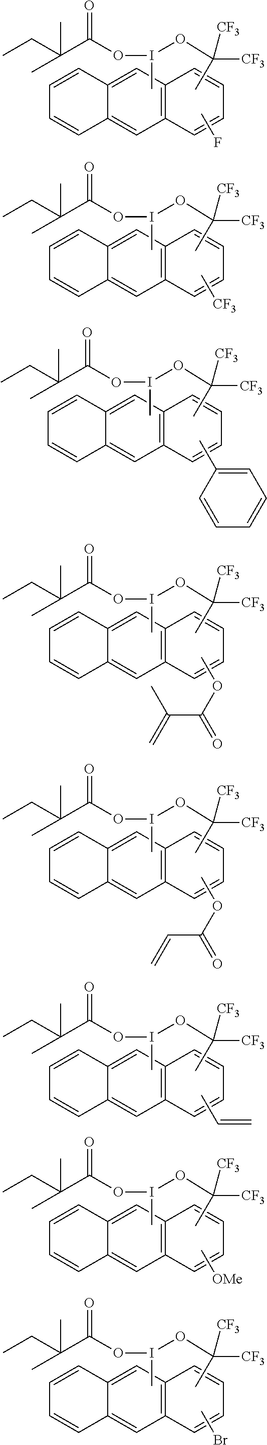

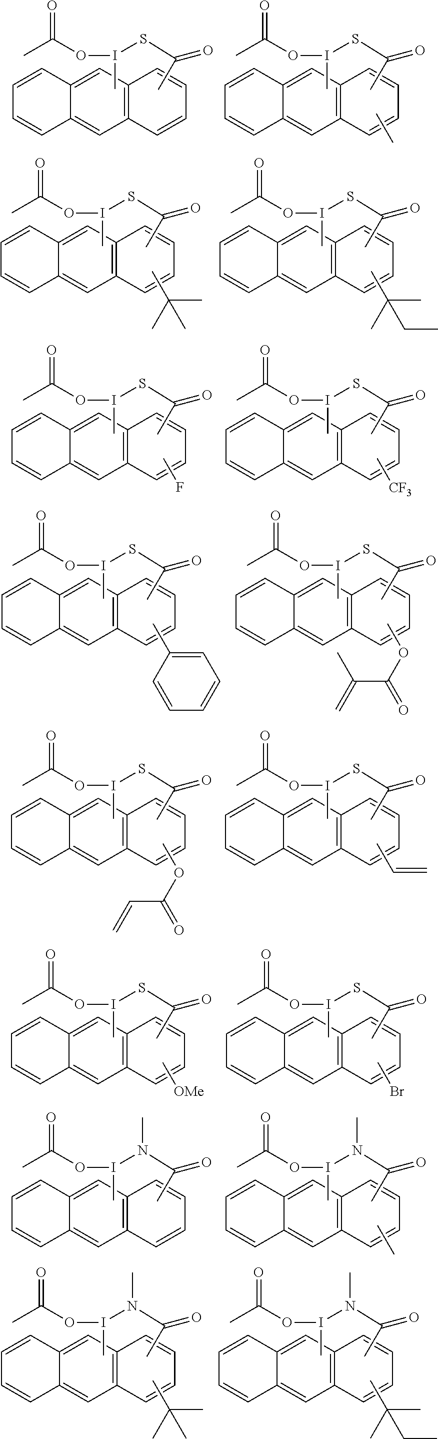

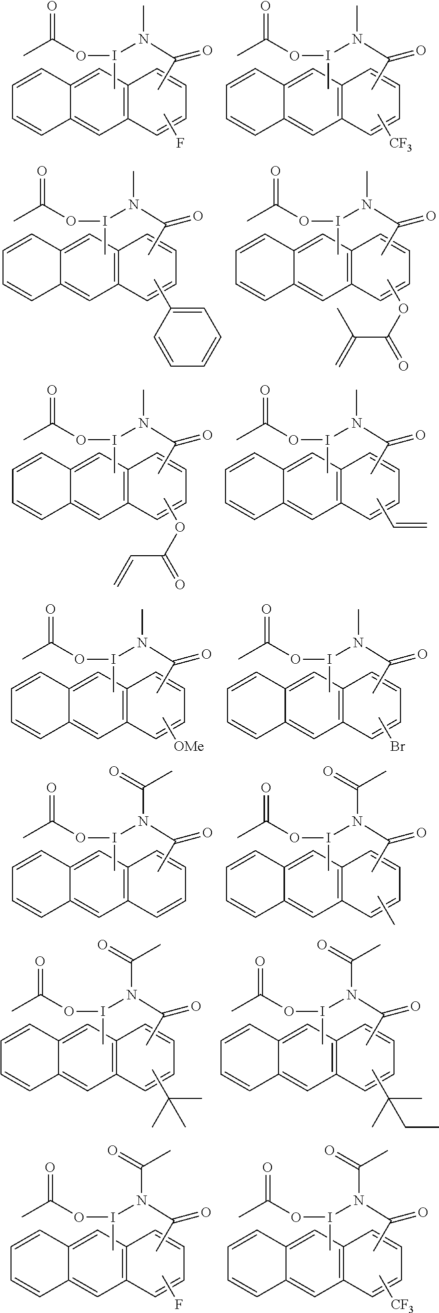

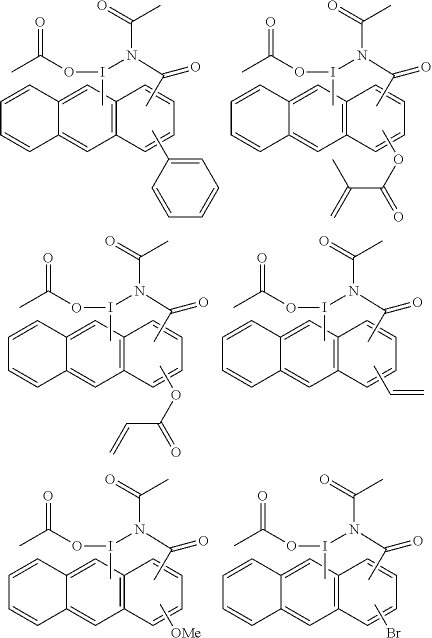

In the general formula (5), m5 is an integer of 0 to 2.

When m5 is 0, n6 is an integer of 1 to 3, n5 is an integer of 0 to 5, and 1≤(n5+n6)≤6 is satisfied.

When m5 is 1, n6 is an integer of 1 to 3, n5 is an integer of 0 to 7, and 1≤(n5+n6)≤8 is satisfied.

When m5 is 2, n6 is an integer of 1 to 3, n5 is an integer of 0 to 9, and 1≤(n5+n6)≤10 is satisfied.

In the general formula (5), R⁵¹ and R⁵² are each independently a halogen atom, or a hydrocarbyl group having 1 to 10 carbon atoms and optionally containing a heteroatom. When n6 is 2 to 3, R⁵¹s and R⁵²s are the same as or different from each other. In addition, R⁵¹ and R⁵² are optionally bound to each other to form a ring together with carbon atoms to which these are bound and an atom between the carbon atoms. Examples of the halogen atom include a fluorine atom, a chlorine atom, a bromine atom, and an iodine atom. The hydrocarbyl group having 1 to 10 carbon atoms may be saturated or unsaturated, and may be any of linear, branched or cyclic. Specific examples thereof include alkyl groups each having 1 to 10 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, tricyclo[5.2.1.0^{2,6}]decanyl group and an adamantyl group; alkenyl groups such as a vinyl group and an allyl group; aryl groups each having 6 to 10 carbon atoms, such as a phenyl group and a naphthyl group; and any group obtained by combination thereof. Some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained. R⁵¹ and R⁵² are each preferably a hydrocarbyl group having 1 to 4 carbon atoms.

In the general formula (5), R⁵³ is a halogen atom, or a hydrocarbyl group having 1 to 40 carbon atoms and optionally containing a heteroatom. Examples of the halogen atom include a fluorine atom, a chlorine atom, a bromine atom, and an iodine atom. The hydrocarbyl group having 1 to 40 carbon atoms may be saturated or unsaturated, and may be any of linear, branched or cyclic. Specific examples thereof include alkyl groups each having 1 to 40 carbon atoms, such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group and a n-decyl group; cyclic saturated hydrocarbyl groups each having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group and an adamantylmethyl group; and aryl groups each having 6 to 40 carbon atoms, such as a phenyl group, a naphthyl group and an anthracenyl group. Some or all of hydrogen atoms in the hydrocarbyl group are each optionally substituted with a group containing a heteroatom such as an oxygen atom, a sulfur atom, a nitrogen atom, or a halogen atom, some of —CH₂— in the hydrocarbyl group are each optionally substituted with a group containing a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like is optionally contained. When n5 is 2 to 9, R⁵³s are the same as or different from each other. In addition, plural R⁵³s are optionally bound to each other to form a ring together with carbon atoms in an aromatic ring to which these are bound.

Specific examples of the hypervalent iodine compound represented by the general formula (5) include the following, but not limited thereto.

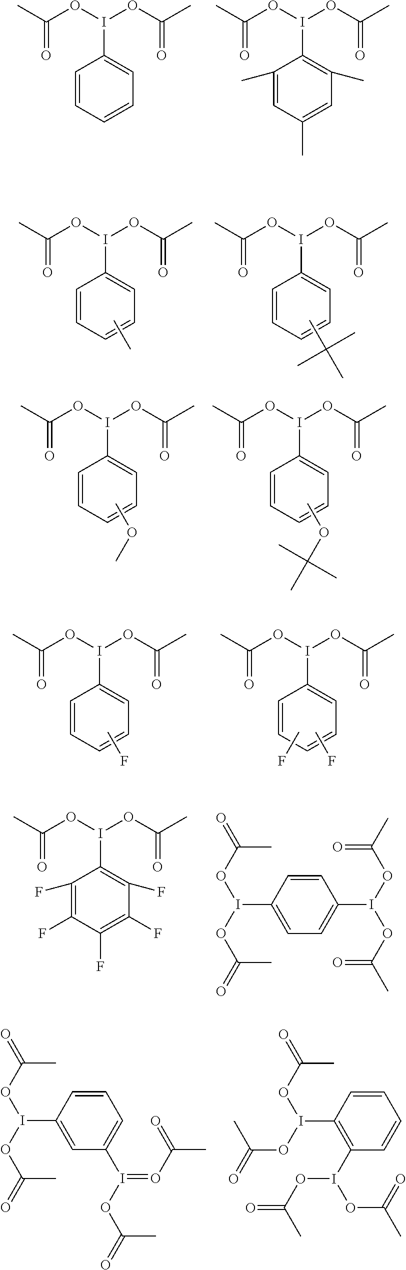

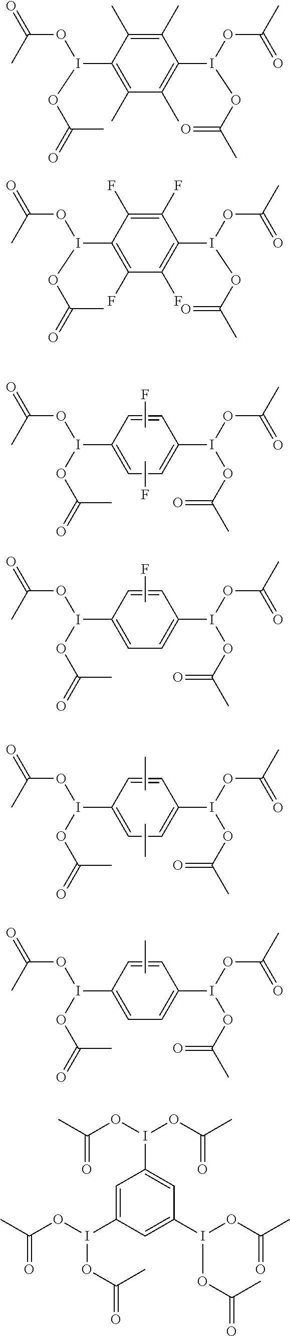

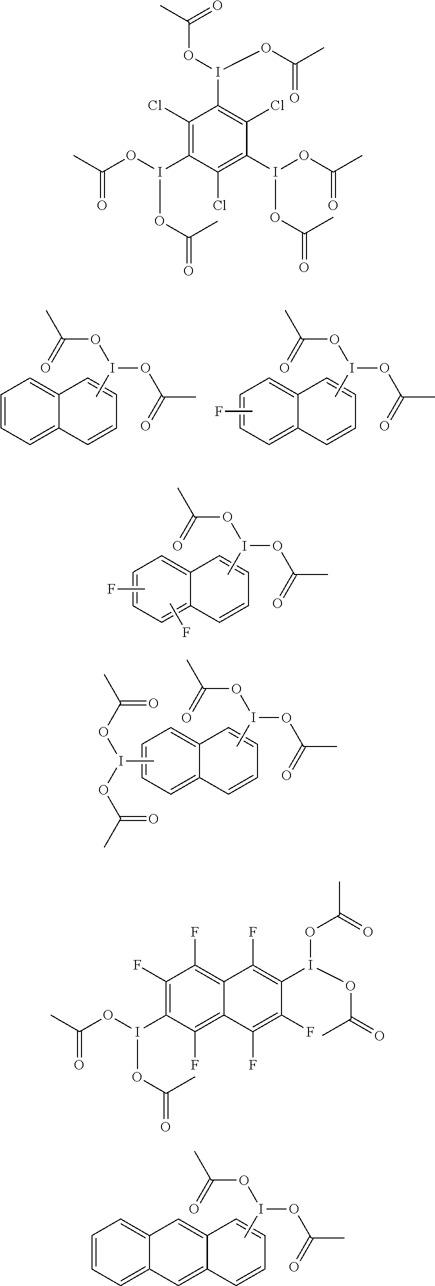

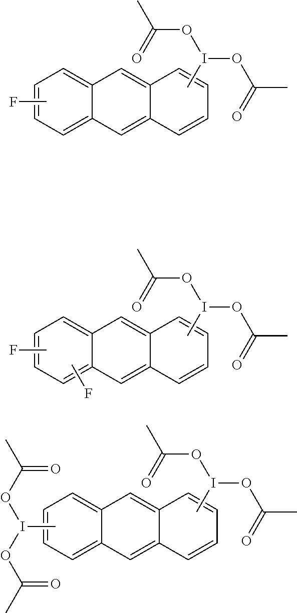

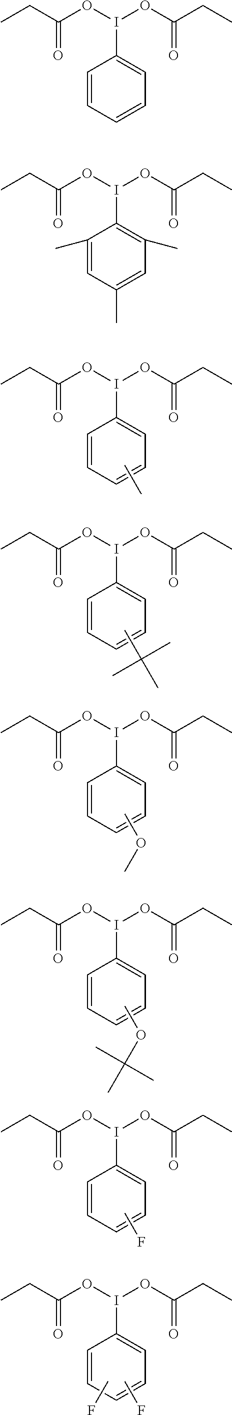

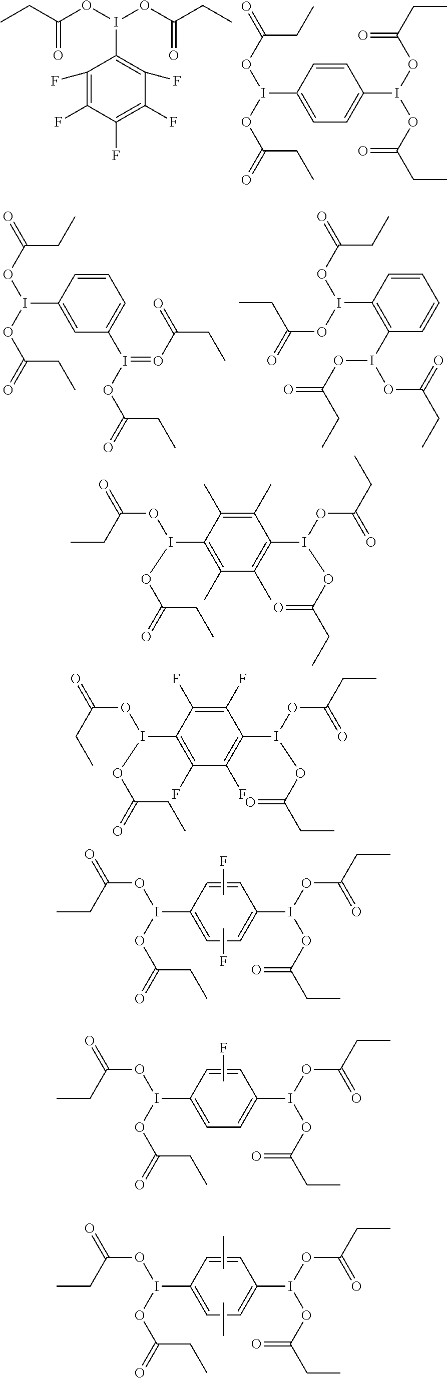

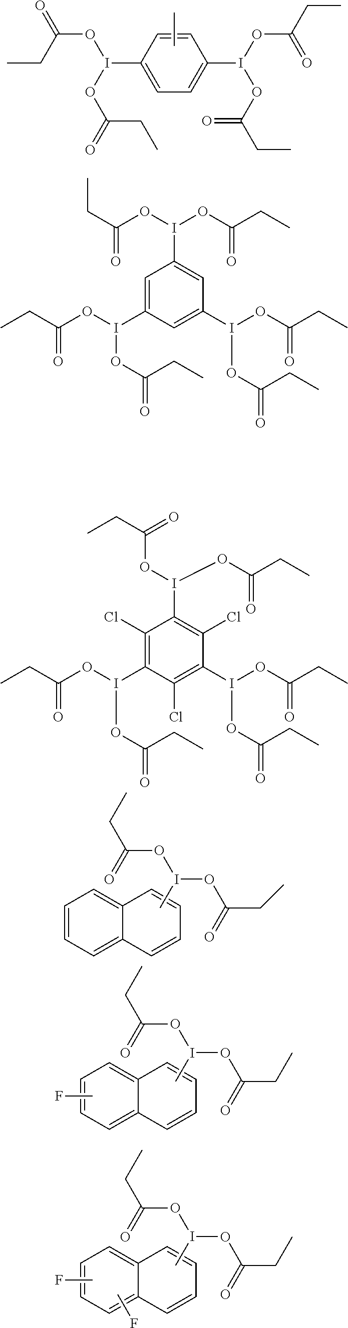

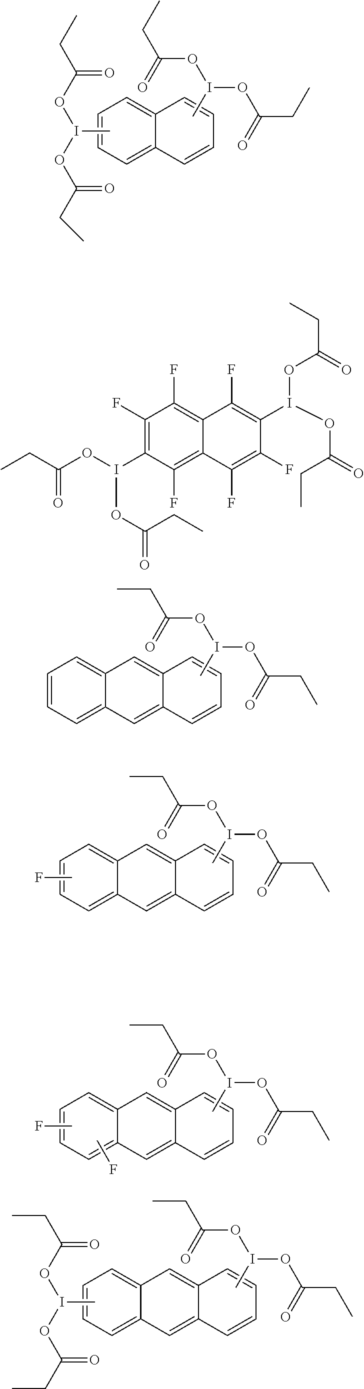

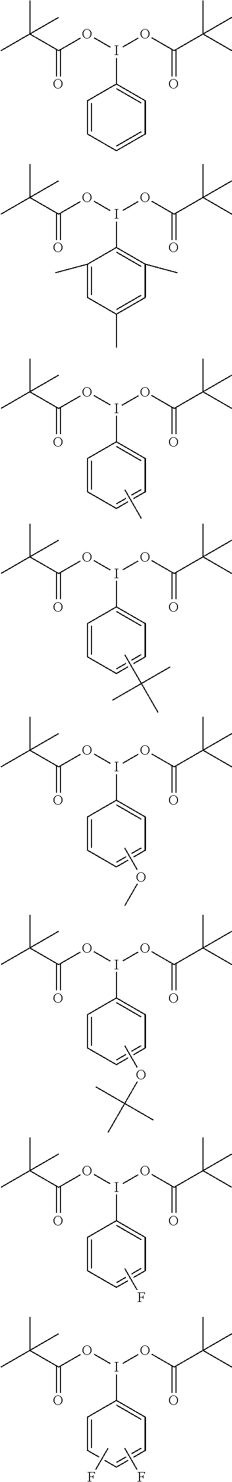

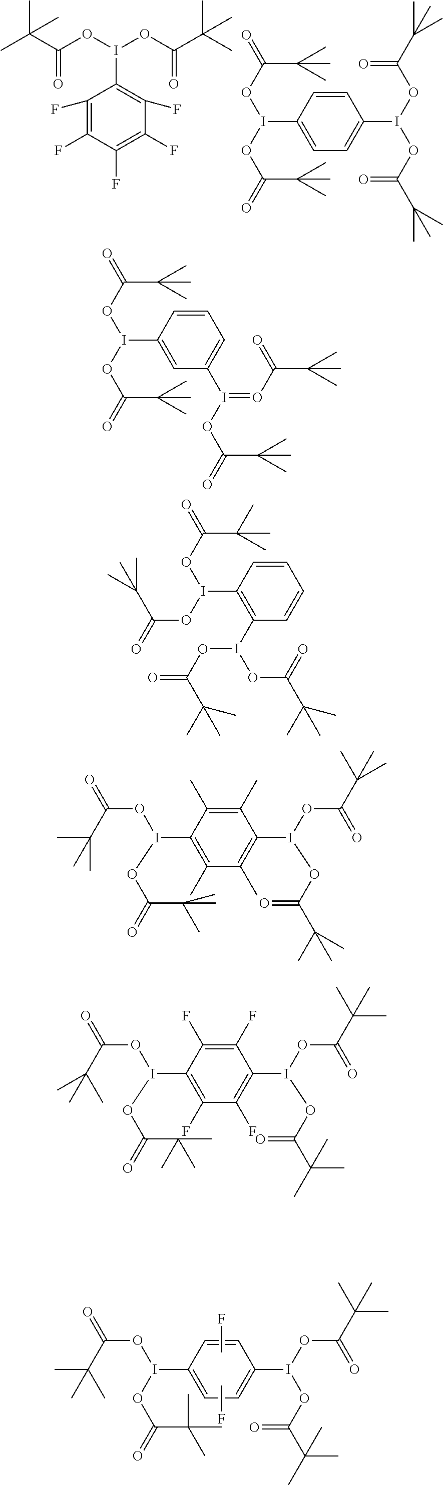

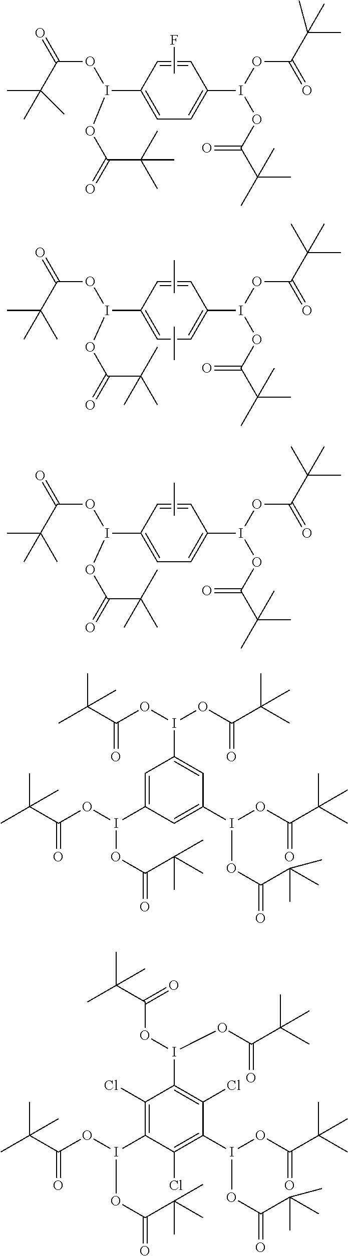

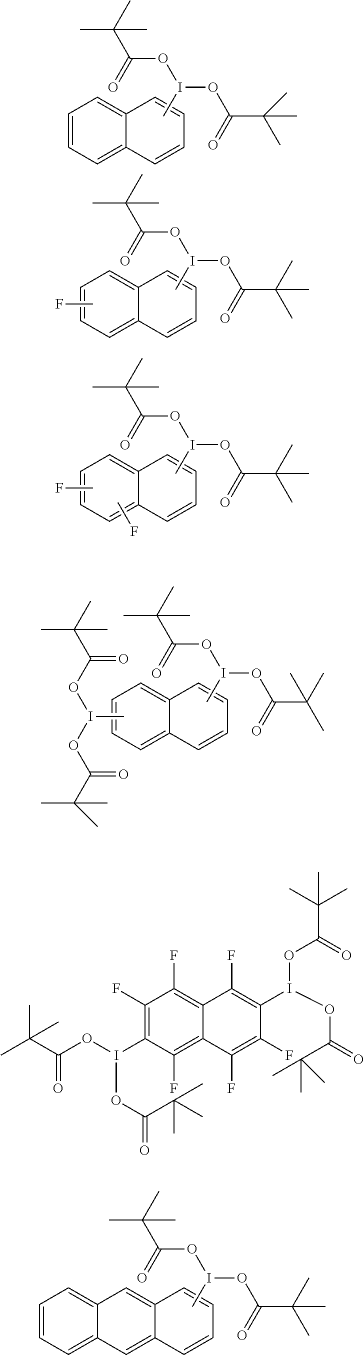

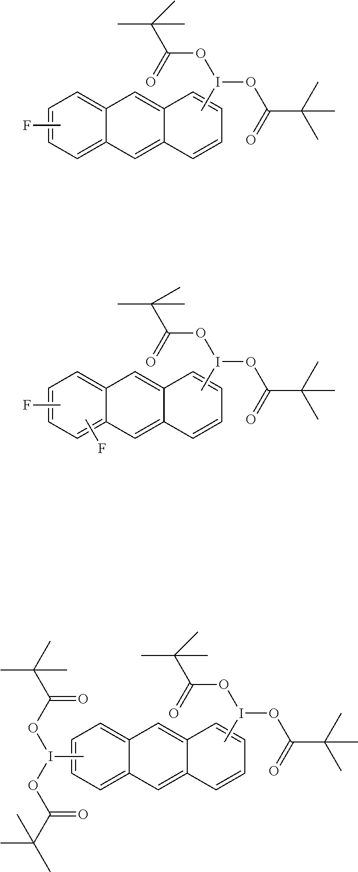

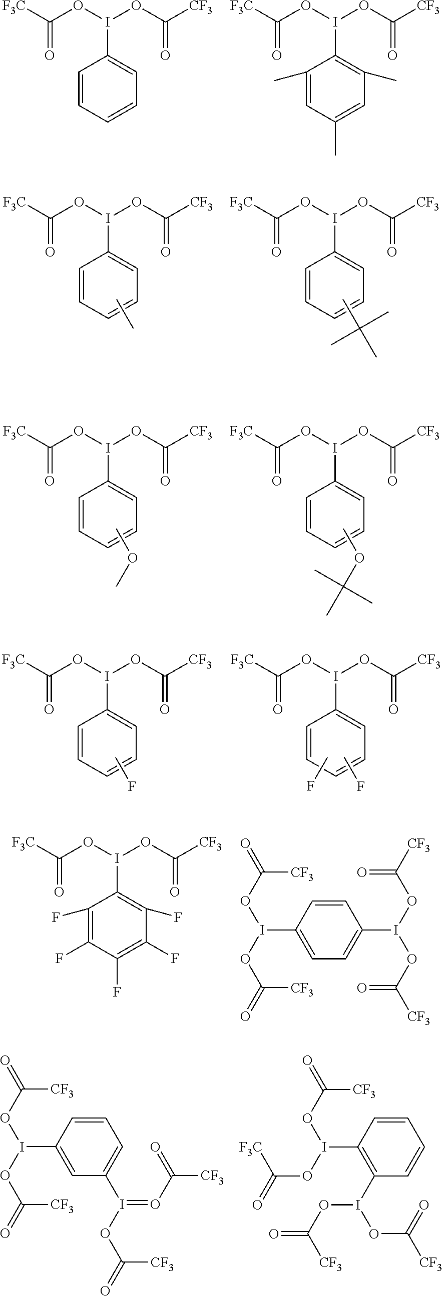

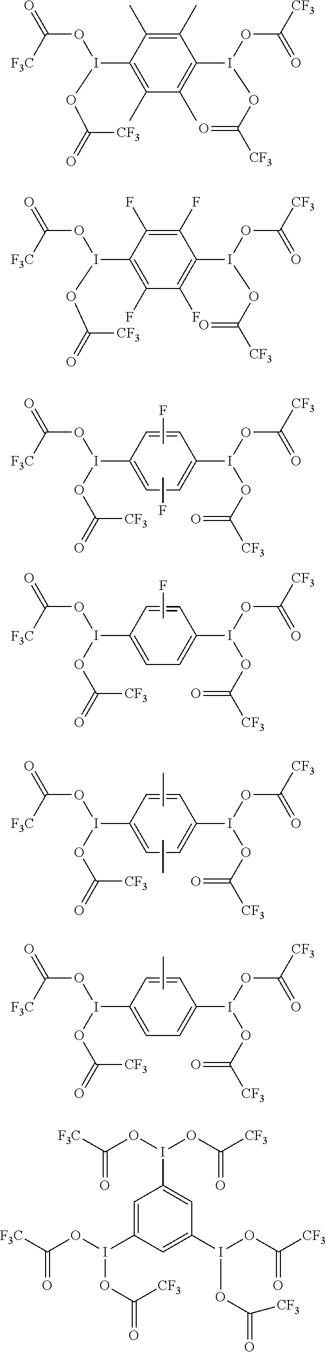

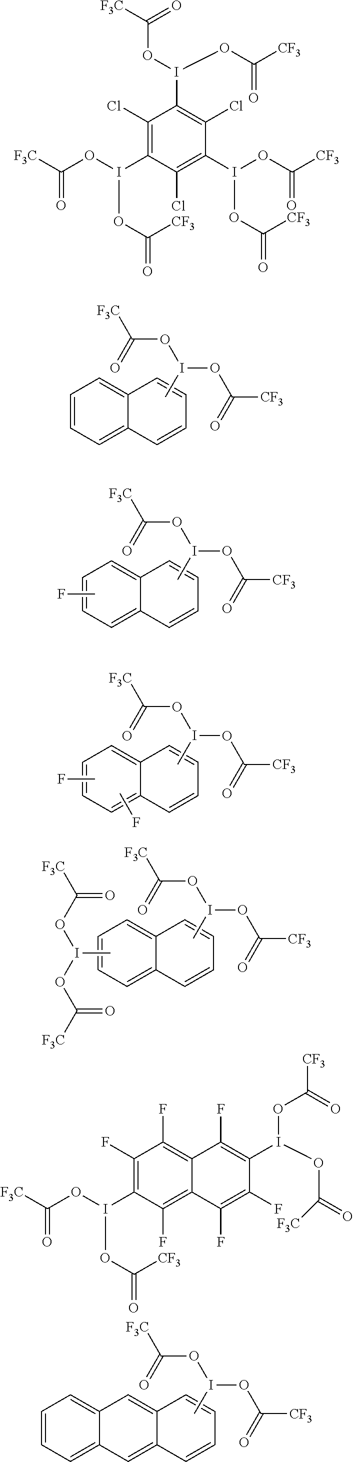

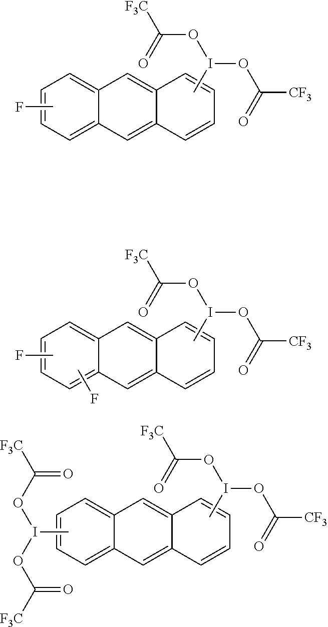

When the resist composition of the present invention contains other hypervalent iodine compound, such other hypervalent iodine compound used here may be only a hypervalent iodine compound represented by the general formula (4), may be only a hypervalent iodine compound represented by the general formula (5), or may be a combination of a hypervalent iodine compound represented by the general formula (4) and a hypervalent iodine compound represented by the general formula (5). In addition, as a hypervalent iodine compound represented by the general formula (4) and a hypervalent iodine compound represented by the general formula (5), one kind of compound may be used singly or a combinations of two or more different kinds thereof may be used.

When the resist composition of the present invention contains such other hypervalent iodine compound represented by the formula (4) or formula (5), the content ratio of other hypervalent iodine compound represented by the formula (4) or formula (5) to the carboxy group-containing compound (when the carboxy group-containing compound is a carboxy group-containing polymer, the content ratio of such other hypervalent iodine compound represented by the formula (4) or formula (5) to a carboxylic acid-containing repeating unit in the polymer) is preferably 1:99 to 99:1, more preferably 10:90 to 90:10, further preferably 20:80 to 80:20 in terms of the molar ratio. In addition, other hypervalent iodine compound represented by the formula (4) or formula (5) is preferably contained at a molar ratio to the hypervalent iodine compound represented by the formula (1), other hypervalent iodine compound represented by the formula (4) or formula (5): hypervalent iodine compound represented by formula (1), of 1:99 to 99:1, more preferably 1:99 to 50:50.

### [Solvent]

The resist composition of the present invention contains a solvent. The solvent is not particularly limited as long as it can dissolve the hypervalent iodine compound represented by the formula (1), the carboxy group-containing compound, other hypervalent iodine compound and any other component described below and can form a resist film by virtue of inclusion the solvent into the resist composition. Such a solvent is preferably an organic solvent, and specific examples thereof include ketones such as cyclohexanone, methyl-2-n-pentyl ketone and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate and propylene glycol mono-tert-butyl ether acetate; carboxylic acids such as formic acid, acetic acid and propionic acid; lactones such as y-butyrolactone; and any mixed solvent thereof.

The content of the solvent in the resist composition of the present invention is preferably an amount so that the solid content concentration in the resist composition is 0.1 to 20% by mass, more preferably an amount so that the concentration is 0.1 to 15% by mass, further preferably an amount so that the concentration is 0.1 to 10% by mass. In the present invention, the term of solid content refers to all components of the resist composition excluding the solvent. As the solvent, one kind of the solvent may be used singly or a mixture of two or more kinds thereof may be used.

### [Other Component]

The resist composition of the present invention may further contain a surfactant. The surfactant is preferably fluorine-based and/or silicone-based surfactant(s). Specific examples of such surfactant(s) include any surfactant described in paragraph [0276] in US 2008/0248425 A. Surfactants other than the fluorine-based and/or silicone-based surfactants described in paragraph [0280] in US 2008/0248425 A can also be further used.

When the resist composition of the present invention contains the above surfactant, the content of the surfactant is preferably 0.0001 to 2% by mass in the total solid content. As the surfactant, one kind thereof may be used singly or a combinations of two or more kinds thereof may be used.

The resist composition of the present invention may further contain at least one selected from a radical scavenger and a crosslinking agent. Thus, an optical reaction in photolithography can be controlled, and the sensitivity can be adjusted.

Specific examples of the radical scavenger include hindered phenols, quinones, hindered amines, and a thiol compound. Specifically, specific examples of the hindered phenols include dibutylhydroxytoluene (BHT) and 2,2′-methylenebis (4-methyl-6-tert-butylphenol). Specific examples of the quinones include 4-methoxyphenol (metoquinone) and hydroquinone. Specific examples of the hindered amines include 2,2,6,6-tetramethylpiperidine-N-oxy radical. Specific examples of the thiols include dodecanethiol and hexadecanethiol.

When the resist composition of the present invention contains the radical scavenger, the content of the radical scavenger is preferably 0.01 to 10% by mass in the total solid content. As the radical scavenger, one kind thereof may be used singly or a combinations of two or more kinds thereof may be used.

Specific examples of the crosslinking agent include a compound having a carbon-carbon unsaturated bond such as a vinyl group, a (meth)acrylate group, an allyl group, an alkynyl group, or an aromatic ring, as a functional group. Specific examples of the compound having a vinyl group include linear alkene, branched alkene, and cyclic alkene each optionally having a substituent. Specific examples of the compound having a (meth)acrylate group include acrylic acid, methacrylic acid, acrylic acid ester and methacrylic acid ester each optionally having a substituent. Specific examples of the compound having an allyl group include allyl alcohol, allyl ether, allyl ester, allylamide, allylamine and allyl group-containing isocyanurate each optionally having a substituent. Specific examples of the compound having an alkynyl group include linear alkyne, branched alkyne, cyclic alkyne, alkynyl alcohol, alkynyl ether, alkynyl ester, alkynylamide, alkynylamine and alkynyl group-containing isocyanurates each optionally having a substituent. Specific examples of the compound having an aromatic ring include arenes, heteroarenes, styrene, stilbene, phenylacetylene, acenaphthylene and chalcone each optionally having a substituent. The crosslinking agent may have only any one of the functional groups, or may have a plurality thereof. The number of the functional groups contained in the crosslinking agent is preferably 1 or more and 10 or less, more preferably 2 or more and 8 or less.

When the resist composition of the present invention contains the crosslinking agent, the content of the crosslinking agent is preferably 0.01 to 50% by mass in the total solid content. As the crosslinking agent, one kind thereof may be used singly or a combinations of two or more kinds thereof may be used.

### [Laminate]

The laminate of the present invention includes
a substrate, and
a resist film on the substrate, the resist film being obtained from the resist composition of the present invention.

In a laminate of the present invention including a resist film obtained from the resist composition of the present invention, the resist film not only has high sensitivity and furthermore exhibits excellent limit resolvability and is effective for precise fine-processing, but also can be applied to both of positive type patterning and negative type patterning. Therefore, the laminate of the present invention can be widely used in a variety of applications, and is highly useful for resist process techniques.

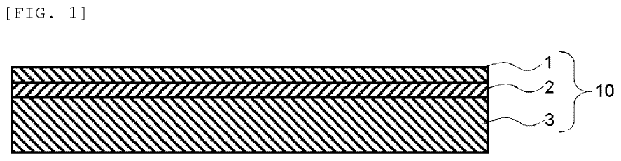

For example, a resist underlayer film 2 may be included between a substrate 3 and a resist film 1, as in a laminate 10 shown in FIG. 1.

When a resist underlayer film is necessary for patterning, the resist underlayer film can also be appropriately disposed between the substrate and the resist film.

For example, the resist film 1 can contain a product of a ligand exchange reaction between the hypervalent iodine compound and the carboxy group-containing compound.

The resist film can be formed by, for example, a ligand exchange reaction between the hypervalent iodine compound and the carboxy group-containing compound contained in the resist composition. Accordingly, the resist film may contain a product of such a ligand exchange reaction.

### [Patterning Process]

In a case where the resist composition of the present invention is used for manufacturing various integrated circuits, known lithography techniques can be applied. Examples of the patterning process include a method including the steps of forming a resist film on a substrate with the resist composition; exposing the resist film to a high energy ray; and developing the resist film having been exposed with, if necessary, a developer.

Specifically, the patterning process of the present invention includes the steps of:
forming a resist film on a substrate or on a resist underlayer film on a substrate on which the resist underlayer film is laminated, with the resist composition of the present invention;
exposing the resist film to a high energy ray; and
developing the resist film having been exposed with a developer.

First, the resist composition of the present invention is applied to a substrate for integrated circuit manufacturing, a resist underlayer film of a substrate on which the resist underlayer film is laminated (Si, SiO₂, SiN, SiON, TiN, WSi, BPSG, SOG, an organic anti-reflection film, or the like), a substrate for mask circuit manufacturing, or a resist underlayer film of a substrate on which the resist underlayer film is laminated (Cr, CrO, CrON, MoSi₂, SiO₂, or the like), for example, by an appropriate application process such as spin coating, roll coating, flow coating, dip coating, spray coating, or doctor coating so that the film thickness by application is 0.01 to 2 μm, for example. A coating film thus obtained can be pre-baked on, for example, a hot plate preferably at 60 to 200° C. for 10 seconds to 30 minutes, more preferably 80 to 180° C. for 30 seconds to 20 minutes, thereby forming a resist film. Herein, the resist underlayer film means a film formed between a substrate and a resist film in a multilayer resist process, and the resist underlayer film is not particularly limited and conventionally known one can be used.

Next, the resist film is exposed with a high energy ray. Specific examples of the high energy ray include ultraviolet rays (g-line (436 nm), h-line (405 nm), i-ray (365 nm), and the like), far-ultraviolet rays, EB, EUV, X-rays, soft X-rays, excimer laser light (KrF excimer laser light, ArF excimer laser light, and the like), y-rays, and synchrotron radiations. The high energy ray used here is preferably an i-ray, a KrF excimer laser, an ArF excimer laser, an electron beam or an extreme-ultraviolet ray. In a case where an ultraviolet ray, a far-ultraviolet ray, EUV, an X-ray, a soft X-ray, excimer laser light, a y-ray, a synchrotron radiation or the like is used as the high energy ray, irradiation is performed directly or with a mask for formation of an objective pattern so that the amount of exposure is preferably about 1 to 300 mJ/cm², more preferably about 10 to 200 mJ/cm². When EB is used as the high energy ray, lithography is performed directly or with a mask for formation of an objective pattern so that the amount of exposure is preferably about 0.1 to 2000 μC/cm², more preferably about 0.5 to 1500 μC/cm². The resist composition of the present invention is suitable particularly for fine patterning with EB or EUV among high energy rays.

After exposure, PEB is, if necessary, performed. It is here preferable to perform PEB on a hot plate or in an oven in conditions of 30 to 150° C. for 10 seconds to 30 minutes, more preferably of 60 to 120° C. for 30 seconds to 20 minutes, after exposure.

After exposure or after PEB, patterning is performed, if necessary, by development with a developer. Examples of the developer used here include aqueous alkali solution such as an aqueous tetramethylammonium hydroxide solution; and organic solvents such as 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, isoamyl alcohol, n-butanol, n-pentanol, cyclohexanol, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxy propionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, diacetone alcohol and 4-methyl-2-pentanol. As such a developer, one kind thereof may be used singly or a mixture of two or more kinds thereof may be used.

After development, rinse is, if necessary, performed. A rinse liquid is preferably a solvent which is miscible with a developer but is not dissolve the resist film. As such a solvent, an alcohol having 3 to 10 carbon atoms, an ether compound each having 8 to 12 carbon atoms, or an alkane, alkene, alkyne or aromatic solvent each having 6 to 12 carbon atoms is preferably used. Alternatively, water may be used as the rinse liquid instead of the organic solvent.

By performing such rinse, the occurrence of collapse and/or defects of a resist pattern can be reduced. Such rinse is not necessarily essential, and the amount of a solvent used can be reduced by not performing such rinse.

Upon exposure, the resist composition of the present invention can form a positive-type or negative-type pattern by the difference in solubility generated between an exposed section and an unexposed section. Therefore, a developer that dissolves an exposed area and that does not dissolve an unexposed area or a developer that dissolves an unexposed area and that does not dissolve an exposed area can be used as the developer. Thus, the patterning process of the present invention can form a positive-type or negative-type pattern by appropriately selecting the developer, and therefore can be widely applied to various kinds of fine patterning.

### EXAMPLES

Hereinafter, the present invention is specifically described with reference to Synthesis Examples, Examples and Comparative Examples, but the present invention is not limited to those.

### [1] Synthesis of Hypervalent Iodine Compound

The hypervalent iodine compounds used in Comparative Examples and Examples are represented by the following formulae (RI-1) to (RI-3) and (I-1) to (I-3).

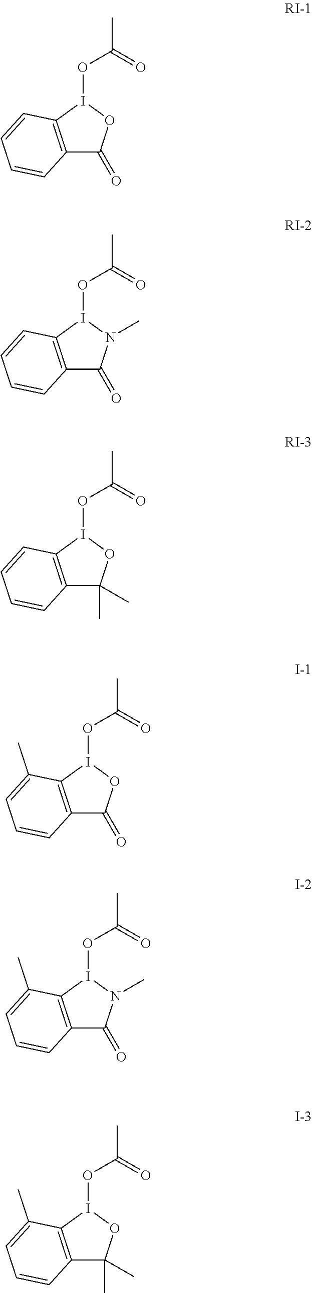 [SMILES: CC(=O)OI1OC(=O)c2ccccc21 ; CC(=O)OI1c2ccccc2C(=O)N1C ; CC(=O)OI1OC(C)(C)c2ccccc21 ; CC(=O)OI1OC(=O)c2cccc(C)c21 ; CC(=O)OI1c2c(C)cccc2C(=O)N1C ; CC(=O)OI1OC(C)(C)c2cccc(C)c21]

The hypervalent iodine compound represented by the formula (RI-1) and the hypervalent iodine compound represented by the formula (I-1) were synthesized with reference to Org. Biomol. Chem., 2015, 13, 8812. The hypervalent iodine compound represented by the formula (RI-2) was synthesized with reference to Org. Lett., 2023, 25, 2739. The hypervalent iodine compound represented by the formula (I-2) was synthesized by the same method as in (RI-2) except that 2-iodo-3-methylbenzoic acid was used as a raw material. The hypervalent iodine compound represented by the formula (RI-3) was synthesized with reference to Org. Biomol. Chem., 2020, 18, 1679. The hypervalent iodine compound represented by the formula (I-3) was synthesized by the same method as in (RI-3) except that 2-(2-iodo-3-methylphenyl)propan-2-ol was used as a raw material.

### [2] Synthesis of Polymer

Monomers used for polymer synthesis are as follows.

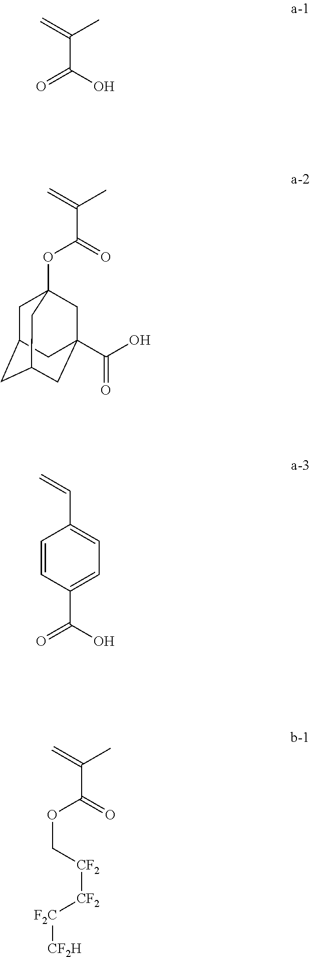

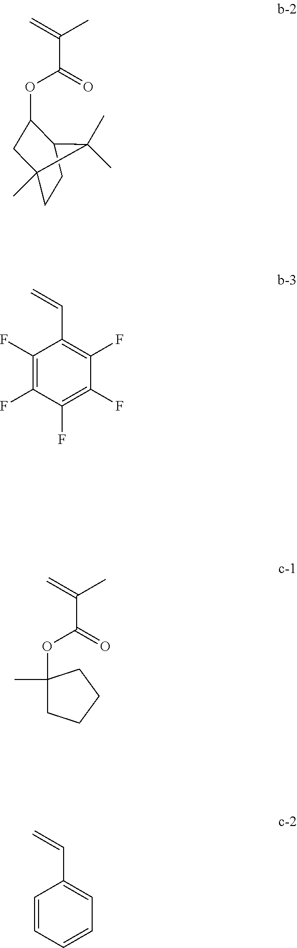

### [Synthesis Example 1] Synthesis of Polymer P-1

Under a nitrogen atmosphere, monomer a-1 (56 g), monomer b-1 (105 g), V-601 (manufactured by FUJIFILM Wako Pure Chemical Corporation) (5.4 g) and MEK (methyl ethyl ketone) (180 g) were put into a flask, to prepare a monomer-polymerization initiator solution. After 55 g of MEK was put into another flask whose atmosphere was a nitrogen atmosphere, and heated to 80° C. with stirring, the monomer-polymerization initiator solution prepared in advance was dropped over 4 hours. After the completion of dropping, the polymerization liquid was continuously stirred for 2 hours with the temperature thereof being kept at 80° C., and then cooled to room temperature. The resulting polymerization liquid was dropped to 4000 g of hexane vigorously stirred, and a polymer precipitated was separated by filtration. Furthermore, the resulting polymer was washed with hexane 1200 g twice, and thereafter dried in vacuum at 50° C. for 20 hours, thereby obtaining polymer P-1 as a white powder (155 g, yield: 96%). The Mw and the Mw/Mn of polymer P-1 were respectively 7700 and 1.82. Herein, the Mw and Mn are values measured in terms of polystyrene by GPC with THF as a solvent. Specifically, measurement was performed in the following conditions (the same applied to the following).
Apparatus: HLC-8320GPC
Columns: TSK guardcolumn
   +TSKgel G4000HXL
   +TSKgel G2000HXL
   +TSKgel superH5000
Pump, column constant temperature: 40° C.
Eluent: THF
Detector: RI (differential refractive) detector
Amount of injection: 100 pl

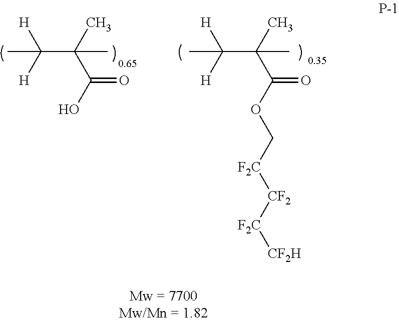

### [Synthesis Example 2-10] Synthesis of Polymers P-2 to P-10

Each polymer shown in Table 1 was synthesized by the same process as in Synthesis Example 1 except that the types of monomers and the blending ratio thereof were changed. Herein, polymer P-10 is a polymer having no carboxy group (—COOH), and does not correspond to the carboxy group-containing compound in the present invention.

TABLE 1

| | | | Introduction | | Introduction | | |
|---|---|---|---|---|---|---|---|
| | | | ratio | | ratio | | |
| | Polymer | Monomer 1 | (mol %) | Monomer 2 | (mol %) | Mw | Mw/Mn |
| Synthesis | P-1 | a-1 | 65 | b-1 | 35 | 7700 | 1.82 |
| Example 1 | | | | | | | |
| Synthesis | P-2 | a-1 | 50 | b-2 | 50 | 8400 | 1.84 |
| Example 2 | | | | | | | |
| Synthesis | P-3 | a-1 | 60 | b-3 | 40 | 8100 | 1.79 |
| Example 3 | | | | | | | |
| Synthesis | P-4 | a-2 | 65 | b-1 | 35 | 8300 | 1.83 |
| Example 4 | | | | | | | |
| Synthesis | P-5 | a-2 | 50 | b-2 | 50 | 8300 | 1.83 |
| Example 5 | | | | | | | |
| Synthesis | P-6 | a-2 | 60 | b-3 | 40 | 8200 | 1.82 |
| Example 6 | | | | | | | |
| Synthesis | P-7 | a-3 | 65 | b-1 | 35 | 8000 | 1.80 |
| Example 7 | | | | | | | |
| Synthesis | P-8 | a-3 | 50 | b-2 | 50 | 8600 | 1.84 |
| Example 8 | | | | | | | |
| Synthesis | P-9 | a-3 | 60 | b-3 | 40 | 7900 | 1.81 |
| Example 9 | | | | | | | |
| Synthesis | P-10 | c-1 | 60 | c-2 | 40 | 9800 | 1.82 |
| Example 10 | | | | | | | |

### [3]Preparation of Resist Composition

### Examples 1-1 to 1-24 and Comparative Examples 1-1 to 1-8

Resist compositions (R-01 to R-24) and comparative resist compositions (CR-01 to CR-06) were each prepared by dissolving the hypervalent iodine compound, other hypervalent iodine compound and the polymer in a solvent containing a 0.01% by mass of surfactant (PF-636, manufactured by OMNOVA Solutions Inc.) at a compositional ratio shown in Table 2 below, and filtrating the resulting solution with a 0.2-μm Teflon (registered trademark) filter. Comparative resist compositions (CR-07 to CR-08) were each prepared by dissolving a polymer, a photo-acid generator and a sensitivity modifier in a solvent containing a 0.01% by mass surfactant (PF-636, manufactured by OMNOVA Solutions Inc.) at a compositional ratio shown in Table 3, and filtrating the resulting solution with a 0.2-μm Teflon (registered trademark) filter.

TABLE 2

| | | Hypervalent iodine | Other | | | |
|---|---|---|---|---|---|---|
| | | compound | hypervalent | Carboxy group- | | |
| | | represented by | iodine | containing | | Solvent 2 |
| | Resist | formula (1) | compound | compound | Solvent 1 | (parts by |
| | composition | (parts by mass) | (parts by mass) | (parts by mass) | (parts by mass) | mass) |
| Example 1-1 | R-01 | I-1(10) | — | P-1(7.7) | PGMEA(800) | AcOH(200) |
| Example 1-2 | R-02 | I-2(10) | — | P-1(7.4) | PGMEA(800) | AcOH(200) |
| Example 1-3 | R-03 | I-3(10) | — | P-1(7.4) | PGMEA(800) | AcOH(200) |
| Example 1-4 | R-04 | I-1(10) | — | P-2(9.6) | PGMEA(800) | AcOH(200) |
| Example 1-5 | R-05 | I-1(10) | — | P-3(6.7) | PGMEA(800) | AcOH(200) |
| Example 1-6 | R-06 | I-1(10) | — | P-4(10.8) | PGMEA(800) | AcOH(200) |
| Example 1-7 | R-07 | I-1(10) | — | P-5(15.2) | PGMEA(800) | AcOH(200) |
| Example 1-8 | R-08 | I-1(10) | — | P-6(12.3) | PGMEA(800) | AcOH(200) |
| Example 1-9 | R-09 | I-1(10) | — | P-7(9.7) | PGMEA(800) | AcOH(200) |
| Example 1-10 | R-10 | I-1(10) | — | P-8(11.6) | PGMEA(800) | AcOH(200) |
| Example 1-11 | R-11 | I-1(10) | — | P-9(8.7) | PGMEA(800) | AcOH(200) |
| Example 1-12 | R-12 | I-1(10) | — | P-1(7.7) | HBM(800) | AcOH(200) |
| Example 1-13 | R-13 | I-1(10) | — | P-1(7.7) | PGMEA(800) | PA(200) |
| Example 1-14 | R-14 | I-1(5) | — | P-1(7.7) | PGMEA(800) | AcOH(200) |
| Example 1-15 | R-15 | I-1(5) | O-1(2.5) | P-1(7.7) | PGMEA(800) | AcOH(200) |
| Example 1-16 | R-16 | I-1(5) | — | P-1(7.7) | PGMEA(800) | AcOH(200) |
| | | I-2(5) | | | | |
| Example 1-17 | R-17 | I-1(10) | — | m-1(3.8) | PGMEA(800) | AcOH(200) |
| Example 1-18 | R-18 | I-1(10) | — | m-2(1.8) | PGMEA(800) | AcOH(200) |
| Example 1-19 | R-19 | I-1(10) | — | m-3(3.7) | PGMEA(800) | AcOH(200) |
| Example 1-20 | R-20 | I-1(10) | — | m-4(3.4) | PGMEA(800) | AcOH(200) |
| Example 1-21 | R-21 | I-1(10) | — | m-5(5.1) | PGMEA(800) | AcOH(200) |
| Example 1-22 | R-22 | I-1(10) | — | m-6(3.9) | PGMEA(800) | AcOH(200) |
| Example 1-23 | R-23 | I-2(10) | — | m-6(3.8) | PGMEA(800) | AcOH(200) |
| Example 1-24 | R-24 | I-3(10) | — | m-6(3.7) | PGMEA(800) | AcOH(200) |
| Comparative | CR-01 | — | RI-1(10) | P-1(8.1) | PGMEA(800) | AcOH(200) |
| Example 1-1 | | | | | | |
| Comparative | CR-02 | — | RI-2(10) | P-1(7.8) | PGMEA(800) | AcOH(200) |
| Example 1-2 | | | | | | |
| Comparative | CR-03 | — | RI-3(10) | P-1(7.7) | PGMEA(800) | AcOH(200) |
| Example 1-3 | | | | | | |
| Comparative | CR-04 | — | RI-1(10) | m-1(3.9) | PGMEA(800) | AcOH(200) |
| Example 1-4 | | | | | | |
| Comparative | CR-05 | — | RI-2(10) | m-1(3.8) | PGMEA(800) | AcOH(200) |
| Example 1-5 | | | | | | |
| Comparative | CR-06 | — | RI-3(10) | m-1(3.7) | PGMEA(800) | AcOH(200) |
| Example 1-6 | | | | | | |

TABLE 3

| | | | Photo-acid | Sensitivity | | |
|---|---|---|---|---|---|---|
| | | Polymer | generator | modifier | | Solvent 2 |
| | Resist | (parts by | (parts by | (parts by | Solvent 1 | (parts by |
| | composition | mass) | mass) | mass) | (parts by mass) | mass) |
| Comparative | CR-07 | P-10(80) | PAG-1(19) | Q-1(6) | PGMEA(1890) | GBL(210) |
| Example 1-7 | | | | | | |
| Comparative | CR-08 | P-10(80) | PAG-1(19) | O-1(5) | PGMEA(1890) | GBL(210) |
| Example 1-8 | | | | | | |

In Tables 2 and 3, other hypervalent iodine compounds 0-1, carboxy group-containing compounds m-1 to m-6, photo-acid generators PAG-1, sensitivity modifiers Q-1 and solvents are as follows.

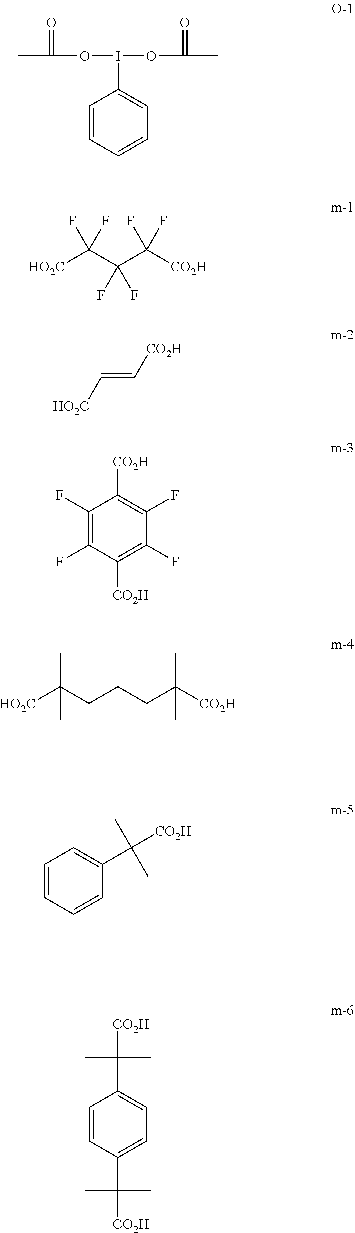

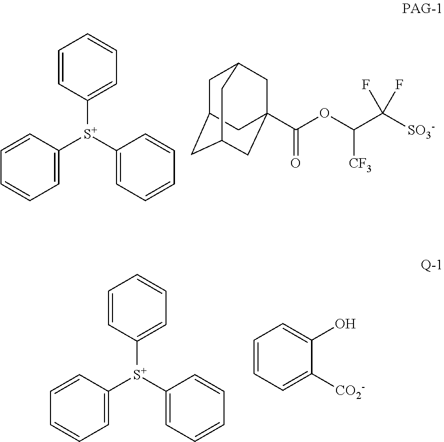

Solvents: PGMEA (propylene glycol monomethyl ether acetate)
   AcOH (acetic acid)
   HBM (methyl 2-hydroxyisobutyrate)
   PA (propionic acid)
   GBL (γ-butyrolactone)

### [4] EUV Lithography Evaluation (Line-and-Space Pattern and Positive Tone Development)

### Examples 2-1 to 2-24 and Comparative Examples 2-1 to 2-8

Each resist composition (R-01 to R-24 and CR-01 to CR-08) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 4 for 60 seconds, thereby producing a resist film having a thickness of 40 nm. In such each resist film produced, a 36 nm line-and-space (LS) (1:1) pattern was exposed with an EUV scanner NXE3400 manufactured by ASML Holding N.V. (NA 0.33, σ 0.9, 90° dipole illumination), and thereafter PEB on a hot plate at a temperature shown in Table 4 for 60 seconds and then development with a developer shown in Table 4 for 30 seconds were performed, thereby forming an LS pattern having a space width of 18 nm and a pitch of 36 nm.

The resist pattern obtained was evaluated as follows. The results are shown in Table 4.

### [Evaluation of Sensitivity]

The LS pattern was observed with a length measurement SEM (CG-6300) manufactured by Hitachi High-Tech Corporation, the optimal amount of exposure Eop (mJ/cm²), in which an LS pattern having a space width of 18 nm and a pitch of 36 nm was obtained, was determined, and this amount was defined as sensitivity.

### [Evaluation of LWR]

The dimensions at 10 positions in the longitudinal direction of the space width of the LS pattern obtained by irradiation in the optimal amount of exposure were measured with a length measurement SEM (CG-6300) manufactured by Hitachi High-Tech Corporation, and a value of three standard deviations (3σ) from the standard deviation (σ) was determined as LWR, from the above results. As this value is smaller, a pattern small in roughness and uniform in space width is obtained.

### [Evaluation of Limit Resolvability]

The line width (nm) at a limit of resolving during formation of a pattern with an increase in amount of exposure little by little from the optimal amount of exposure in which the LS pattern was formed was determined with a length measurement SEM (CG-6300) manufactured by Hitachi High-Tech Corporation, and this line width was defined as the limit resolution (nm). It is indicated that, as this value is smaller, a finer pattern having excellent limit resolvability can be formed.

TABLE 4

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 2-1 | R-01 | 130/90 | nBA | 24 | 2.3 | 8 |
| Example 2-2 | R-02 | 130/90 | nBA | 25 | 2.8 | 9 |
| Example 2-3 | R-03 | 130/90 | nBA | 25 | 2.7 | 9 |
| Example 2-4 | R-04 | 130/90 | nBA | 27 | 2.6 | 8 |
| Example 2-5 | R-05 | 130/90 | nBA | 29 | 2.3 | 8 |
| Example 2-6 | R-06 | 130/90 | nBA | 30 | 2.5 | 10 |
| Example 2-7 | R-07 | 130/90 | nBA | 29 | 2.6 | 11 |
| Example 2-8 | R-08 | 130/90 | nBA | 30 | 2.4 | 11 |
| Example 2-9 | R-09 | 130/90 | nBA | 25 | 2.3 | 12 |
| Example 2-10 | R-10 | 130/90 | nBA | 27 | 2.5 | 11 |
| Example 2-11 | R-11 | 130/90 | nBA | 23 | 2.1 | 12 |
| Example 2-12 | R-12 | 130/90 | nBA | 22 | 2.1 | 8 |
| Example 2-13 | R-13 | 130/90 | CHA | 17 | 2.2 | 8 |
| Example 2-14 | R-14 | 130/90 | nBA | 21 | 2.0 | 7 |
| Example 2-15 | R-15 | 130/90 | nBA | 24 | 2.1 | 8 |
| Example 2-16 | R-16 | 130/90 | nBA | 25 | 2.5 | 8 |
| Example 2-17 | R-17 | 130/90 | nBA | 22 | 2.4 | 10 |
| Example 2-18 | R-18 | 130/90 | nBA | 26 | 2.6 | 9 |
| Example 2-19 | R-19 | 130/90 | nBA | 23 | 2.4 | 10 |
| Example 2-20 | R-20 | 130/90 | nBA | 23 | 2.3 | 8 |
| Example 2-21 | R-21 | 130/90 | nBA | 22 | 2.7 | 8 |
| Example 2-22 | R-22 | 130/90 | nBA | 24 | 2.0 | 10 |
| Example 2-23 | R-23 | 130/90 | nBA | 27 | 2.2 | 11 |
| Example 2-24 | R-24 | 130/90 | nBA | 30 | 2.2 | 9 |
| Comparative | CR-01 | 130/90 | nBA | 39 | 3.6 | 14 |
| Example 2-1 | | | | | | |
| Comparative | CR-02 | 130/90 | nBA | 40 | 3.8 | 16 |
| Example 2-2 | | | | | | |
| Comparative | CR-03 | 130/90 | nBA | 41 | 3.7 | 15 |
| Example 2-3 | | | | | | |
| Comparative | CR-04 | 130/90 | nBA | 40 | 4.0 | 18 |
| Example 2-4 | | | | | | |
| Comparative | CR-05 | 130/90 | nBA | 45 | 3.9 | 16 |
| Example 2-5 | | | | | | |
| Comparative | CR-06 | 130/90 | nBA | 48 | 4.1 | 16 |
| Example 2-6 | | | | | | |
| Comparative | CR-07 | 105/90 | TMAH | 80 | 4.5 | 18 |
| Example 2-7 | | | | | | |
| Comparative | CR-08 | 105/90 | TMAH | 85 | 4.8 | 18 |
| Example 2-8 | | | | | | |

Developers: nBA (butyl acetate)
   CHA (cyclohexyl acetate)
   TMAH (aqueous 2.38% by mass
tetramethylammonium hydroxide solution)

### [5] EUV Lithography Evaluation (Line-and-Space Pattern and Negative Tone Development)

### Examples 3-1 to 3-24 and Comparative Examples 3-1 to 3-8

Each resist composition (R-1 to R-24 and CR-01 to CR-08) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 5 for 60 seconds, thereby producing a resist film having a thickness of 40 nm. Such each resist film produced was subjected to exposure of a 36 nm line-and-space (LS) (1:1) pattern with an EUV scanner NXE3400 manufactured by ASML Holding N.V. (NA 0.33, σ 0.9, 90° dipole illumination), and thereafter bake (PEB) on a hot plate at a temperature shown in Table 5 for 60 seconds and then development with a developer shown in Table 5 for 30 seconds, thereby forming an LS pattern having a space width of 18 nm and a pitch of 36 nm.

The resist pattern obtained was evaluated as follows. The results are shown in Table 5.

### [Evaluation of Sensitivity]

The LS pattern was observed with a length measurement SEM (CG-6300) manufactured by Hitachi High-Tech Corporation, the optimum amount of exposure Eop (mJ/cm²), in which an LS pattern having a space width of 18 nm and a pitch of 36 nm, was determined, and this amount was defined as sensitivity.

### [Evaluation of LWR]

The dimensions at 10 positions in the longitudinal direction of the space width of the LS pattern obtained by irradiation in the optimal amount of exposure were measured with a length measurement SEM (CG-6300) manufactured by Hitachi High-Tech Corporation, and a value of three standard deviations (3σ) from the standard deviation (σ) was determined as LWR, from the above results. As this value is smaller, a pattern small in roughness and uniform in space width is obtained.

### [Evaluation of Limit Resolvability]

The line width (nm) at a limit of resolving during formation of a pattern with an increase in amount of exposure little by little from the optimal amount of exposure in which the LS pattern was formed was determined with a length measurement SEM (CG-6300) manufactured by Hitachi High-Tech Corporation, and this line width was defined as the limit resolution (nm). It is indicated that, as this value is smaller, a finer pattern having excellent limit resolvability can be formed.

TABLE 5

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 3-1 | R-01 | 130/90 | TMAH | 24 | 2.7 | 9 |
| Example 3-2 | R-02 | 130/90 | TMAH | 25 | 3.1 | 10 |
| Example 3-3 | R-03 | 130/90 | TMAH | 25 | 3.1 | 9 |
| Example 3-4 | R-04 | 130/90 | TMAH | 26 | 3.0 | 10 |
| Example 3-5 | R-05 | 130/90 | TMAH | 27 | 2.6 | 10 |
| Example 3-6 | R-06 | 130/90 | TMAH | 28 | 2.8 | 11 |
| Example 3-7 | R-07 | 130/90 | TMAH | 27 | 2.9 | 13 |
| Example 3-8 | R-08 | 130/90 | TMAH | 28 | 2.9 | 12 |
| Example 3-9 | R-09 | 130/90 | TMAH | 25 | 2.7 | 13 |
| Example 3-10 | R-10 | 130/90 | TMAH | 25 | 2.8 | 11 |
| Example 3-11 | R-11 | 130/90 | TMAH | 23 | 2.6 | 10 |
| Example 3-12 | R-12 | 130/90 | TMAH | 22 | 2.6 | 9 |
| Example 3-13 | R-13 | 130/90 | TMAH | 17 | 2.6 | 10 |
| Example 3-14 | R-14 | 130/90 | TMAH | 21 | 2.5 | 9 |
| Example 3-15 | R-15 | 130/90 | TMAH | 24 | 2.3 | 10 |
| Example 3-16 | R-16 | 130/90 | TMAH | 25 | 2.9 | 10 |
| Example 3-17 | R-17 | 130/90 | TMAH | 22 | 2.8 | 11 |
| Example 3-18 | R-18 | 130/90 | TMAH | 26 | 3.0 | 12 |
| Example 3-19 | R-19 | 130/90 | TMAH | 23 | 2.9 | 12 |
| Example 3-20 | R-20 | 130/90 | TMAH | 21 | 2.8 | 10 |
| Example 3-21 | R-21 | 130/90 | TMAH | 22 | 3.1 | 10 |
| Example 3-22 | R-22 | 130/90 | TMAH | 24 | 2.4 | 11 |
| Example 3-23 | R-23 | 130/90 | TMAH | 24 | 2.7 | 10 |
| Example 3-24 | R-24 | 130/90 | TMAH | 23 | 3.0 | 11 |
| Comparative | CR-01 | 130/90 | TMAH | 40 | 4.1 | 16 |
| Example 3-1 | | | | | | |
| Comparative | CR-02 | 130/90 | TMAH | 42 | 4.2 | 17 |
| Example 3-2 | | | | | | |
| Comparative | CR-03 | 130/90 | TMAH | 43 | 4.0 | 18 |
| Example 3-3 | | | | | | |
| Comparative | CR-04 | 130/90 | TMAH | 41 | 4.5 | 20 |
| Example 3-4 | | | | | | |
| Comparative | CR-05 | 130/90 | TMAH | 45 | 4.3 | 15 |
| Example 3-5 | | | | | | |
| Comparative | CR-06 | 130/90 | TMAH | 41 | 4.2 | 17 |
| Example 3-6 | | | | | | |
| Comparative | CR-07 | 105/90 | nBA | 83 | 4.6 | 18 |
| Example 3-7 | | | | | | |
| Comparative | CR-08 | 105/90 | nBA | 86 | 4.9 | 18 |
| Example 3-8 | | | | | | |

It has been found from the results shown in Table 4 and Table 5 that the resist composition of the present invention is excellent in sensitivity, LWR and resolvability in each of a positive tone and a negative tone in line-and-space patterning by EUV exposure.

### [6] EUV Lithography Evaluation (Contact Hole Pattern)

### Examples 4-1 to 4-24 and Comparative Examples 4-1 to 4-8

Each resist composition (R-01 to R-24 and CR-01 to CR-08) was applied to a Si substrate on which a silicon-containing Spin-on hard mask SHB-A940 (silicon content 43% by mass) manufactured by Shin-Etsu Chemical Co., Ltd. was formed at a thickness of 20 nm, by spin-coating, and subjected to post apply bake (PAB) with a hot plate at a temperature shown in Table 6 for 60 seconds, thereby producing a resist film having a thickness of 50 nm. Next, the resist film was exposed with an EUV scanner NXE3400 manufactured by ASML Holding N.V. (NA 0.33, σ 0.9/0.6, quadrupole illumination, mask of a hole pattern with a pitch of 64 nm and a bias of +20% as dimensions on a wafer), subjected to bake (PEB) on a hot plate at a temperature shown in Table 6 for 60 seconds, and developed with a developer shown in Table 6 for 30 seconds, then a hole pattern having holes each having a dimension of 32 nm was obtained.

The resist pattern obtained was evaluated as follows. The results are shown in Table 6.

### [Evaluation of Sensitivity]

The contact hole pattern was observed with a length measurement SEM (CG-6300) manufactured by Hitachi High-Tech Corporation, the optimal amount of exposure Eop (mJ/cm²), in which a hole pattern having holes each having a dimension of 32 nm was obtained, was determined.

### [Evaluation of CD Uniformity (CDU)l

The dimensions at 50 positions of the hole pattern obtained by irradiation in the optimal amount of exposure were measured, and a value of three standard deviations (3σ) from the standard deviation (σ) calculated from the above results was defined as CDU. As this value is smaller, a pattern uniform in hole diameter is obtained.

### [Evaluation of Limit Resolvability]

The hole diameter (nm) at a limit of resolving during formation of a hole pattern with a decrease in amount of exposure little by little from the optimal amount of exposure in which the hole pattern was formed was determined with a length measurement SEM (CG-6300) manufactured by Hitachi High-Tech Corporation, and this hole diameter was defined as the limit resolution (nm). It is indicated that, as this value is smaller, a pattern having excellent limit resolvability and a finer hole diameter can be formed.

TABLE 6

| | | | | | | Limit |
|---|---|---|---|---|---|---|
| | Resist | PAB/PEB | | Eop | CDU | resolution |
| | composition | (° C.) | Developer | (mJ/cm²) | (nm) | (nm) |
| Example 4-1 | R-01 | 130/90 | nBA | 16 | 2.1 | 18 |
| Example 4-2 | R-02 | 130/90 | nBA | 17 | 2.2 | 19 |
| Example 4-3 | R-03 | 130/90 | nBA | 17 | 2.1 | 19 |
| Example 4-4 | R-04 | 130/90 | nBA | 19 | 2.3 | 18 |
| Example 4-5 | R-05 | 130/90 | nBA | 21 | 2.0 | 18 |
| Example 4-6 | R-06 | 130/90 | nBA | 20 | 2.1 | 20 |
| Example 4-7 | R-07 | 130/90 | nBA | 21 | 2.2 | 21 |
| Example 4-8 | R-08 | 130/90 | nBA | 21 | 2.1 | 21 |
| Example 4-9 | R-09 | 130/90 | nBA | 17 | 1.9 | 20 |
| Example 4-10 | R-10 | 130/90 | nBA | 21 | 2.1 | 20 |
| Example 4-11 | R-11 | 130/90 | nBA | 15 | 1.9 | 21 |
| Example 4-12 | R-12 | 130/90 | nBA | 14 | 1.9 | 19 |
| Example 4-13 | R-13 | 130/90 | CHA | 12 | 1.8 | 19 |
| Example 4-14 | R-14 | 130/90 | nBA | 13 | 1.7 | 18 |
| Example 4-15 | R-15 | 130/90 | nBA | 16 | 1.8 | 19 |
| Example 4-16 | R-16 | 130/90 | nBA | 17 | 2.1 | 19 |
| Example 4-17 | R-17 | 130/90 | nBA | 14 | 2.0 | 18 |
| Example 4-18 | R-18 | 130/90 | nBA | 18 | 2.2 | 20 |
| Example 4-19 | R-19 | 130/90 | nBA | 15 | 2.1 | 21 |
| Example 4-20 | R-20 | 130/90 | nBA | 15 | 2.0 | 19 |
| Example 4-21 | R-21 | 130/90 | nBA | 16 | 2.1 | 19 |
| Example 4-22 | R-22 | 130/90 | nBA | 16 | 1.7 | 20 |
| Example 4-23 | R-23 | 130/90 | nBA | 17 | 1.8 | 21 |
| Example 4-24 | R-24 | 130/90 | nBA | 15 | 1.8 | 19 |
| Comparative | CR-01 | 130/90 | nBA | 25 | 2.8 | 26 |
| Example 4-1 | | | | | | |
| Comparative | CR-02 | 130/90 | nBA | 26 | 2.9 | 28 |
| Example 4-2 | | | | | | |
| Comparative | CR-03 | 130/90 | nBA | 24 | 2.7 | 29 |
| Example 4-3 | | | | | | |
| Comparative | CR-04 | 130/90 | nBA | 26 | 2.9 | 28 |
| Example 4-4 | | | | | | |
| Comparative | CR-05 | 130/90 | nBA | 26 | 2.7 | 28 |
| Example 4-5 | | | | | | |
| Comparative | CR-06 | 130/90 | nBA | 25 | 2.9 | 29 |
| Example 4-6 | | | | | | |
| Comparative | CR-07 | 105/90 | TMAH | 42 | 3.8 | 32 |
| Example 4-7 | | | | | | |
| Comparative | CR-08 | 105/90 | TMAH | 40 | 4.0 | 32 |
| Example 4-8 | | | | | | |

It has been found from the results shown in Table 6 that the resist composition of the present invention is excellent in sensitivity, CDU and resolvability in contact hole patterning by EUV exposure.

In other words, it has been found from Examples above that the resist composition of the present invention can exhibit both high sensitivity and high resolution in a patterning process, and is extremely effective for formation of a fine pattern.

The present description includes the following inventions.
[1] A resist composition comprising:
   a hypervalent iodine compound represented by the following formula (1);
   a carboxy group-containing compound; and
   a solvent:

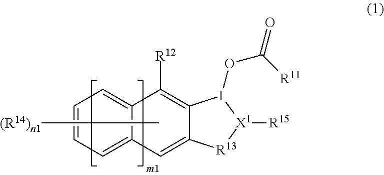

wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom;
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.
[2] The resist composition according to [1], wherein the carboxy group-containing compound is a polymer containing a repeating unit represented by the following formula (2) or a compound represented by the following formula (3):

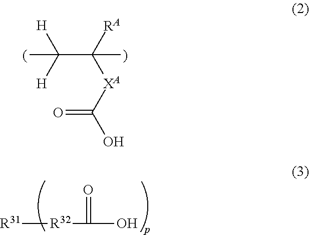

wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a mainchain;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted with a group containing a heteroatom, and some of —CH₂— in the p-valent hydrocarbon group are each optionally substituted with a group containing a heteroatom;
R³² is a single bond or a hydrocarbylene group having 1 to 10 carbon atoms, some or all of hydrogen atoms in the hydrocarbylene group are each optionally substituted with a group containing a heteroatom, and some of —CH₂— in the hydrocarbylene group are each optionally substituted with a group containing a heteroatom; and when “p” is 2, 3 or 4, R³²s are the same as or different from each other.
[3] The resist composition according to [1] or [2], further comprising at least one hypervalent iodine compound represented by the following formula (4) or (5):

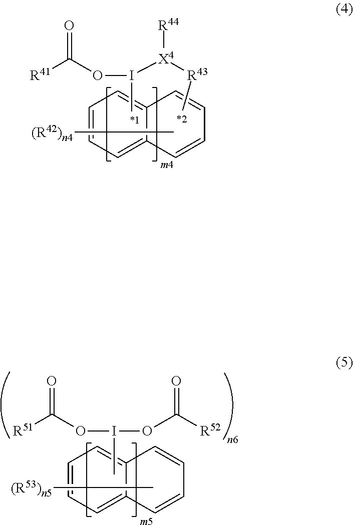

wherein m4 and m5 are each an integer of 0 to 2,
n4 is an integer of 0 to 3 when m4 is 0, or is an integer of 0 to 5 when m4 is 1, or is an integer of 0 to 7 when m4 is 2;
when m5 is 0, n6 is an integer of 1 to 3, n5 is an integer of 0 to 5, and 1≤(n5+n6)≤6 is satisfied;
when m5 is 1, n6 is an integer of 1 to 3, n5 is an integer of 0 to 7, and 1≤(n5+n6)≤8 is satisfied;
when m5 is 2, n6 is an integer of 1 to 3, n5 is an integer of 0 to 9, and 1≤(n5+n6)≤10 is satisfied;
*1 and *2 each represent a point of attachment to a carbon atom in an aromatic ring in the formula, provided that *1 and *2 have to be bound to adjacent carbon atoms in an aromatic ring;
R⁴¹ is a halogen atom, or a hydrocarbyl group having 1 to 10 carbon atoms and optionally containing a heteroatom;
R⁴² is a halogen atom, or a hydrocarbyl group having 1 to 40 carbon atoms and optionally containing a heteroatom; and when n4 is 2 to 7, R⁴²s are the same as or different from each other, and plural R⁴²s are optionally bound to each other to form a ring together with carbon atoms in an aromatic ring to which these are bound, provided that R⁴² is not bound to any carbon atom in an aromatic ring adjacent to *1;
R⁴³ is a carbonyl group, or a hydrocarbylene group having 1 to 10 carbon atoms and optionally containing a heteroatom;
X⁴ is an oxygen atom, a nitrogen atom, or a sulfur atom, and when X⁴ is a nitrogen atom, R⁴⁴ is present; and R⁴⁴ is a hydrogen atom, a carbonyl group, a halogen atom, or a hydrocarbyl group or ester having 1 to 20 carbon atoms and optionally containing a heteroatom;
R⁵¹ and R⁵² are each independently a halogen atom, or a hydrocarbyl group having 1 to 10 carbon atoms and optionally containing a heteroatom; and when n6 is 2 to 3, R⁵¹s and R⁵²s are the same as or different from each other; and
R⁵³ is a halogen atom, or a hydrocarbyl group having 1 to 40 carbon atoms and optionally containing a heteroatom; and when n5 is 2 to 9, R⁵³s are the same as or different from each other, and plural R⁵³s are optionally bound to each other to form a ring together with carbon atoms in an aromatic ring to which these are bound.
[4] A laminate comprising:
   a substrate; and
   a resist film on the substrate, the resist film being obtained from the resist composition according to any one of [1] to [3].
[5] The laminate according to [4], further comprising a resist underlayer film between the substrate and the resist film.
[6] The laminate according to [4] or [5], wherein the resist film contains a product of a ligand exchange reaction between the hypervalent iodine compound and the carboxy group-containing compound.
[7] A patterning process comprising the steps of:
   forming a resist film on a substrate or on a resist underlayer film on a substrate on which the resist underlayer film is laminated, with the resist composition according to any one of [1] to [3];
   exposing the resist film to a high energy ray; and
   developing the resist film having been exposed with a developer.
[8] The patterning process according to [7], wherein an i-ray, a KrF excimer laser, an ArF excimer laser, an electron beam or an extreme-ultraviolet ray is used as the high energy ray.
[9] The patterning process according to [7] or [8], wherein a developer that dissolves an exposed area and that does not dissolve an unexposed area is used as the developer.
[10] The patterning process according to [7] or [8], wherein a developer that dissolves an unexposed area and that does not dissolve an exposed area is used as the developer.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A resist composition comprising:
a hypervalent iodine compound represented by the following formula (1);
a carboxy group-containing compound; and
a solvent: 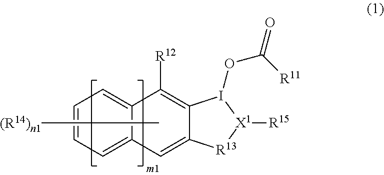
wherein m1 is an integer of 0 to 2, n1 is an integer of 0 to 3 when m1 is 0, or is an integer of 0 to 5 when m1 is 1, or is an integer of 0 to 7 when m1 is 2;
R¹¹ is a halogen atom, or a hydrocarbyl group having 1 to 10 carbon atoms and optionally containing a heteroatom;
R¹² is a halogen atom, or a hydrocarbyl group having 1 to 40 carbon atoms and optionally containing a heteroatom;
R¹⁴ is a halogen atom, or a hydrocarbyl group having 1 to 40 carbon atoms and optionally containing a heteroatom; and when n1 is 2 or more, R¹⁴s are the same as or different from each other, and plural R¹⁴s are optionally bound to each other to form a ring together with carbon atoms in an aromatic ring to which these are bound;
R¹³ is a carbonyl group, or a hydrocarbylene group having 1 to 10 carbon atoms and optionally containing a heteroatom;
X¹ is an oxygen atom, a nitrogen atom, or a sulfur atom, and when X¹ is a nitrogen atom, R¹⁵ is present; and R¹⁵ is a hydrogen atom, a carbonyl group, a halogen atom, or a hydrocarbyl group or ester having 1 to 20 carbon atoms and optionally containing a heteroatom.

2. The resist composition according to claim 1, wherein the carboxy group-containing compound is a polymer containing a repeating unit represented by the following formula (2) or a compound represented by the following formula (3): 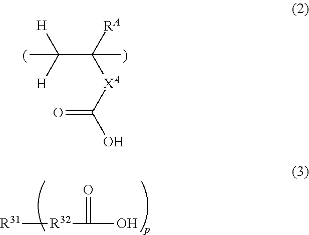
wherein R^{A} is a hydrogen atom, a halogen atom, a methyl group or a trifluoromethyl group;
X^{A} is a single bond, a phenylene group, a naphthylene group or *—C(═O)—O—X^{A1}—; X^{A1} is a saturated hydrocarbylene group having 1 to 10 carbon atoms, a phenylene group or a naphthylene group, and the saturated hydrocarbylene group optionally contains a hydroxy group, an ether bond, an ester bond or a lactone ring; and * represents a point of attachment to a carbon atom in a mainchain;
“p” is 1, 2, 3 or 4;
R³¹ is a p-valent hydrocarbon group having 1 to 40 carbon atoms or a p-valent heterocyclic group having 2 to 40 carbon atoms, and when “p” is 2, R³¹ is optionally an ether bond, a carbonyl group, an azo group, a thioether bond, a carbonate bond, a carbamate bond, a sulfinyl group or a sulfonyl group; and some or all of hydrogen atoms in the p-valent hydrocarbon group or the p-valent heterocyclic group are each optionally substituted with a group containing a heteroatom, and some of —CH₂— in the p-valent hydrocarbon group are each optionally substituted with a group containing a heteroatom;
R³² is a single bond or a hydrocarbylene group having 1 to 10 carbon atoms, some or all of hydrogen atoms in the hydrocarbylene group are each optionally substituted with a group containing a heteroatom, and some of —CH₂— in the hydrocarbylene group are each optionally substituted with a group containing a heteroatom; and when “p” is 2, 3 or 4, R³²s are the same as or different from each other.

3. The resist composition according to claim 1, further comprising at least one hypervalent iodine compound represented by the following formula (4) or (5): 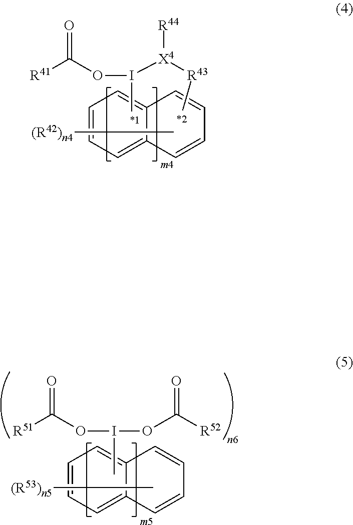
wherein m4 and m5 are each an integer of 0 to 2,
n4 is an integer of 0 to 3 when m4 is 0, or is an integer of 0 to 5 when m4 is 1, or is an integer of 0 to 7 when m4 is 2;
when m5 is 0, n6 is an integer of 1 to 3, n5 is an integer of 0 to 5, and 1≤(n5+n6)≤6 is satisfied;
when m5 is 1, n6 is an integer of 1 to 3, n5 is an integer of 0 to 7, and 1≤(n5+n6)≤8 is satisfied;
when m5 is 2, n6 is an integer of 1 to 3, n5 is an integer of 0 to 9, and 1≤(n5+n6)≤10 is satisfied;
*1 and *2 each represent a point of attachment to a carbon atom in an aromatic ring in the formula, provided that *1 and *2 have to be bound to adjacent carbon atoms in an aromatic ring;
R⁴¹ is a halogen atom, or a hydrocarbyl group having 1 to 10 carbon atoms and optionally containing a heteroatom;
R⁴² is a halogen atom, or a hydrocarbyl group having 1 to 40 carbon atoms and optionally containing a heteroatom; and when n4 is 2 to 7, R⁴²s are the same as or different from each other, and plural R⁴²s are optionally bound to each other to form a ring together with carbon atoms in an aromatic ring to which these are bound, provided that R⁴² is not bound to any carbon atom in an aromatic ring adjacent to *1;
R⁴³ is a carbonyl group, or a hydrocarbylene group having 1 to 10 carbon atoms and optionally containing a heteroatom;
X⁴ is an oxygen atom, a nitrogen atom, or a sulfur atom, and when X⁴ is a nitrogen atom, R⁴⁴ is present; and
R⁴⁴ is a hydrogen atom, a carbonyl group, a halogen atom, or a hydrocarbyl group or ester having 1 to 20 carbon atoms and optionally containing a heteroatom;
R⁵¹ and R⁵² are each independently a halogen atom, or a hydrocarbyl group having 1 to 10 carbon atoms and optionally containing a heteroatom; and when n6 is 2 to 3, R⁵¹s and R⁵²s are the same as or different from each other; and
R⁵³ is a halogen atom, or a hydrocarbyl group having 1 to 40 carbon atoms and optionally containing a heteroatom; and when n5 is 2 to 9, R⁵³s are the same as or different from each other, and plural R⁵³s are optionally bound to each other to form a ring together with carbon atoms in an aromatic ring to which these are bound.

4. A laminate comprising:
a substrate; and
a resist film on the substrate, the resist film being obtained from the resist composition according to claim 1.

5. A laminate comprising:
a substrate; and
a resist film on the substrate, the resist film being obtained from the resist composition according to claim 2.

6. A laminate comprising:
a substrate; and
a resist film on the substrate, the resist film being obtained from the resist composition according to claim 3.

7. The laminate according to claim 4, further comprising a resist underlayer film between the substrate and the resist film.

8. The laminate according to claim 4, wherein the resist film contains a product of a ligand exchange reaction between the hypervalent iodine compound and the carboxy group-containing compound.

9. A patterning process comprising the steps of:
forming a resist film on a substrate or on a resist underlayer film on a substrate on which the resist underlayer film is laminated, with the resist composition according to claim 1;
exposing the resist film to a high energy ray; and
developing the resist film having been exposed with a developer.

10. A patterning process comprising the steps of:
forming a resist film on a substrate or on a resist underlayer film on a substrate on which the resist underlayer film is laminated, with the resist composition according to claim 2;
exposing the resist film to a high energy ray; and
developing the resist film having been exposed with a developer.

11. A patterning process comprising the steps of:
forming a resist film on a substrate or on a resist underlayer film on a substrate on which the resist underlayer film is laminated, with the resist composition according to claim 3;
exposing the resist film to a high energy ray; and
developing the resist film having been exposed with a developer.

12. The patterning process according to claim 9, wherein an i-ray, a KrF excimer laser, an ArF excimer laser, an electron beam or an extreme-ultraviolet ray is used as the high energy ray.

13. The patterning process according to claim 9, wherein a developer that dissolves an exposed area and that does not dissolve an unexposed area is used as the developer.

14. The patterning process according to claim 9, wherein a developer that dissolves an unexposed area and that does not dissolve an exposed area is used as the developer.
